(19) United States
(12) Patent Application Publication
(10) Pub. No.: US 2026/0255869 A1
(43) Pub. Date: Aug. 27, 2026

(54) ORGANIC ELECTROLUMINESCENT MATERIALS AND DEVICES

(71) Applicant: UNIVERSAL DISPLAY CORPORATION, Ewing, NJ (US)

(72) Inventors: NICHOLAS J. THOMPSON, NEW HOPE, PA (US); HSIAO-FAN CHEN, LAWRENCE TOWNSHIP, NJ (US); SEAN MICHAEL RYNO, YARDLEY, PA (US); IVAN MILAS, SUMMIT, NJ (US)

(73) Assignee: UNIVERSAL DISPLAY CORPORATION, Ewing, NJ (US)

(21) Appl. No.: 19/645,710

(22) Filed: Apr. 13, 2026

Related U.S. Application Data
(63) Continuation of application No. 16/952,352, filed on Nov. 19, 2020.
(60) Provisional application No. 62/945,273, filed on Dec. 9, 2019.

(51) Int. Cl. H10K 85/30; C07F 15/00; C09K 11/02; C09K 11/06; H10K 50/11; H10K 101/10

(52) U.S. Cl. CPC H10K 85/346; C07F 15/0086; C09K 11/02; C09K 11/06; C09K 2211/1007; C09K 2211/1014; C09K 2211/1022; C09K 2211/1029; C09K 2211/1044; C09K 2211/185; H10K 50/11; H10K 2101/10

(57) ABSTRACT

Provided are organometallic compounds. Also provided are formulations comprising these organometallic compounds. Further provided are OLEDs and related consumer products that utilize these organometallic compounds.

### CROSS-REFERENCE TO RELATED APPLICATIONS

This application is a continuation of U.S. patent application Ser. No. 16/952,352, filed on Nov. 19, 2020, which claims priority under 35 U.S.C. § 119(e) to U.S. Provisional Application No. 62/945,273, filed on Dec. 9, 2019, the entire contents of which are incorporated herein by reference.

### FIELD

The present disclosure generally relates to organometallic compounds and formulations and their various uses including as emitters in devices such as organic light emitting diodes and related electronic devices.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as flat panel displays, illumination, and backlighting.

One application for phosphorescent emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light.

In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

In one aspect, the present disclosure provides a compound comprising a ligand L_{A} of

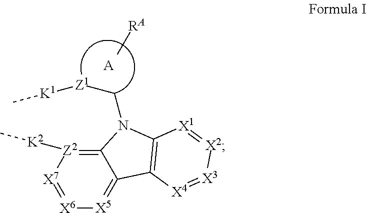

wherein one of Z¹ and Z² is C and the other is N; each of K¹ and K² is independently a direct bond, S, or O; ring A is a 5-membered or 6-membered carbocyclic or heterocyclic ring; R^{A} represents zero, mono, or up to the maximum allowed number of substitutions to its associated ring; each of X¹—X⁷ is independently N or CR; at least one of R and R^{A} has a structure of

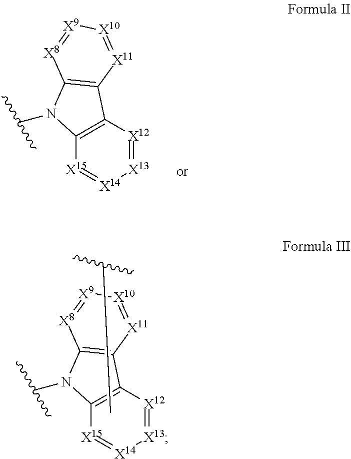

wherein: each of X⁸—X¹⁵ is independently N or CR′, the particular one of X⁸—X¹⁵ that is bonded to one of X¹—X⁷ or ring A of Formula I is C; the maximum number of N atoms that can connect to each other within a ring is two; each of the remaining R and R^{A} is independently a hydrogen, Formula II, Formula III, or a substituent selected from the group consisting of the general substituents defined herein; each of R′ and R^{B} is independently a hydrogen, or a substituent selected from the group consisting of the general substituents defined herein; the ligand L_{A} is coordinated to a metal M by the indicated dash lines; the ligand L_{A} can be linked with other ligands to form a tridentate or tetradentate ligand; M is Pd or Pt, and can be coordinated to additional ligands; and any two adjacent R, R′, or R^{A} can be joined or fused together to form a ring.

In another aspect, the present disclosure provides a formulation of a compound comprising a ligand L_{A} of Formula I as described herein.

In yet another aspect, the present disclosure provides an OLED having an organic layer comprising a compound comprising a ligand L_{A} of Formula I as described herein.

In yet another aspect, the present disclosure provides a consumer product comprising an OLED with an organic layer comprising a compound comprising a ligand L_{A} of Formula I as described herein.

### BRIEF DESCRIPTION OF THE DRAWINGS

FIG. 1 shows an organic light emitting device.

FIG. 2 shows an inverted organic light emitting device that does not have a separate electron transport layer.

### DETAILED DESCRIPTION

### A. Terminology

Unless otherwise specified, the below terms used herein are defined as follows:

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level.

Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value.

Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

The terms “halo,” “halogen,” and “halide” are used interchangeably and refer to fluorine, chlorine, bromine, and iodine.

The term “acyl” refers to a substituted carbonyl radical (C(O)—Rₛ).

The term “ester” refers to a substituted oxycarbonyl (—O—C(O)—Rₛ or —C(O)—O—Rₛ) radical.

The term “ether” refers to an —ORₛ radical.

The terms “sulfanyl” or “thio-ether” are used interchangeably and refer to a —SRₛ radical.

The term “sulfinyl” refers to a —S(O)—Rₛ radical.

The term “sulfonyl” refers to a —SO₂—Rₛ radical.

The term “phosphino” refers to a —P(Rₛ)₃ radical, wherein each Rₛ can be same or different.

The term “silyl” refers to a —Si(Rₛ)₃ radical, wherein each Rₛ can be same or different.

The term “boryl” refers to a —B(Rₛ)₂ radical or its Lewis adduct —B(Rₛ)₃ radical, wherein Rₛ can be same or different.

In each of the above, Rₛ can be hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. Preferred Rₛ is selected from the group consisting of alkyl, cycloalkyl, aryl, heteroaryl, and combination thereof.

The term “alkyl” refers to and includes both straight and branched chain alkyl radicals. Preferred alkyl groups are those containing from one to fifteen carbon atoms and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group may be optionally substituted.

The term “cycloalkyl” refers to and includes monocyclic, polycyclic, and spiro alkyl radicals. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group may be optionally substituted.

The terms “heteroalkyl” or “heterocycloalkyl” refer to an alkyl or a cycloalkyl radical, respectively, having at least one carbon atom replaced by a heteroatom. Optionally the at least one heteroatom is selected from O, S, N, P, B, Si and Se, preferably, O, S or N. Additionally, the heteroalkyl or heterocycloalkyl group may be optionally substituted.

The term “alkenyl” refers to and includes both straight and branched chain alkene radicals. Alkenyl groups are essentially alkyl groups that include at least one carbon-carbon double bond in the alkyl chain. Cycloalkenyl groups are essentially cycloalkyl groups that include at least one carbon-carbon double bond in the cycloalkyl ring. The term “heteroalkenyl” as used herein refers to an alkenyl radical having at least one carbon atom replaced by a heteroatom. Optionally the at least one heteroatom is selected from O, S, N, P, B, Si, and Se, preferably, O, S, or N.

Preferred alkenyl, cycloalkenyl, or heteroalkenyl groups are those containing two to fifteen carbon atoms.

Additionally, the alkenyl, cycloalkenyl, or heteroalkenyl group may be optionally substituted.

The term “alkynyl” refers to and includes both straight and branched chain alkyne radicals. Alkynyl groups are essentially alkyl groups that include at least one carbon-carbon triple bond in the alkyl chain. Preferred alkynyl groups are those containing two to fifteen carbon atoms. Additionally, the alkynyl group may be optionally substituted.

The terms “aralkyl” or “arylalkyl” are used interchangeably and refer to an alkyl group that is substituted with an aryl group. Additionally, the aralkyl group may be optionally substituted.

The term “heterocyclic group” refers to and includes aromatic and non-aromatic cyclic radicals containing at least one heteroatom. Optionally the at least one heteroatom is selected from O, S, N, P, B, Si, and Se, preferably, O, S, or N. Hetero-aromatic cyclic radicals may be used interchangeably with heteroaryl. Preferred hetero-non-aromatic cyclic groups are those containing 3 to 7 ring atoms which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group may be optionally substituted.

The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group may be optionally substituted.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The terms alkyl, cycloalkyl, heteroalkyl, heterocycloalkyl, alkenyl, cycloalkenyl, heteroalkenyl, alkynyl, aralkyl, heterocyclic group, aryl, and heteroaryl, as used herein, are independently unsubstituted, or independently substituted, with one or more general substituents.

In many instances, the general substituents are selected from the group consisting of deuterium, halogen, alkyl, cycloalkyl, heteroalkyl, heterocycloalkyl, arylalkyl, alkoxy, aryloxy, amino, silyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof.

In some instances, the preferred general substituents are selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, sulfanyl, and combinations thereof.

In some instances, the preferred general substituents are selected from the group consisting of deuterium, fluorine, alkyl, cycloalkyl, alkoxy, aryloxy, amino, silyl, boryl, aryl, heteroaryl, sulfanyl, and combinations thereof.

In yet other instances, the more preferred general substituents are selected from the group consisting of deuterium, fluorine, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H.

Similarly, when R¹ represents zero or no substitution, R′, for example, can be a hydrogen for available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2, 2′ positions in a biphenyl, or 1, 8 position in a naphthalene, as long as they can form a stable fused ring system.

### B. The Compounds of the Present Disclosure

In one aspect, the present disclosure provides a compound comprising a ligand L_{A} of

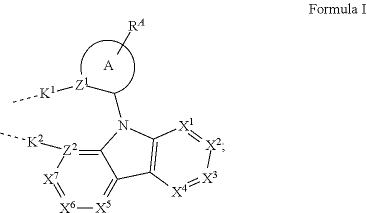

wherein:
one of Z¹ and Z² is C and the other is N;
each of K¹ and K² is independently a direct bond, S, or O;
ring A is a 5-membered or 6-membered carbocyclic or heterocyclic ring;
R^{A} represents zero, mono, or up to the maximum allowed number of substitutions to its associated ring; each of X¹—X⁷ is independently N or CR;
at least one of R and R^{A} has a structure of

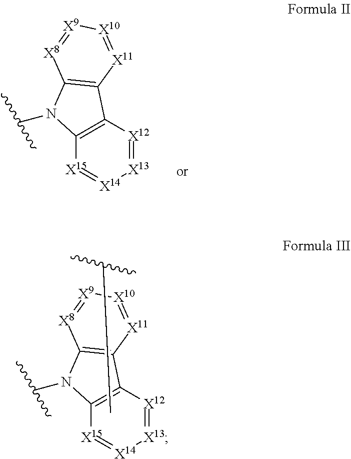

wherein: each squiggly line represents a bond to the relevant part of Formula I;
each of X⁸—X¹⁵ is independently N or CR′, the particular one of X⁸—X¹⁵ that is bonded to one of X¹—X⁷ or ring A of Formula I is C;
the maximum number of N atoms that can connect to each other within a ring is two;
each of the remaining R and R^{A} is independently a hydrogen, Formula II, Formula III, or a substituent selected from the group consisting of then general substituents defined herein;
each of R′ and R^{B} is independently a hydrogen or a substituent selected from the group consisting of the general substituents defined herein;
the ligand L_{A} is coordinated to a metal M by the indicated dash lines;
the ligand L_{A} can be linked with other ligands to form a tridentate or tetradentate ligand;
M is Pd or Pt, and can be coordinated to additional ligands; and
any two adjacent R, R′, or R^{A} can be joined or fused together to form a ring.

In some embodiments, one R can have a structure of Formula II or Formula III. In some embodiments, one R^{A} can have a structure of Formula II or Formula III.

In some embodiments, in addition to at least one of R and R^{A} having a structure of Formula II or Formula III, each of the remaining R and R^{A} can be independently a hydrogen or a substituent selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, sulfanyl, and combinations thereof.

In some embodiments, K¹ and K² can be each a direct bond. In some embodiments, one of K¹ or K² can be O.

In some embodiments, X¹—X⁷ can each be independently CR, and X¹—X¹⁵ can each be independently C or CR′. In some embodiments, one of X¹—X¹¹ can be N, and the remainder can each be independently CR for X¹—X⁷ and independently C or CR′ for X¹—X¹⁵. In some embodiments, one of X¹—X⁴ can be N, and the remainder of X¹—X¹⁵ can each be independently CR for X¹—X⁷ and independently C or CR′ for X¹—X¹⁵. In some embodiments, one of X¹—X⁷ can be N, and the remainder of X¹—X¹¹ can each be independently CR for X¹—X⁷ and independently C or CR′ for X⁸—X¹⁵. In some embodiments, one of X⁸—X¹¹ can be N, and the remainder of X¹—X¹⁵ can each be independently CR for X¹—X⁷ and independently C or CR′ for X⁸—X¹¹. In some embodiments, one of X¹²—X¹¹ can be N, and the remainder of X¹-X¹⁵ can each be independently CR for X¹—X⁷ and independently C or CR′ for X⁸—X^{1′}. In some embodiments, two of X¹—X¹⁵ can be N, and the remainder of X¹—X¹⁵ can each be independently CR for X¹—X⁷ and independently C or CR′ for X¹—X¹⁵. In some embodiments, two of X¹—X⁷ can be N, and the remainder of X¹—X¹⁵ can each be independently CR for X¹—X⁷ and independently C or CR′ for X¹—X¹⁵. In some embodiments, two of X¹—X¹⁵ can be N, and the remainder of X¹—X⁵ can each be independently CR for X¹—X⁷ and independently C or CR′ for X¹—X¹¹. In some embodiments, one of X¹—X⁷ can be N, one of X¹—X¹¹ can be N, and the remainder of X¹—X¹¹ can each be independently CR for X¹—X⁷ and independently C or CR′ for X¹—X¹⁵.

In some embodiments, Z¹ can be N, and Z² can be C. In some embodiments, Z¹ can be C, and Z² can be N.

In some embodiments, ring A can be a 5-membered or 6-membered aromatic ring. In some embodiments, ring A can be selected from the group consisting of pyrimidine, pyridine, pyridazine, pyrazine, triazine, benzene, imidazole, triazole, pyrazole, isothiazole, oxazole, and thiazole. In some embodiments, ring A can be selected from the group consisting of pyridine, pyrimidine, benzene, and imidazole.

In some embodiments, the compound can comprise a ligand L_{A} of

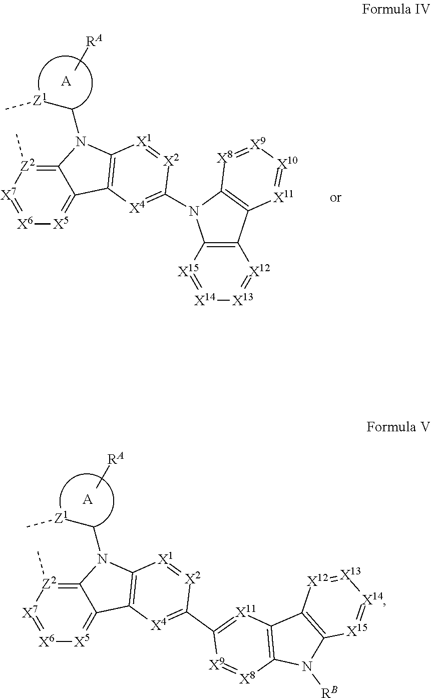

wherein X¹—X¹⁵, Z¹, Z², R, R^{A}, R^{B} and ring A are all same as defined above for Formula I.

In the above embodiments, ring A can be pyrimidine, pyridine, pyridazine, pyrazine, triazine, benzene, imidazole, triazole, pyrazole, isothiazole, oxazole, or thiazole. In some embodiments, ring A can be pyridine, pyrimidine, imidazole, or benzene.

In the above embodiments, R^{A} can be an alkyl, a cycloalkyl, an aryl, a heteroaryl, or a combination thereof.

In some embodiments, R^{A} can be an alkyl, or a cycloalkyl.

In some embodiments, the ligand L_{A} can be a tetradentate ligand.

In some embodiments, the compound can have a structure of

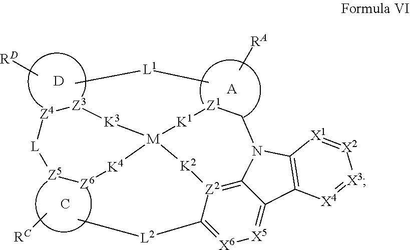

wherein:
each of X¹—X⁶ is independently N or CR;
at least one of R and R^{A} has a structure of

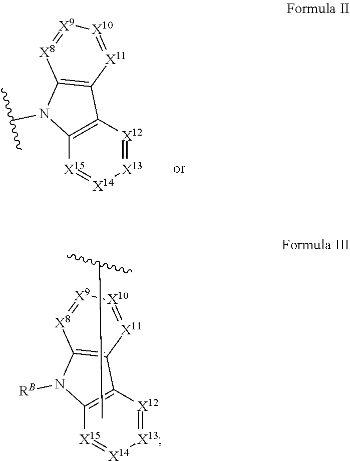

wherein: each squiggly line represents a bond to the relevant part of Formula VI;
each of X⁸—X¹⁵ is independently N or CR′, the particular one of X⁸—X¹⁵ that is bonded to one of X¹—X⁶ or ring A of Formula I is C; rings C and D are each independently a 5-membered or 6-membered carbocyclic or heterocyclic ring;
each of K¹, K², K³ or K⁴ is independently a direct bond, S, or O, with at least two of them being direct bonds;
Z³, Z⁴, Z⁵, and Z⁶ are each independently C or N;
L, L¹, and L² are each independently selected from the group consisting of a direct bond, being absent, O, S, CR″R″′, SiR″R″′, BR″, and NR″, wherein at least one of L¹ and L² is present;
R^{C} and R^{D} each independently represent zero, mono, or up to the maximum allowed number of substitutions to its associated ring;
each of R″, R″′, R^{C}, and R^{D} is independently a hydrogen or a substituent selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, sulfanyl, and combinations thereof;
M is Pd or Pt;
any two adjacent R, R′, R″, R″′, R^{A}, R^{B}, R^{C}, or R^{D} can be joined or fused together to form a ring where chemically feasible; and X¹—X⁶, X⁸—X¹⁵, Z¹, Z², R^{A}, R^{B} and ring A are all defined the same as above.

In some of the above embodiments, ring C can be a 5-membered or 6-membered heteroaromatic ring. In some embodiments, ring C and ring D can both be 6-membered aromatic rings. In some embodiments, ring C and ring D can both be independently pyrimidine, pyridine, pyridazine, pyrazine, triazine, or benzene. In some embodiments, ring D can be a 5-membered heteroaromatic ring. In some embodiments, ring D can be imidazole, triazole, pyrazole, isothiazole, oxazole, or thiazole ring.

In some of the above embodiments, two R^{D} substituents can be joined to form a fused ring. In some embodiments, two R^{C} substituents can be joined to form a fused ring system. In some embodiments, the fused ring can be a 6-membered aromatic ring.

In some embodiments, each of K¹, K², K³ or K⁴ can be independently a direct bond. In some embodiments, one of K¹, K², K³ or K⁴ can be O. In some embodiments, one of K¹ or K² can be O. In some embodiments, one of K³ or K⁴ can be O.

In some of the above embodiments, Z³ can be N and Z⁶ can be C. In some embodiments, Z³ can be C and Z⁶ can be N. In some embodiments, both Z³ and Z⁶ can be C. In some embodiments, both Z⁴ and Z⁵ can be C. In some embodiments, Z⁴ can be N and Z⁵ can be C.

In some of the above embodiments, L can be a direct bond. In some embodiments, L can be NR″. In some embodiments, L¹ can be absent. In some embodiments, L² can be O, NR″, or CR″R″′. In some embodiments, L² can be O. In some embodiments, L can be a direct bond, L¹ can be absent, and L² can be O.

In some embodiments, M can be Pd. In some embodiments, M can be Pt.

In some embodiments, the compound can be selected from the group consisting of:

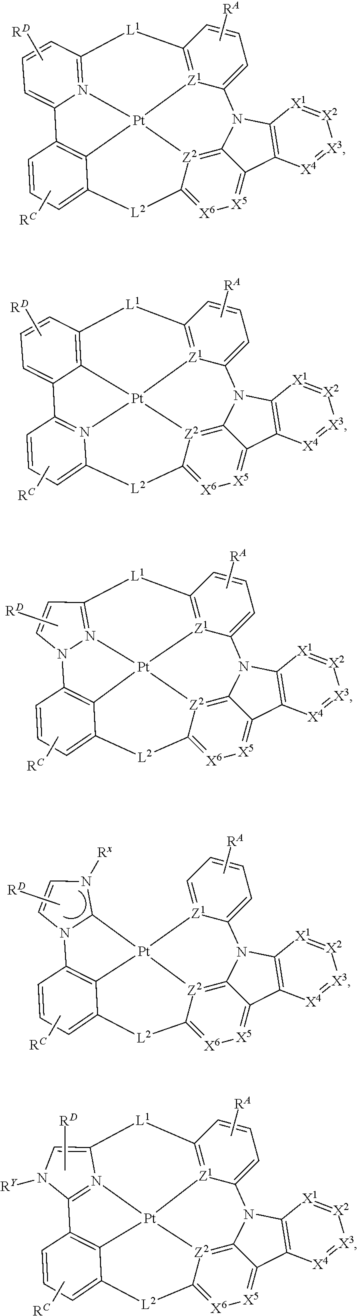

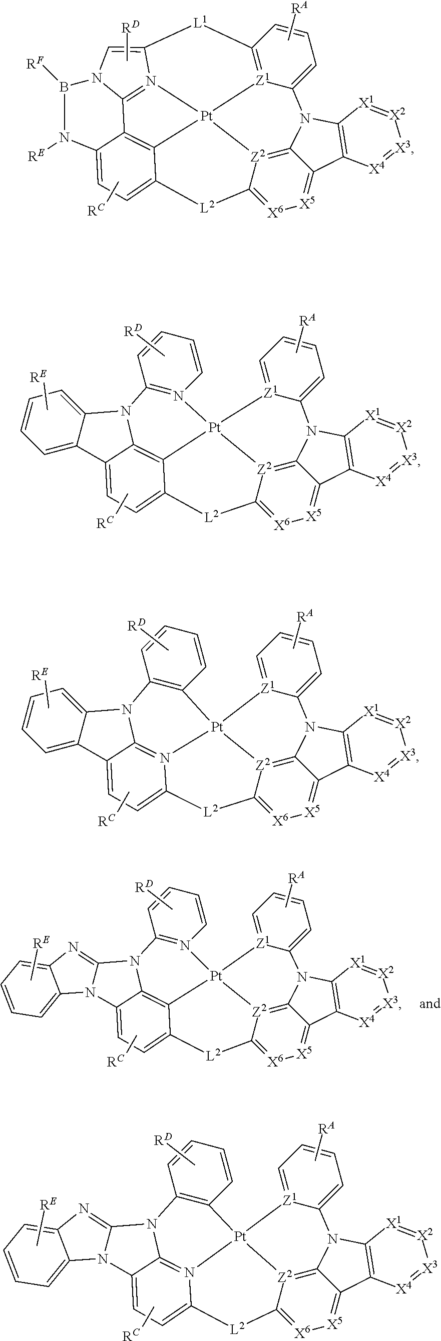

wherein: each of X¹—X⁶ is independently N or CR; and at least one R or R^{A} has a structure of

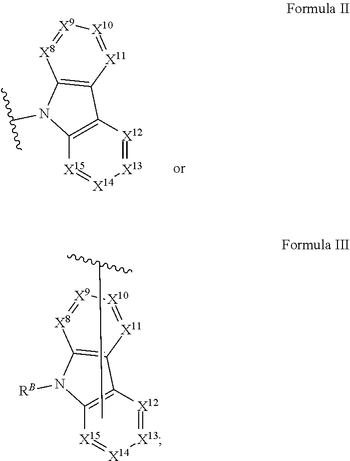

wherein: each squiggly line represents a bond to the relevant part of the base compound structure;
each of X⁸—X¹⁵ is independently N or CR′, the particular one of X⁸—X¹⁵ that is bonded to one of X¹—X⁶ is C;
R^{x} and R^{y} are each independently selected from the group consisting of alkyl, cycloalkyl, heteroalkyl, heterocycloalkyl, aryl, heteroaryl, and combinations thereof;
R^{E} for each occurrence is independently a hydrogen or a substituent selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, sulfanyl, and combinations thereof; and
X¹—X⁶, X⁸—X¹⁵, Z, Z², R^{A}, R^{B}, R^{C}, R^{D}, L¹ and L² are all same as defined above for Formula I and Formula VI.

In the above embodiments, L¹ can be absent. In the above embodiments, L² can be O, NR″, or CR″R″′.

In some embodiments, the compound can be selected from the group consisting of the structures listed in LIST 1 below:

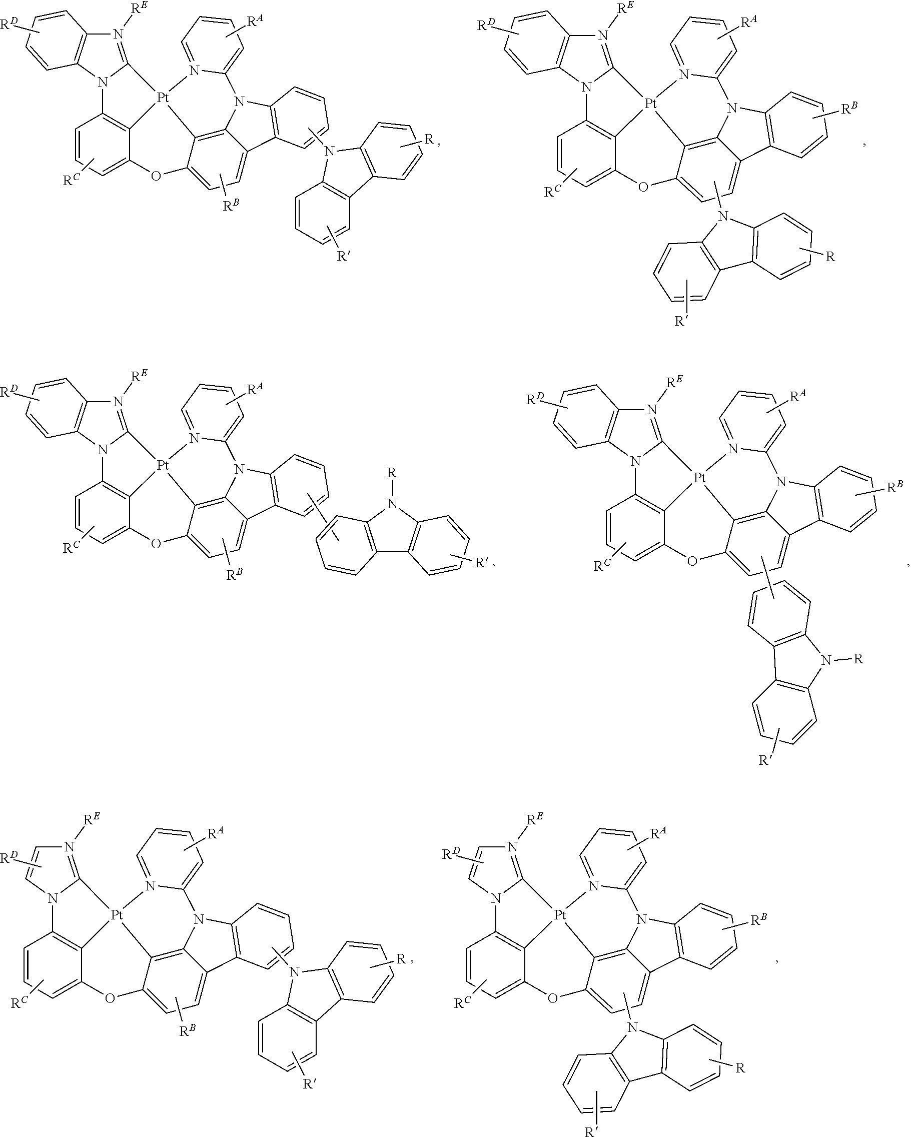

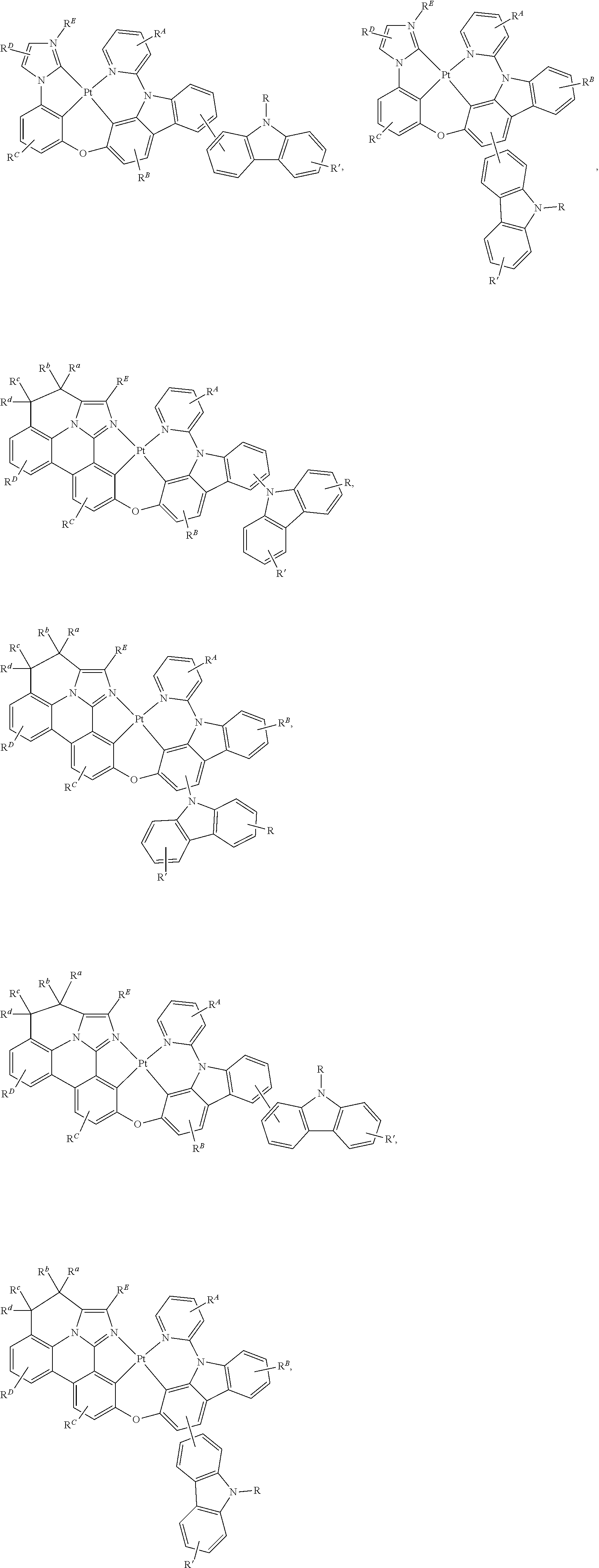

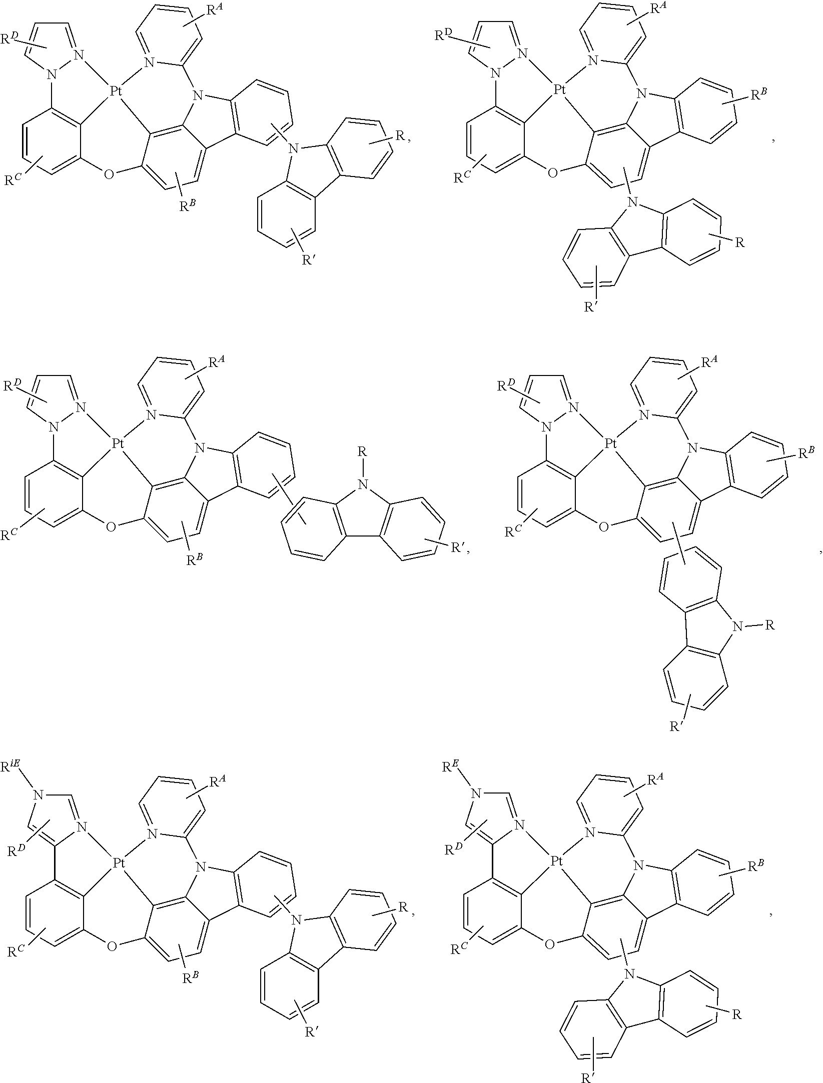

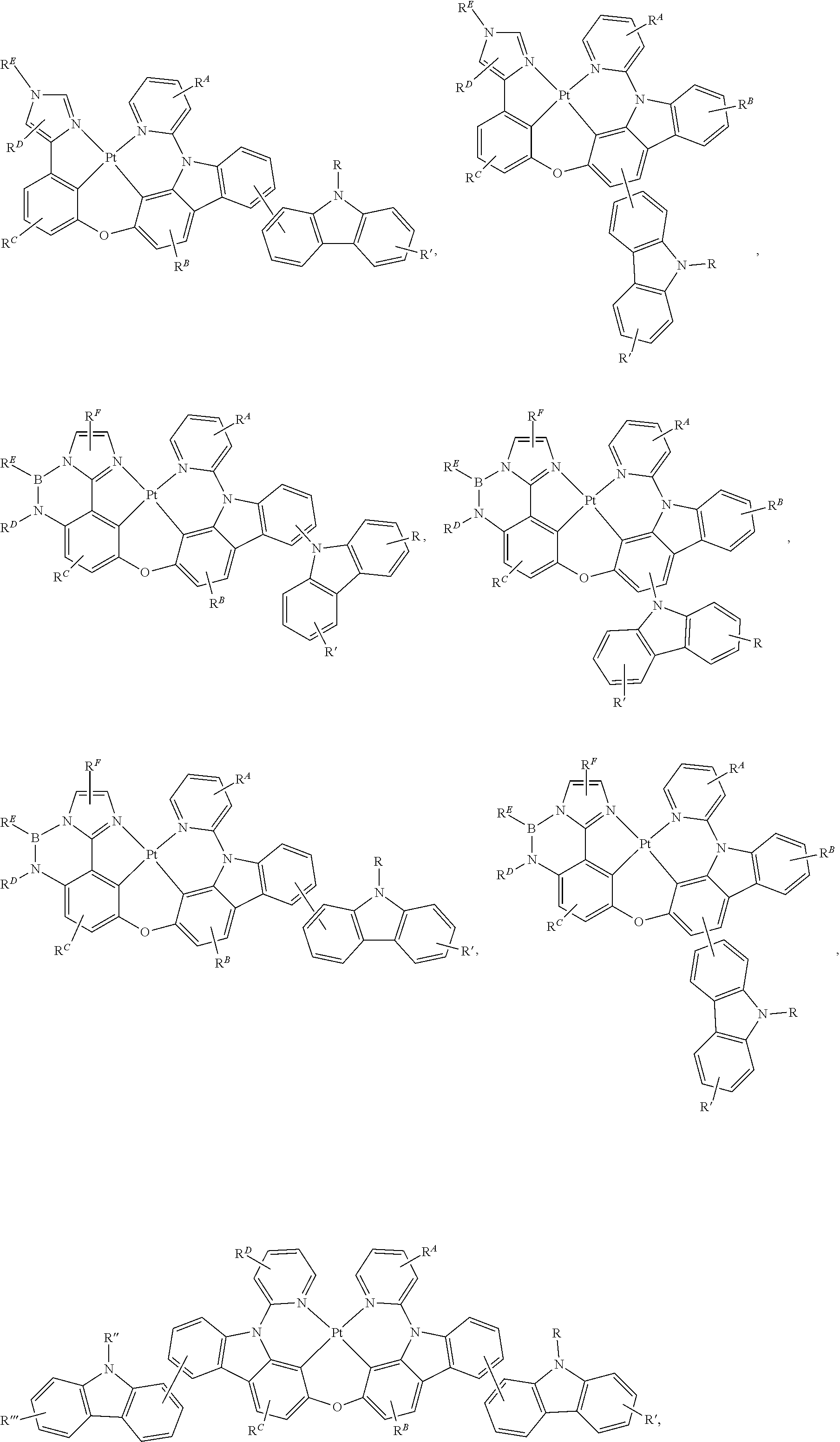

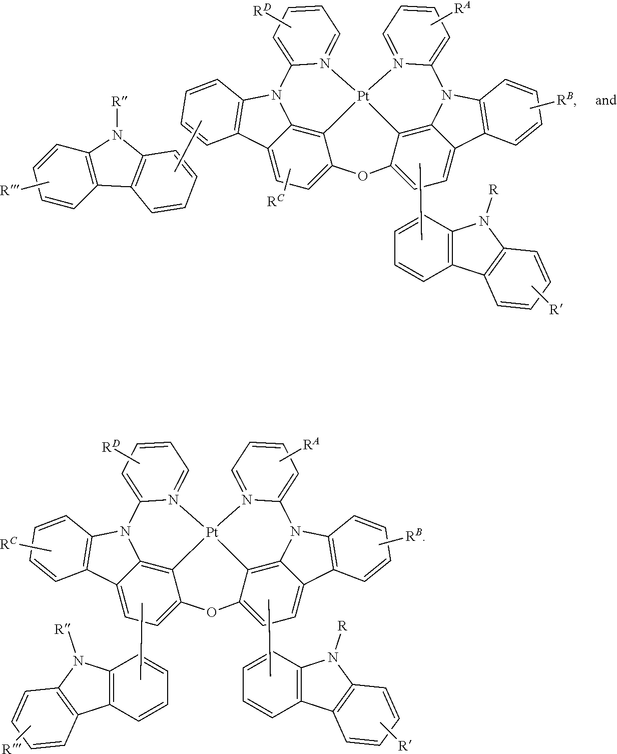

In some embodiments, the compound can be selected from the group consisting of Compound (l)-I-(A′i)(Bj)(Bk) to Compound (l)-XIV-(A′i)(Bj)(Bk), wherein l,i,j, and k are as defined below, and each Compound having the formula of Pt(L_{A})(L_{B}) with the following structure:

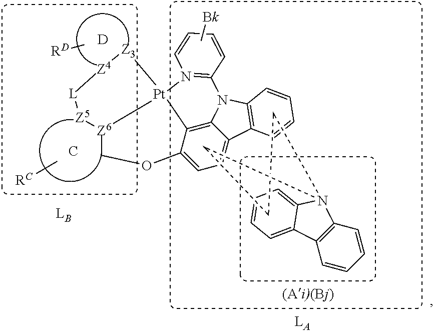

wherein L_{A} has the structure shown above and is selected from the group consisting of I-(A′i)(Bj)(Bk) to XIV-(A′i)(Bj)(Bk), wherein i is an integer from 1 to 7 and k is an integer from 1 to 47, and when i=1 to 3, j is an integer from 1 to 41, and when i=4 to 7, j is an integer from 1 to 47;
wherein L_{B} has the structure shown above and is selected from the group consisting of Ll, wherein l is an integer from 1 to 230107;
wherein rings C and D are as defined above for Formula VI; or
   the compound can be selected from the group consisting of Compound [I-(A′i)(Bj)(Bk)][I-(A′m)(Bn)(Bo)] to Compound [XIV-(A′i)(Bj)(Bk)][XIV-(A′m)(Bn)(Bo)], each Compound having the formula of Pt(L_{A})(L_{C}) with the
following structure:

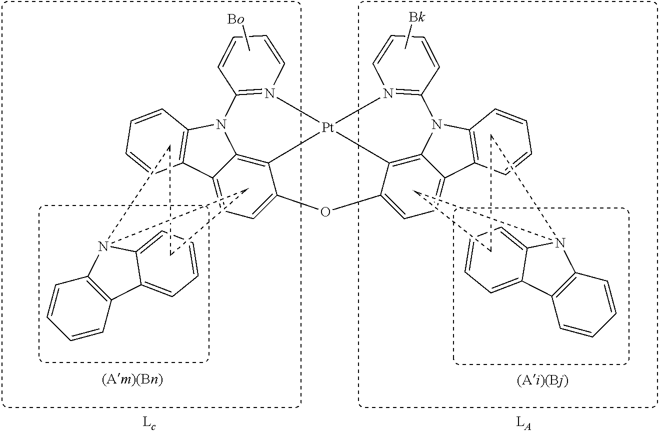

wherein L_{A} is as defined above;
wherein L_{C} has the structure shown above and is selected from the group consisting of I-(A′m)(Bn)(Bo) to XIV-(A′m)(Bn)(Bo);
wherein Ll for each occurrence independently has the structure defined in the following LIST 2 below, wherein each squiggly line in each structure is independently for linking to the relevant part of L_{A}:

| Ll | Structure of Ll | Ar¹, Ar², Ar³, R¹, R² |
|---|---|---|
| for each Ll, wherein l = 330(p − 1) + q, wherein p is an integer from 1 to 30, and q is an integer from 1 to 330, | thus defined ligands L1 to L9900 each has a structure of 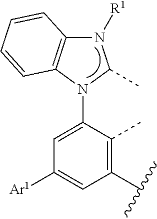 | wherein Ar¹ = Ap, and R¹ = Rq, and |
| for each Ll, wherein l = 330(p − 1) + q + 9900, wherein p is an integer from 1 to 30, and q is an integer from 1 to 330, | thus defined ligands L9901 to L19800 each has a structure of 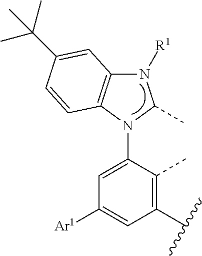 | wherein Ar¹ = Ap and R¹ = Rq, and |
| for each Ll, wherein l = 330(p − 1) + q + 19800, wherein p is an integer from 1 to 30, and q is an integer from 1 to 330, | thus defined ligands Ll9801 to L29700 each has a structure of 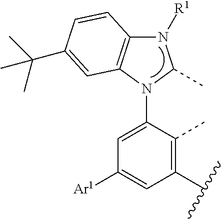 | wherein Ar¹ = Ap and R¹ = Rq, and |
| for each Ll, wherein l = 330(p − 1) + q + 29700, wherein p is an integer from 1 to 30, and q is an integer from 1 to 330, | thus defined ligands L29701 to L39600 each has a structure of 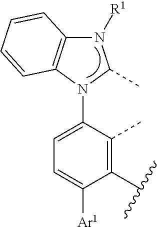 | wherein Ar¹ = Ap and R¹ = Rq, and |
| for each Ll, wherein l = 330(p − 1) + q + 39600, wherein p is an integer from 1 to 30, and q is an integer from 1 to 330, | thus defined ligands L39601 to L49500 each has a structure of 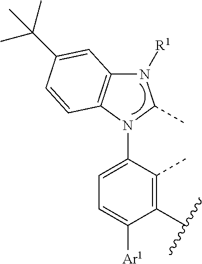 | wherein Ar¹ = Ap and R¹ = Rq, and |
| for each Ll, wherein l = 330(p − 1) + q + 49500, wherein p is an integer from 1 to 30, and q is an integer from 1 to 330, | thus defined ligands L49501 to L59400 each has a structure of 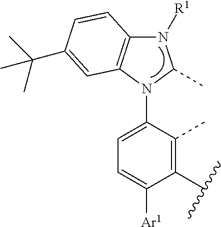 | wherein Ar¹ = Ap and R¹ = Rq, and |
| for each Ll, wherein l = 330(p − 1) + q + 59400, wherein p is an integer from 1 to 30, and q is an integer from 1 to 330, | thus defined ligands L59401 to L69300 each has a structure of 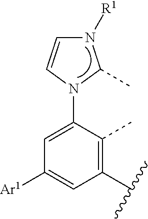 | wherein Ar¹ = Ap and R¹ = Rq, and |
| for each Ll, wherein l = 330(p − 1) + q + 69300, wherein p is an integer from 1 to 30, and q is an integer from 1 to 330, | thus defined ligands L69301 to L79200 each has a structure of 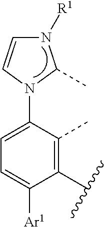 | wherein Ar¹ = Ap and R¹ = Rq, and |
| for each Ll, wherein l = q + 79200, wherein q is an integer from 1 to 330, | thus defined ligands L79201 to L79530 each has a structure of 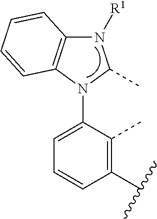 | wherein R¹ = Rq, and |
| for each Ll, wherein l = q + 79530, wherein q is an integer from 1 to 330, | thus defined ligands L79531 to L79860 each has a structure of 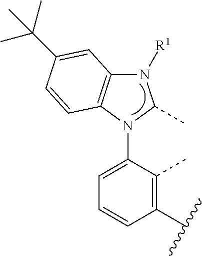 | wherein R¹ = Rq, and |
| for each Ll, wherein l = q + 79860, wherein q is an integer from 1 to 330, | thus defined ligands L79861 to L80190 each has a structure of 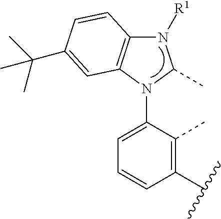 | wherein R¹ = Rq, and |
| for each Ll, wherein l = q + 80190, wherein q is an integer from 1 to 330, | thus defined ligands L80191 to L80520 each has a structure of 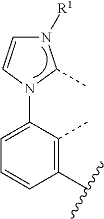 | wherein R¹ = Rq, and |
| for each Ll, wherein l = 330(p − 1) + q + 80520, wherein p is an integer from 1 to 30, and q is an integer from 1 to 330, | thus defined ligands L80521 to L81510 each has a structure of 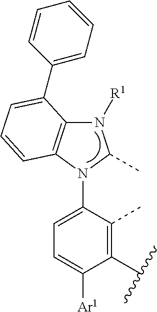 | wherein Ar¹ = Ap and R¹ = Rq, and |
| for each Ll, wherein l = q + 81510, wherein q is an integer from 1 to 330, | thus defined ligands L81511 to L82500 each has a structure of 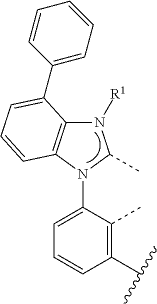 | wherein R¹ = Rq, and |
| for each Ll, wherein l = q + 82500, wherein q is an integer from 1 to 330, | thus defined ligands L82501 to L82830 each has a structure of 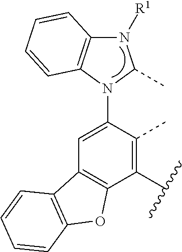 | wherein R¹ = Rq, and |
| for each Ll, wherein l = q + 82830, wherein q is an integer from 1 to 330, | thus defined ligands L82831 to L83160 each has a structure of 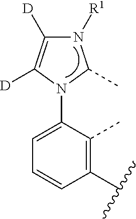 | wherein R¹ = Rq, and |
| for each Ll, wherein l = 330(p − 1) + q + 83160, wherein p is an integer from 1 to 30, and q is an integer from 1 to 330, | thus defined ligands L83161 to L84150 each has a structure of 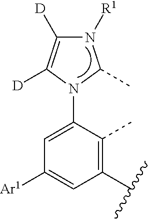 | wherein Ar¹ = Ap and R¹ = Rq, and |
| for each Ll, wherein l = 330(p − 1) + q + 84150, wherein p is an integer from 1 to 30, and q is an integer from 1 to 330, | thus defined ligands L84151 to L85140 each has a structure of 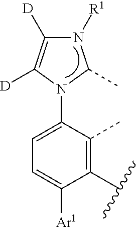 | wherein Ar¹ = Ap and R¹ = Rq, and |
| for each Ll, wherein l = q + 85140, wherein q is an integer from 1 to 330, | thus defined ligands L85141 to L85470 each has a structure of 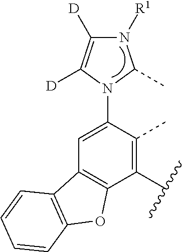 | wherein R¹ = Rq, and |
| for each Ll, wherein l = q + 85470, wherein q is an integer from 1 to 330, | thus defined ligands L85471 to L85800 each has a structure of 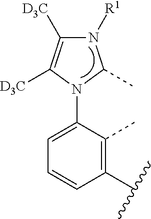 | wherein R¹ = Rq, and |
| for each Ll, wherein l = 330(p − 1) + q + 85800, wherein p is an integer from 1 to 30, and q is an integer from 1 to 330, | thus defined ligands L85801 to L86790 each has a structure of 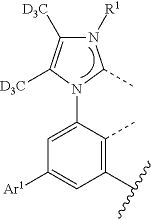 | wherein Ar¹ = Ap and R¹ = Rq, and |
| for each Ll, wherein l = 330(p − 1) + q + 8679, wherein p is an integer from 1 to 30, and q is an integer from 1 to 330, | thus defined ligands L86791 to L87780 each has a structure of 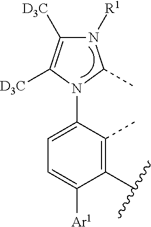 | wherein Ar¹ = Ap and R¹ = Rq, and |
| for each Ll, wherein l = q + 87780, wherein q is an integer from 1 to 330, | thus defined ligands L87781 to L88110 each has a structure of 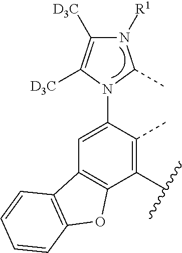 | wherein R¹ = Rq, and |
| for each Ll, wherein l = r + 88110, wherein r is an integer from 1 to 30, | thus defined ligands L88111 to L88140 each has a structure of 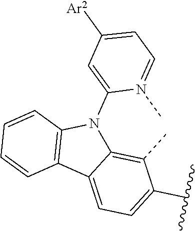 | wherein Ar² = Ar, and |
| | wherein ligand L88141 has the structure 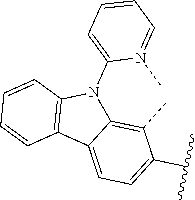 | |
| for each Ll, wherein l = 30(r − 1) + s + 88141, wherein r is an integer from 1 to 30, and s is an integer from 1 to 30, | thus defined ligands L88142 to L89041 each has a structure of 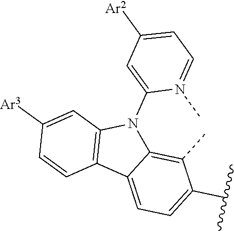 | wherein Ar² = Ar and Ar³ = As, and |
| for each Ll, wherein l = r + 89041, wherein r is an integer from 1 to 30, | thus defined ligands L89042 to L89071 each has a structure of 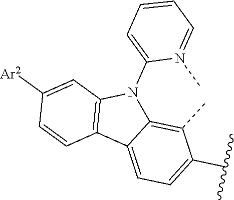 | wherein Ar² = Ar, and |
| for each Ll, wherein l = 30(r − 1) + s + 89071, wherein r is an integer from 1 to 30, and s is an integer from 1 to 30, | thus defined ligands L89072 to L89971 each has a structure of 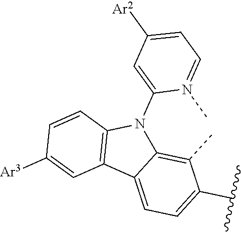 | wherein Ar² = Ar and Ar³ = As, and |
| for each Ll, wherein l = r + 89971, wherein r is an integer from 1 to 30, | thus defined ligands L89972 to L90001 each has a structure of 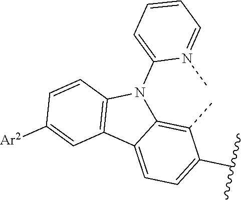 | wherein Ar² = Ar, and |
| for each Ll, wherein l = r + 90001, wherein r is an integer from 1 to 30, | thus defined ligands L90002 to L90031 each has a structure of 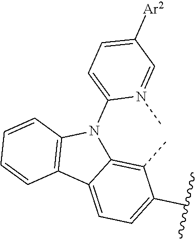 | wherein Ar² = Ar, and |
| for each Ll, wherein l = 30(r − 1) + s + 90031, wherein r is an integer from 1 to 30, and s is an integer from 1 to 30, | thus defined ligands L90032 to L90931 each has a structure of 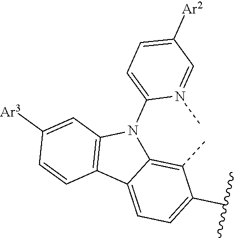 | wherein Ar² = Ar and Ar³ = As, and |
| for each Ll, wherein l = 30(r − 1) + s + 90931, wherein r is an integer from 1 to 30, and s is an integer from 1 to 30, | thus defined ligands L90932 to L91831 each has a structure of 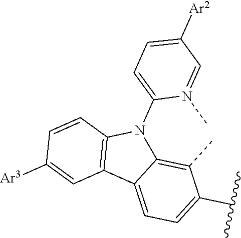 | wherein Ar² = Ar and Ar³ = As, and |
| for each Ll, wherein l = 30(r − 1) + s + 91831, wherein r is an integer from 1 to 30, and s is an integer from 1 to 30, | thus defined ligands L91832 to L92731 each has a structure of 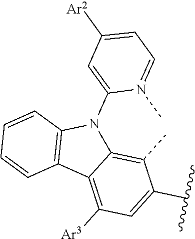 | wherein Ar² = Ar and Ar³ = As, and |
| for each Ll, wherein l = r + 92731, wherein r is an integer from 1 to 30, | thus defined ligands L92732 to L92761 each has a structure of 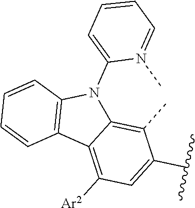 | wherein Ar² = Ar, and |
| for each Ll, wherein l = 30(r − 1) + s + 92761, wherein r is an integer from 1 to 30, and s is an integer from 1 to 30, | thus defined ligands L92762 to L93661 each has a structure of 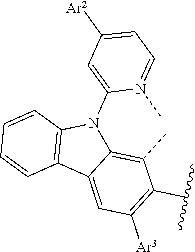 | wherein Ar² = Ar and Ar³ = As, and |
| for each Ll, wherein l = r + 93661, wherein r is an integer from 1 to 30, | thus defined ligands L93662 to L93691 each has a structure of 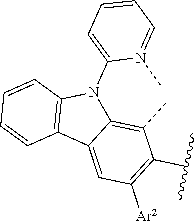 | wherein Ar² = Ar, and |
| for each Ll, wherein l = 30(r − 1) + s + 93691, wherein r is an integer from 1 to 30, and s is an integer from 1 to 30, | thus defined ligands L93692 to L94591 each has a structure of 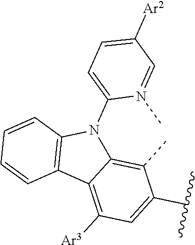 | wherein Ar² = Ar and Ar³ = As, and |
| for each Ll, wherein l = 30(r − 1) + s + 94591, wherein r is an integer from 1 to 30, and s is an integer from 1 to 30, | thus defined ligands L94592 to L95491 each has a structure of 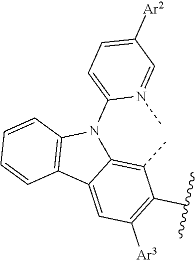 | wherein Ar² = Ar and Ar³ = As, and |
| | ligand L95492 has the structure of 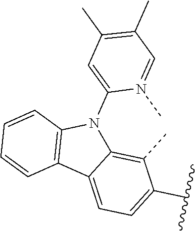 | |
| for each Ll, wherein l = r + 95492, wherein r is an integer from 1 to 30, | thus defined ligands L95493 to L95522 each has a structure of 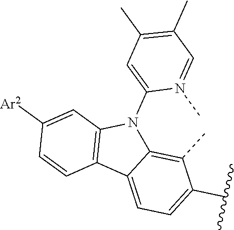 | wherein Ar² = Ar, and |
| for each Ll, wherein l = r + 95522, wherein r is an integer from 1 to 30, | thus defined ligands L95523 to L95552 each has a structure of 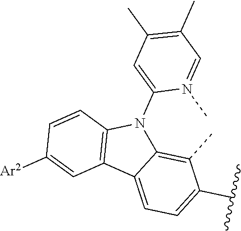 | wherein Ar² = Ar, and |
| for each Ll, wherein l = r + 95552, wherein r is an integer from 1 to 30, | thus defined ligands L95553 to L95582 each has a structure of 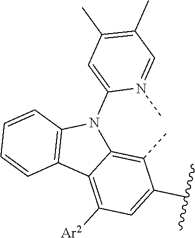 | wherein Ar² = Ar, and |
| for each Ll, wherein l = r + 95582, wherein r is an integer from 1 to 30, | thus defined ligands L95583 to L95612 each has a structure of 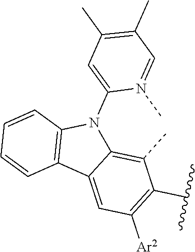 | wherein Ar² = Ar, and |
| | ligand L95613 has the structure of 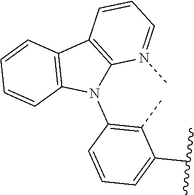 | |
| for each Ll, wherein l = r + 95613, wherein r is an integer from 1 to 30, | thus defined ligands L95614 to L95643 each has a structure of 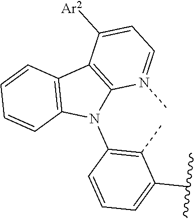 | wherein Ar² = Ar, and |
| for each Ll, wherein l = 30(r − 1) + s + 95643, wherein r is an integer from 1 to 30, and s is an integer from 1 to 30, | thus defined ligands L95644 to L96543 each has a structure of 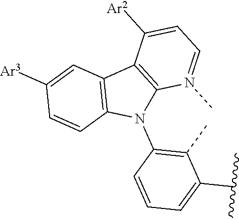 | wherein Ar² = Ar and Ar³ = As, and |
| for each Ll, wherein l = r + 96543, wherein r is an integer from 1 to 30, | thus defined ligands L96544 to L96573 each has a structure of 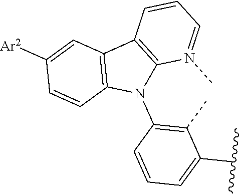 | wherein Ar² = Ar, and |
| for each Ll, wherein l = 30(r − 1) + s + 96573, wherein r is an integer from 1 to 30, and s is an integer from 1 to 30, | thus defined ligands L96574 to L97473 each has a structure of 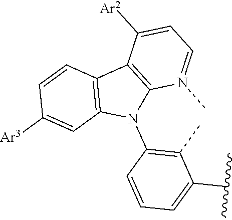 | wherein Ar² = Ar and Ar³ = As, and |
| for each Ll, wherein l = r + 97473, wherein r is an integer from 1 to 30, | thus defined ligands L97474 to L97503 each has a structure of 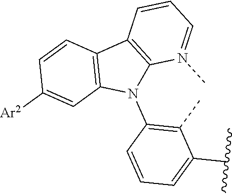 | wherein Ar² = Ar, and |
| for each Ll, wherein l = r + 97503, wherein r is an integer from 1 to 30, | thus defined ligands L97504 to L97533 each has a structure of 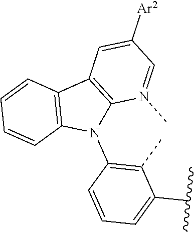 | wherein Ar² = Ar, and |
| for each Ll, wherein l = 30(r − 1) + s + 97533, wherein r is an integer from 1 to 30, and s is an integer from 1 to 30, | thus defined ligands L97534 to L98433 each has a structure of 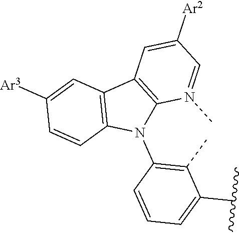 | wherein Ar² = Ar and Ar³ = As, and |
| for each Ll, wherein l = 30(r − 1) + s + 98433, wherein r is an integer from 1 to 30, and s is an integer from 1 to 30, | thus defined ligands L98434 to L99333 each has a structure of 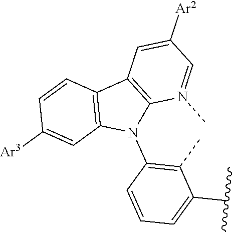 | wherein Ar² = Ar and Ar³ = As, and |
| for each Ll, wherein l = r + 99333, wherein r is an integer from 1 to 30, | thus defined ligands L99334 to L99363 each has a structure of 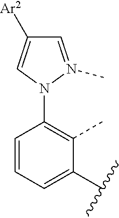 | wherein Ar² = Ar, and |
| | ligand L99364 has the structure of 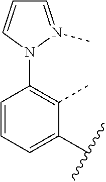 | |
| for each Ll, wherein l = r + 99364, wherein r is an integer from 1 to 30, | thus defined ligands L99365 to L99394 each has a structure of 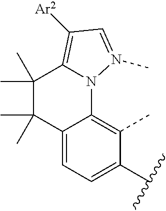 | wherein Ar² = Ar, wherein r is an integer from 1 to 30, and |
| | ligand L99395 has the structure of 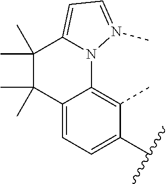 | |
| for each Ll, wherein l = 100(r − 1) + q + 99395, wherein r is an integer from 1 to 30, and q is an integer from 1 to 100, | thus defined ligands L99396 to L102395 each has a structure of 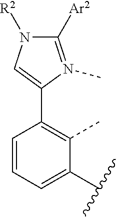 | wherein Ar² = Ar and R² = Rq, and |
| for each Ll, wherein l = q + 102395, wherein q is an integer from 1 to 100, | thus defined ligands L102396 to L102495 each has a structure of 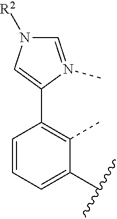 | wherein R² = Rq, and |
| for each Ll, wherein l = 100(r − 1) + q + 102495, wherein r is an integer from 1 to 30, and q is an integer from 1 to 100, | thus defined ligands L102496 to L105495 each has a structure of 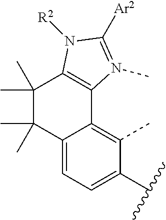 | wherein Ar² = Ar and R² = Rq, and |
| for each Ll, wherein l = q + 105495, wherein q is an integer from 1 to 100, | thus defined ligands L105496 to L105595 each has a structure of 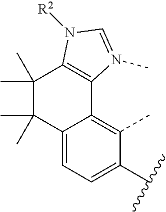 | wherein R² = Rq, and |
| for each Ll, wherein l = 100(r − 1) + q + 105595, wherein r is an integer from 1 to 30, and q is an integer from 1 to 100, | thus defined ligands L105596 to L108595 each has a structure of 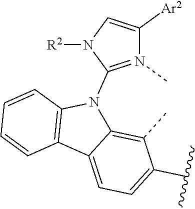 | wherein Ar² = Ar and R² = Rq, and |
| for each Ll, wherein l = q + 108595, wherein q is an integer from 1 to 100, | thus defined ligands L108596 to L108695 each has a structure of 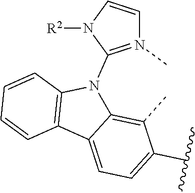 | wherein R² = Rq, and |
| for each Ll, wherein l = 100(r − 1) + q + 111695, wherein r is an integer from 1 to 30, and q is an integer from 1 to 100, | thus defined ligands L108696 to L111695 each has a structure of 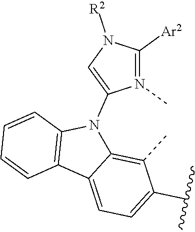 | wherein Ar² = Ar and R² = Rq, and |
| for each Ll, wherein l = q + 111795, wherein q is an integer from 1 to 100, | thus defined ligands L111696 to L111795 each has a structure of 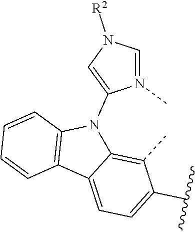 | wherein R² = Rq, and |
| for each Ll, wherein l = 100(r − 1) + q + 111795, wherein r is an integer from 1 to 30, and q is an integer from 1 to 100, | thus defined ligands L111796 to L114795 each has a structure of 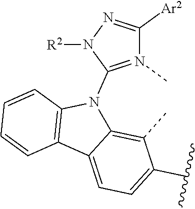 | wherein Ar² = Ar and R² = Rq, and |
| for each Ll, wherein l = q + 114795, wherein q is an integer from 1 to 100, | thus defined ligands L114796 to L114895 each has a structure of 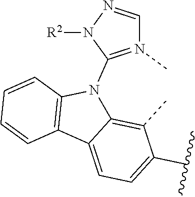 | wherein R² = Rq, and |
| for each Ll, wherein l = 100(r − 1) + q + 114895, wherein r is an integer from 1 to 30, and q is an integer from 1 to 100, | thus defined ligands L114896 to L117895 each has a structure of 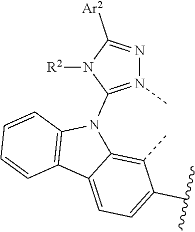 | wherein Ar² = Ar and R² = Rq, and |
| for each Ll, wherein l = q + 117895, wherein q is an integer from 1 to 100, | thus defined ligands L117896 to L117995 each has a structure of 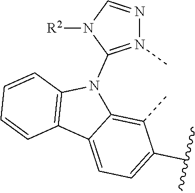 | wherein R² = Rq, and |
| for each Ll, wherein l = 100(r − 1) + q + 117995, wherein r is an integer from 1 to 30, and q is an integer from 1 to 100, | thus defined ligands L117996 to L120995 each has a structure of 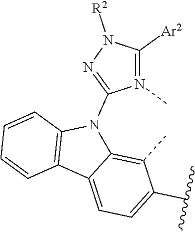 | wherein Ar² = Ar and R² = Rq, and |
| for each Ll, wherein l = q + 120995, wherein q is an integer from 1 to 100, | thus defined ligands L120996 to L121095 each has a structure of 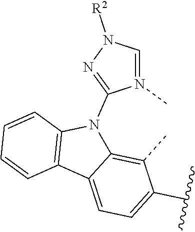 | wherein R² = Rq, and |
| for each Ll, wherein l = r + 121095, wherein r is an integer from 1 to 30, | thus defined ligands L121096 to L121125 each has a structure of 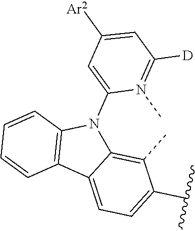 | wherein Ar² = Ar, and |
| | ligand L121126 has the structure of 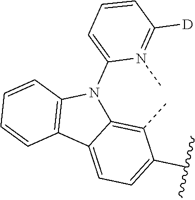 | |
| for each Ll, wherein l = 30(r − 1) + s + 121126, wherein r is an integer from 1 to 30, and s is an integer from 1 to 30, | thus defined ligands L121127 to L122026 each has a structure of 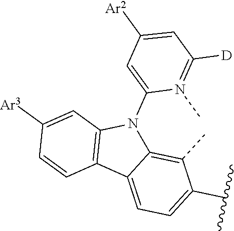 | wherein Ar² = Ar and Ar³ = As, and |
| for each Ll, wherein l = r + 122026, wherein r is an integer from 1 to 30, | thus defined ligands L122027 to L122056 each has a structure of 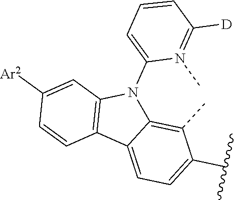 | wherein Ar² = Ar, and |
| for each Ll, wherein l = 30(r − 1) + s + 122056, wherein r is an integer from 1 to 30, and s is an integer from 1 to 30, | thus defined ligands L122057 to L122956 each has a structure of 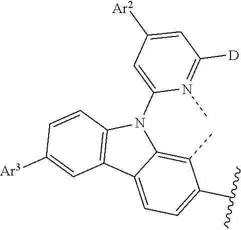 | wherein Ar² = Ar and Ar³ = As, and |
| for each Ll, wherein l = r + 122956, wherein r is an integer from 1 to 30, | thus defined ligands L122957 to L122986 each has a structure of 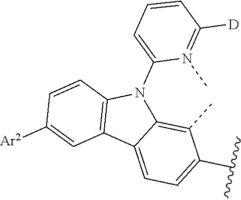 | wherein Ar² = Ar, and |
| for each Ll, wherein l = r + 122986, wherein r is an integer from 1 to 30, | thus defined ligands L122987 to L123016 each has a structure of 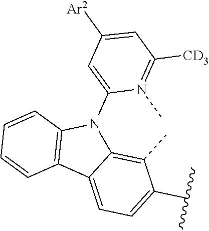 | wherein Ar² = Ar, and |
| | Ligand L123017 has a structure of 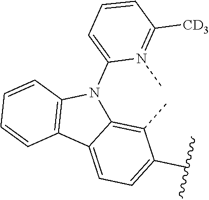 | |
| for each Ll, wherein l = 30(r − 1) + s + 123017, wherein r is an integer from 1 to 30, and s is an integer from 1 to 30, | thus defined ligands L123018 to L123917 each has a structure of 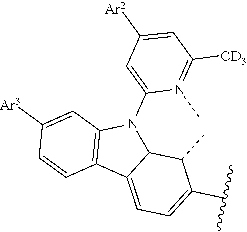 | wherein Ar² = Ar and Ar³ = As, and |
| for each Ll, wherein l = r + 223917, wherein r is an integer from 1 to 30, | thus defined ligands L123918 to L123947 each has a structure of 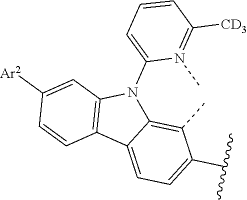 | wherein Ar² = Ar, and |
| for each Ll, wherein l = 30(r − 1) + s + 223947, wherein r is an integer from 1 to 30, and s is an integer from 1 to 30, | thus defined ligands L223948 to L224847 each has a structure of 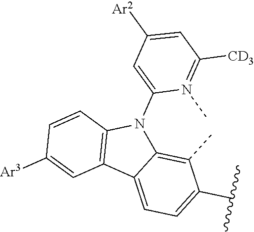 | wherein Ar² = Ar and Ar³ = As, and |
| for each Ll, wherein l = r + 224847, wherein r is an integer from 1 to 30, | thus defined ligands L224848 to L224877 each has a structure of 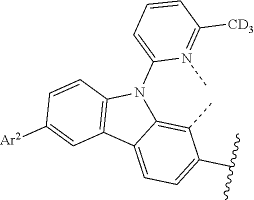 | wherein Ar² = Ar, and |
| for each Ll, wherein l = 30(r − 1) + s + 224877, wherein r is an integer from 1 to 30, and s is an integer from 1 to 30, | thus defined ligands L224878 to L225777 each has a structure of 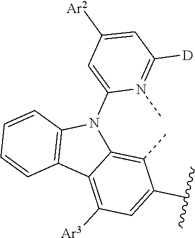 | wherein Ar² = Ar and Ar³ = As, and |
| for each Ll, wherein l = r + 225777, wherein r is an integer from 1 to 30, | thus defined ligands L225778 to L225807 each has a structure of 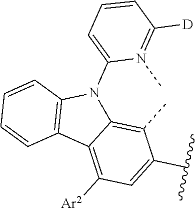 | wherein Ar² = Ar, and |
| for each Ll, wherein l = 30(r − 1) + s + 225807, wherein r is an integer from 1 to 30, and s is an integer from 1 to 30, | thus defined ligands L225808 to L226707 each has a structure of 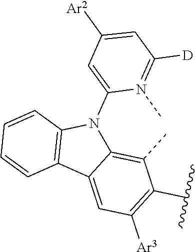 | wherein Ar² = Ar and Ar³ = As, and |
| for each Ll, wherein l = r + 226707, wherein r is an integer from 1 to 30, | thus defined ligands L226708 to L226737 each has a structure of 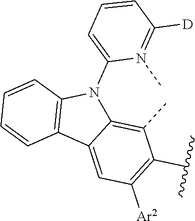 | wherein Ar² = Ar, and |
| for each Ll, wherein l = 30(r − 1) + s + 226737, wherein r is an integer from 1 to 30, and s is an integer from 1 to 30, | thus defined ligands L226738 to L227637 each has a structure of 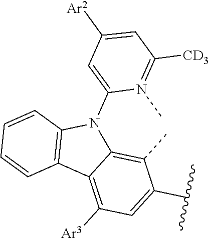 | wherein Ar² = Ar and Ar³ = As, and |
| for each Ll, wherein l = r + 227637, wherein r is an integer from 1 to 30, | thus defined ligands L227638 to L227667 each has a structure of 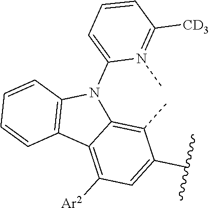 | wherein Ar² = Ar, and |
| for each Ll, wherein l = 30(r − 1) + s + 227667, wherein r is an integer from 1 to 30, and s is an integer from 1 to 30, | thus defined ligands L227668 to L228567 each has a structure of 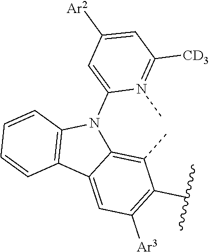 | wherein Ar² = Ar and Ar³ = As, and |
| for each Ll, wherein l = r + 228567, wherein r is an integer from 1 to 30, | thus defined ligands L228568 to L228597 each has a structure of 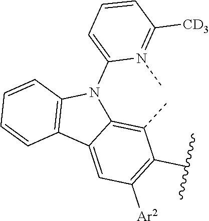 | wherein Ar² = Ar, and |
| for each Ll, wherein l = r + 228597, wherein r is an integer from 1 to 30, | thus defined ligands L228598 to L228627 each has a structure of 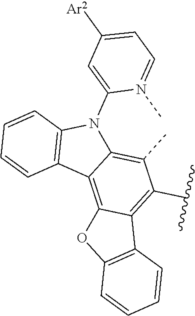 | wherein Ar² = Ar, and |
| for each Ll, wherein l = r + 228627, wherein r is an integer from 1 to 30, | thus defined ligands L228628 to L228657 each has a structure of 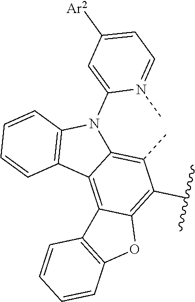 | wherein Ar² = Ar, and |
| for each Ll, wherein l = r + 228657, wherein r is an integer from 1 to 30, | thus defined ligands L228658 to L228687 each has a structure of 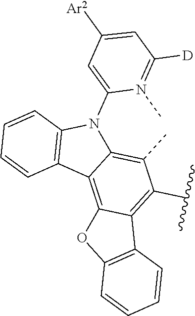 | wherein Ar² = Ar, and |
| for each Ll, wherein l = r + 228787, wherein r is integer from 1 to 30, | thus defined ligands L228688 to L228717 each has a structure of 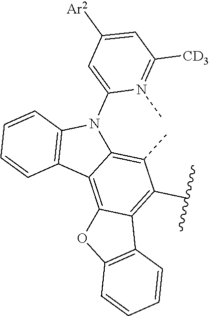 | wherein Ar² = Ar, and |
| for each Ll, wherein l = r + 228717, wherein r is an integer from 1 to 30, | thus defined ligands L228718 to L228747 each has a structure of 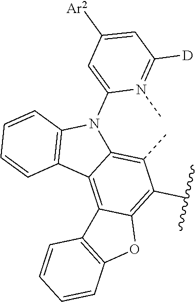 | wherein Ar² = Ar, and |
| for each Ll, wherein l = r + 228747, wherein r is an integer from 1 to 30, | thus defined ligands L228748 to L228777 each has a structure of 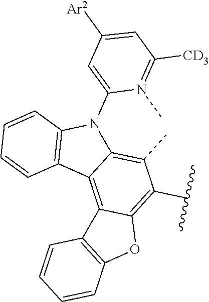 | wherein Ar² = Ar, and |
| | ligand L228778 has a structure of 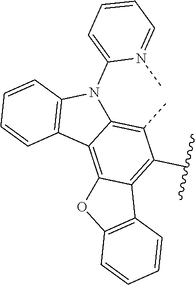 | |
| | ligand L228779 has a structure of 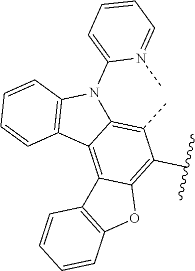 | |
| | ligand L228780 has a structure of 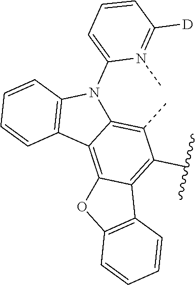 | |
| | ligand L228781 has a structure of 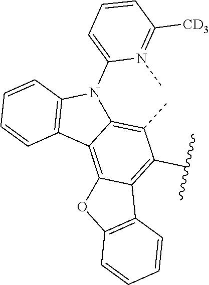 | |
| | ligand L228782 has a structure of 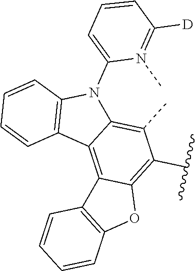 | |
| | ligand L228783 has a structure of 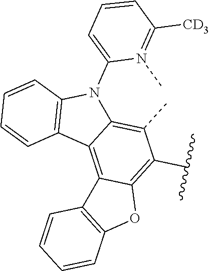 | |
| for each Ll, wherein l = q + 228783, wherein q is an integer from 1 to 330, | thus defined ligands L228784 to L229114 each has a structure of 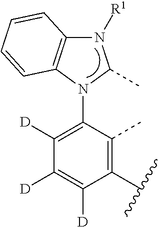 | wherein R¹ = Rq, and |
| for each Ll, wherein l = q + 229114, wherein q is an integer from 1 to 330, | thus defined ligands L229115 to L229445 each has a structure of 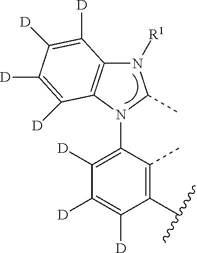 | wherein R¹ = Rq, and |
| for each Ll, wherein l = q + 229445, wherein q is an integer from 1 to 330, | thus defined ligands L229446 to L229776 each has a structure of 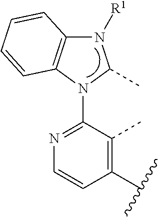 | wherein R¹ = Rq, and |
| for each Ll, wherein l = q + 229776, wherein q is an integer from 1 to 330, | thus defined ligands L229777 to L230107 each has a structure of 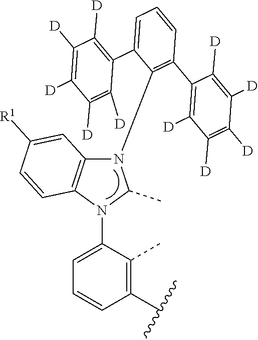 | wherein R¹ = Rq, and |

wherein A1 to A30 have the following structures:

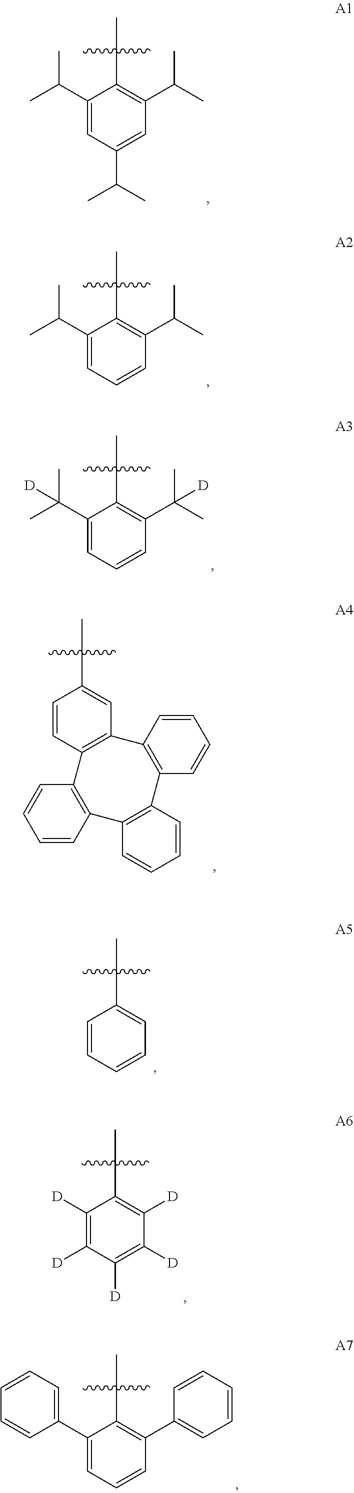

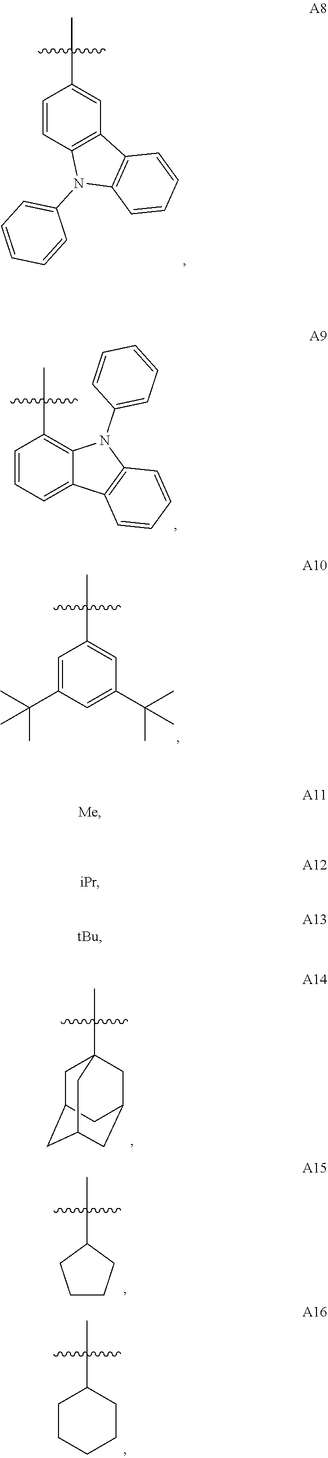 [SMILES: *c1ccc2c(c1)c1ccccc1n2-c1ccccc1 ; *c1cccc2c3ccccc3n(-c3ccccc3)c12 ; *c1cc(C(C)(C)C)cc(C(C)(C)C)c1 ; *C12CC3CC(CC(C3)C1)C2 ; *C1CCCC1 ; *C1CCCCC1]

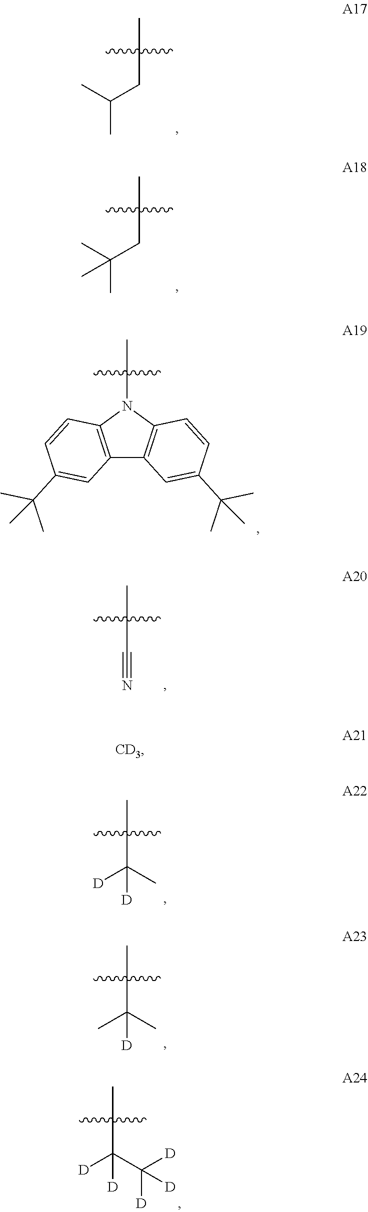

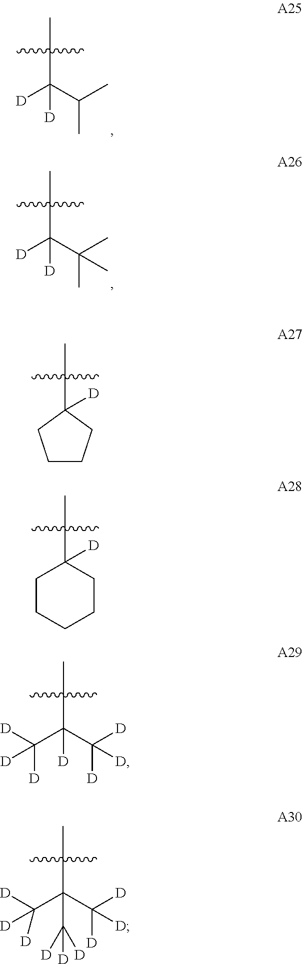

and wherein R1 to R330 have the following structures:

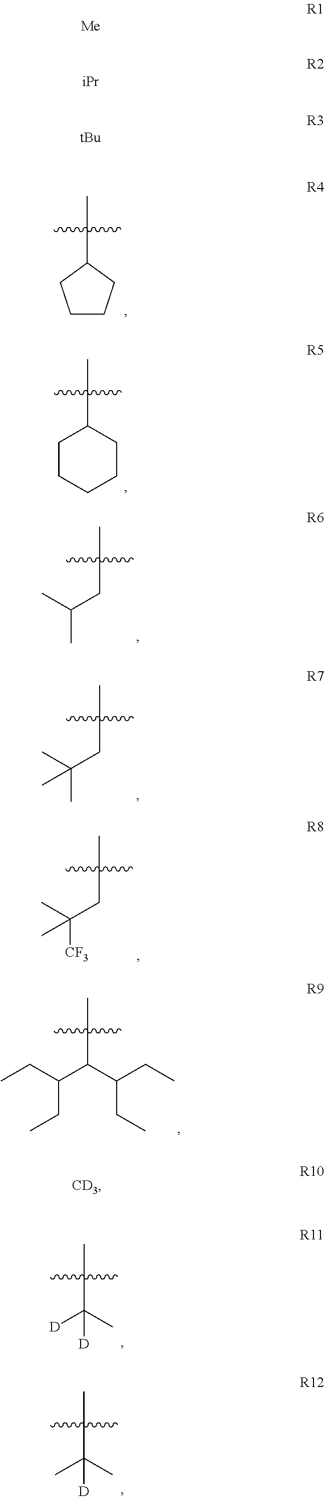

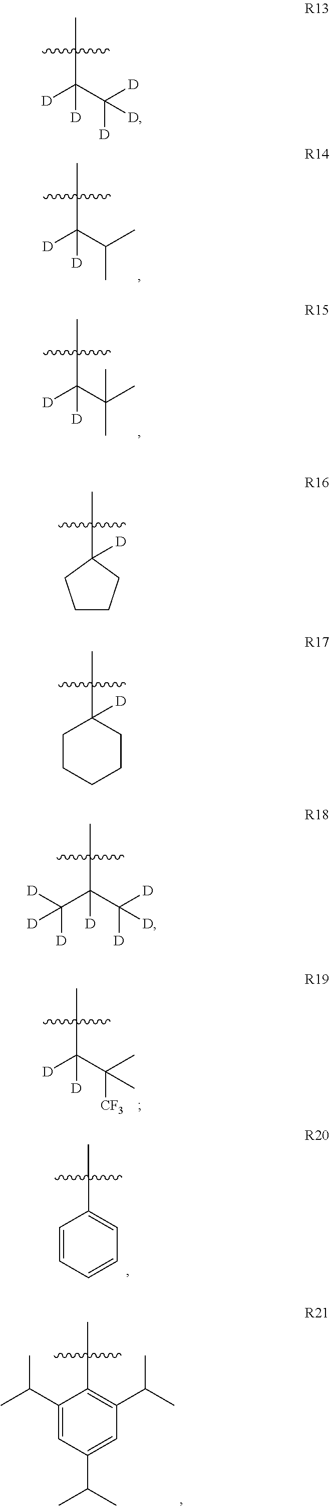

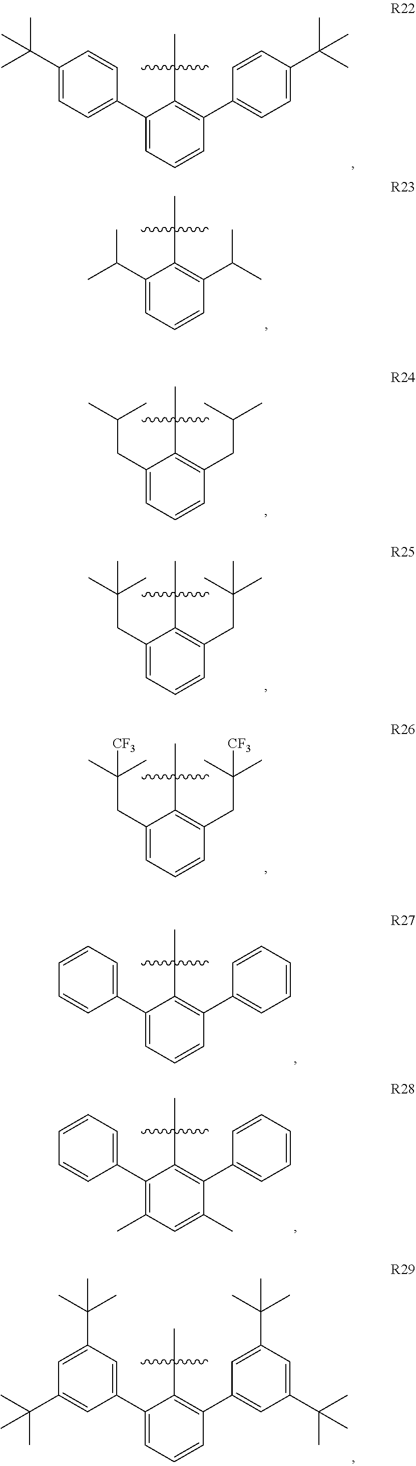

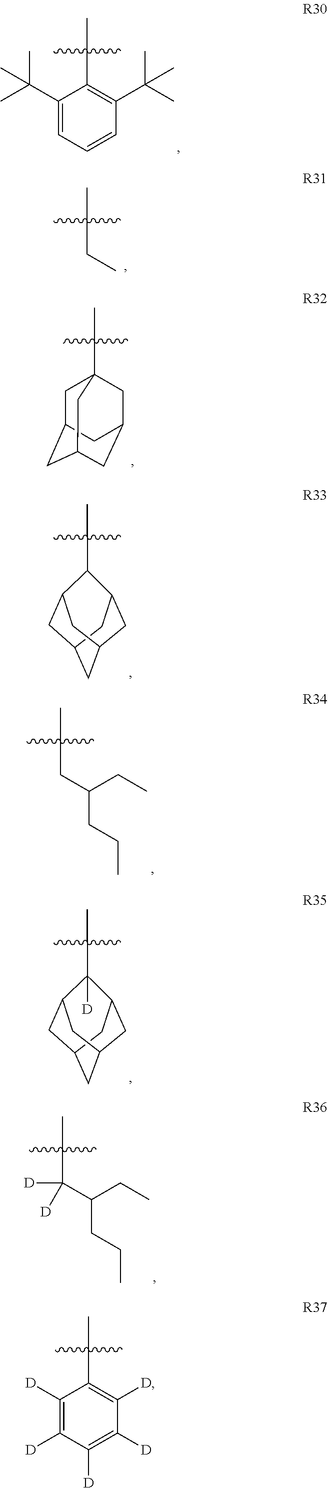

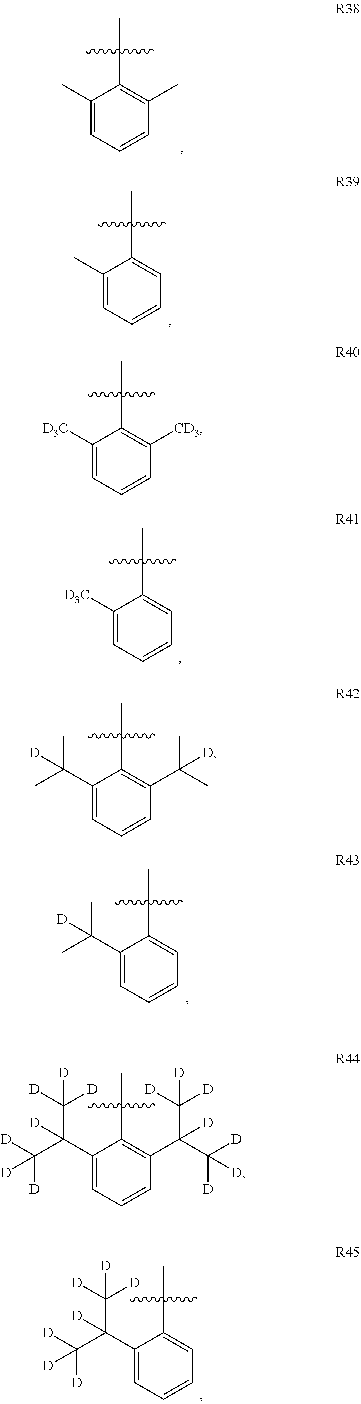

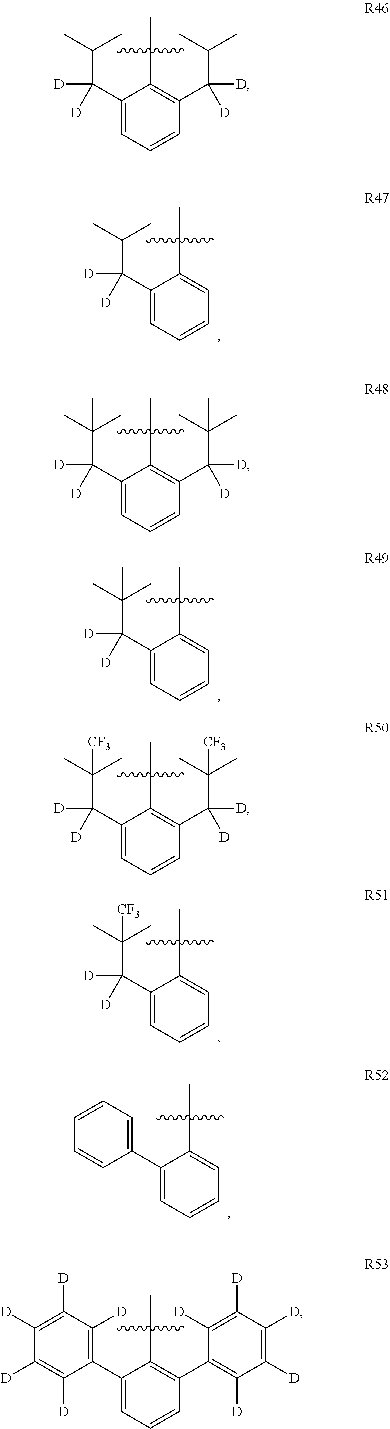

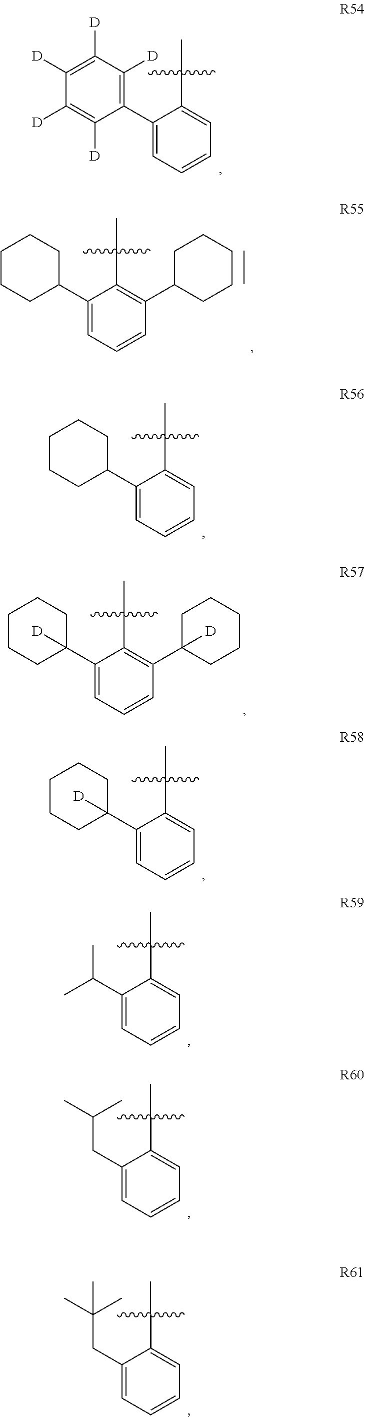

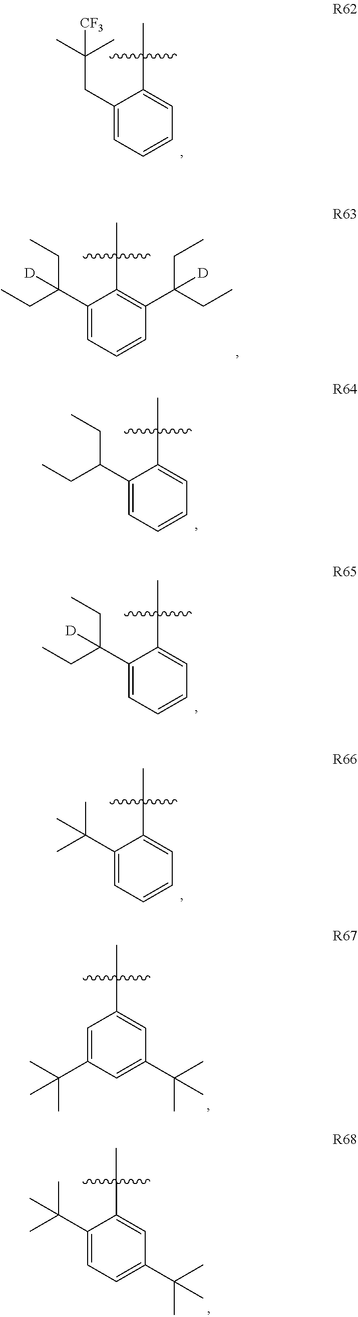

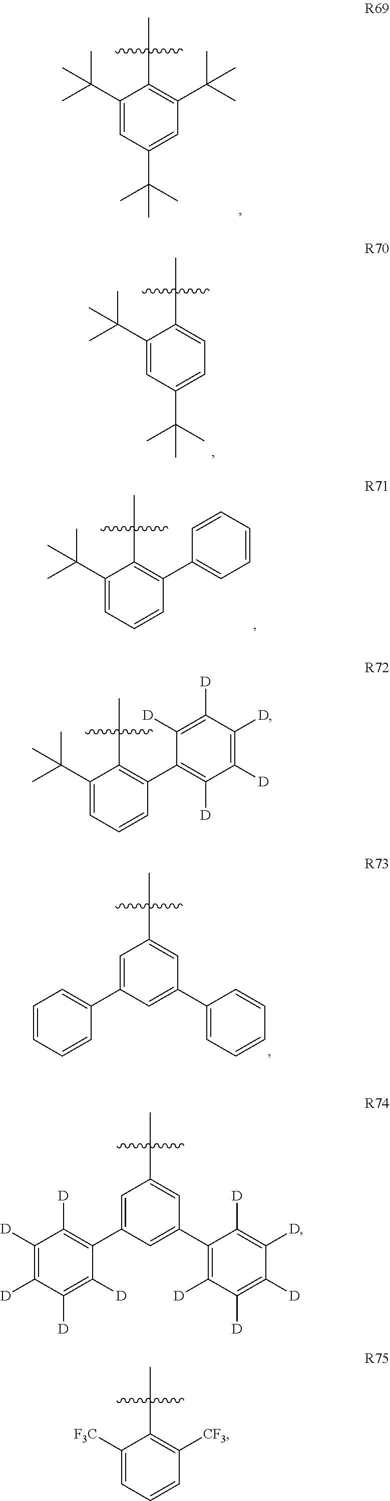

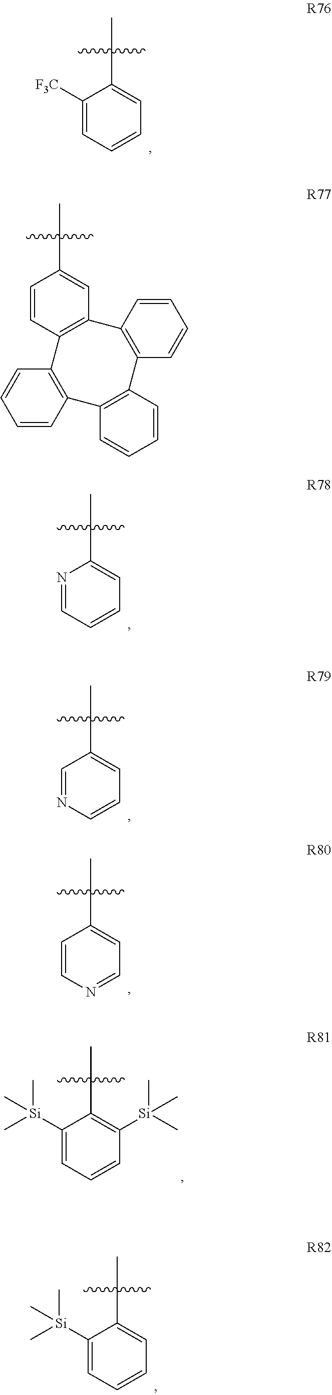

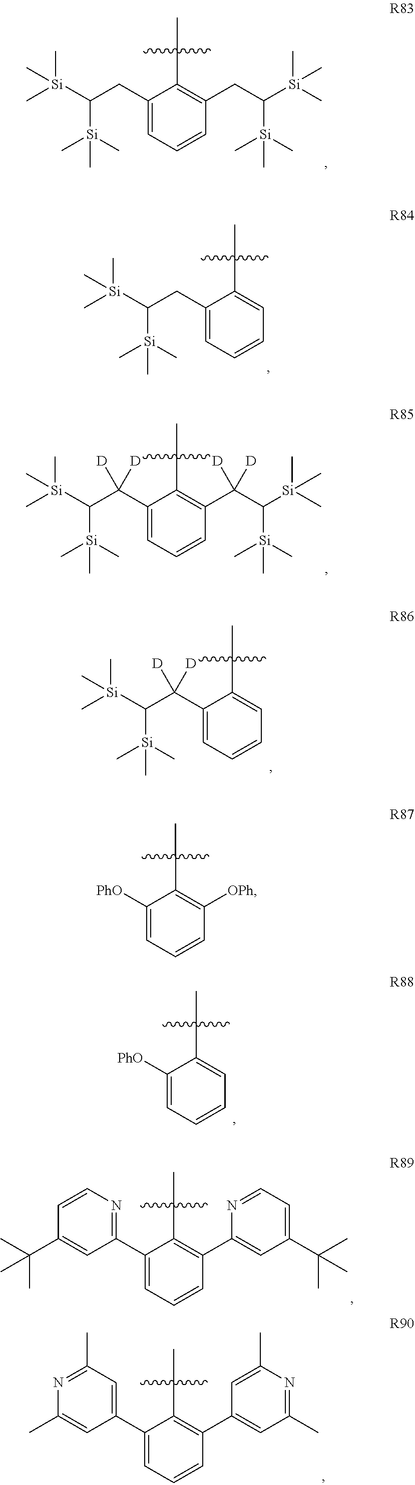

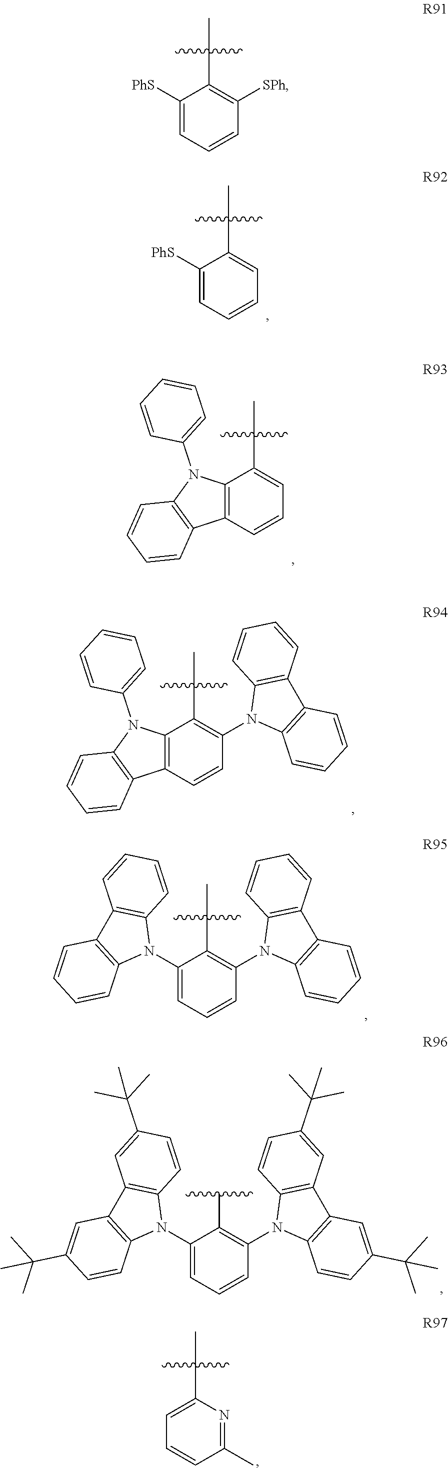

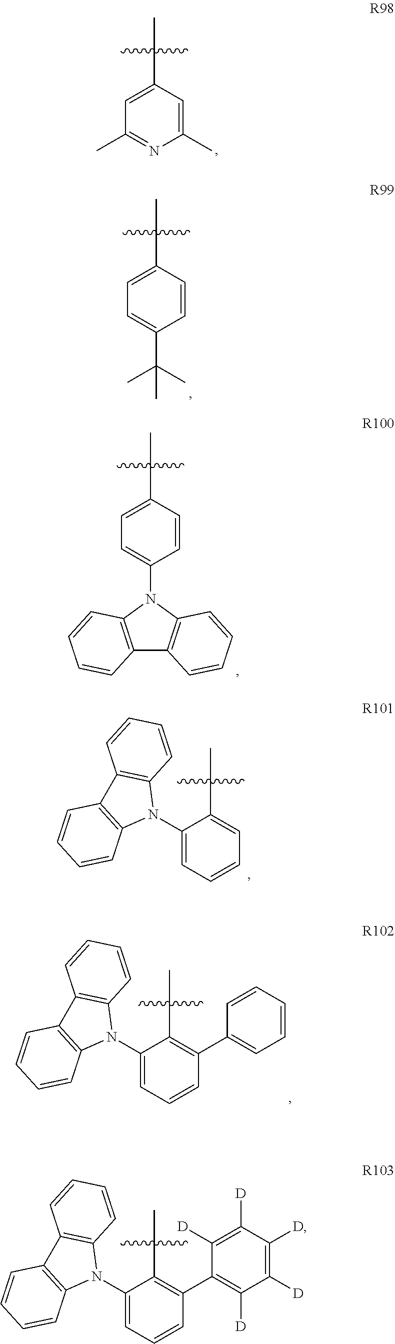

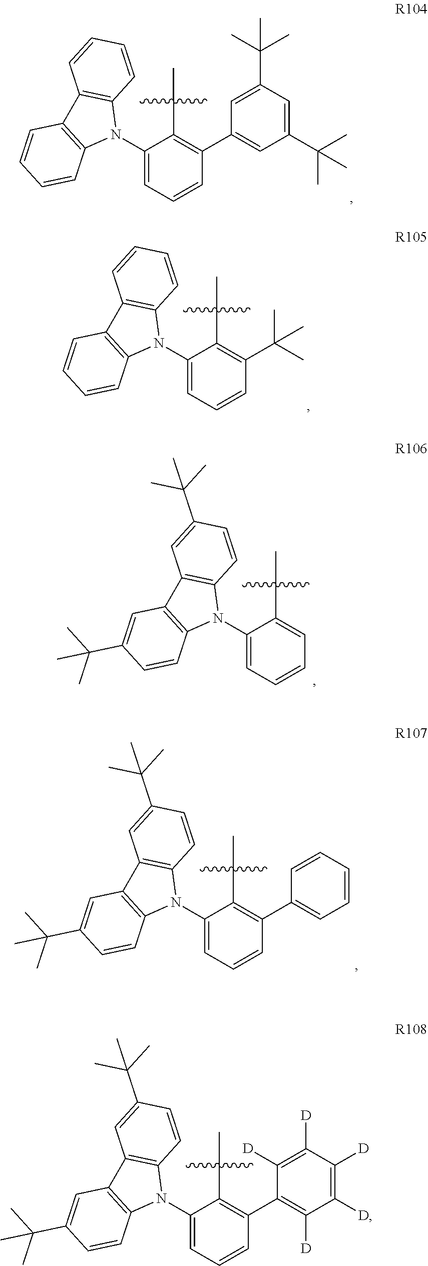

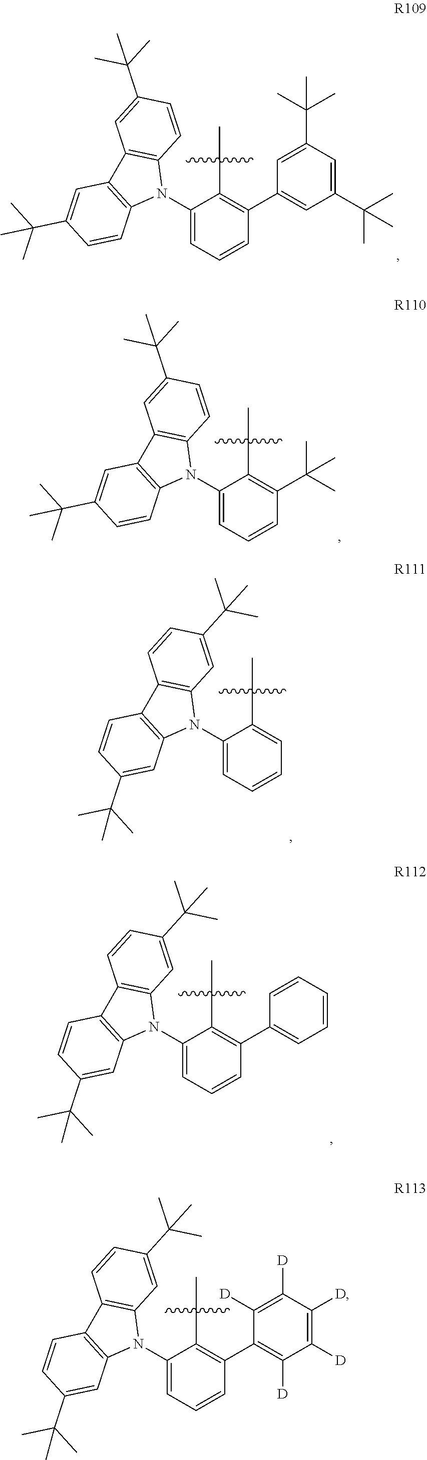

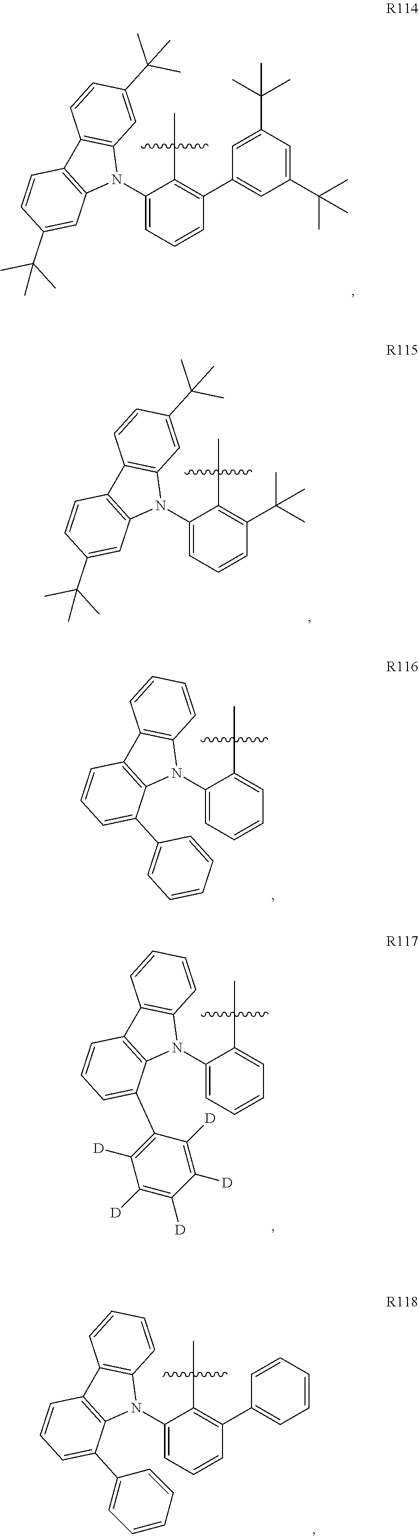

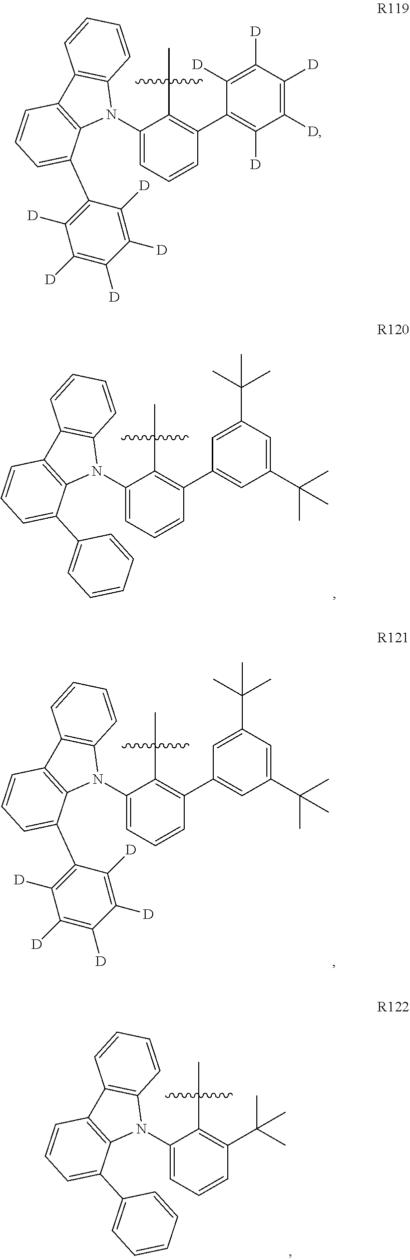

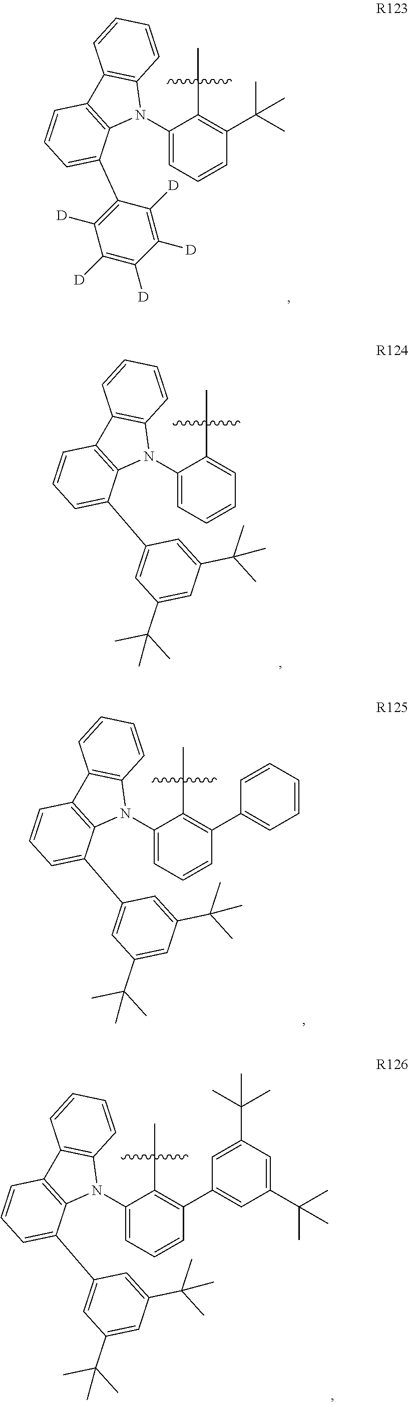

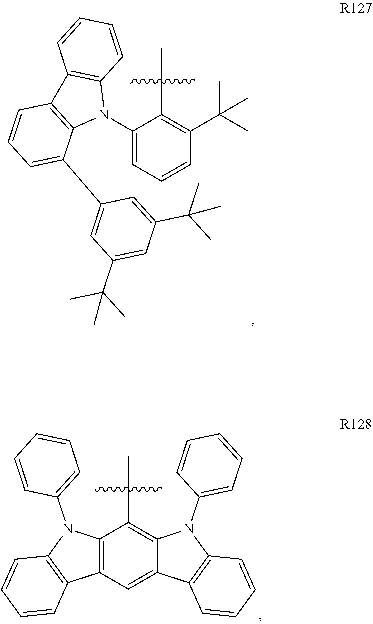

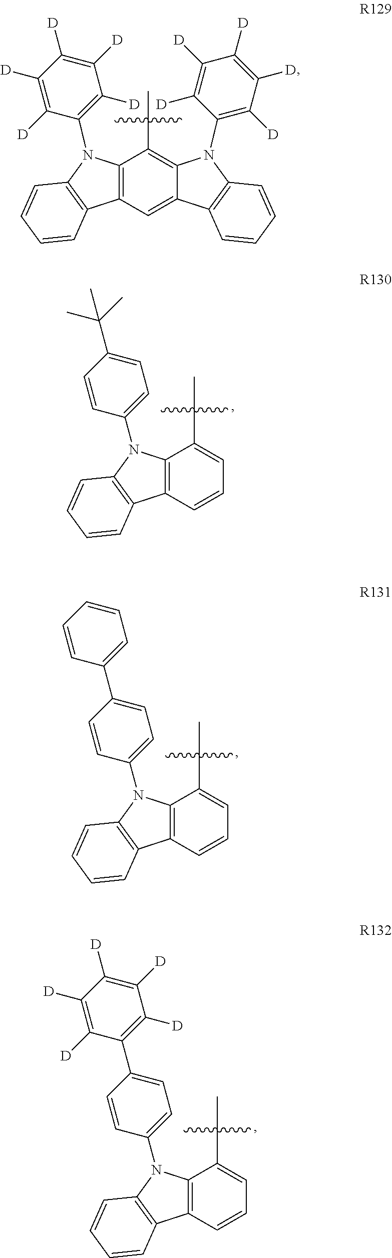

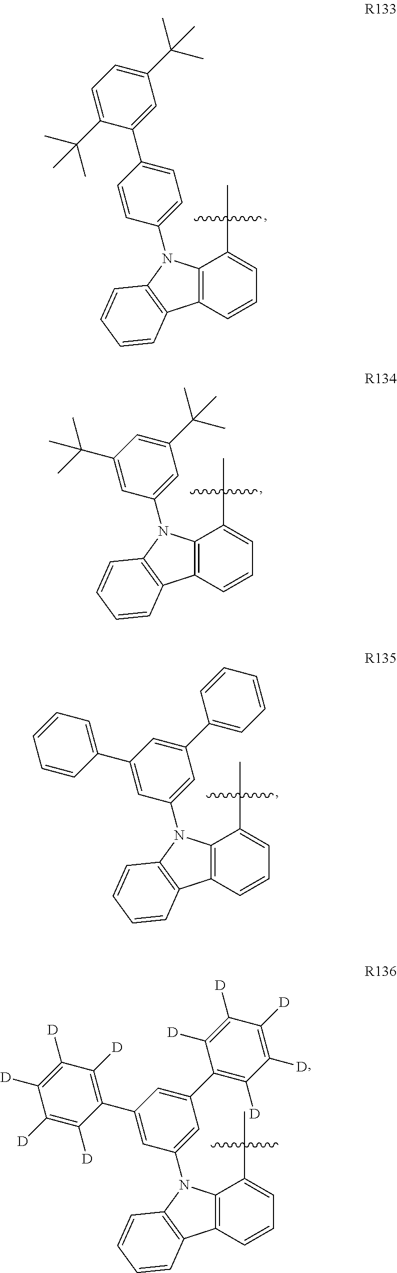

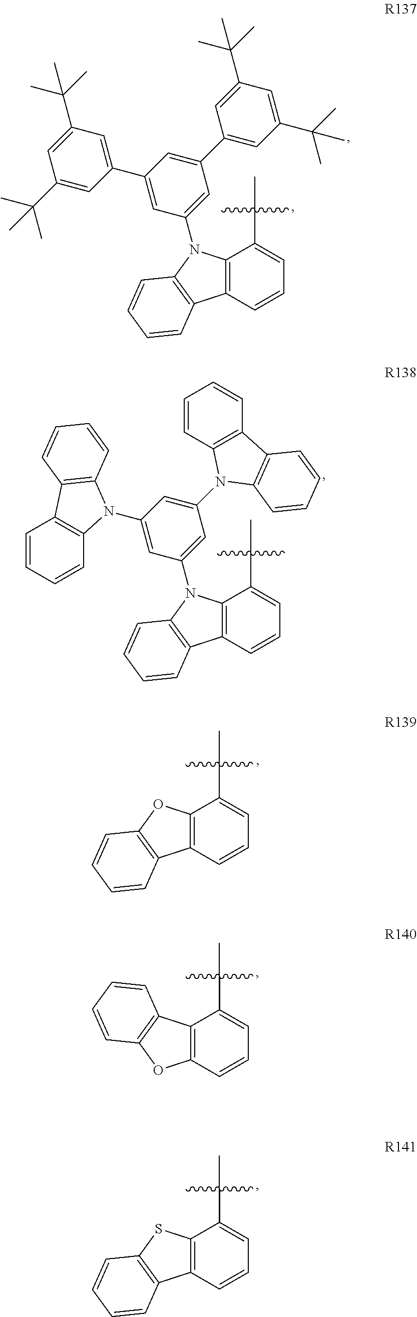

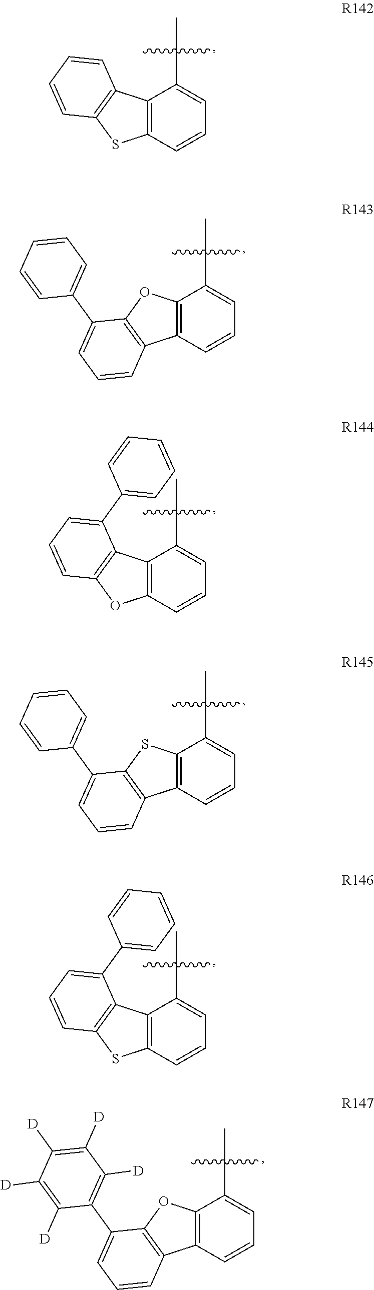

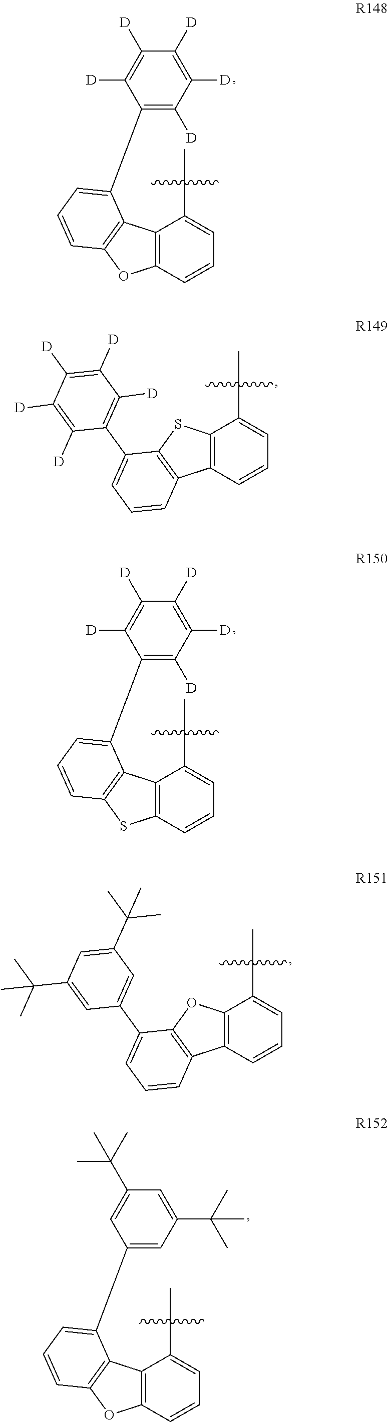

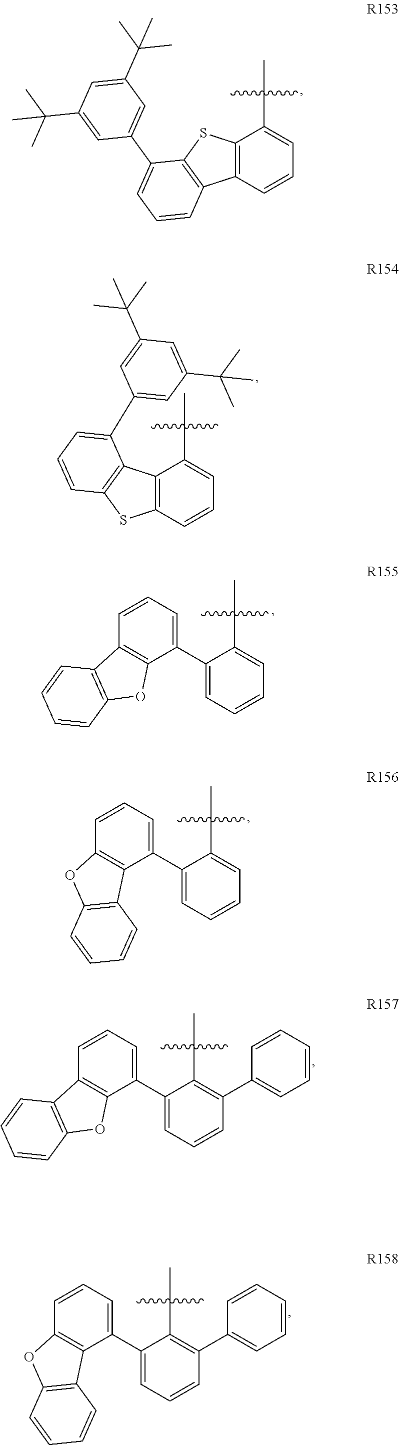

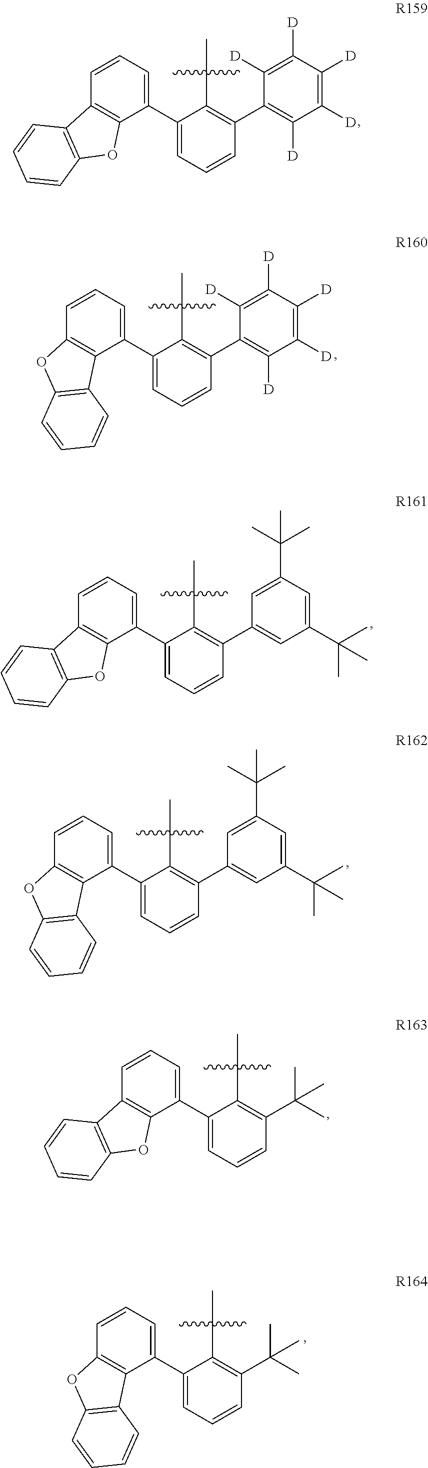

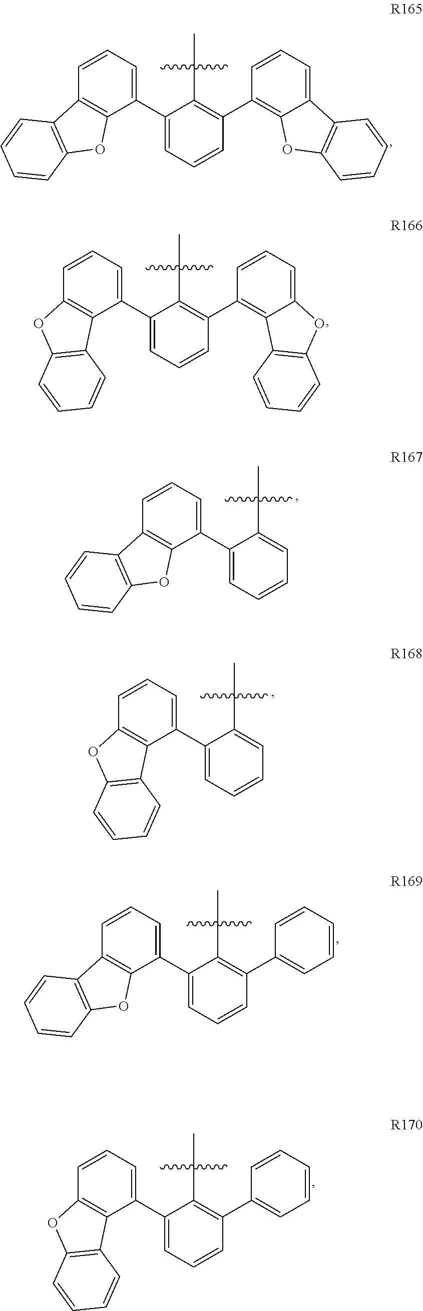

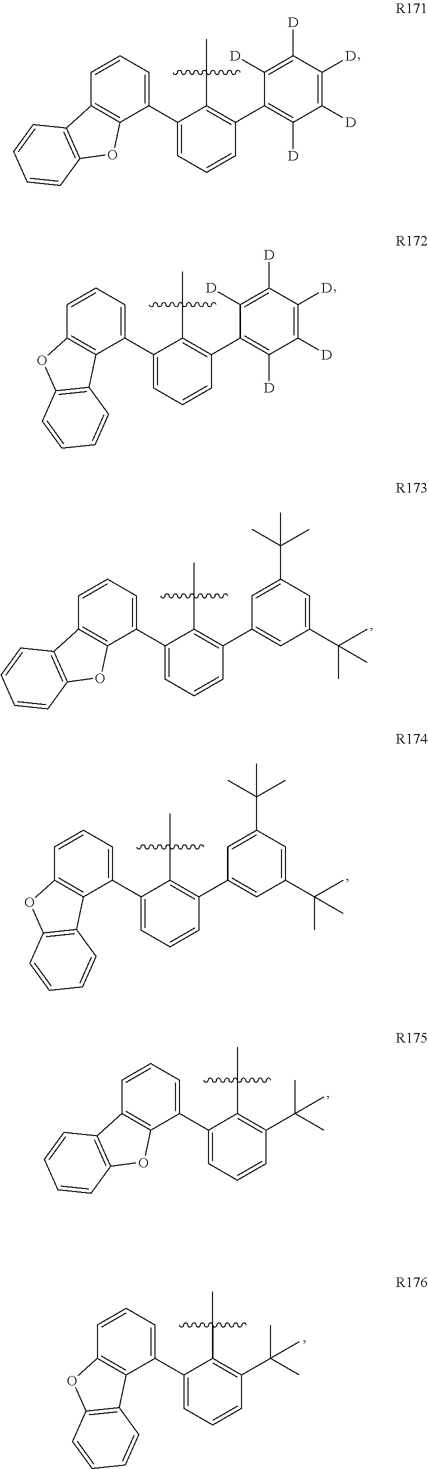

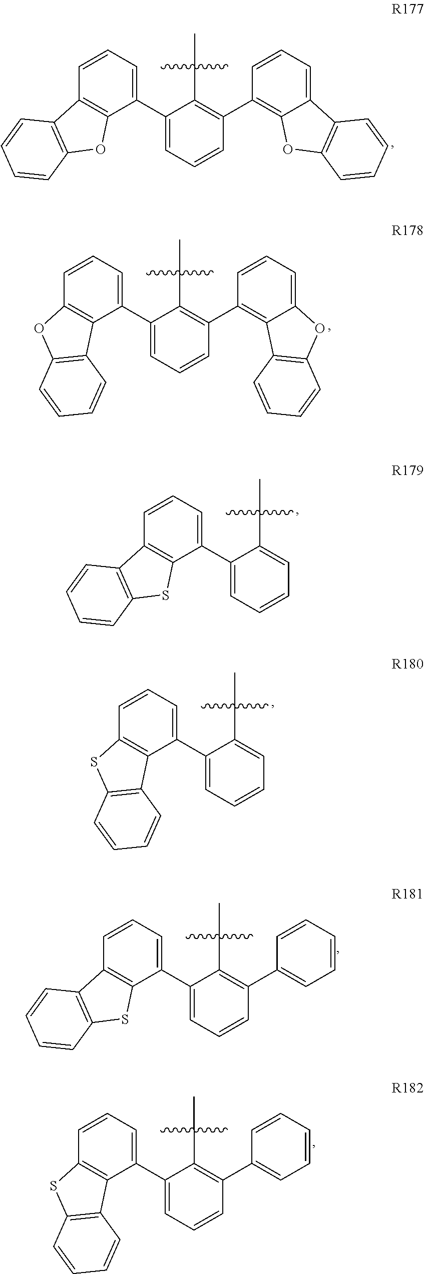

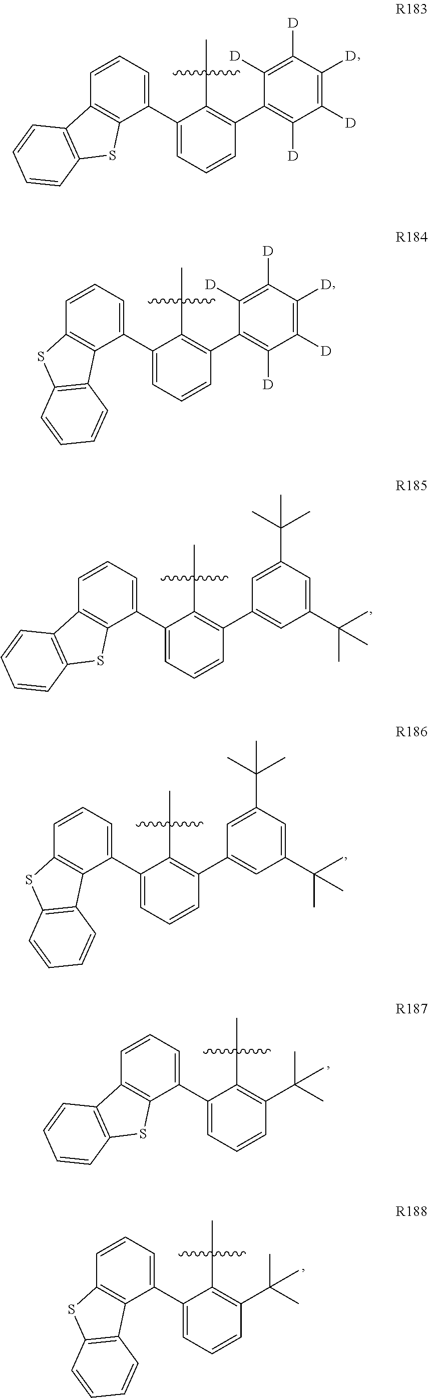

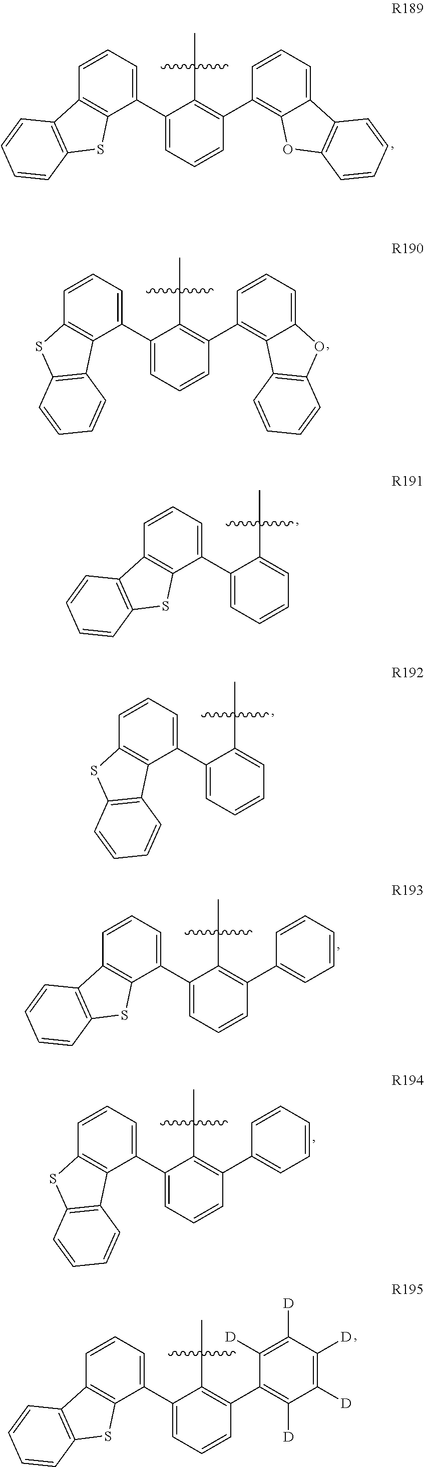

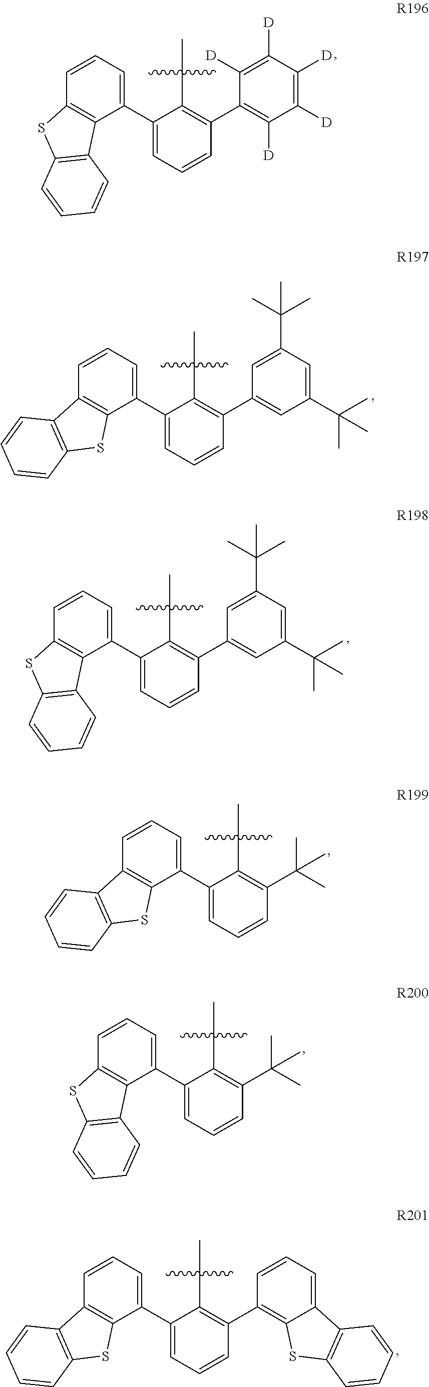

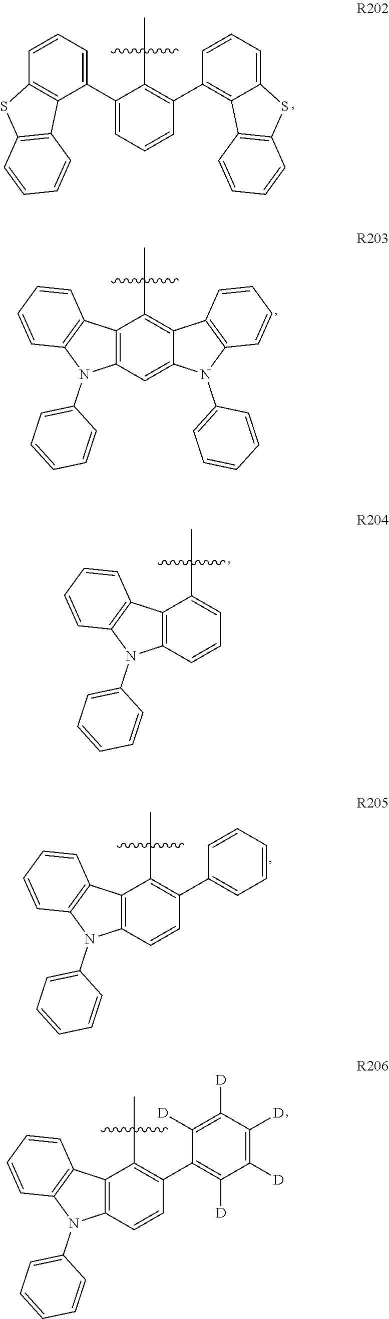

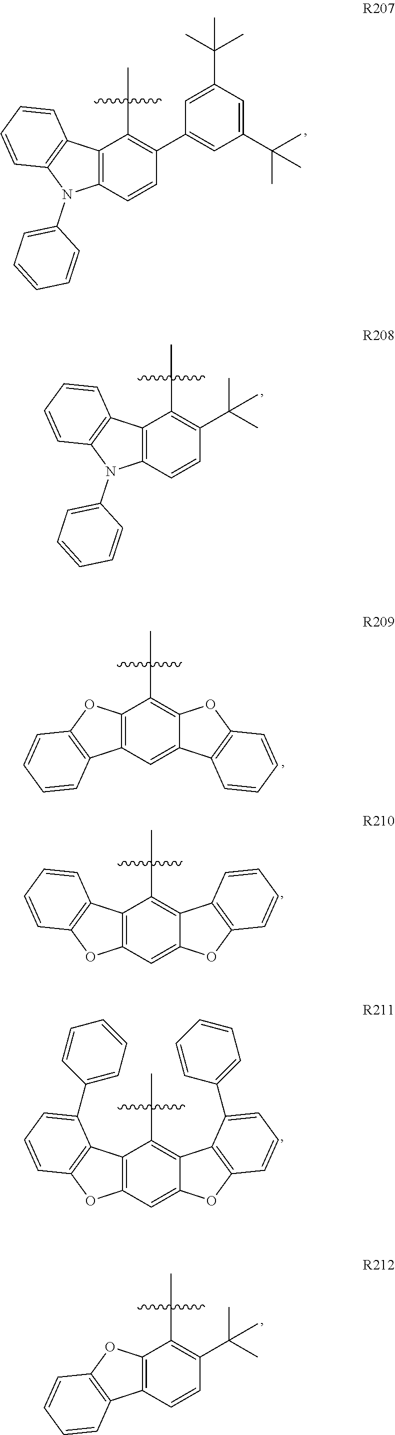

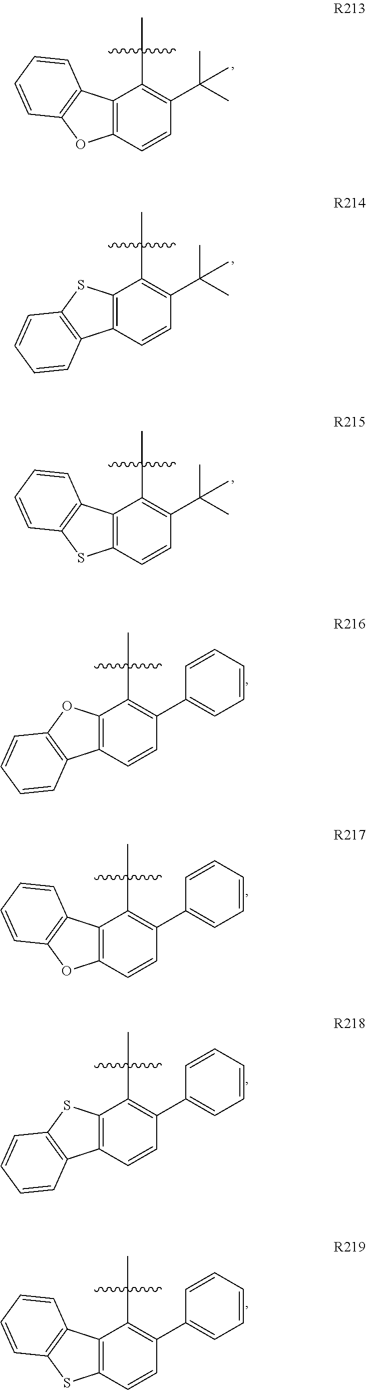

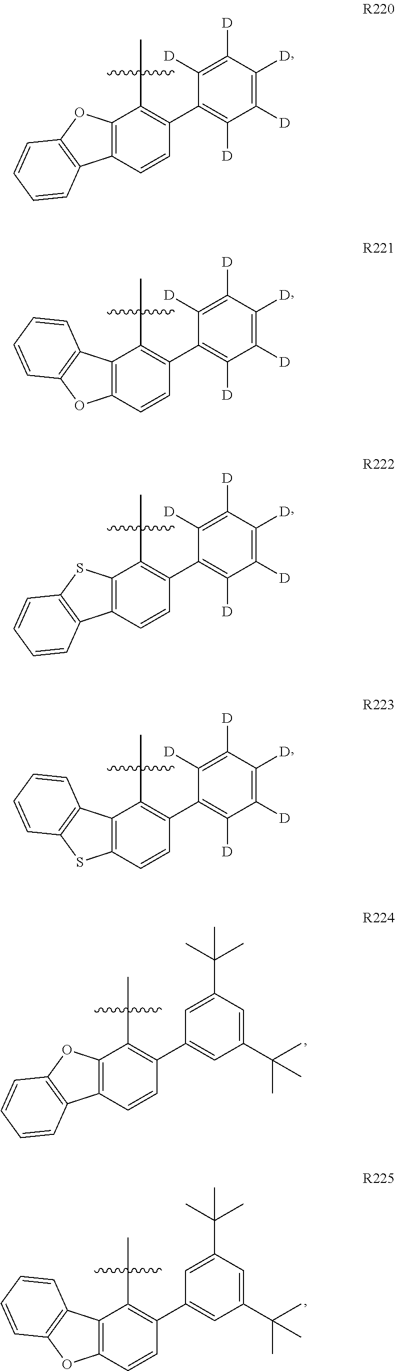

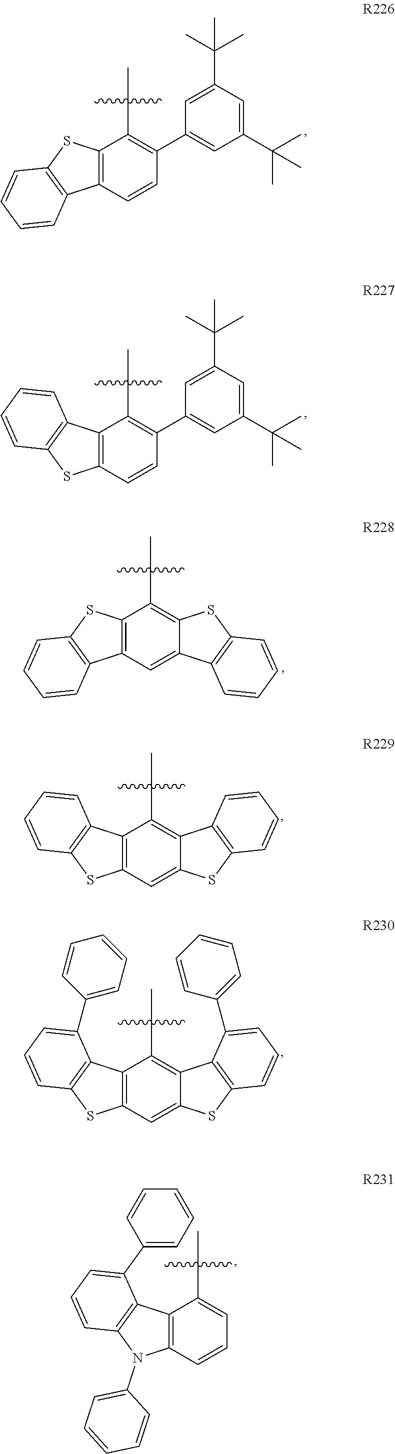

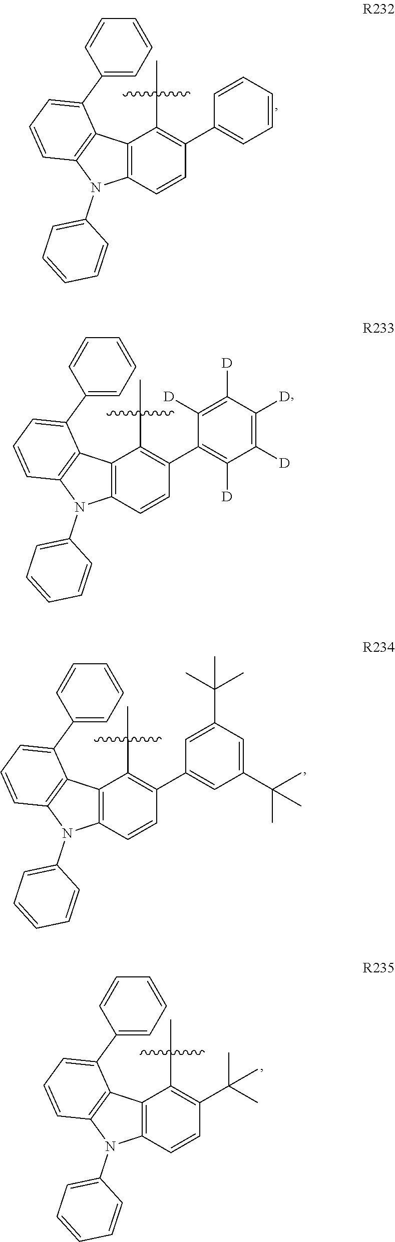

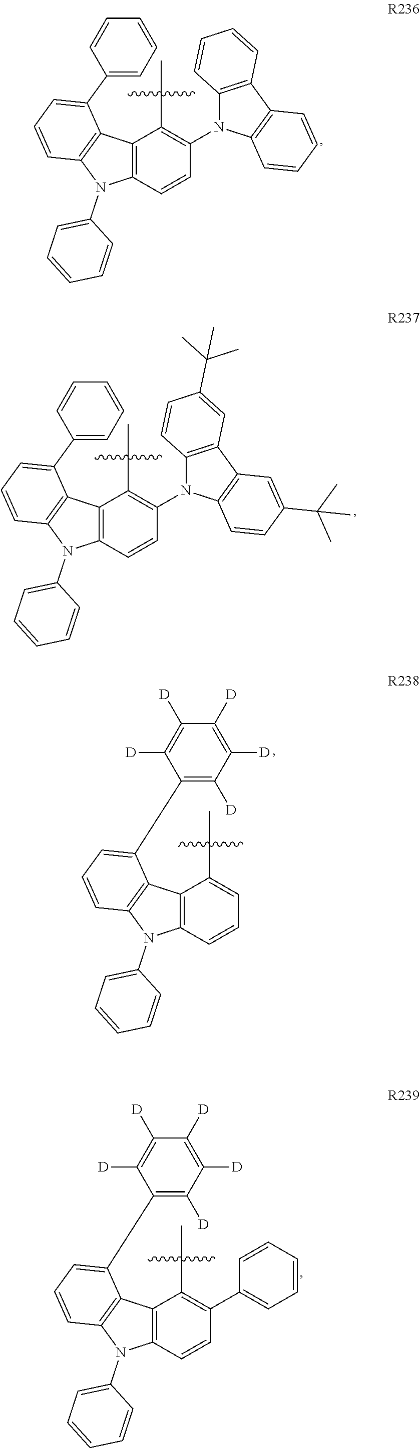

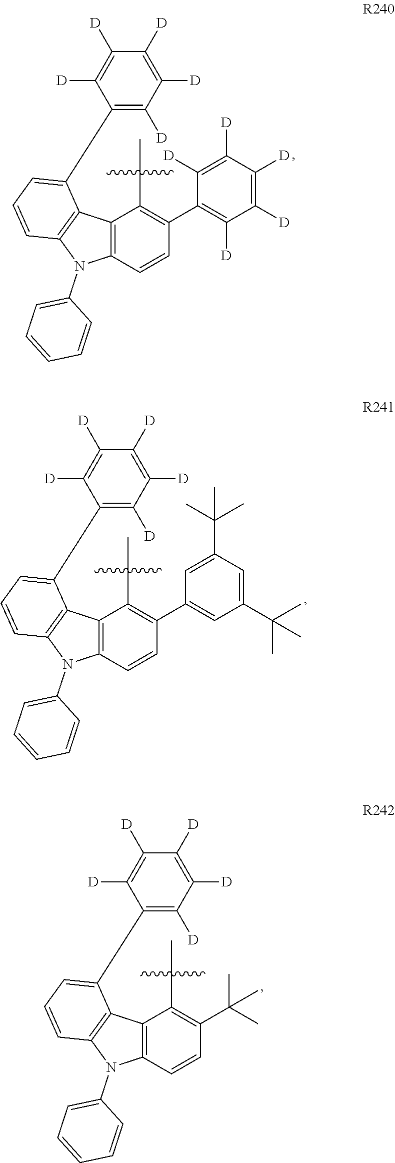

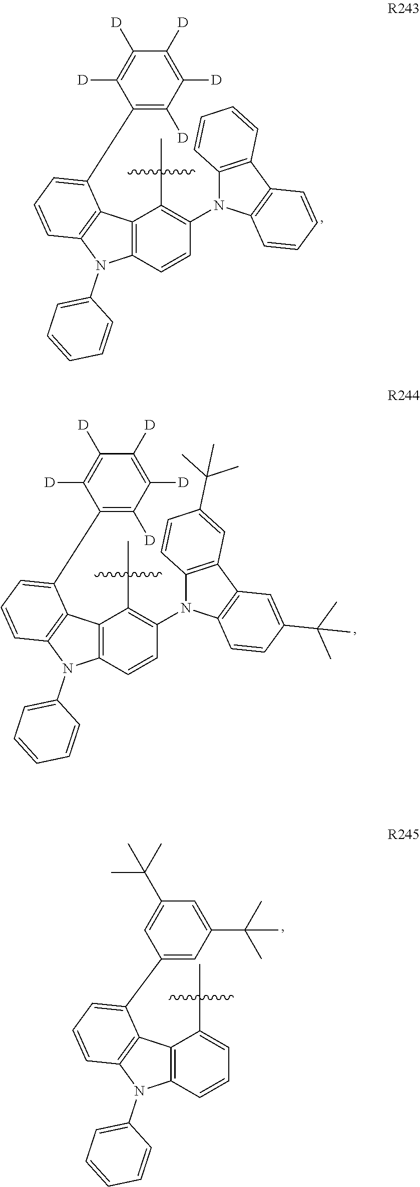

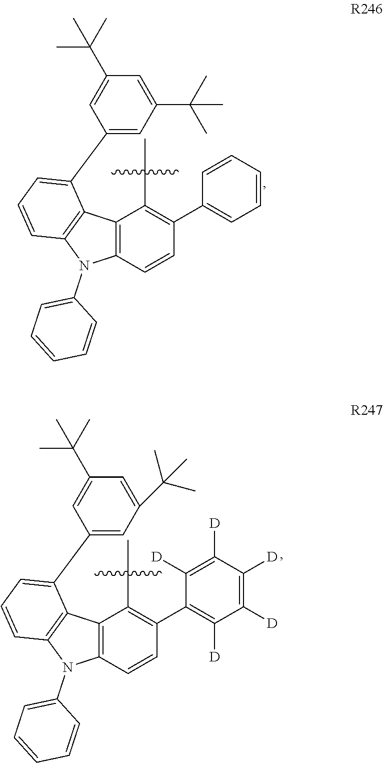

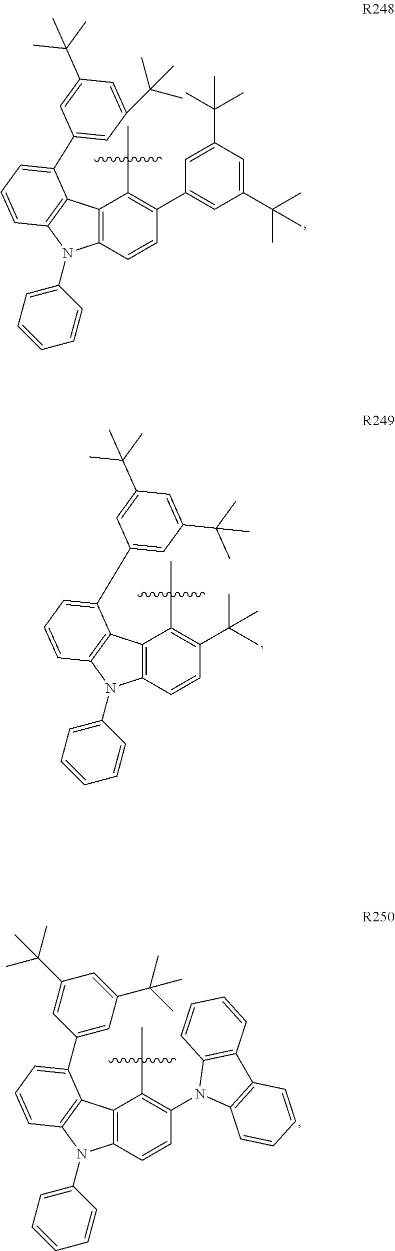

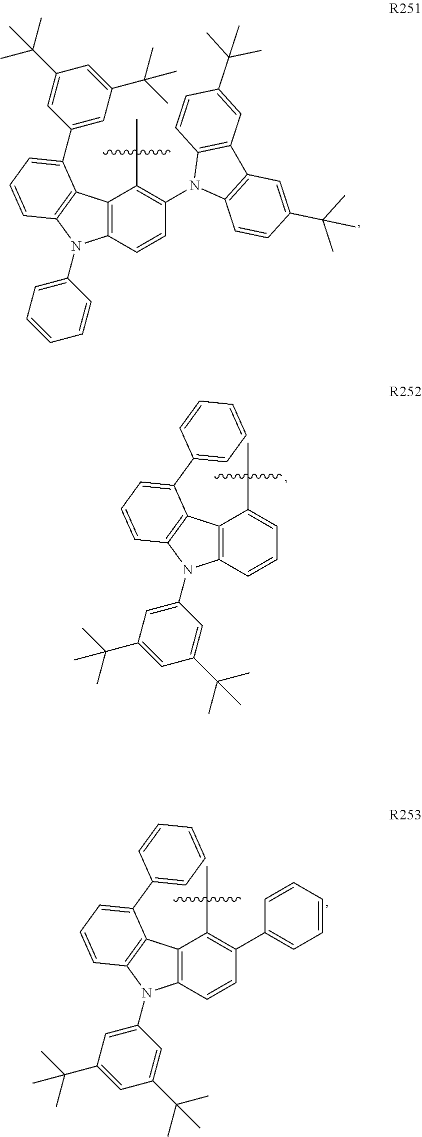

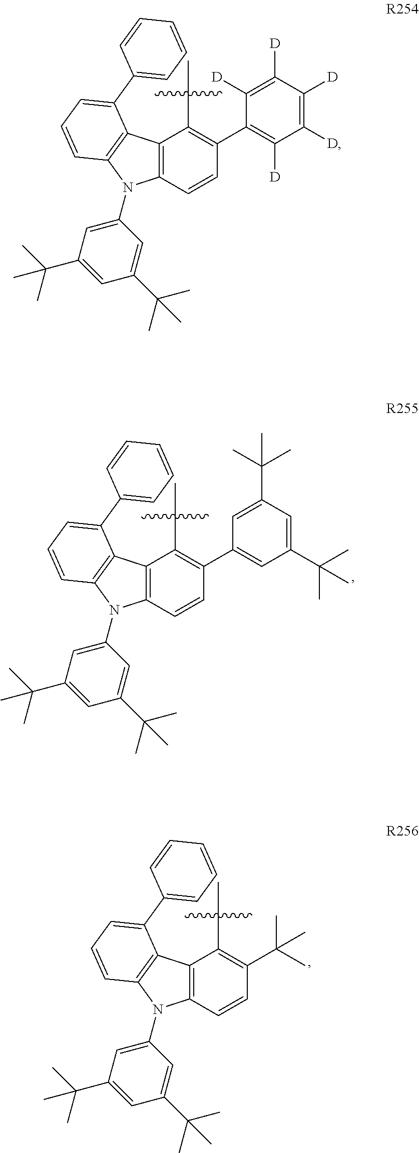

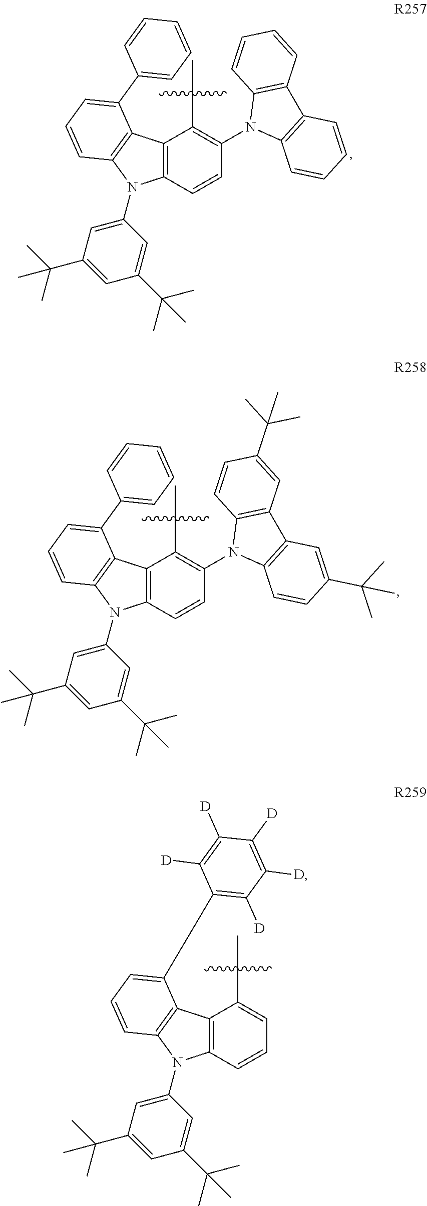

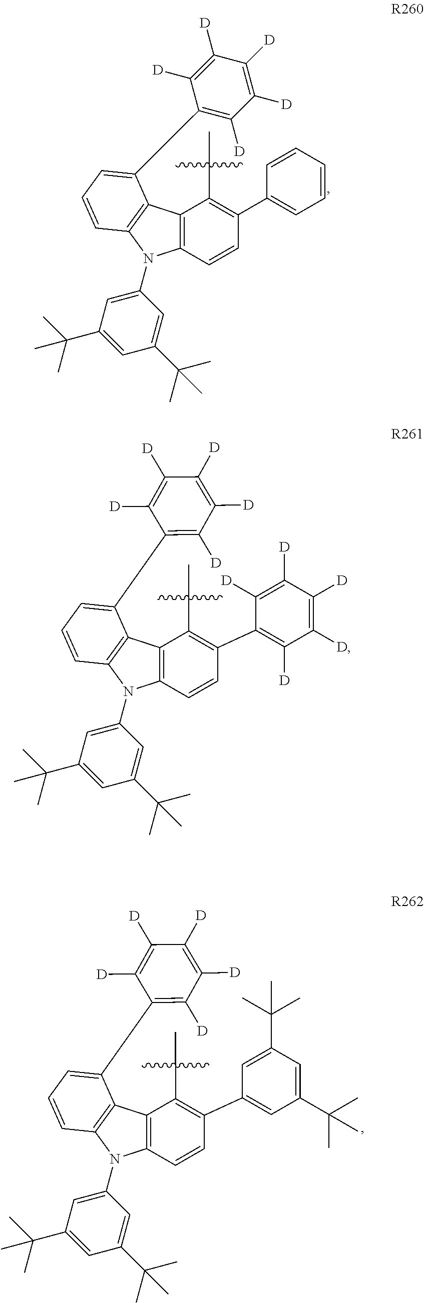

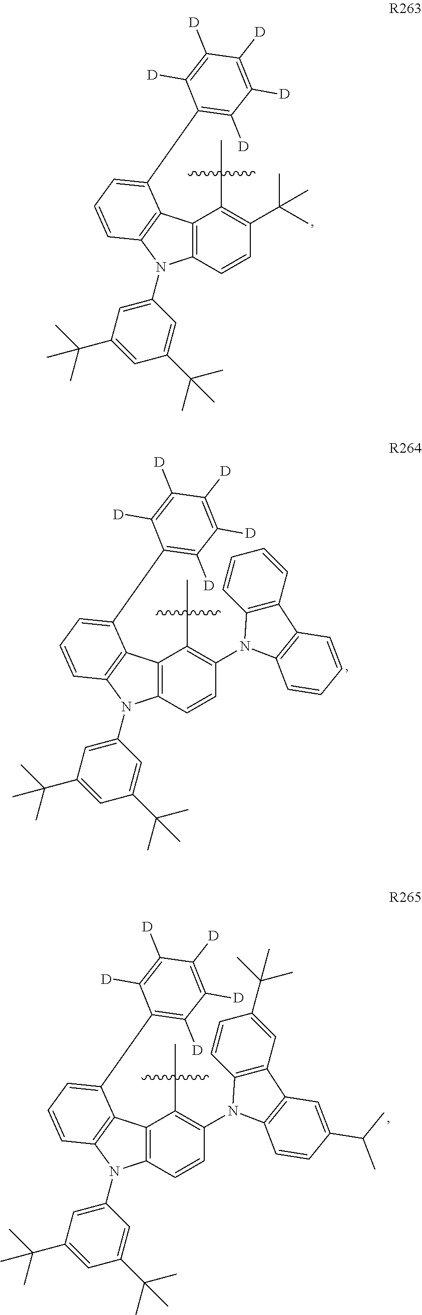

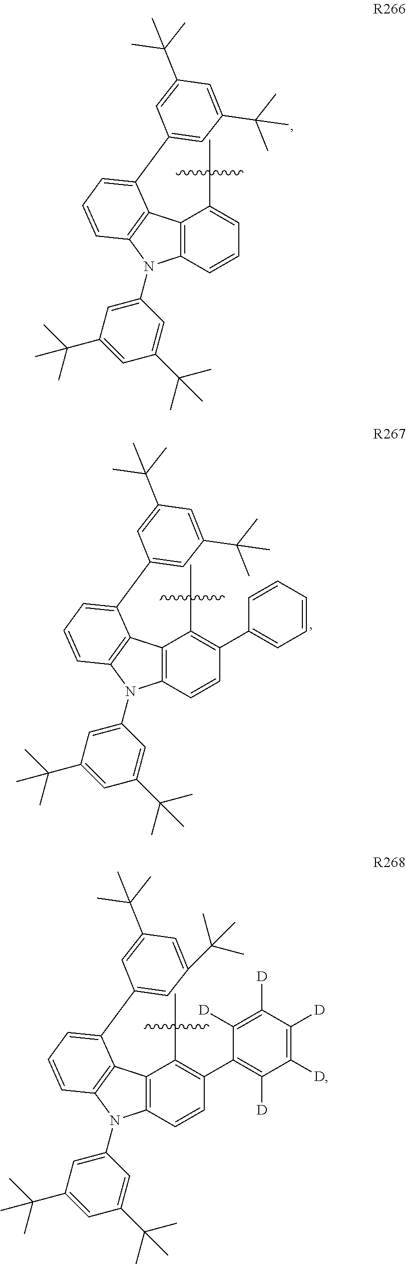

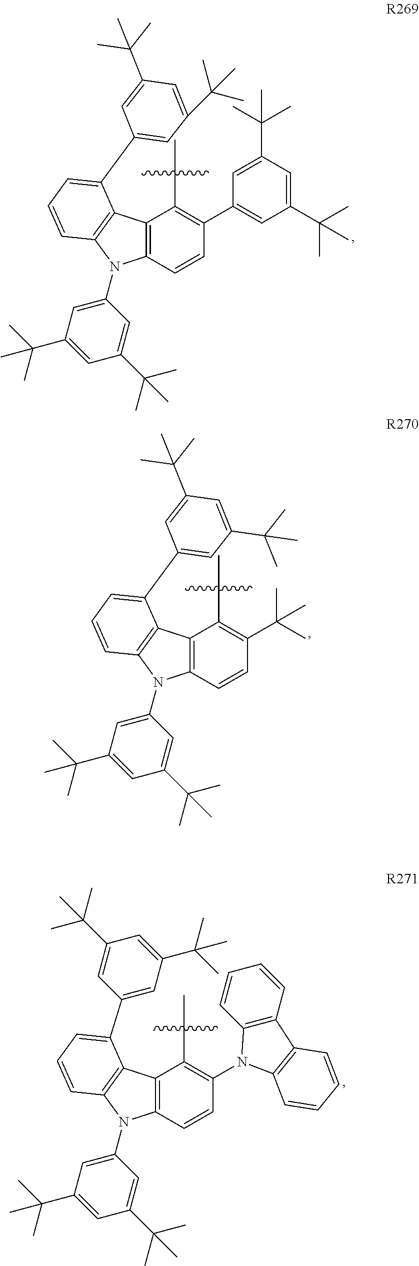

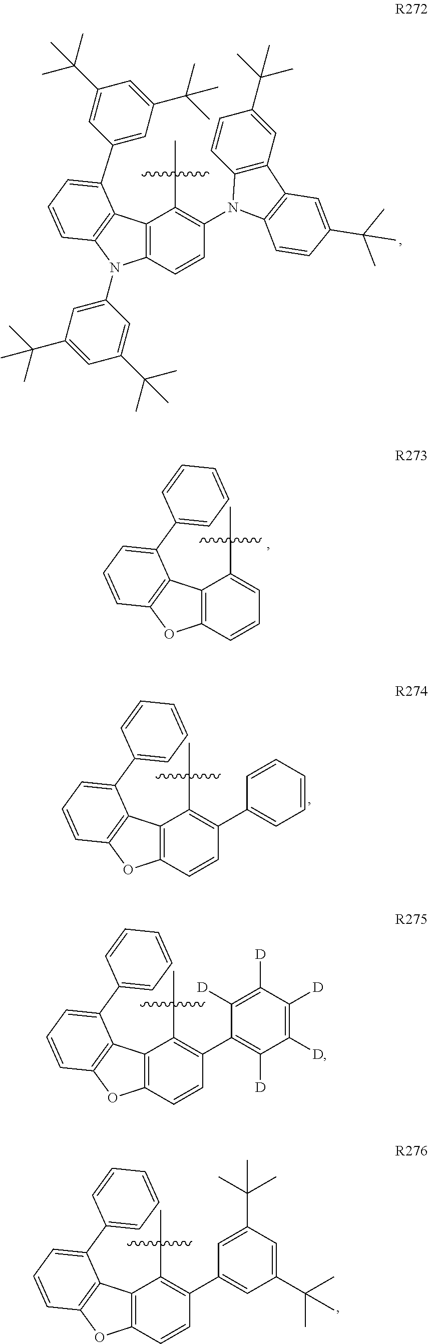

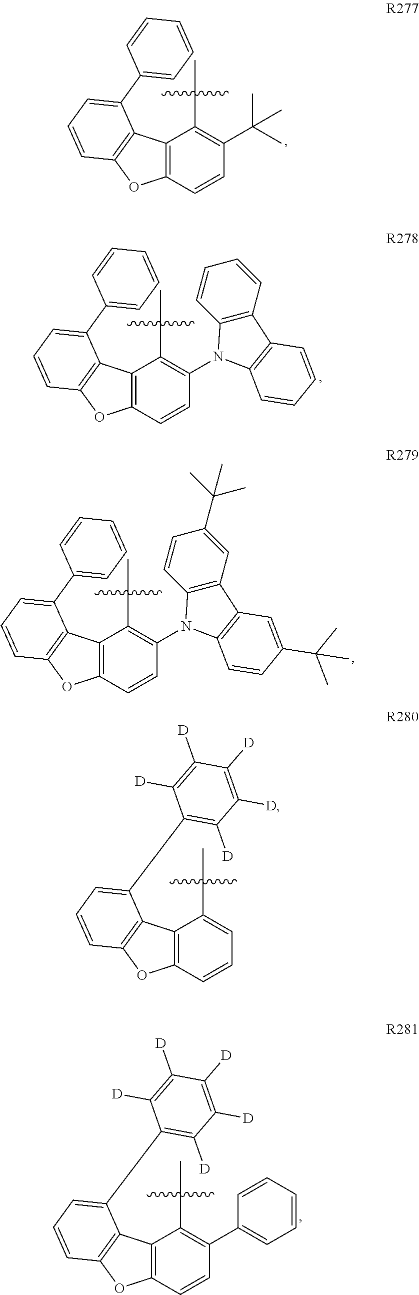

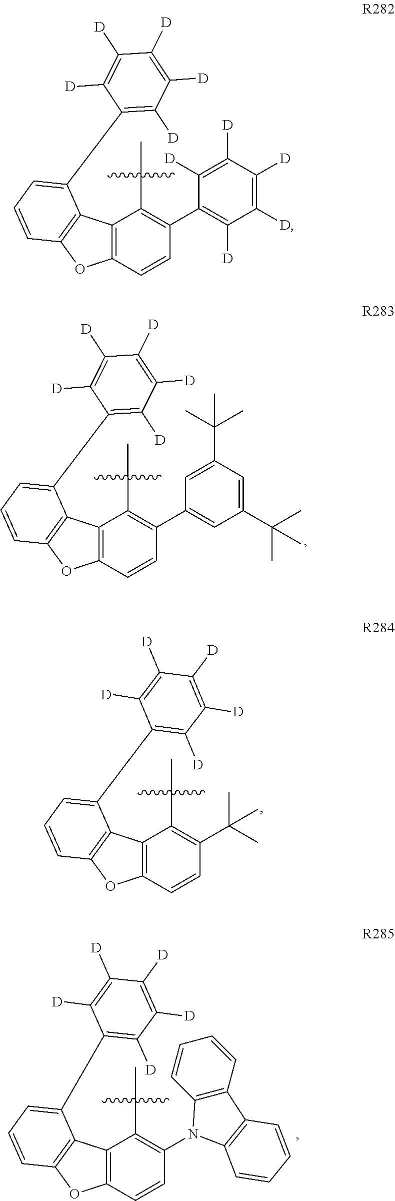

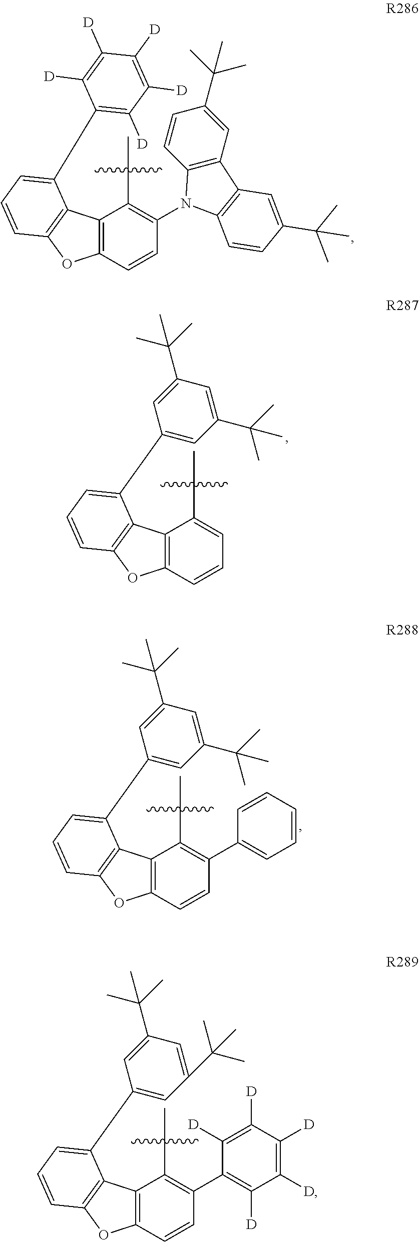

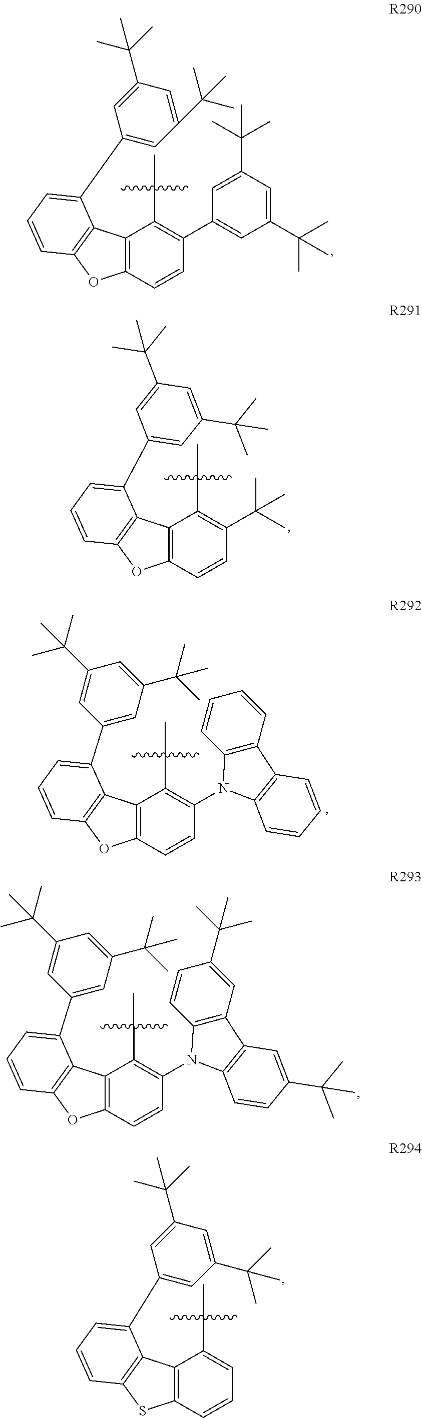

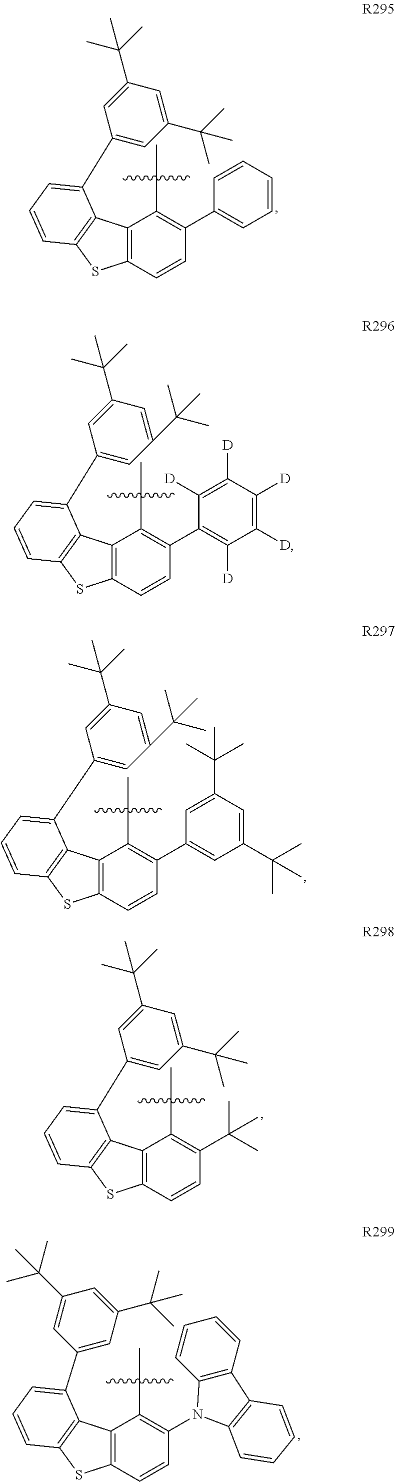

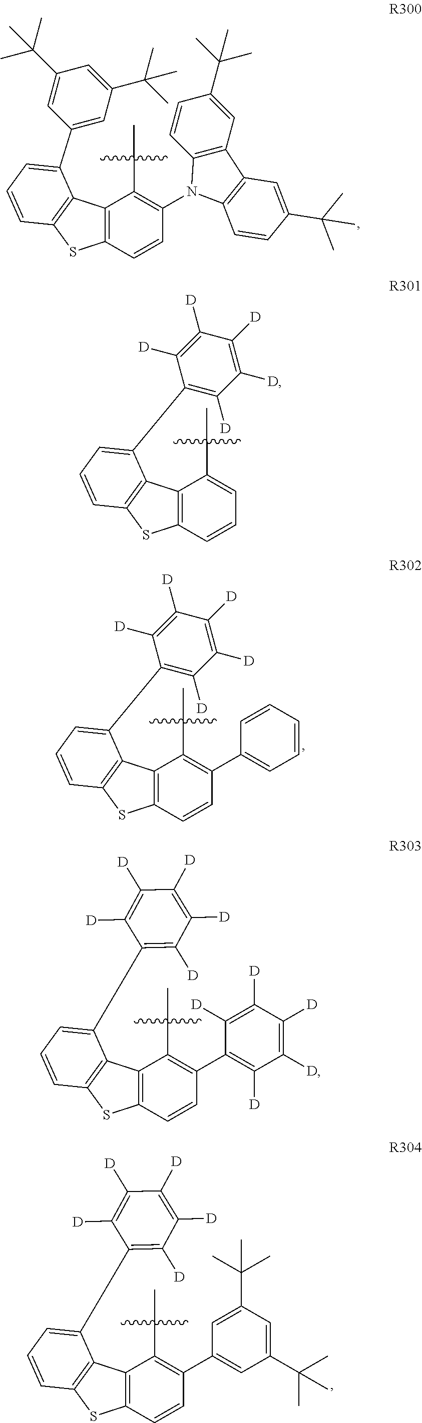

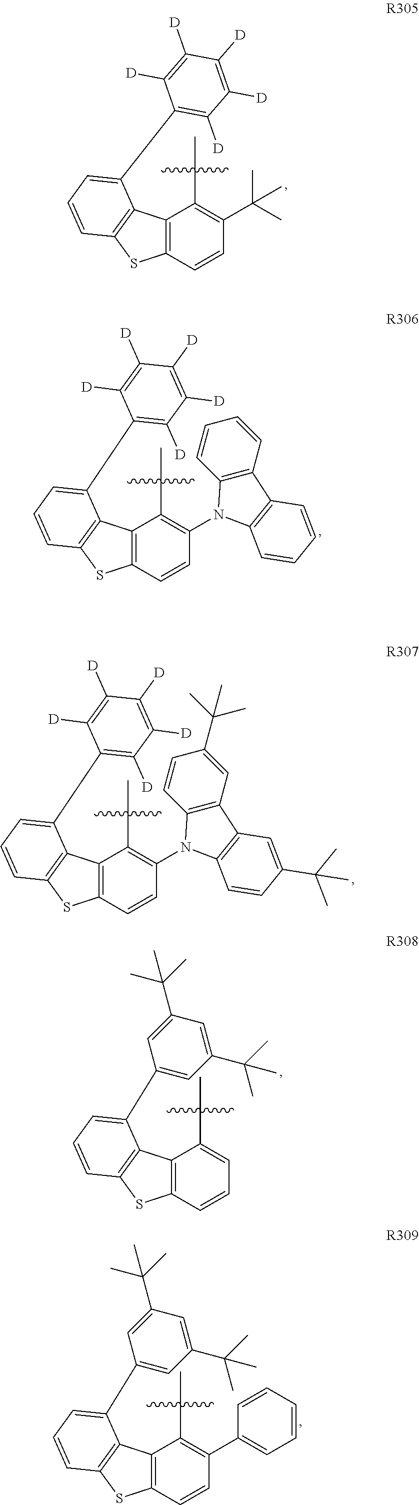

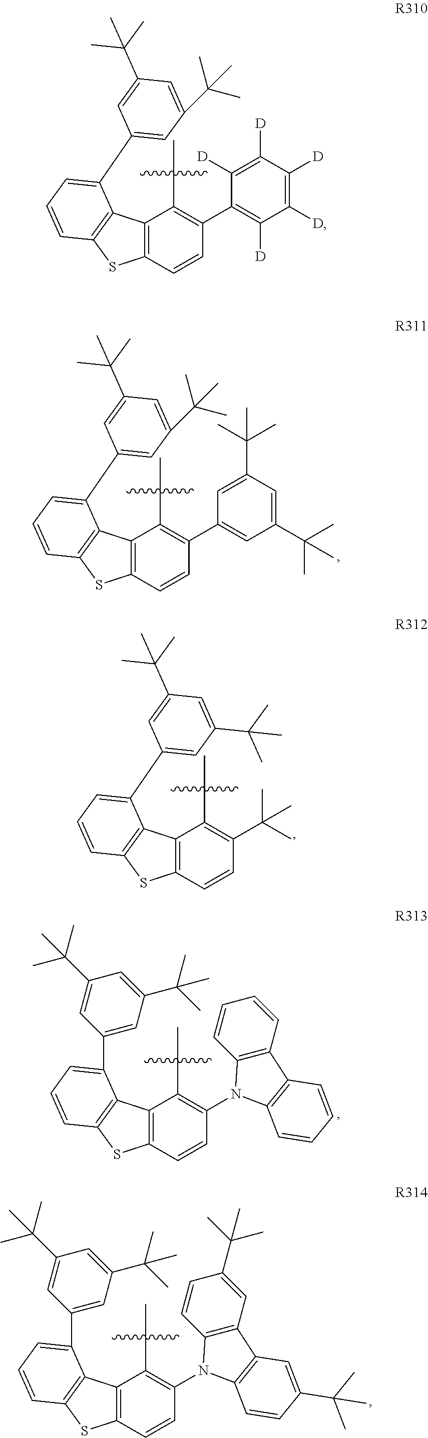

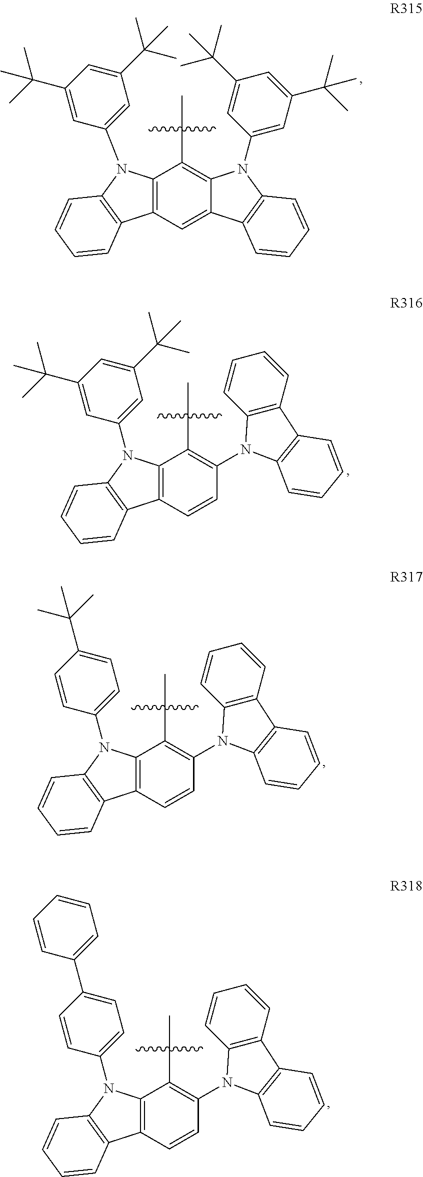

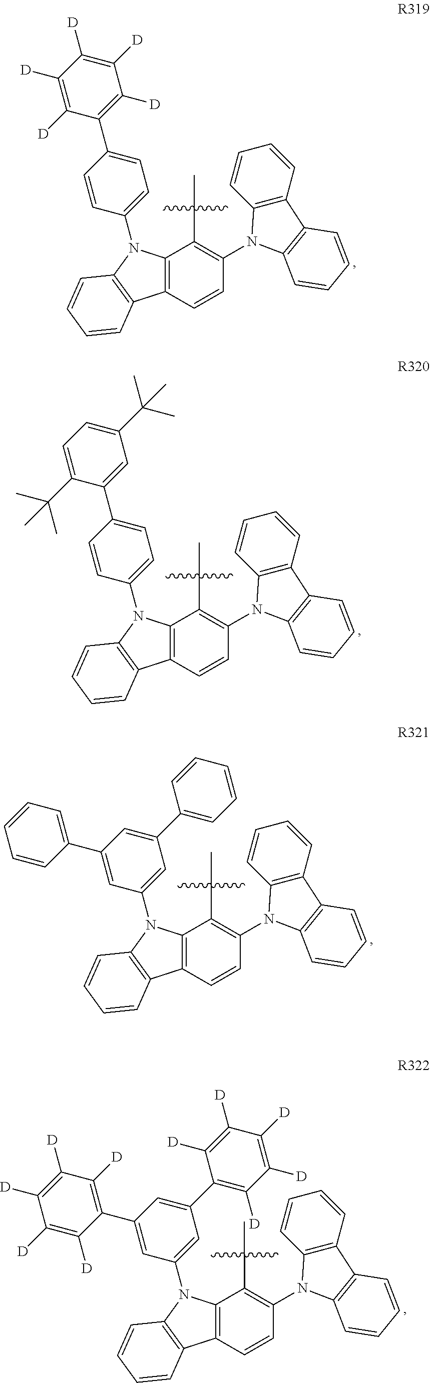

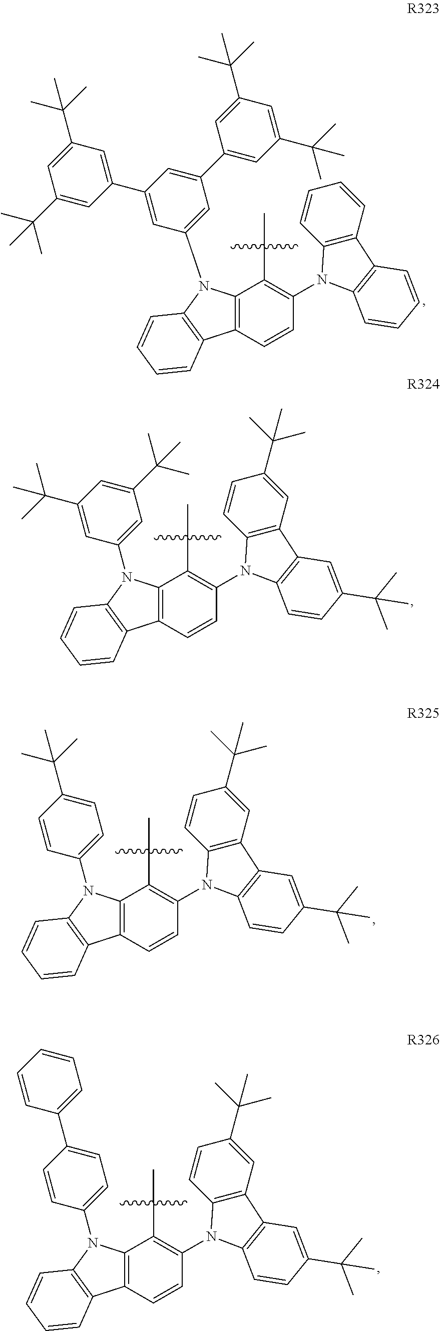

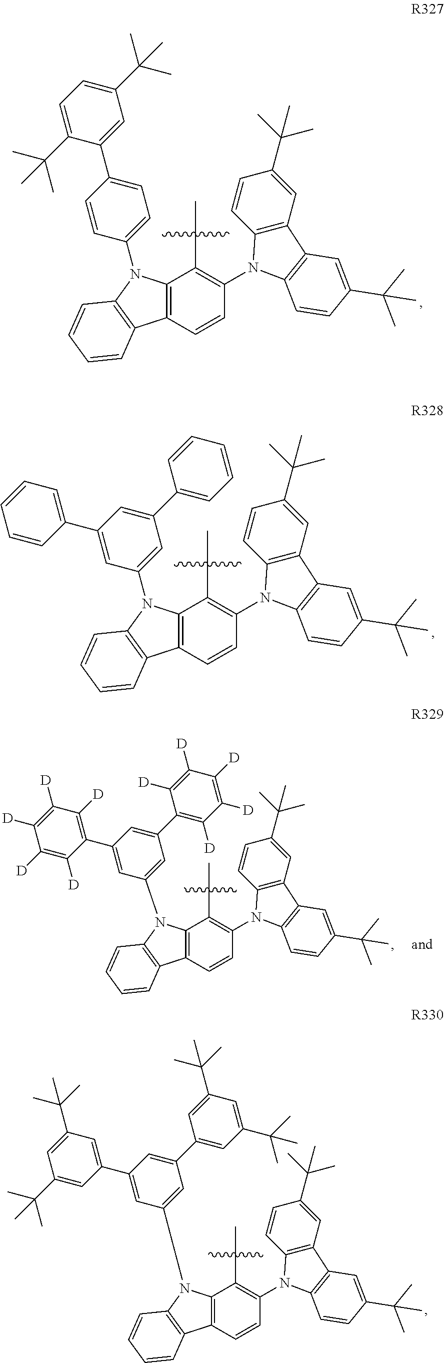

wherein L_{A} and L_{C} independently have the structures defined in the following LIST 3:

| | Structure | i, j, k, m, n, o |
|---|---|---|
| where L_{A} is I-(A′i)(Bj)(Bk) and L_{C} is I-(A′m)(Bn)(Bo) having the structure | 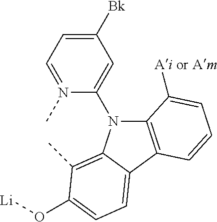 | wherein i is an integer from 1 to 7 and k is an integer from 1 to 47, and when i = 1 to 3, j is an integer from 1 to 41, and when i = 4 to 7, j is an integer from 1 to 47; wherein m is an integer from 1 to 7 and o is an integer from 1 to 47, and when m = 1 to 3, n is an integer from 1 to 41, and when m = 4 to 7, n is an integer from 1 to 47; wherein L_{A} and L_{C} are independently selected from the group consisting of I- (A′1)(B1)(B1) to I-(A′3)(B41)(B47), and I-(A′4)(B1)(B1) to I-(A′7)(B47)(B47), |
| where L_{A} is II- (A′i)(Bj)(Bk) and L_{C} is II (A′m)(Bn)(Bo) having the structure | 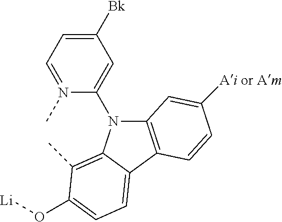 | wherein i is an integer from 1 to 7 and k is an integer from 1 to 47; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of II-(A′1)(B1)(B1) to II- (A′3)(B41)(B47), and II-(A′4)(B1)(B1) to II-(A′7)(B47)(B47), |
| where L_{A} is III- (A′i)(Bj)(Bk) and L_{C} is III- (A′m)(Bn)(Bo), having the structure | 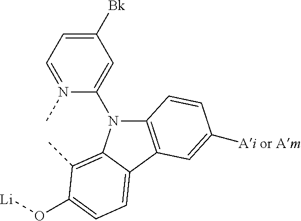 | wherein i is an integer from 1 to 7 and k is an integer from 1 to 47; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of III-(A′1)(B1)(B1) to III- (A′3)(B41)(B47), and III-(A′4)(B1)(B1) to III-(A′7)(B47)(B47), |
| where L_{A} is IV- (A′i)(Bj)(Bk) and L_{C} is IV- (A′m)(Bn)(Bo), having the structure | 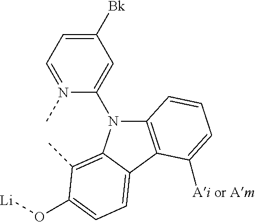 | wherein i is an integer from 1 to 7 and k is an integer from 1 to 47; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of IV-(A′1)(B1)(B1) to IV- (A′3)(B41)(B47), and IV-(A′4)(B1)(B1) to IV-(A′7)(B47)(B47), |
| where L_{A} is V- (A′i)(Bj)(Bk) and L_{C} is V- (A′m)(Bn)(Bo), having the structure | 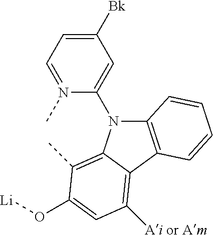 | wherein i is an integer from 1 to 7 and k is an integer from 1 to 47; when i or m = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of V-(A′1)(B1)(B1) to V- (A′3)(B41)(B47), and V-(A′4)(B1)(B1) to V-(A′7)(B47)(B47), |
| where L_{A} is VI- (A′i)(Bj)(Bk) and L_{C} is VI- (A′m)(Bn)(Bo), having the structure | 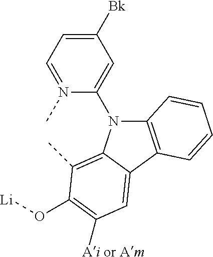 | wherein i is an integer from 1 to 7 and k is an integer from 1 to 47; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of VI-(A′1)(B1)(B1) to VI- (A′3)(B41)(B47), and VI-(A′4)(B1)(B1) to VI-(A′7)(B47)(B47), |
| where L_{A} is VII-(A′i)(Bj) and L_{C} is VII-(A′m)(Bn), having the structure | 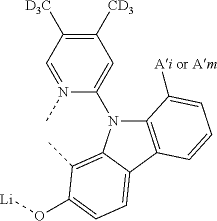 | wherein i is an integer from 1 to 7; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of VII-(A′1)(B1)(B1) to VII- (A′3)(B41)(B47), and VII-(A′4)(B1)(B1) to VII-(A′7)(B47)(B47), |
| where L_{A} is VIII-(A′i)(Bj) and L_{C} is VIII-(A′m)(Bn), having the structure | 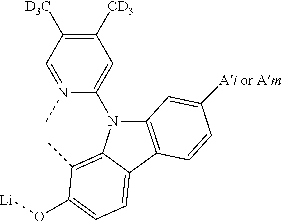 | wherein i is an integer from 1 to 7; when i = 1 to 3, j is an integer from 1 to 41 and when i or m = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of VII-(A′1)(B1)(B1) to VII- (A′3)(B41)(B47), and VII-(A′4)(B1)(B1) to VII-(A′7)(B47)(B47), |
| where L_{A} is IX-(A′i)(Bj) and L_{C} is IX-(A′m)(Bn), having the structure | 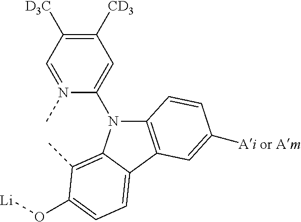 | wherein i is an integer from 1 to 7; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of IX-(A′1)(B1)(B1) to IX- (A′3)(B41)(B47), and IX-(A′4)(B1)(B1) to IX-(A′7)(B47)(B47), |
| where L_{A} is X-(A′i)(Bj) and L_{C} is X-(A′m)(Bn), having the structure | 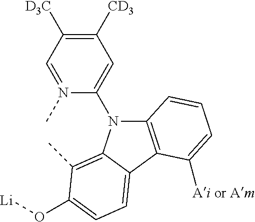 | wherein i is an integer from 1 to 7; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of X-(A′1)(B1)(B1) to X- (A′3)(B41)(B47), and X-(A′4)(B1)(B1) to X-(A′7)(B47)(B47), |
| where L_{A} is XI-(A′i)(Bj) and L_{C} is XI-(A′m)(Bn), having the structure | 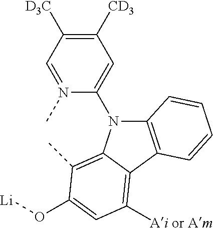 | wherein i is an integer from 1 to 7; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of XI-(A′1)(B1)(B1) to XI- (A′3)(B41)(B47), and XI-(A4)(B1)(B1) to XI-(A′7)(B47)(B47), |
| where L_{A} is XII-(A′i)(Bj) and L_{C} is XII-(A′m)(Bn), having the structure | 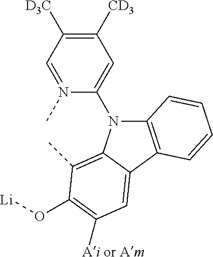 | wherein i is an integer from 1 to 7; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of XII-(A′1)(B1)(B1) to XII- (A′3)(B41)(B47), and XII-(A′4)(B1)(B1) to XI-(A′7)(B47)(B47), |
| where L_{A} is XIII- (A′i)(Bj)(Bk) and L_{C} is XIII-(A′m)(Bn)(Bo), having the structure | 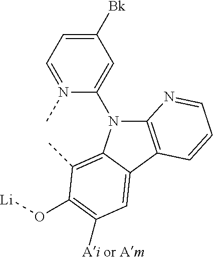 | wherein i is an integer from 1 to 7 and k is an integer from 1 to 47; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of XIII-(A′1)(B1)(B1) to XIII- (A′3)(B41)(B47), and XIII-(A′4)(B1)(B1) to XI-(A′7)(B47)(B47), |
| where L_{A} is XIV- (A′)(Bj)(Bk) and L_{C} is XIV-(A′m)(Bn)(Bo), having the structure | 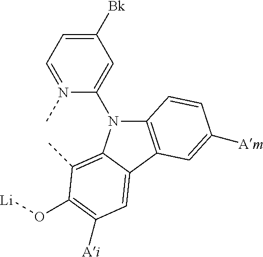 | wherein i is an integer from 1 to 7 and k is an integer from 1 to 47; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of XII-(A′1)(B1)(B1) to XII- (A′3)(B41)(B47), and XII-(A′4)(B1)(B1) to XI-(A′7)(B47)(B47), |

wherein A′1 to A′7 have the following structures:

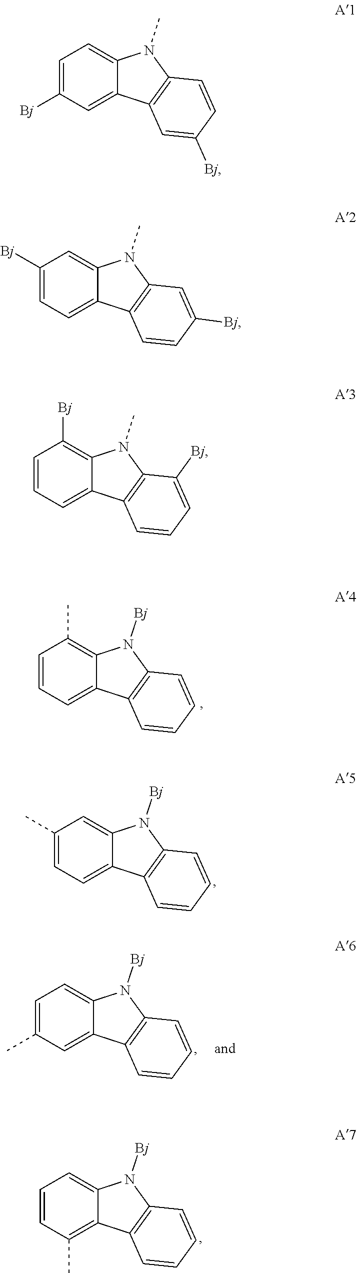

wherein B1 to B47 have the following structures:

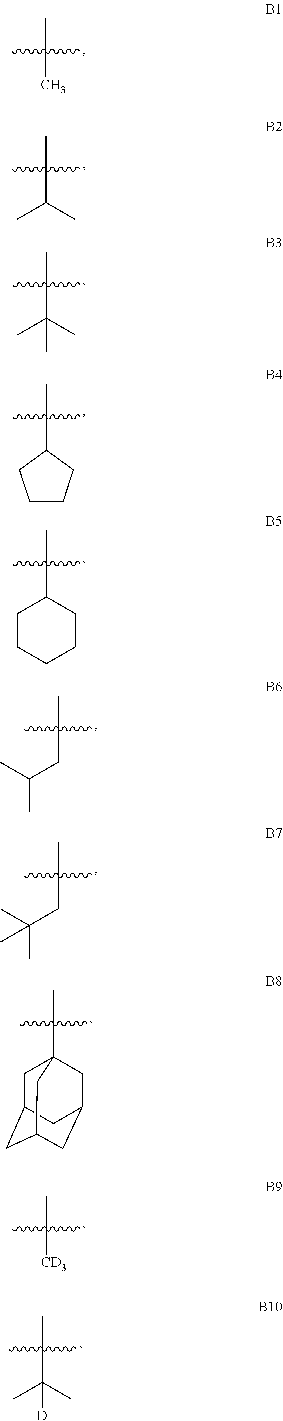

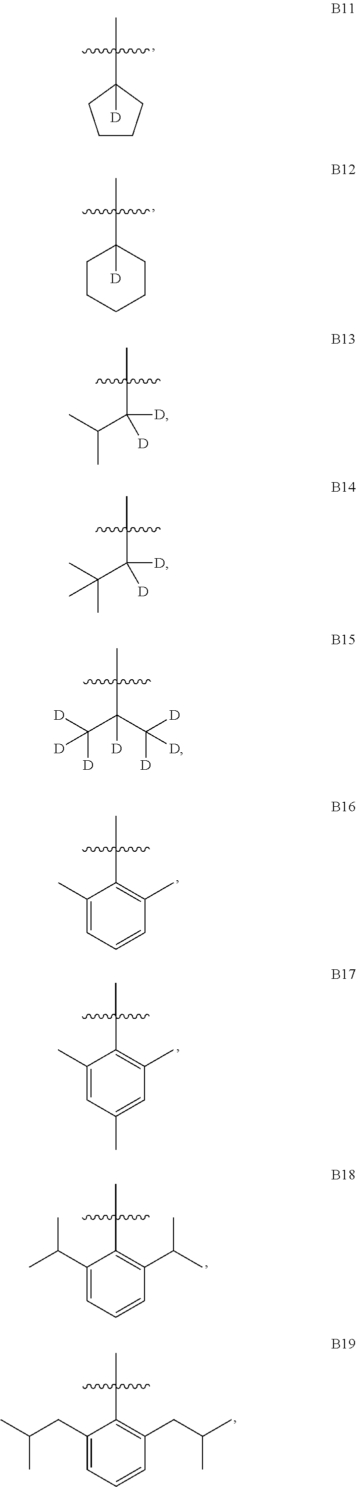

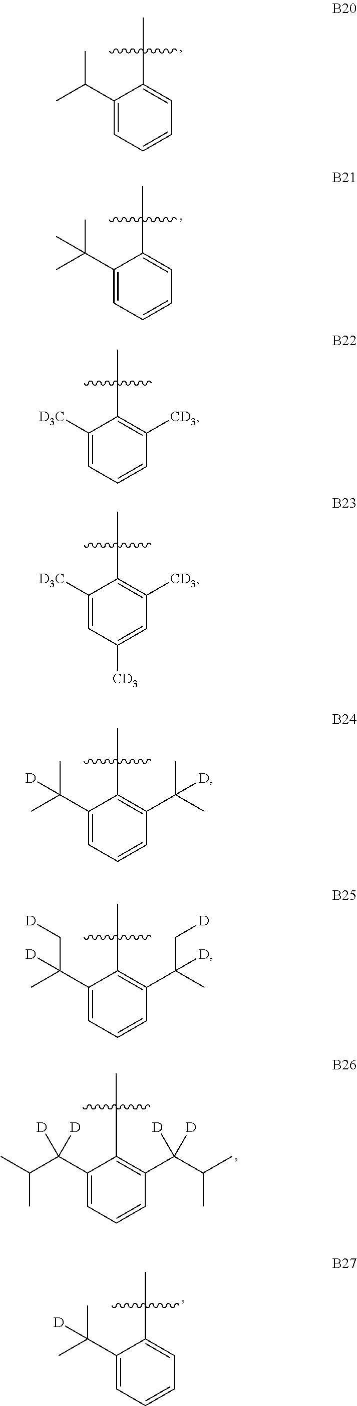

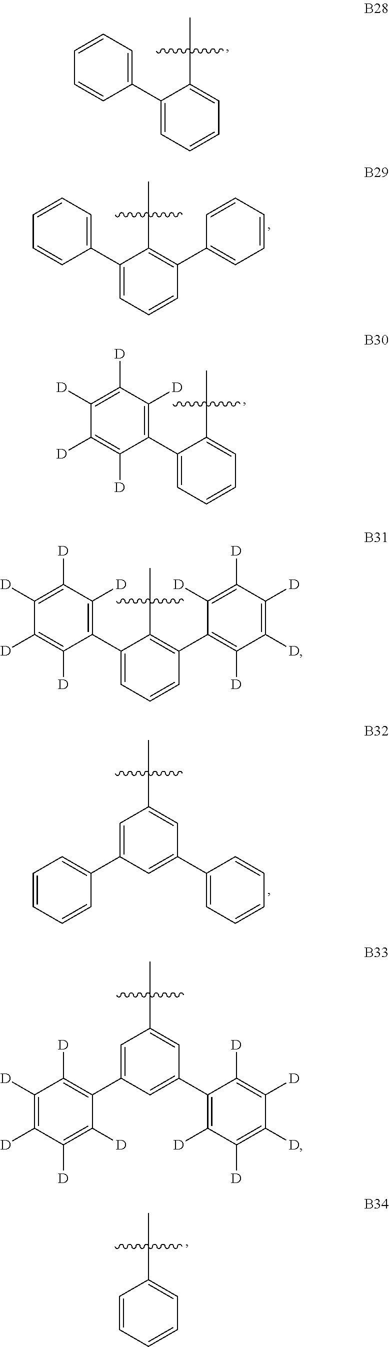

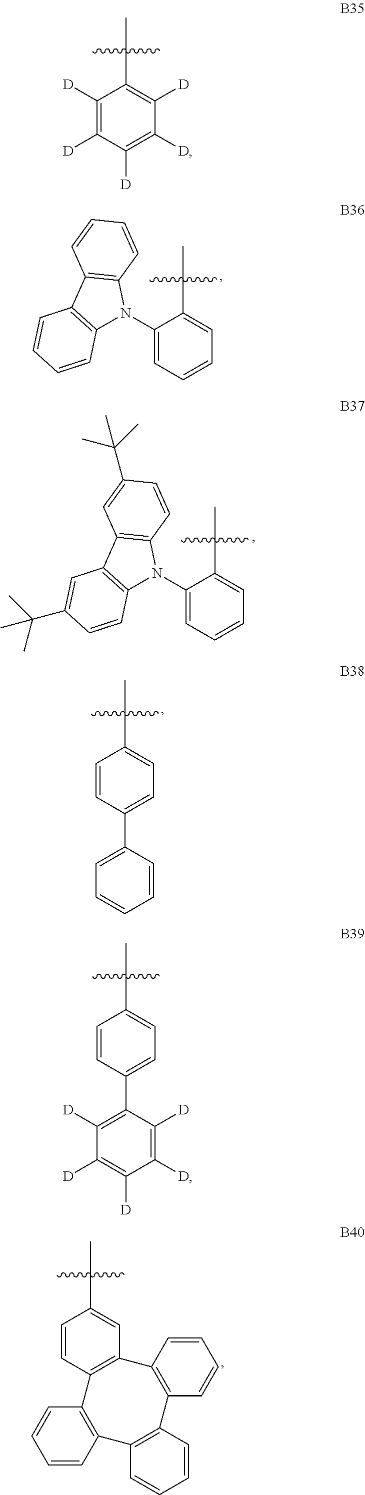

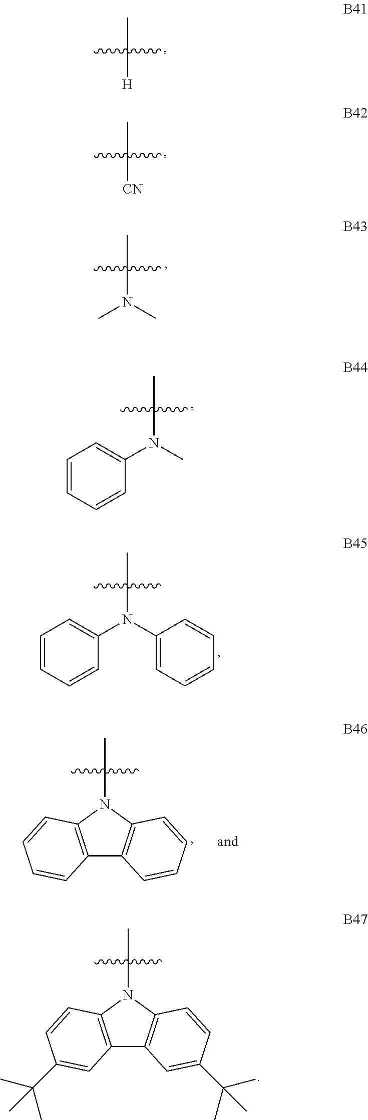

In some embodiments, each of Bj and Bk can be independently selected from the group consisting of B1, B2, B3, B9, B10, B16, B18, B20, B22, B24, B25, B27, B29, B31, B32, B33, B34, B34, B40, B44, B45, and B46.

In some embodiments, Ai for each occurrence can be independently selected from the group consisting of A1, A2, A3, A7, A10, A11, A12, A13, A19, A20, A21, A23, and A29.

In some embodiments, R¹ for each occurrence can be independently selected from the group consisting of R1, R2, R3, R10, R12, R20, R21, R22, R23, R27, R28, R29, R37, R38, R40, R41, R42, R52, R53, R54, R66, R67, R73, R74, R93, R94, R96, R101, R106, R130, R134, R135, R136, R137, R316, R317, R321, R322, R328, R329, and R330.

In some embodiments, the compound can be selected from the group consisting of LIST 4 below:

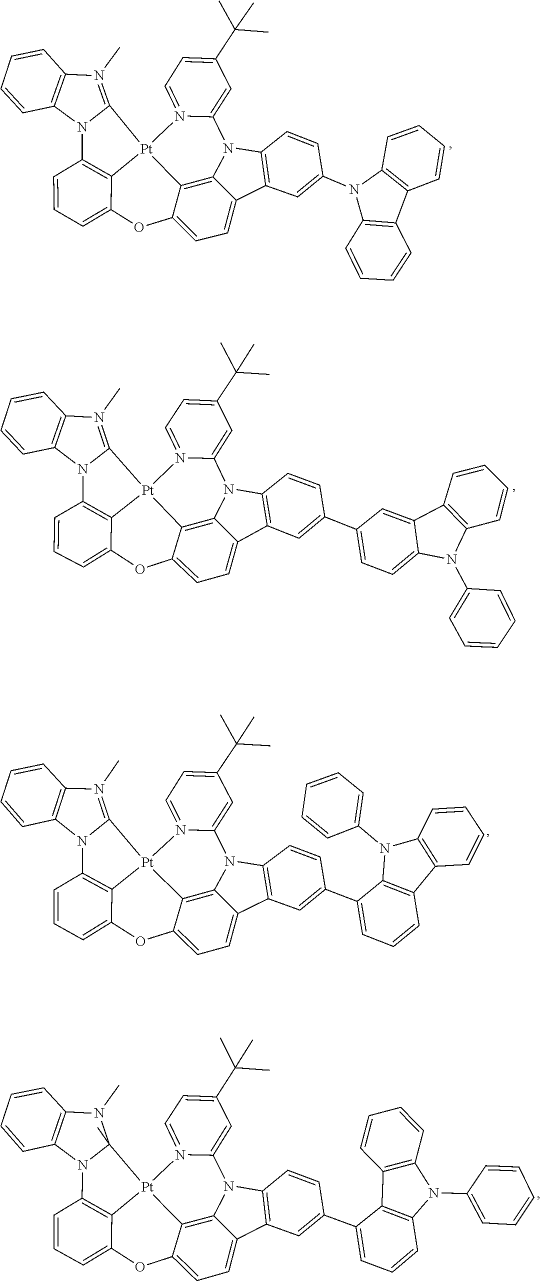

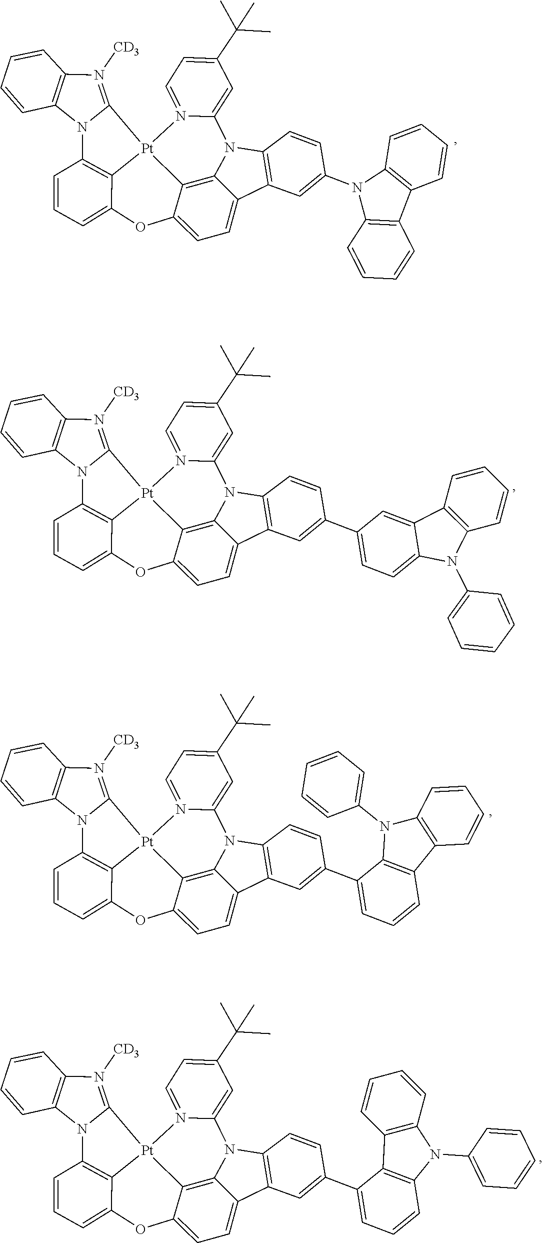

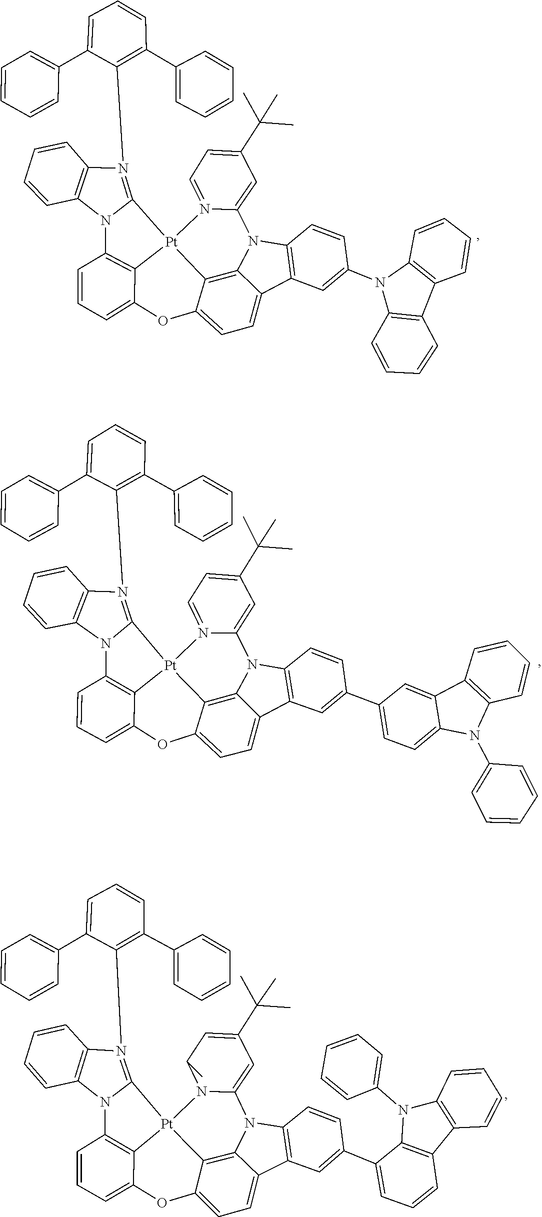

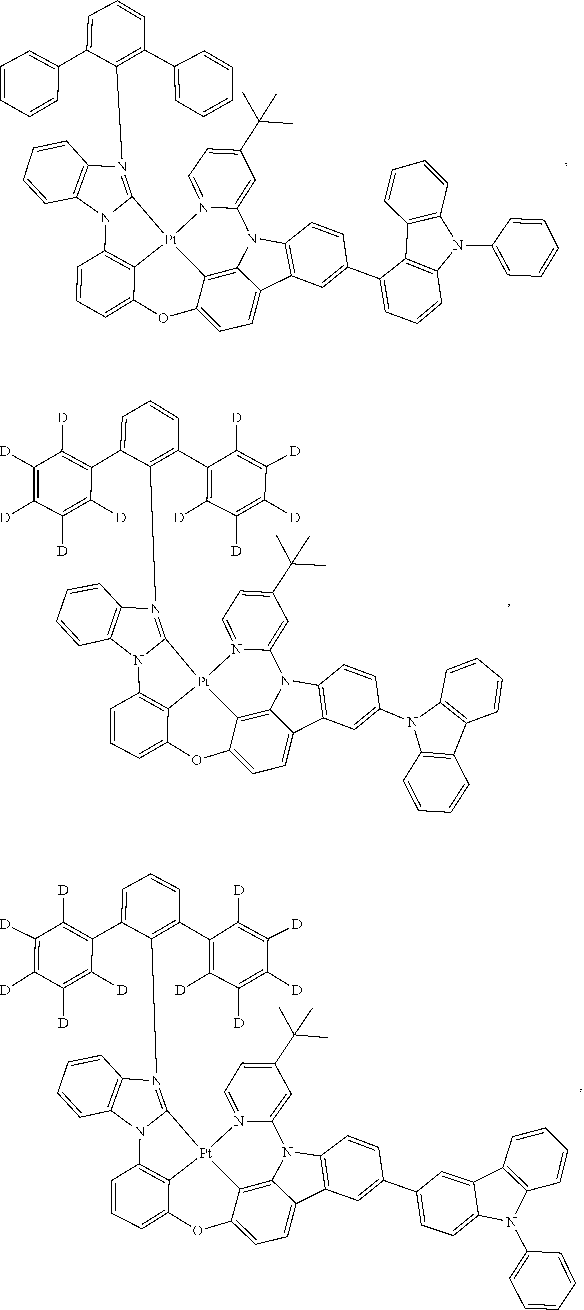

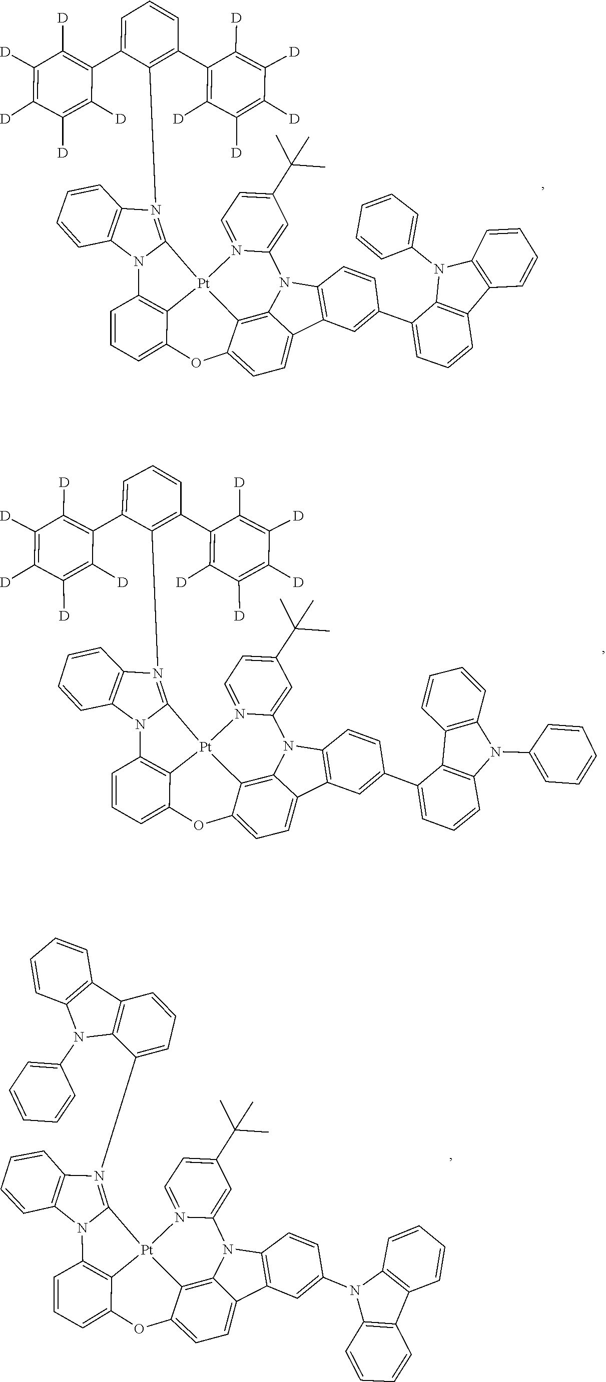

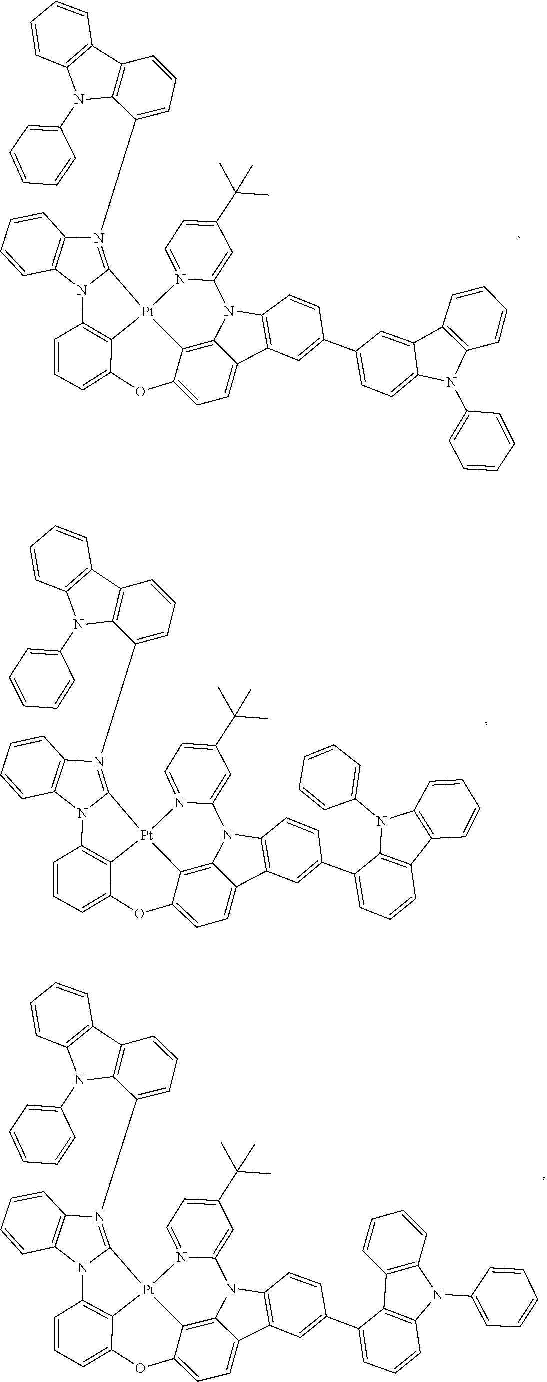

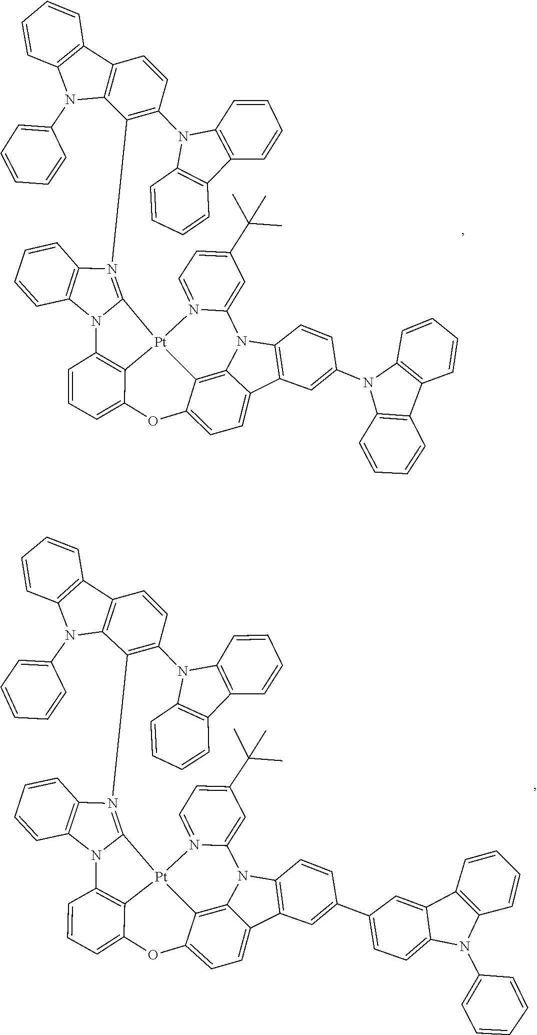

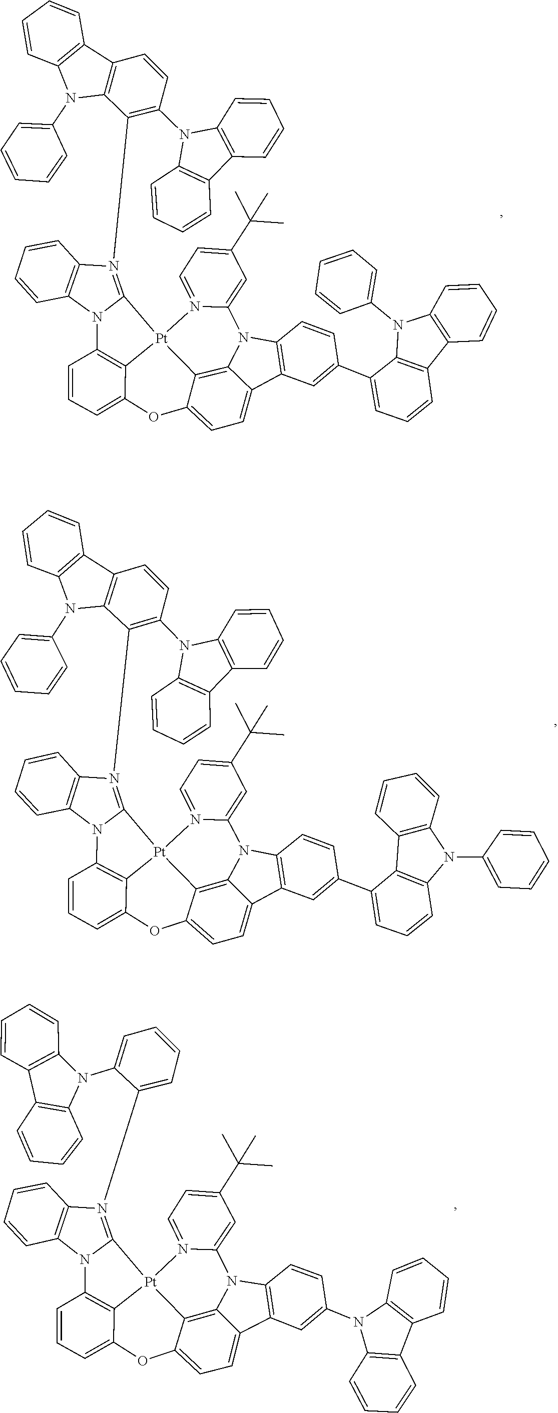

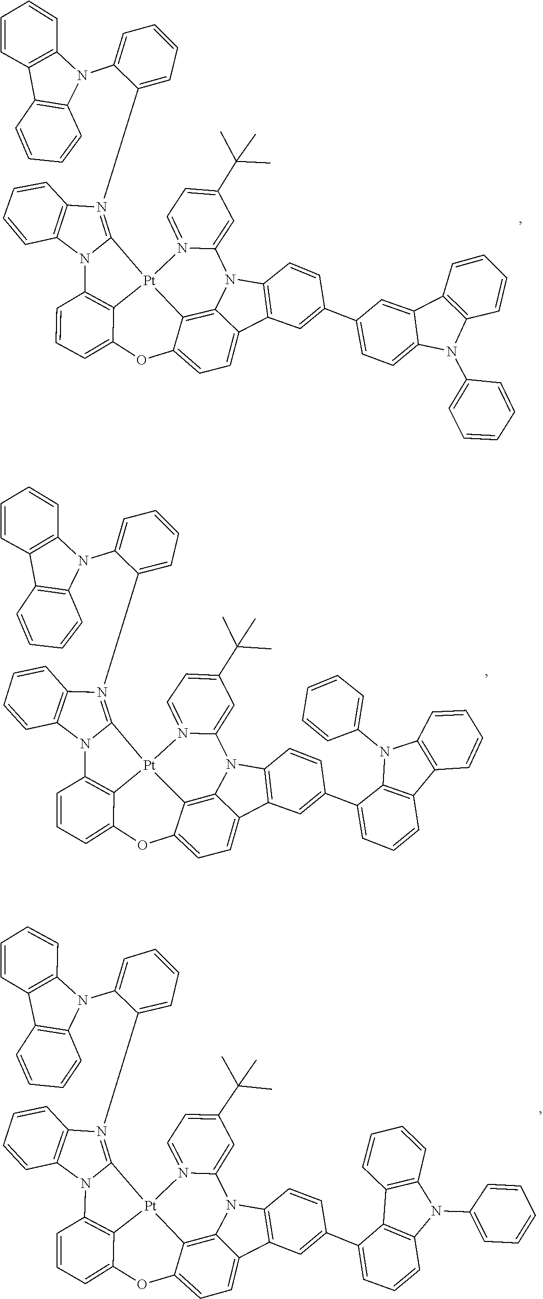

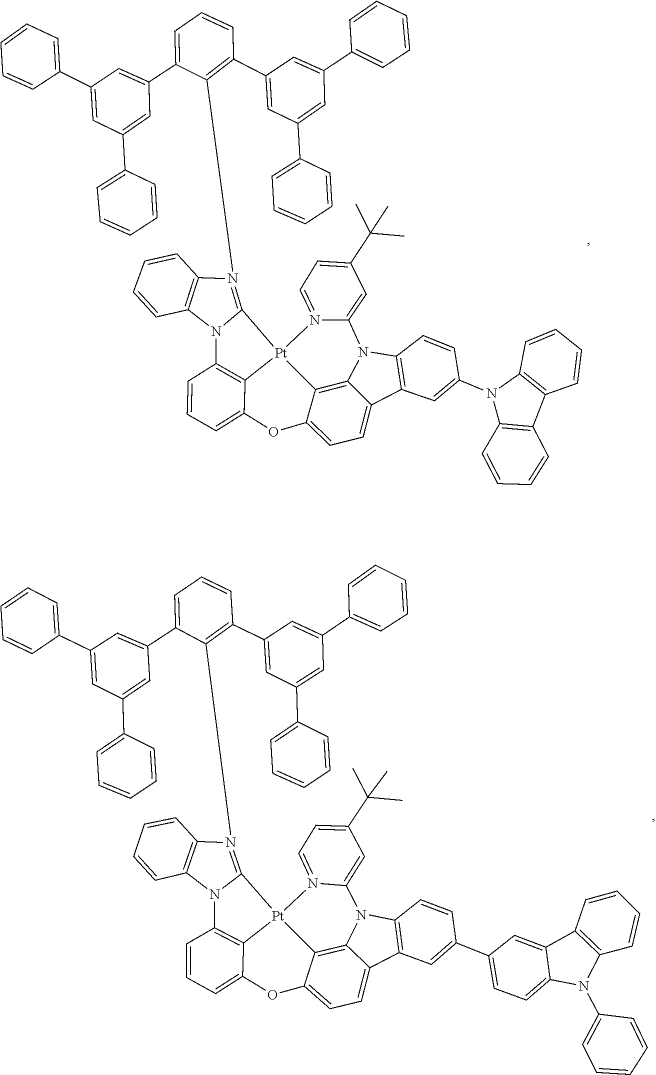

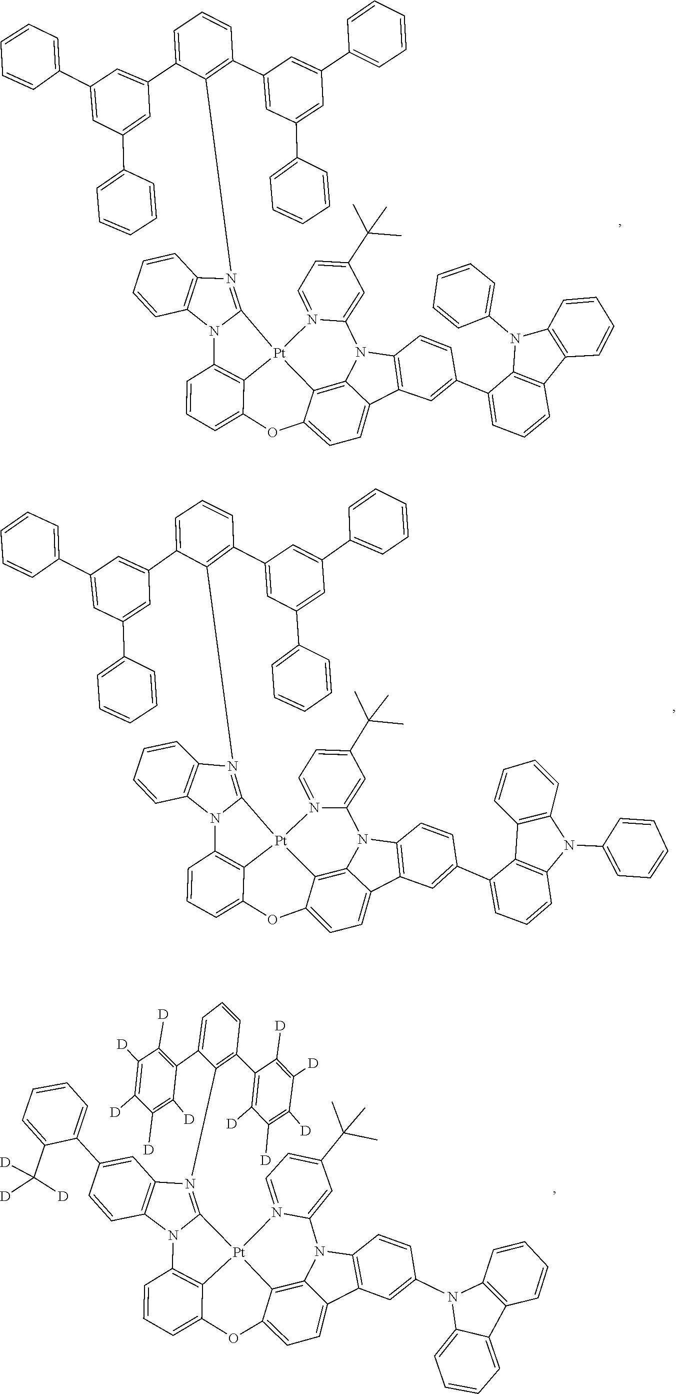

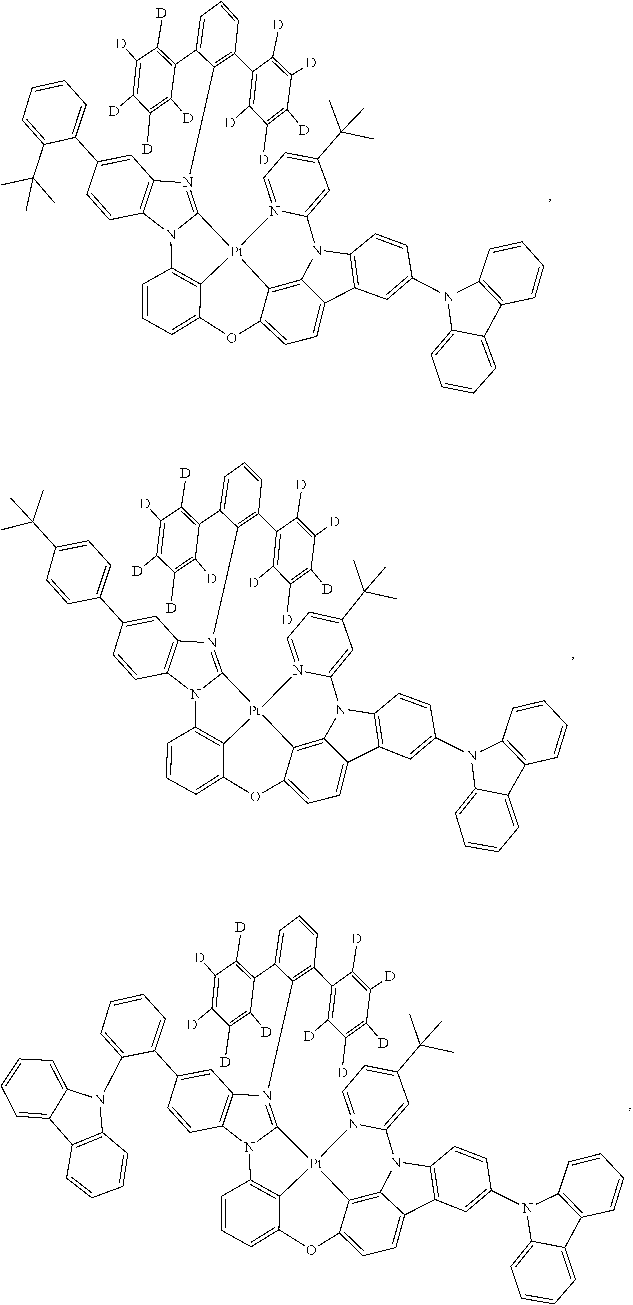

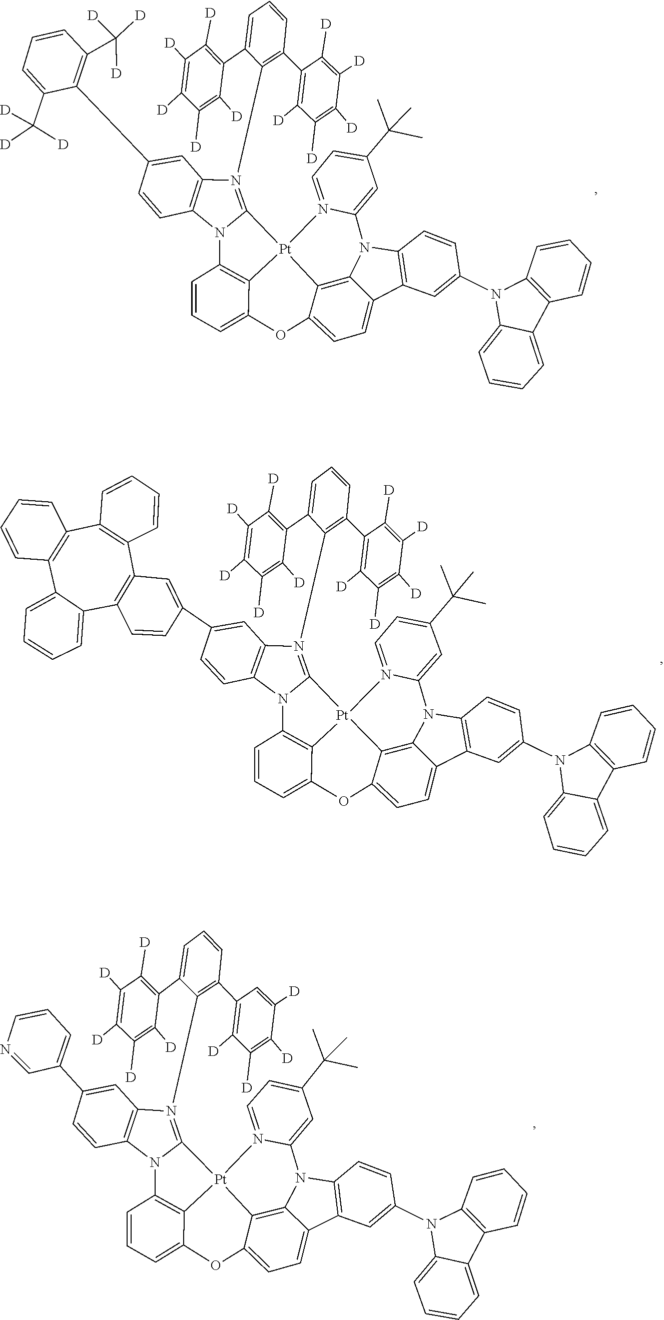

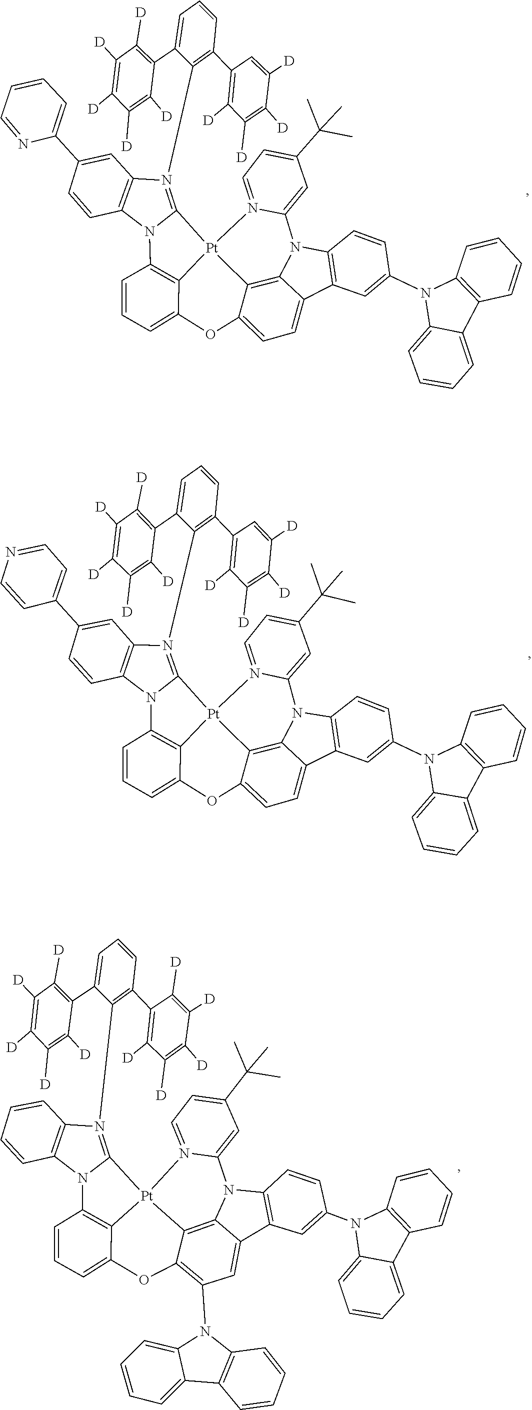

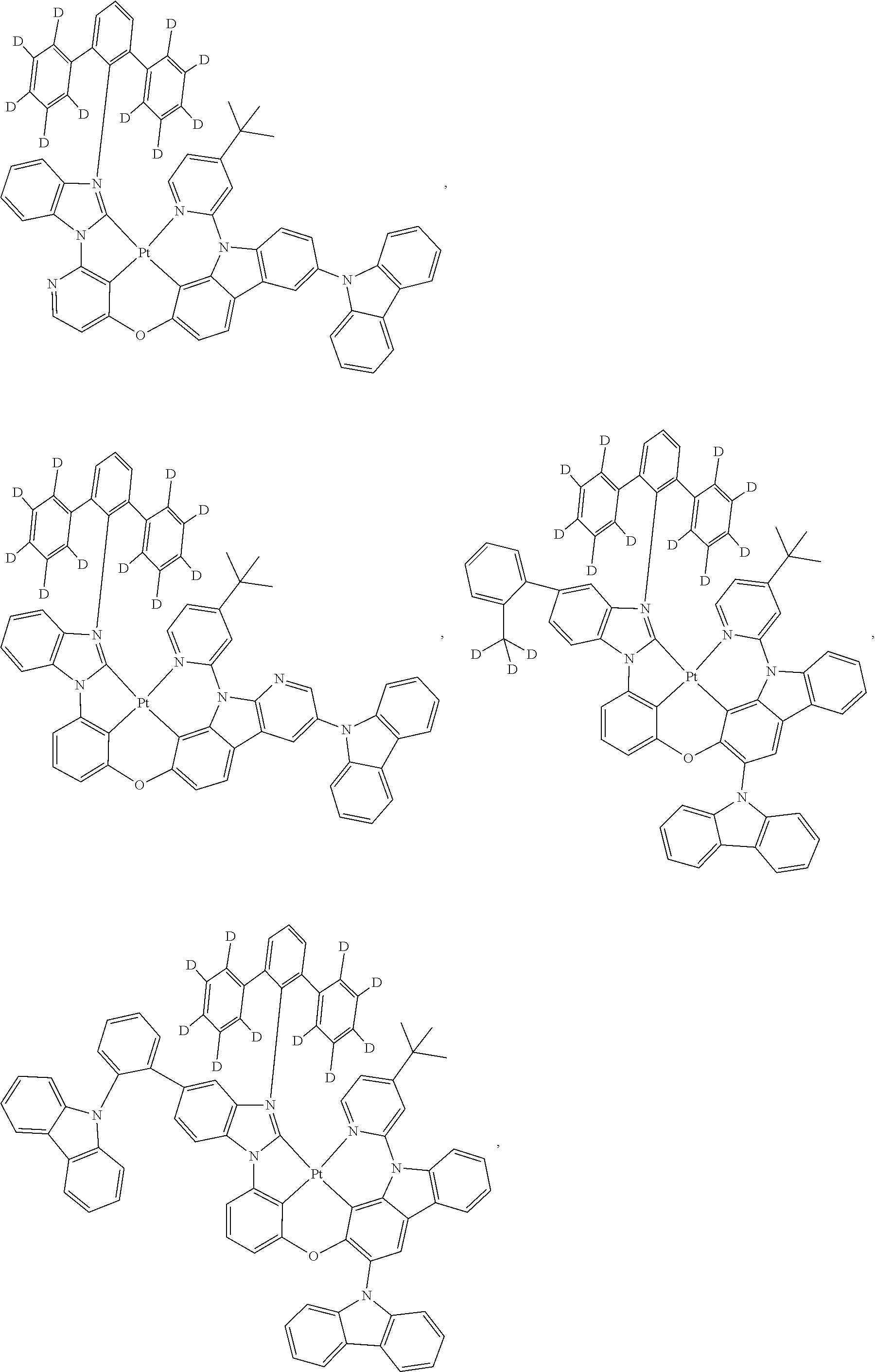

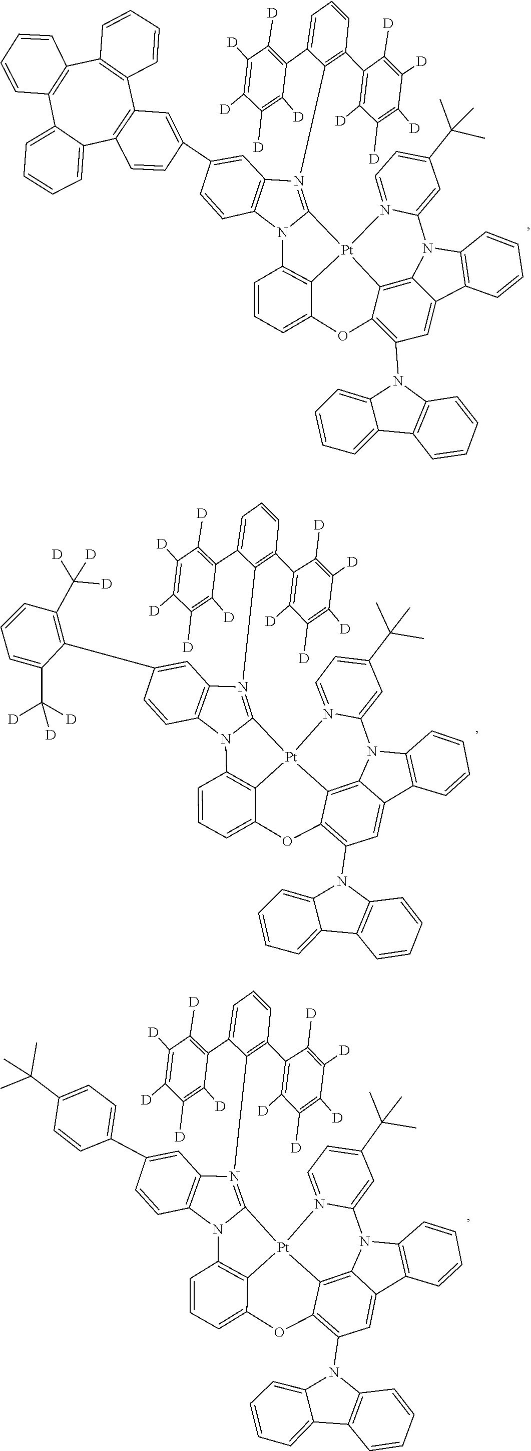

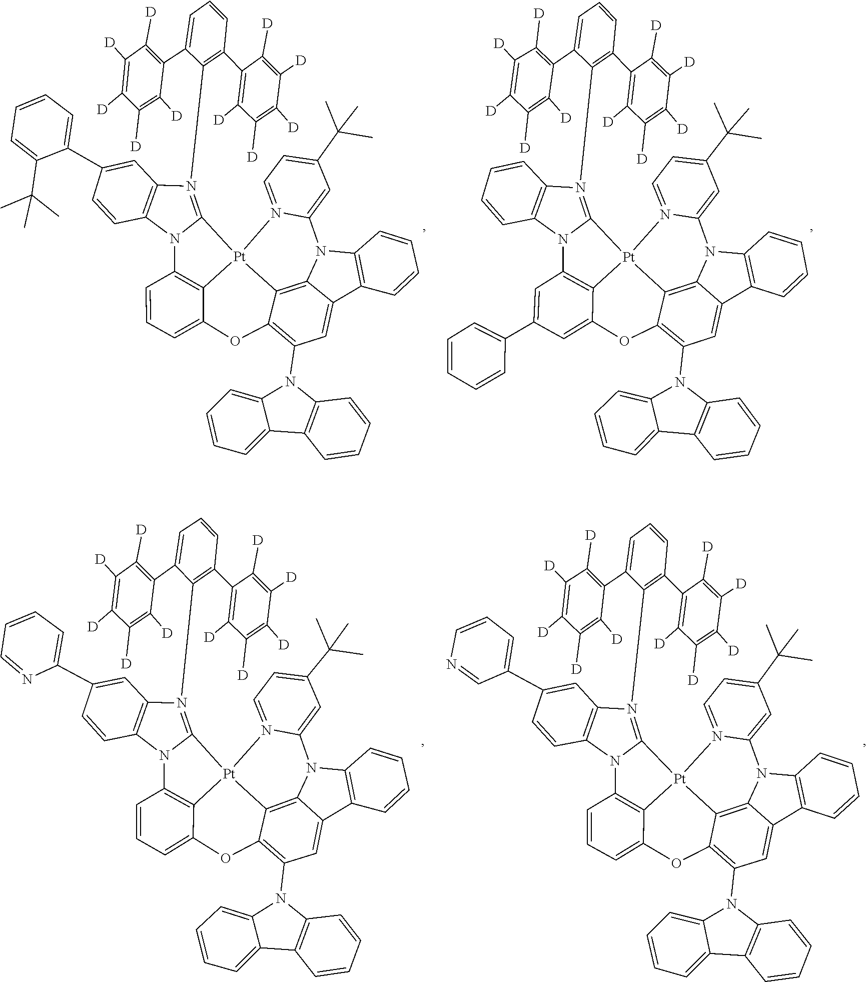

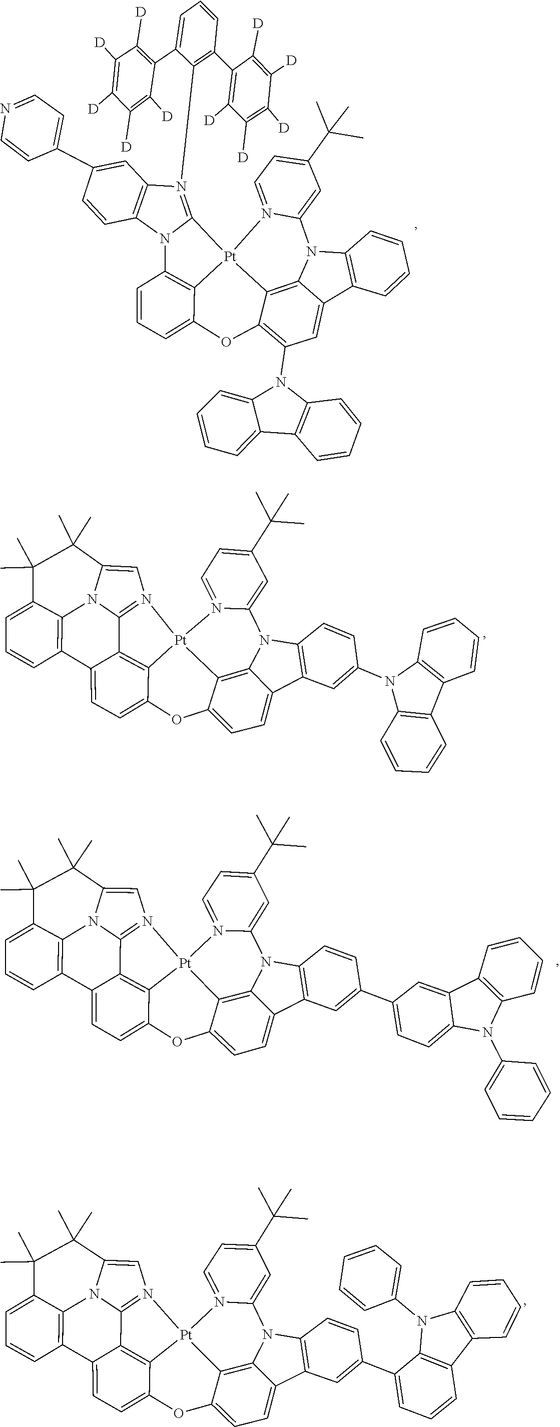

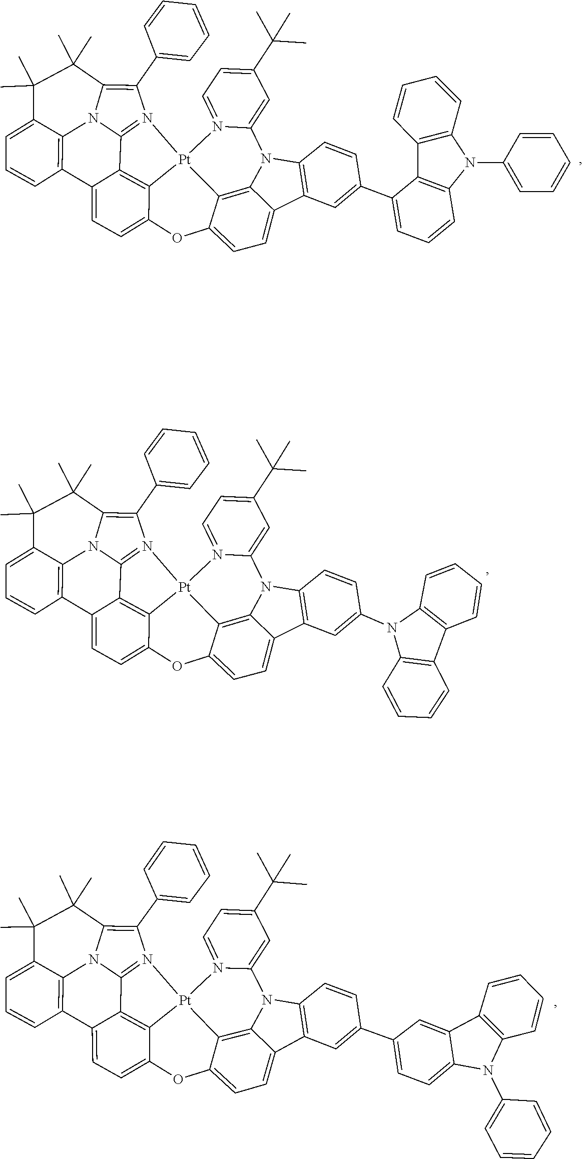

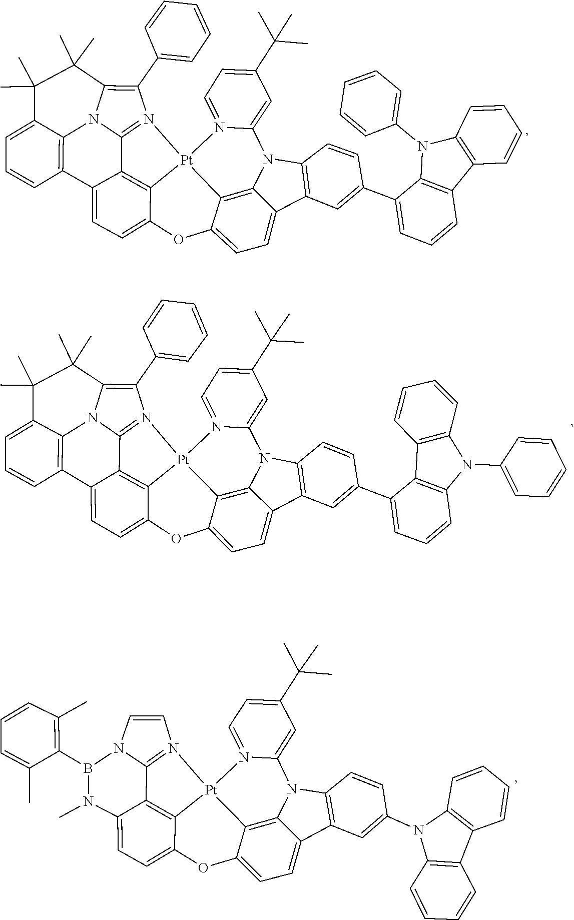

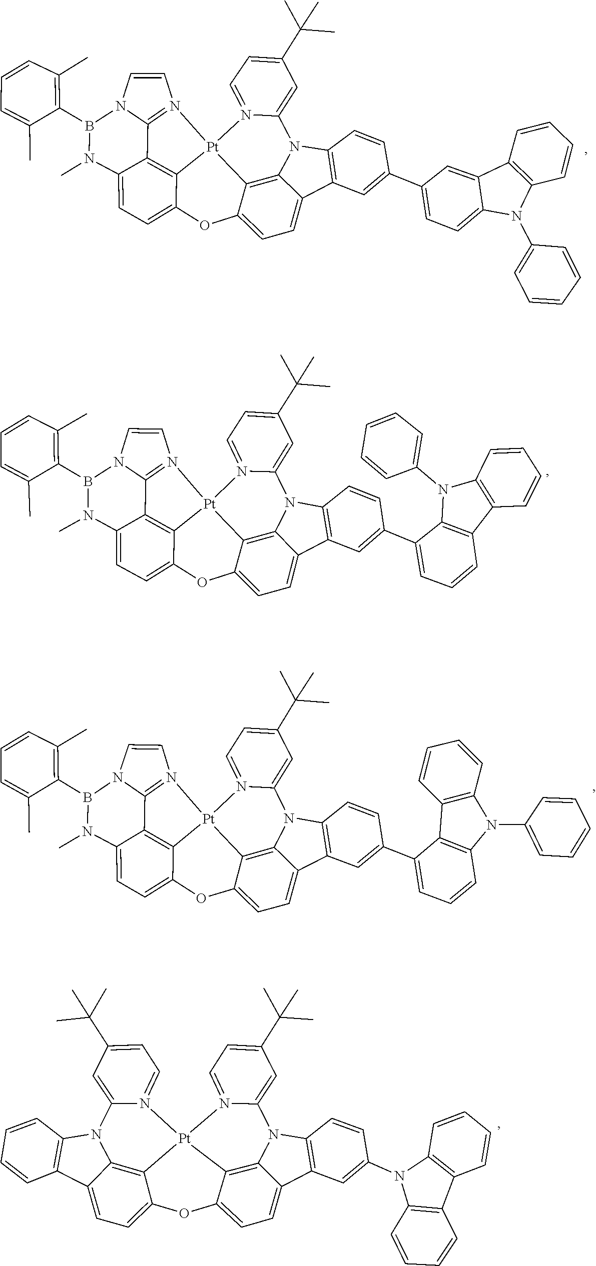

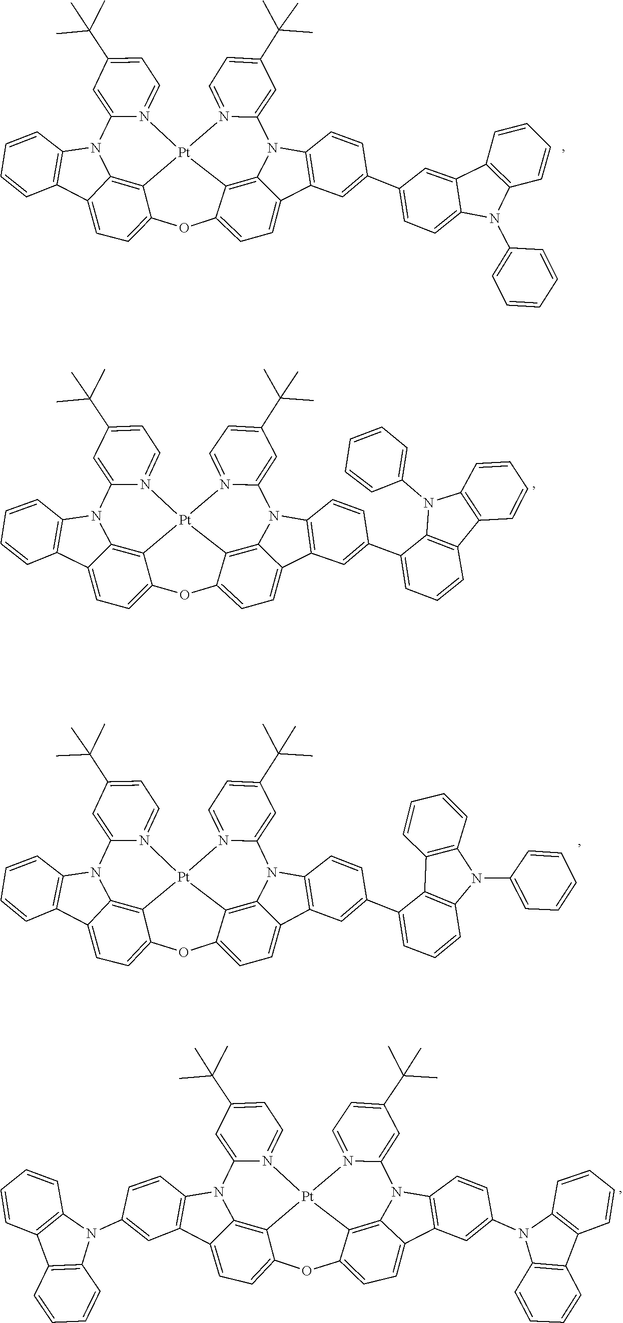

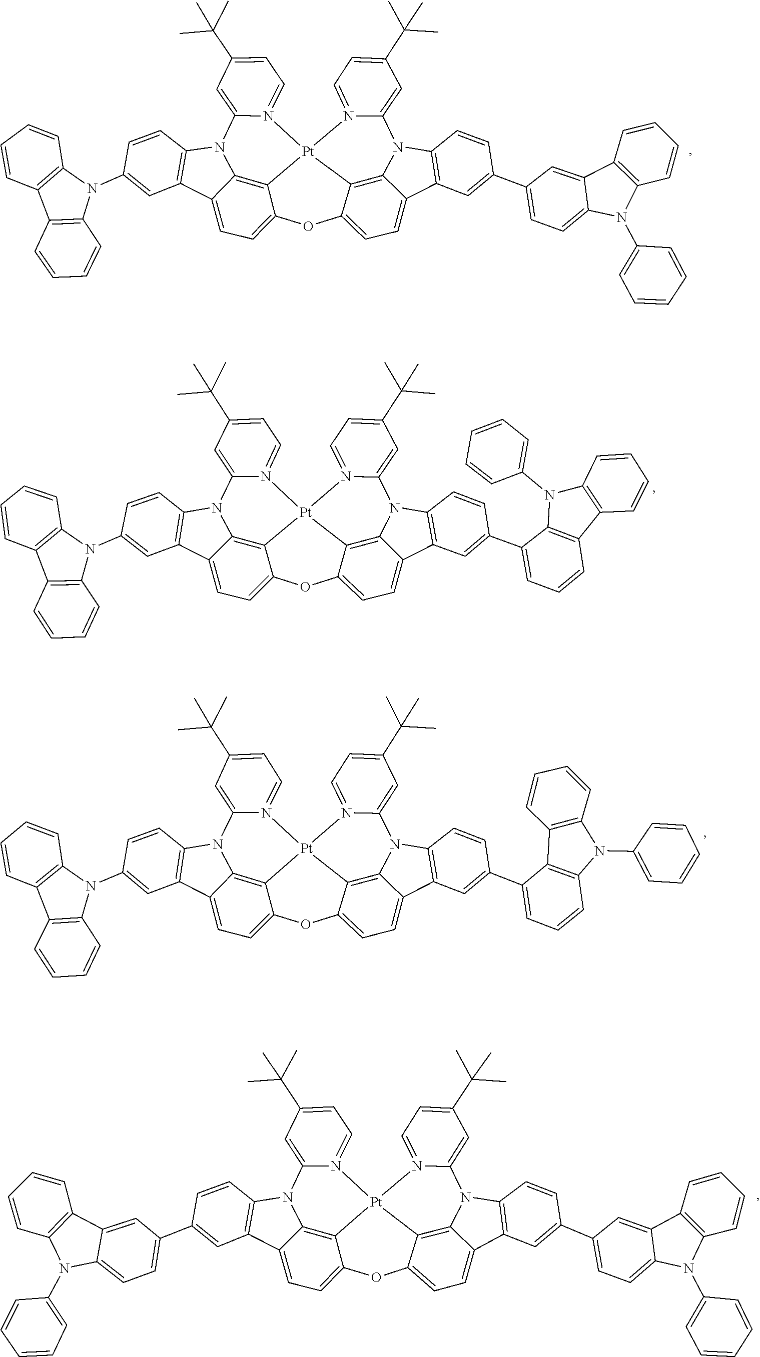

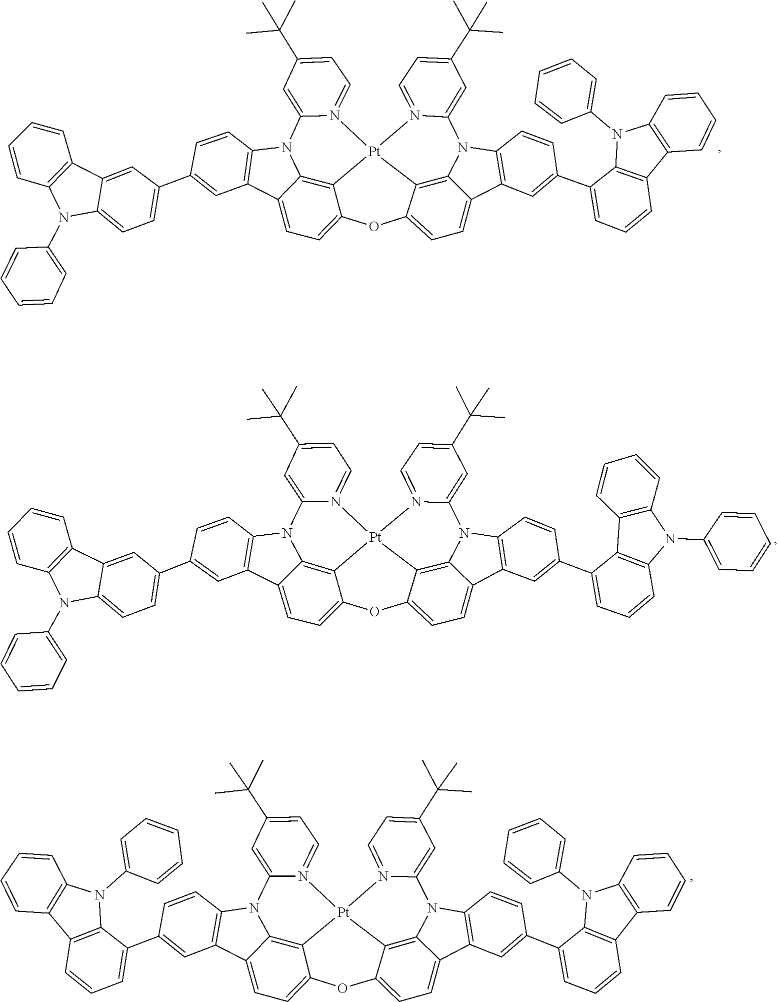

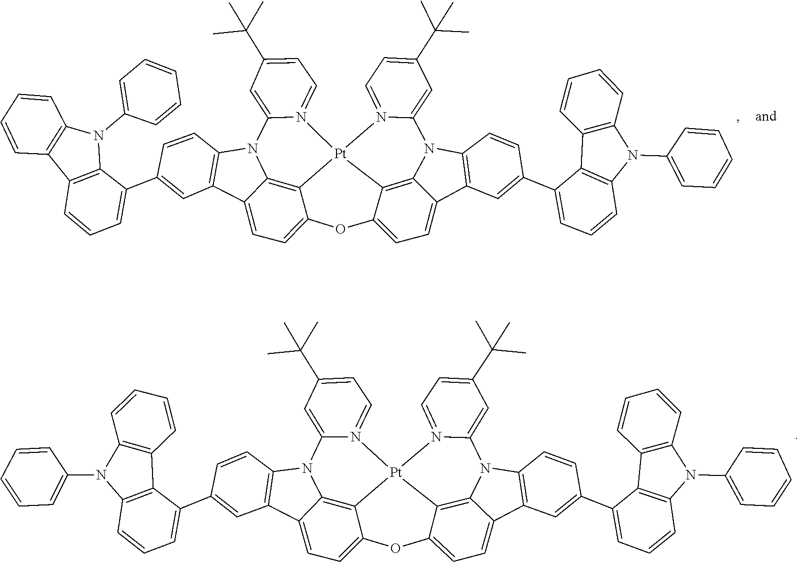

### C. The OLEDs and the Devices of the Present Disclosure

In another aspect, the present disclosure also provides an OLED device comprising an organic layer that contains a compound as disclosed in the above compounds section of the present disclosure.

In some embodiments, the organic layer may comprise a compound comprising a ligand L_{A} of

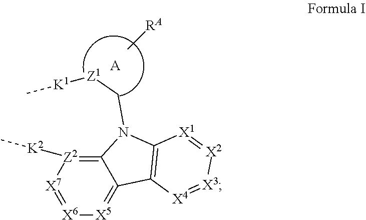

wherein one of Z¹ and Z² is C and the other is N; each of K¹ and K² is independently a direct bond, S, or O; ring A is a 5-membered or 6-membered carbocyclic or heterocyclic ring; R^{A} represents zero, mono, or up to the maximum allowed number of substitutions to its associated ring; each of X¹—X⁷ is independently N or CR; at least one of R and R^{A} has a structure of

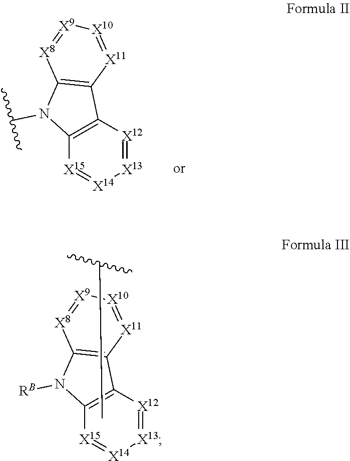

wherein: each of X⁸—X¹⁵ is independently N or CR′, the particular one of X⁸—X¹⁵ that is bonded to one of X¹—X⁷ or ring A of Formula I is C; the maximum number of N atoms that can connect to each other within a ring is two; each of remaining R and R^{A} is independently a hydrogen, Formula II, Formula III, or a substituent selected from the group consisting of the general substituents defined herein; each of R′ and R^{B} is independently a hydrogen, or a substituent selected from the group consisting of the general substituents defined herein; the ligand L_{A} is coordinated to a metal M by the indicated dash lines; the ligand L_{A} can be linked with other ligands to form a tridentate or tetradentate ligand; M is Pd or Pt, and can be coordinated to additional ligands; and any two adjacent R, R′, or R^{A} can be joined or fused together to form a ring.

In some embodiments, the organic layer may be an emissive layer and the compound as described herein may be an emissive dopant or a non-emissive dopant.

In some embodiments, the organic layer may further comprise a host, wherein the host comprises a triphenylene containing benzo-fused thiophene or benzo-fused furan, wherein any substituent in the host is an unfused substituent independently selected from the group consisting of CₙH₂ₙ₊₁, OCₙH₂ₙ₊₁, OAr₁, N(CₙH₂ₙ₊₁)₂, N(Ar₁)(Ar₂), CH═CH—CₙH₂n+₁, C≡CCₙH₂n+₁, Ar₁, Ar₁—Ar₂, CₙH₂ₙ—Ar₁, or no substitution, wherein n is from 1 to 10; and wherein Ar₁ and Ar₂ are independently selected from the group consisting of benzene, biphenyl, naphthalene, triphenylene, carbazole, and heteroaromatic analogs thereof.

In some embodiments, the organic layer may further comprise a host, wherein host comprises at least one chemical moiety selected from the group consisting of triphenylene, carbazole, indolocarbazole, dibenzothiphene, dibenzofuran, dibenzoselenophene, 5,9-dioxa-13b-boranaphtho[3,2,1-de]anthracene, aza-triphenylene, aza-carbazole, aza-indolocarbazole, aza-dibenzothiophene, aza-dibenzofuran, aza-dibenzoselenophene, and aza-(5,9-dioxa-13b-boranaphtho[3,2,1-de]anthracene).

In some embodiments, the host may be selected from the group consisting of:

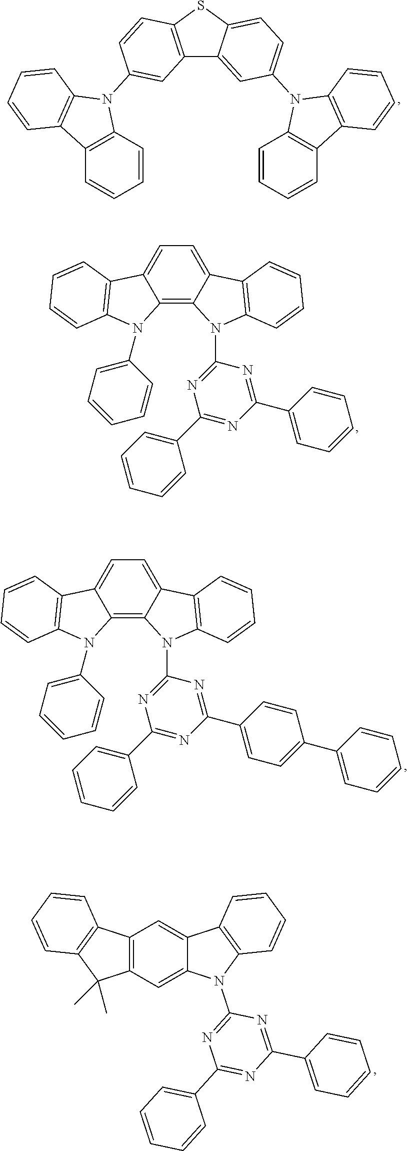 [SMILES: c1ccc2c(c1)c1ccccc1n2-c1ccc2sc3ccc(-n4c5ccccc5c5ccccc54)cc3c2c1 ; c1ccc(-c2nc(-c3ccccc3)nc(-n3c4ccccc4c4ccc5c6ccccc6n(-c6ccccc6)c5c43)n2)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; CC1(C)c2ccccc2-c2cc3c4ccccc4n(-c4nc(-c5ccccc5)nc(-c5ccccc5)n4)c3cc21]

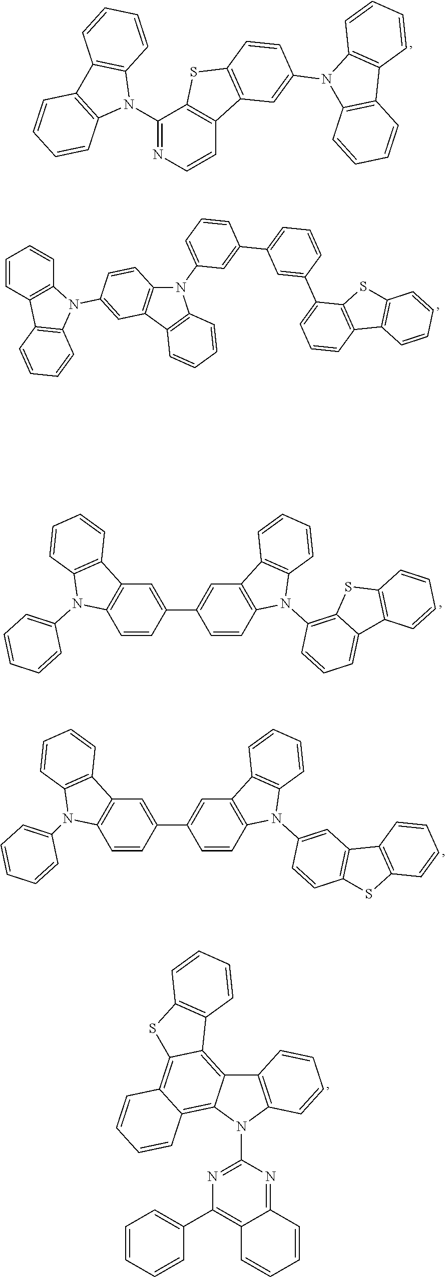 [SMILES: c1ccc2c(c1)c1ccccc1n2-c1ccc2sc3c(-n4c5ccccc5c5ccccc54)nccc3c2c1 ; c1cc(-c2cccc(-n3c4ccccc4c4cc(-n5c6ccccc6c6ccccc65)ccc43)c2)cc(-c2cccc3c2sc2ccccc23)c1 ; c1ccc(-n2c3ccccc3c3cc(-c4ccc5c(c4)c4ccccc4n5-c4cccc5c4sc4ccccc45)ccc32)cc1 ; c1ccc(-n2c3ccccc3c3cc(-c4ccc5c(c4)c4ccccc4n5-c4ccc5sc6ccccc6c5c4)ccc32)cc1 ; c1ccc(-c2nc(-n3c4ccccc4c4c5c6ccccc6sc5c5ccccc5c43)nc3ccccc23)cc1]

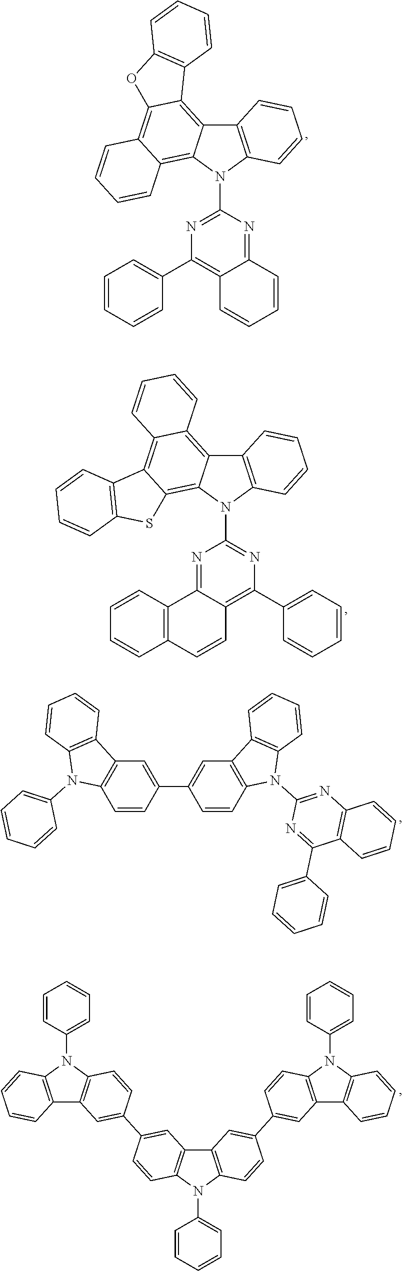 [SMILES: c1ccc(-c2nc(-n3c4ccccc4c4c5c6ccccc6oc5c5ccccc5c43)nc3ccccc23)cc1 ; c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

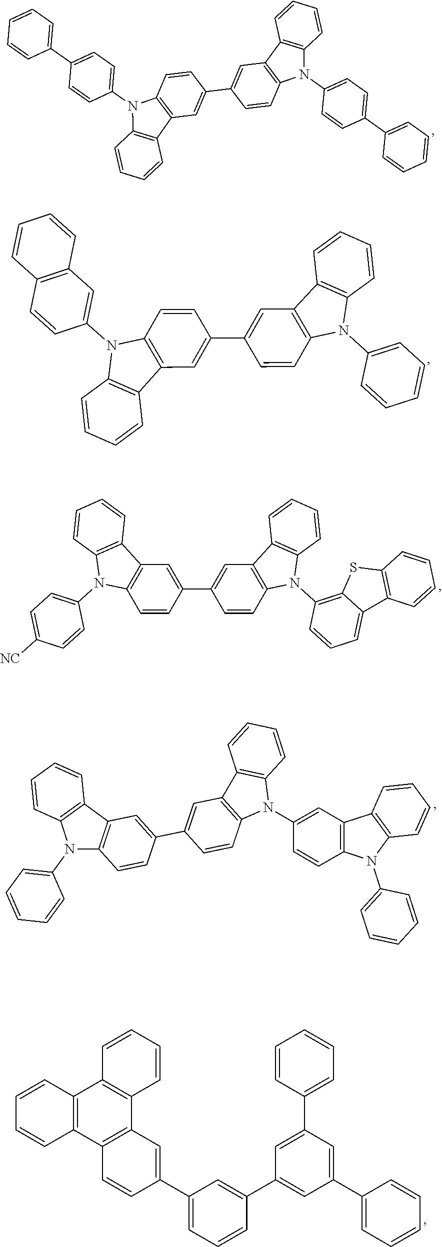

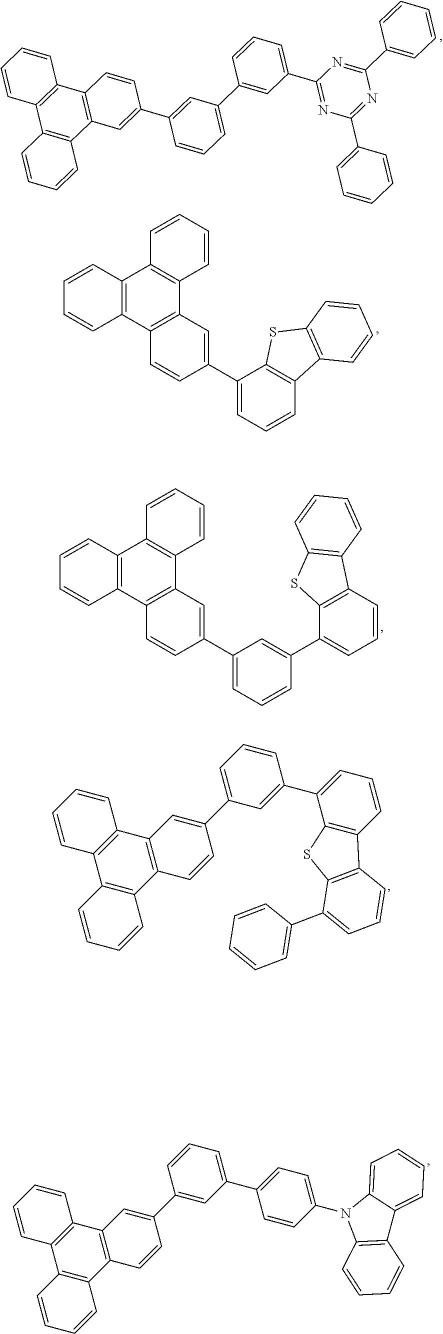

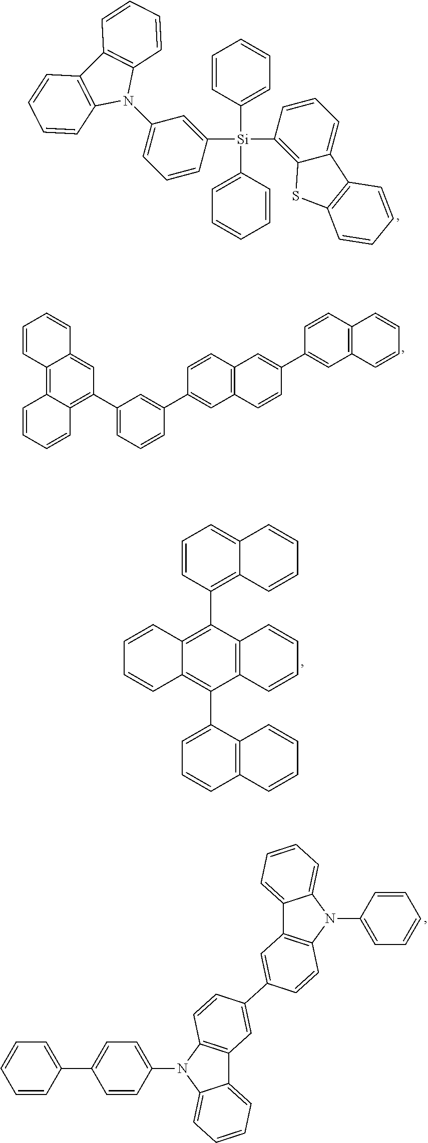

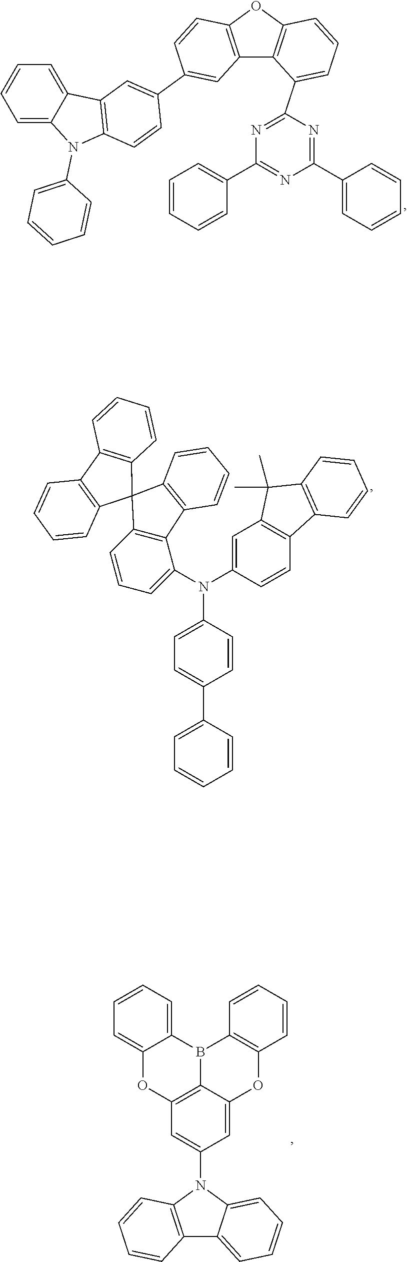 [SMILES: c1ccc(-c2nc(-c3ccccc3)nc(-c3cccc4oc5ccc(-c6ccc7c(c6)c6ccccc6n7-c6ccccc6)cc5c34)n2)cc1 ; CC1(C)c2ccccc2-c2ccc(N(c3ccc(-c4ccccc4)cc3)c3cccc4c3-c3ccccc3C43c4ccccc4-c4ccccc43)cc21 ; c1ccc2c(c1)Oc1cc(-n3c4ccccc4c4ccccc43)cc3c1B2c1ccccc1O3]

combinations thereof.

In some embodiments, the organic layer may further comprise a host, wherein the host comprises a metal complex.

In some embodiments, the compound as described herein may be a sensitizer; wherein the device may further comprise an acceptor; and wherein the acceptor may be selected from the group consisting of fluorescent emitter, delayed fluorescence emitter, and combination thereof.

In yet another aspect, the OLED of the present disclosure may also comprise an emissive region containing a compound as disclosed in the above compounds section of the present disclosure.

In some embodiments, the emissive region may comprise a compound comprising a ligand L_{A} of

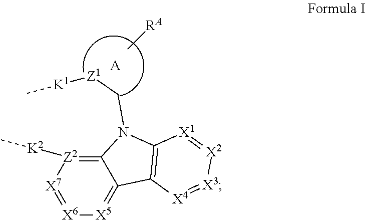

wherein one of Z¹ and Z² is C and the other is N; each of K¹ and K² is independently a direct bond, S, or O; ring A is a 5-membered or 6-membered carbocyclic or heterocyclic ring; R^{A} represents zero, mono, or up to the maximum allowed number of substitutions to its associated ring; each of X¹—X⁷ is independently N or CR; at least one of R and R^{A} has a structure of

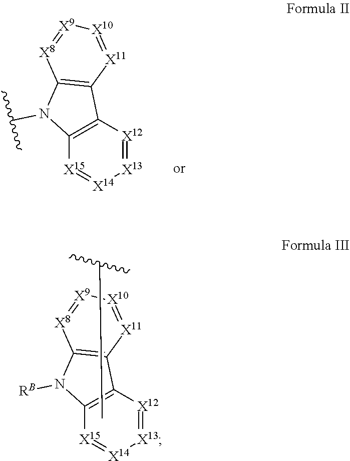

wherein: each of X⁸—X¹⁵ is independently N or CR′, the particular one of X⁸—X¹⁵ that is bonded to one of X¹—X⁷ or ring A of Formula I is C; the maximum number of N atoms that can connect to each other within a ring is two; each of remaining R and R^{A} is independently a hydrogen, Formula II, Formula III, or a substituent selected from the group consisting of the general substituents defined herein; each of R′ and R^{B} is independently a hydrogen, or a substituent selected from the group consisting of the general substituents defined herein; the ligand L_{A} is coordinated to a metal M by the indicated dash lines; the ligand L_{A} can be linked with other ligands to form a tridentate or tetradentate ligand; M is Pd or Pt, and can be coordinated to additional ligands; and any two adjacent R, R′, or R^{A} can be joined or fused together to form a ring.

In yet another aspect, the present disclosure also provides a consumer product comprising an organic light-emitting device (OLED) having an anode; a cathode; and an organic layer disposed between the anode and the cathode, wherein the organic layer may comprise a compound as disclosed in the above compounds section of the present disclosure.

In some embodiments, the consumer product comprises an organic light-emitting device (OLED) having an anode; a cathode; and an organic layer disposed between the anode and the cathode, wherein the organic layer may comprise a compound comprising a ligand L_{A} of Formula I as described herein.

In some embodiments, the consumer product can be one of a flat panel display, a computer monitor, a medical monitor, a television, a billboard, a light for interior or exterior illumination and/or signaling, a heads-up display, a fully or partially transparent display, a flexible display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, a light therapy device, and a sign.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

Several OLED materials and configurations are described in U.S. Pat. Nos. 5,844,363, 6,303,238, and 5,707,745, which are incorporated herein by reference in their entirety.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

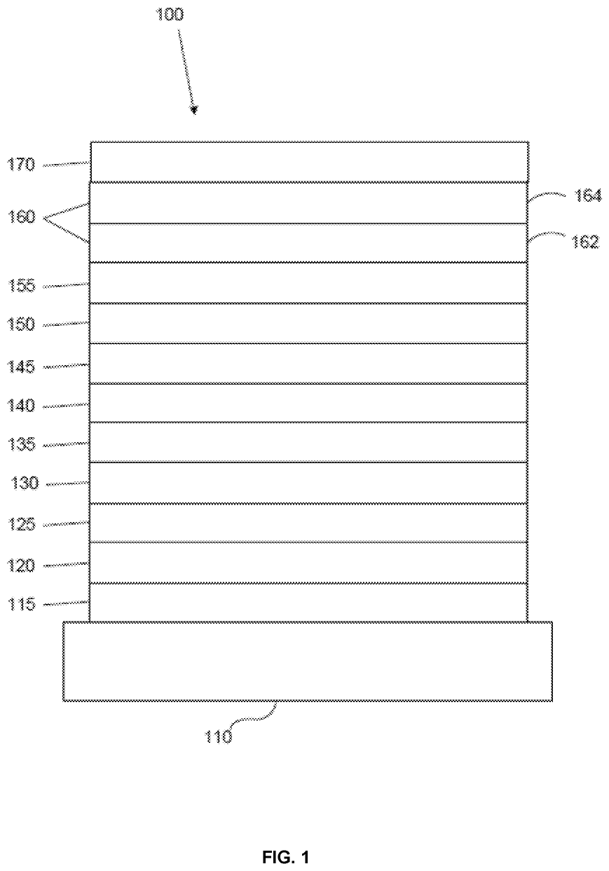

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety.

Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

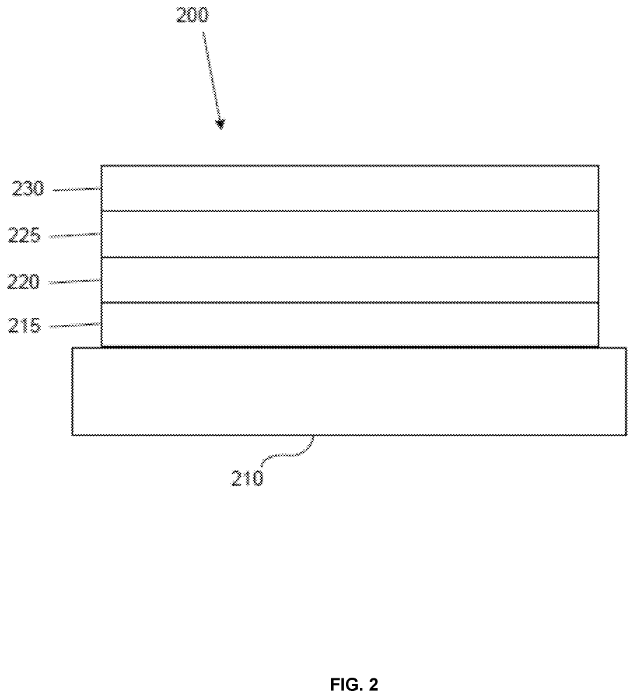

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the present disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and organic vapor jet printing (OVJP). Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons are a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc.

The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the present disclosure can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the present disclosure can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, rollable displays, foldable displays, stretchable displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, a light therapy device, and a sign. Various control mechanisms may be used to control devices fabricated in accordance with the present disclosure, including passive matrix and active matrix.

Many of the devices are intended for use in a temperature range comfortable to humans, such as 18 degrees C. to 30 degrees C., and more preferably at room temperature (20-25° C.), but could be used outside this temperature range, for example, from −40 degree C. to +80° C.

More details on OLEDs, and the definitions described above, can be found in U.S. Pat. No. 7,279,704, which is incorporated herein by reference in its entirety.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence; see, e.g., U.S. application Ser. No. 15/700,352, which is hereby incorporated by reference in its entirety), triplet-triplet annihilation, or combinations of these processes. In some embodiments, the emissive dopant can be a racemic mixture, or can be enriched in one enantiomer. In some embodiments, the compound can be homoleptic (each ligand is the same). In some embodiments, the compound can be heteroleptic (at least one ligand is different from others). When there are more than one ligand coordinated to a metal, the ligands can all be the same in some embodiments. In some other embodiments, at least one ligand is different from the other ligands. In some embodiments, every ligand can be different from each other. This is also true in embodiments where a ligand being coordinated to a metal can be linked with other ligands being coordinated to that metal to form a tridentate, tetradentate, pentadentate, or hexadentate ligands. Thus, where the coordinating ligands are being linked together, all of the ligands can be the same in some embodiments, and at least one of the ligands being linked can be different from the other ligand(s) in some other embodiments.

In some embodiments, the compound can be used as a phosphorescent sensitizer in an OLED where one or multiple layers in the OLED contains an acceptor in the form of one or more fluorescent and/or delayed fluorescence emitters. In some embodiments, the compound can be used as one component of an exciplex to be used as a sensitizer. As a phosphorescent sensitizer, the compound must be capable of energy transfer to the acceptor and the acceptor will emit the energy or further transfer energy to a final emitter. The acceptor concentrations can range from 0.001% to 100%. The acceptor could be in either the same layer as the phosphorescent sensitizer or in one or more different layers. In some embodiments, the acceptor is a TADF emitter. In some embodiments, the acceptor is a fluorescent emitter. In some embodiments, the emission can arise from any or all of the sensitizer, acceptor, and final emitter.

According to another aspect, a formulation comprising the compound described herein is also disclosed.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

In yet another aspect of the present disclosure, a formulation that comprises the novel compound disclosed herein is described. The formulation can include one or more components selected from the group consisting of a solvent, a host, a hole injection material, hole transport material, electron blocking material, hole blocking material, and an electron transport material, disclosed herein.

The present disclosure encompasses any chemical structure comprising the novel compound of the present disclosure, or a monovalent or polyvalent variant thereof. In other words, the inventive compound, or a monovalent or polyvalent variant thereof, can be a part of a larger chemical structure. Such chemical structure can be selected from the group consisting of a monomer, a polymer, a macromolecule, and a supramolecule (also known as supermolecule). As used herein, a “monovalent variant of a compound” refers to a moiety that is identical to the compound except that one hydrogen has been removed and replaced with a bond to the rest of the chemical structure. As used herein, a “polyvalent variant of a compound” refers to a moiety that is identical to the compound except that more than one hydrogen has been removed and replaced with a bond or bonds to the rest of the chemical structure. In the instance of a supramolecule, the inventive compound can also be incorporated into the supramolecule complex without covalent bonds.

### D. Combination of the Compounds of the Present Disclosure with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

### a) Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

Non-limiting examples of the conductivity dopants that may be used in an OLED in combination with materials disclosed herein are exemplified below together with references that disclose those materials: EP01617493, EP01968131, EP2020694, EP2684932, US20050139810, US20070160905, US20090167167, US2010288362, WO06081780, WO2009003455, WO2009008277, WO2009011327, WO2014009310, US2007252140, US2015060804, US20150123047, and US2012146012.

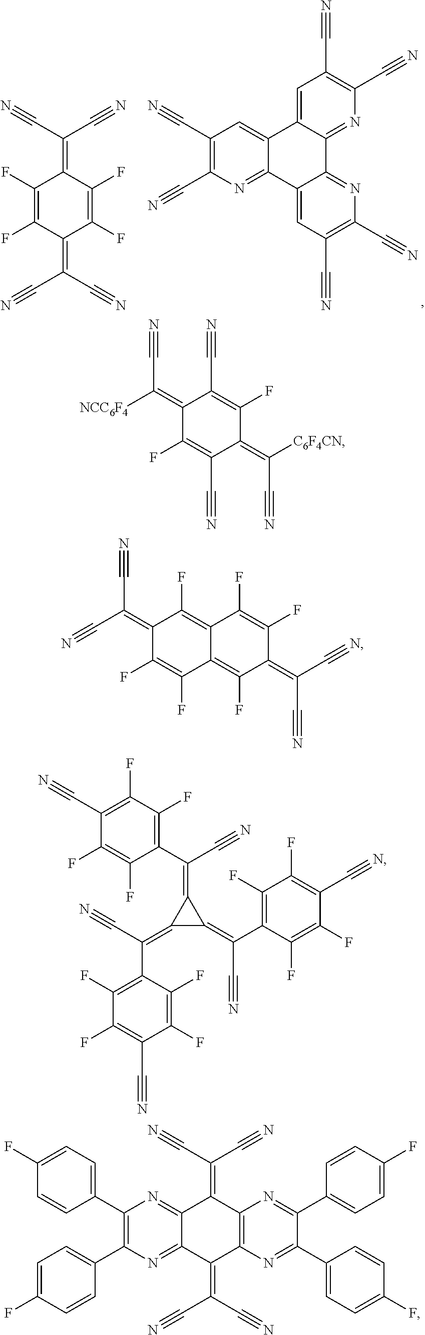

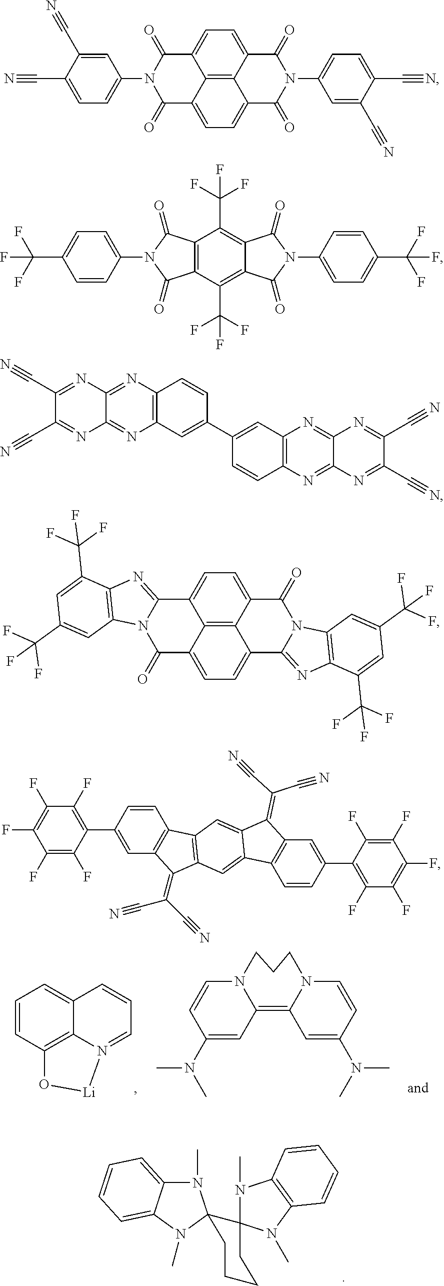

### b) HIL/HTL:

A hole injecting/transporting material to be used in the present disclosure is not particularly limited, and any compound may be used as long as the compound is typically used as a hole injecting/transporting material.

Examples of the material include, but are not limited to: a phthalocyanine or porphyrin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and silane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

Examples of aromatic amine derivatives used in HIL or HTL include, but not limit to the following general structures:

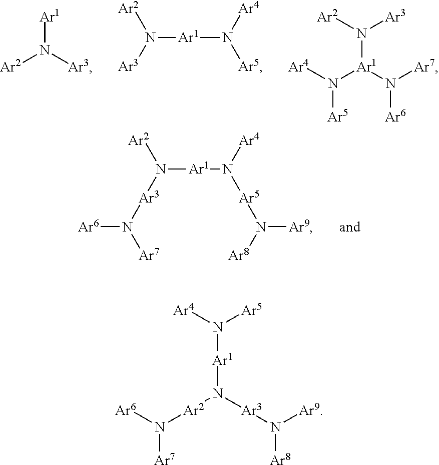

Each of A¹ to Ar⁹ is selected from the group consisting of aromatic hydrocarbon cyclic compounds such as benzene, biphenyl, triphenyl, triphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each Ar may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, Ar¹ to Ar⁹ is independently selected from the group consisting of:

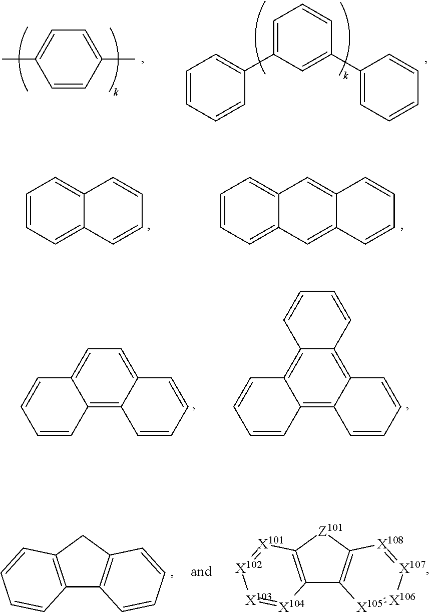

wherein k is an integer from 1 to 20; X¹⁰¹ to X¹⁰⁸ is C (including CH) or N; Z¹⁰¹ is NAr¹, O, or S; Ar¹ has the same group defined above.

Examples of metal complexes used in HIL or HTL include, but are not limited to the following general formula:

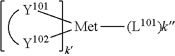

wherein Met is a metal, which can have an atomic weight greater than 40; (Y¹⁰¹—Y¹⁰²) is a bidentate ligand, Y¹⁰¹ and Y¹⁰² are independently selected from C, N, O, P, and S; L¹⁰¹ is an ancillary ligand; k′ is an integer value from 1 to the maximum number of ligands that may be attached to the metal; and k′+k″ is the maximum number of ligands that may be attached to the metal.

In one aspect, (Y¹⁰¹—Y¹⁰²) is a 2-phenylpyridine derivative. In another aspect, (Y¹⁰¹—Y¹⁰²) is a carbene ligand. In another aspect, Met is selected from Ir, Pt, Os, and Zn. In a further aspect, the metal complex has a smallest oxidation potential in solution vs. Fc+/Fc couple less than about 0.6 V.

Non-limiting examples of the HIL and HTL materials that may be used in an OLED in combination with materials disclosed herein are exemplified below together with references that disclose those materials: CN102702075, DE102012005215, EP01624500, EP01698613, EP01806334, EP01930964, EP01972613, EP01997799, EP02011790, EP02055700, EP02055701, EP1725079, EP2085382, EP2660300, EP650955, JP07-073529, JP2005112765, JP2007091719, JP2008021687, JP2014-009196, KR20110088898, KR20130077473, TW201139402, U.S. Ser. No. 06/517,957, US20020158242, US20030162053, US20050123751, US20060182993, US20060240279, US20070145888, US20070181874, US20070278938, US20080014464, US20080091025, US20080106190, US20080124572, US20080145707, US20080220265, US20080233434, US20080303417, US2008107919, US20090115320, US20090167161, US2009066235, US2011007385, US20110163302, US2011240968, US2011278551, US2012205642, US2013241401, US20140117329, US2014183517, U.S. Pat. Nos. 5,061,569, 5,639,914, WO05075451, WO07125714, WO08023550, WO08023759, WO2009145016, WO2010061824, WO2011075644, WO2012177006, WO2013018530, WO2013039073, WO2013087142, WO2013118812, WO2013120577, WO2013157367, WO2013175747, WO2014002873, WO2014015935, WO2014015937, WO2014030872, WO2014030921, WO2014034791, WO2014104514, WO2014157018.

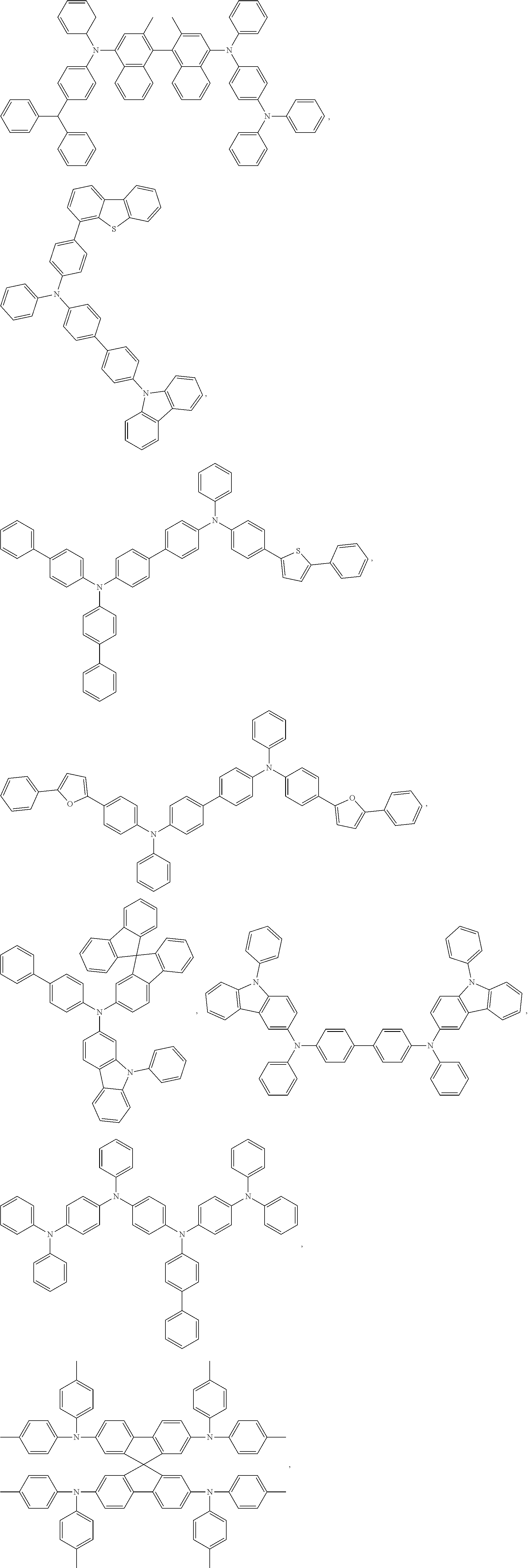

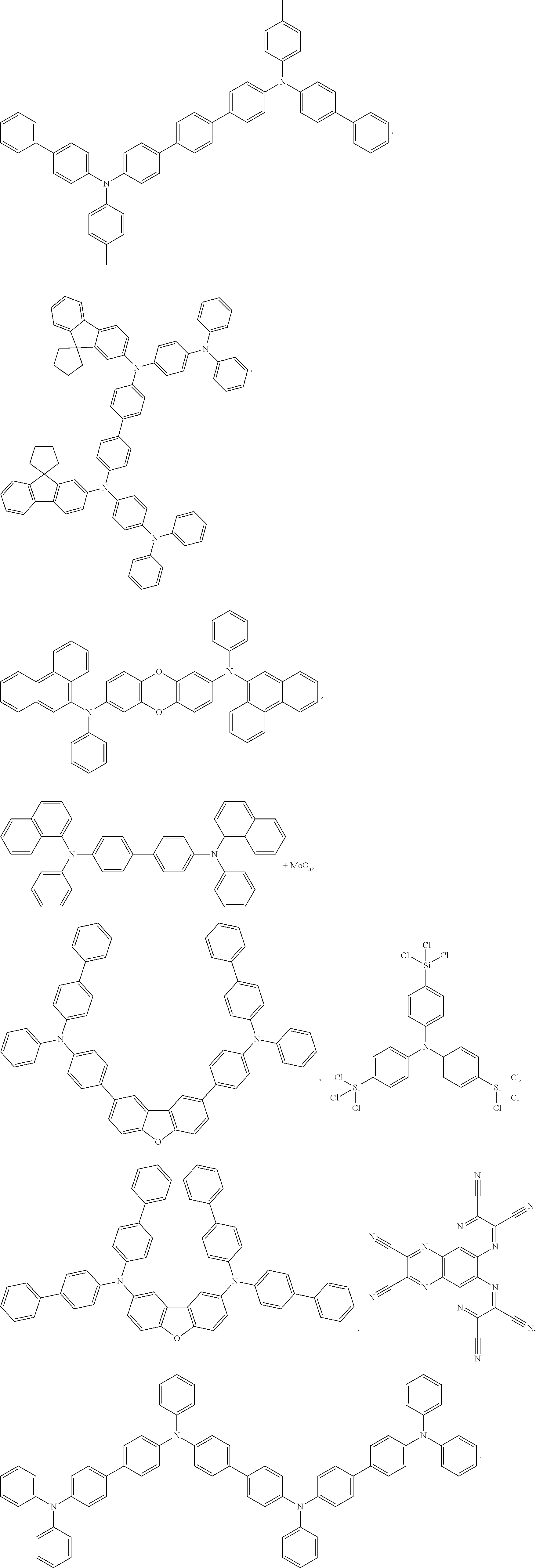

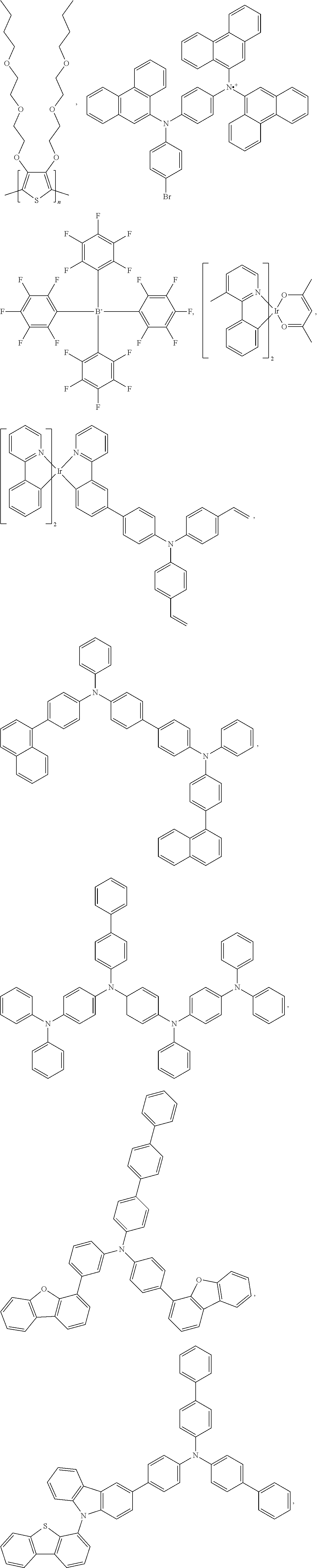

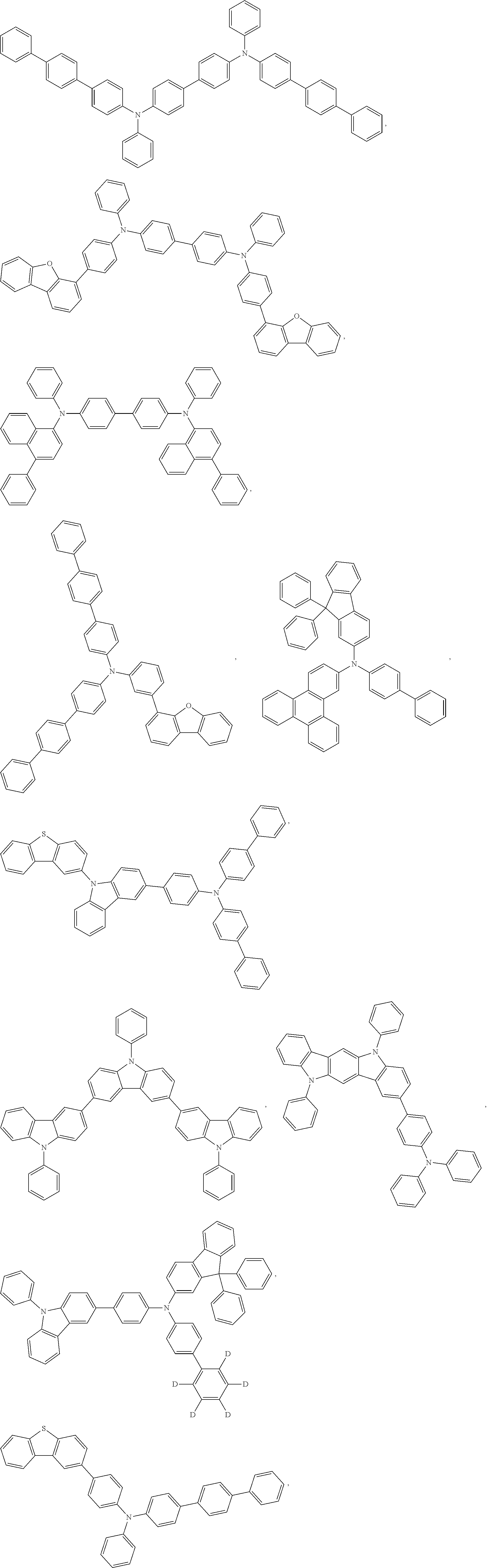

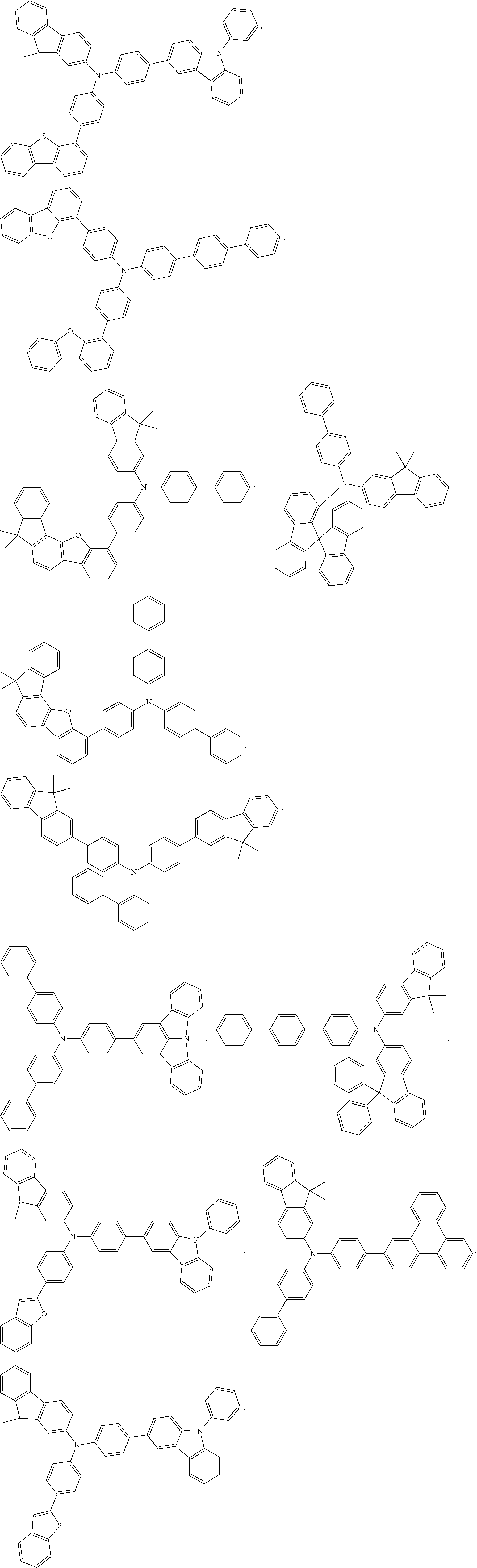

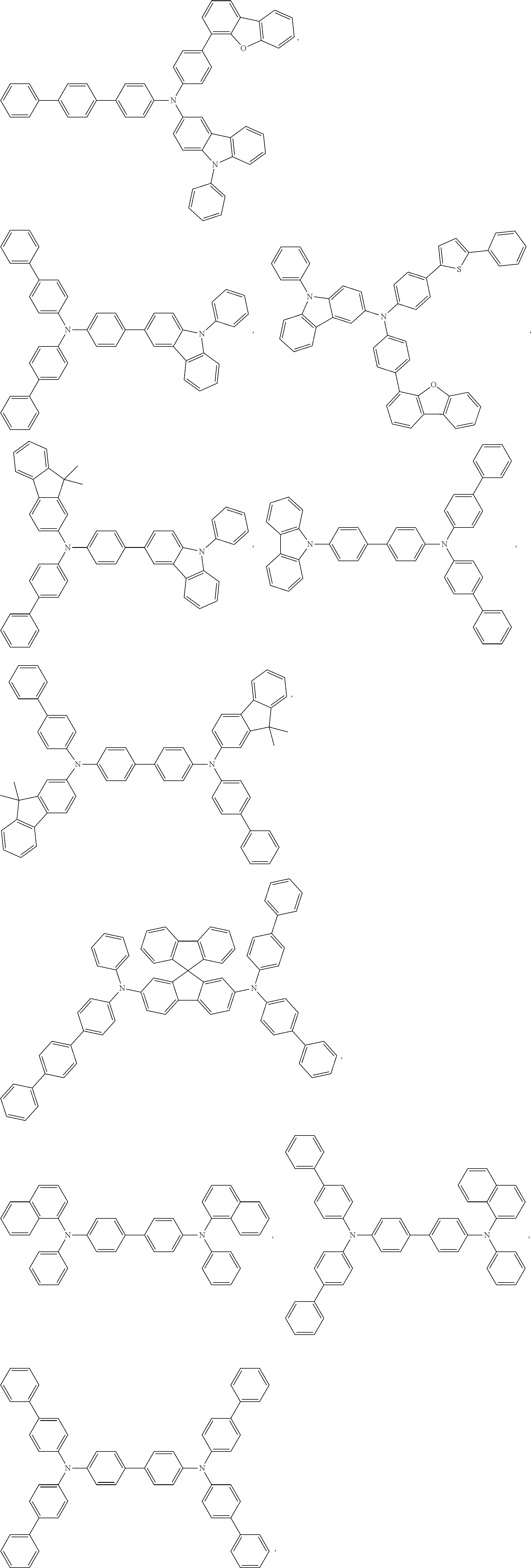

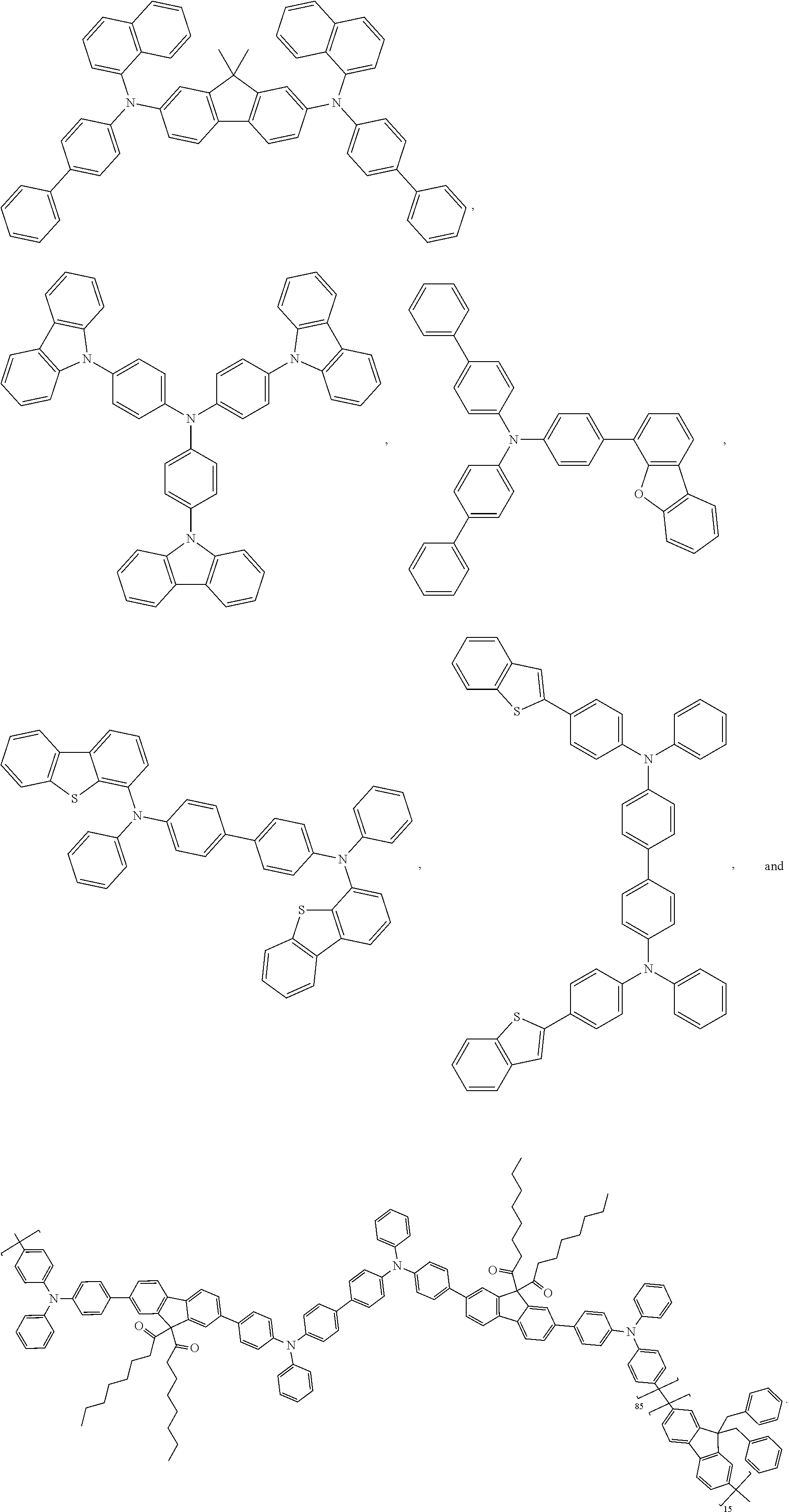

### c) EBL:

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and/or higher triplet energy than one or more of the hosts closest to the EBL interface. In one aspect, the compound used in EBL contains the same molecule or the same functional groups used as one of the hosts described below.

### d) Hosts:

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

Examples of metal complexes used as host are preferred to have the following general formula:

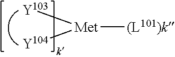

wherein Met is a metal; (Y¹⁰³—Y¹⁰⁴) is a bidentate ligand, Y¹⁰³ and Y¹⁰⁴ are independently selected from C, N, O, P, and S; L¹⁰¹ is an another ligand; k′ is an integer value from 1 to the maximum number of ligands that may be attached to the metal; and k′+k″ is the maximum number of ligands that may be attached to the metal.

In one aspect, the metal complexes are:

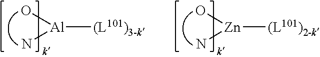

wherein (O—N) is a bidentate ligand, having metal coordinated to atoms O and N.

In another aspect, Met is selected from Ir and Pt. In a further aspect, (Y¹⁰³—Y¹⁰⁴) is a carbene ligand.

In one aspect, the host compound contains at least one of the following groups selected from the group consisting of aromatic hydrocarbon cyclic compounds such as benzene, biphenyl, triphenyl, triphenylene, tetraphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each option within each group may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, the host compound contains at least one of the following groups in the molecule:

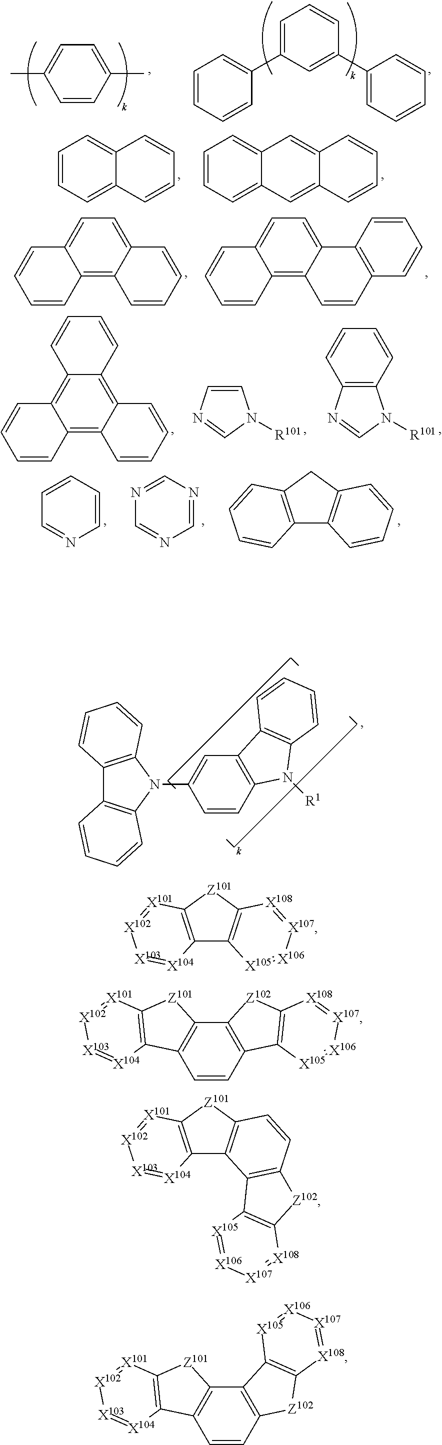

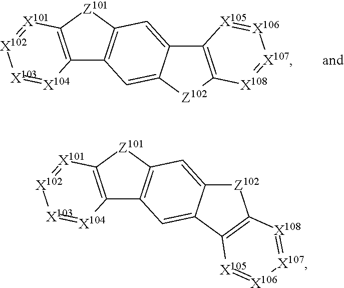

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, and when it is aryl or heteroaryl, it has the similar definition as Ar's mentioned above. k is an integer from 0 to 20 or 1 to 20. X¹¹ to X¹⁰⁸ are independently selected from C (including CH) or N. Z¹⁰¹ and Z¹⁰² are independently selected from NR¹⁰¹, O, or S.

Non-limiting examples of the host materials that may be used in an OLED in combination with materials disclosed herein are exemplified below together with references that disclose those materials: EP2034538, EP2034538A, EP2757608, JP2007254297, KR20100079458, KR20120088644, KR20120129733, KR20130115564, TW201329200, US20030175553, US20050238919, US20060280965, US20090017330, US20090030202, US20090167162, US20090302743, US20090309488, US20100012931, US20100084966, US20100187984, US2010187984, US2012075273, US2012126221, US2013009543, US2013105787, US2013175519, US2014001446, US20140183503, US20140225088, US2014034914, U.S. Pat. No. 7,154,114, WO2001039234, WO2004093207, WO2005014551, WO2005089025, WO2006072002, WO2006114966, WO2007063754, WO2008056746, WO2009003898, WO2009021126, WO2009063833, WO2009066778, WO2009066779, WO2009086028, WO2010056066, WO2010107244, WO2011081423, WO2011081431, WO2011086863, WO2012128298, WO2012133644, WO2012133649, WO2013024872, WO2013035275, WO2013081315, WO2013191404, WO2014142472, US20170263869, US20160163995, U.S. Pat. No. 9,466,803,

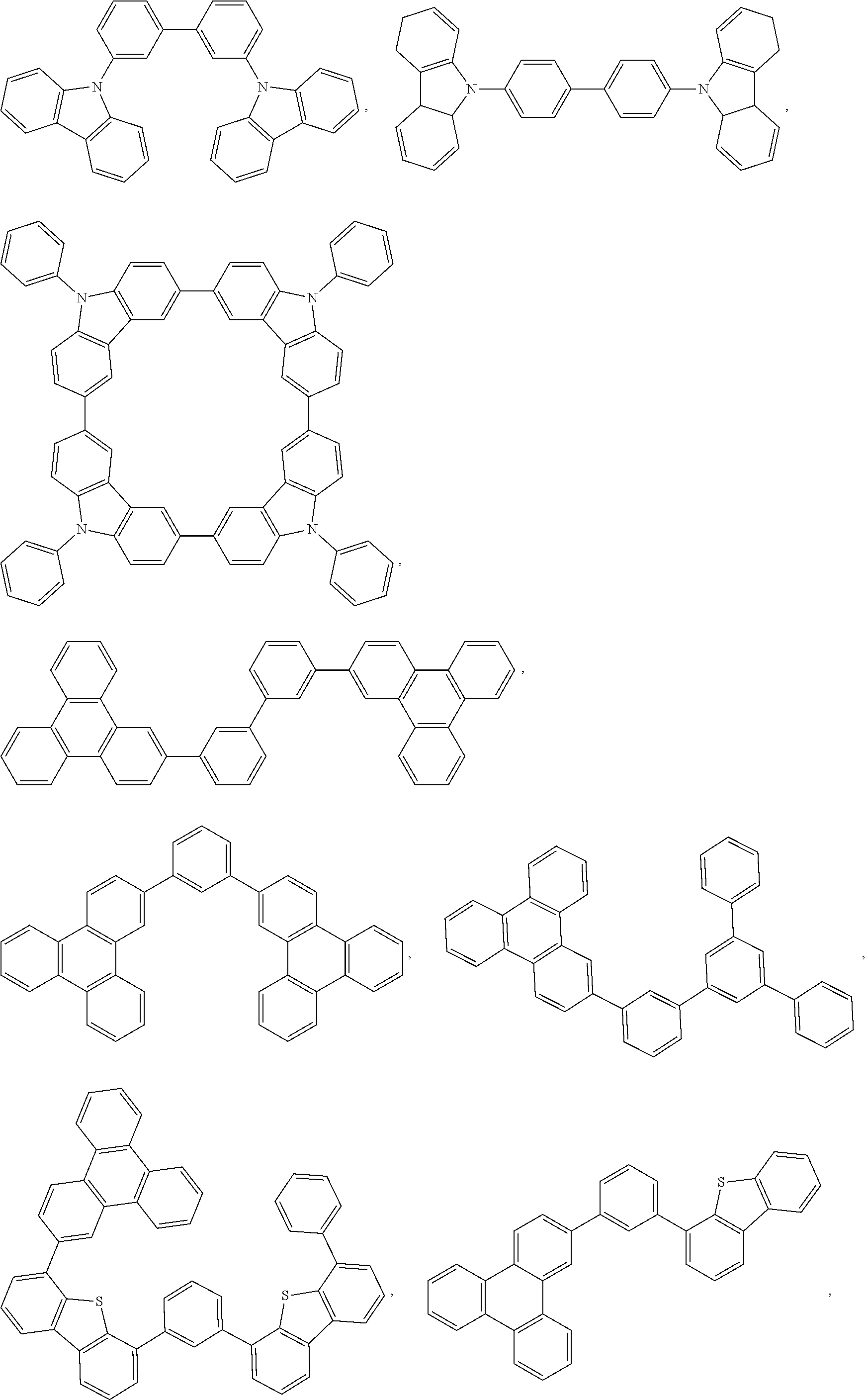

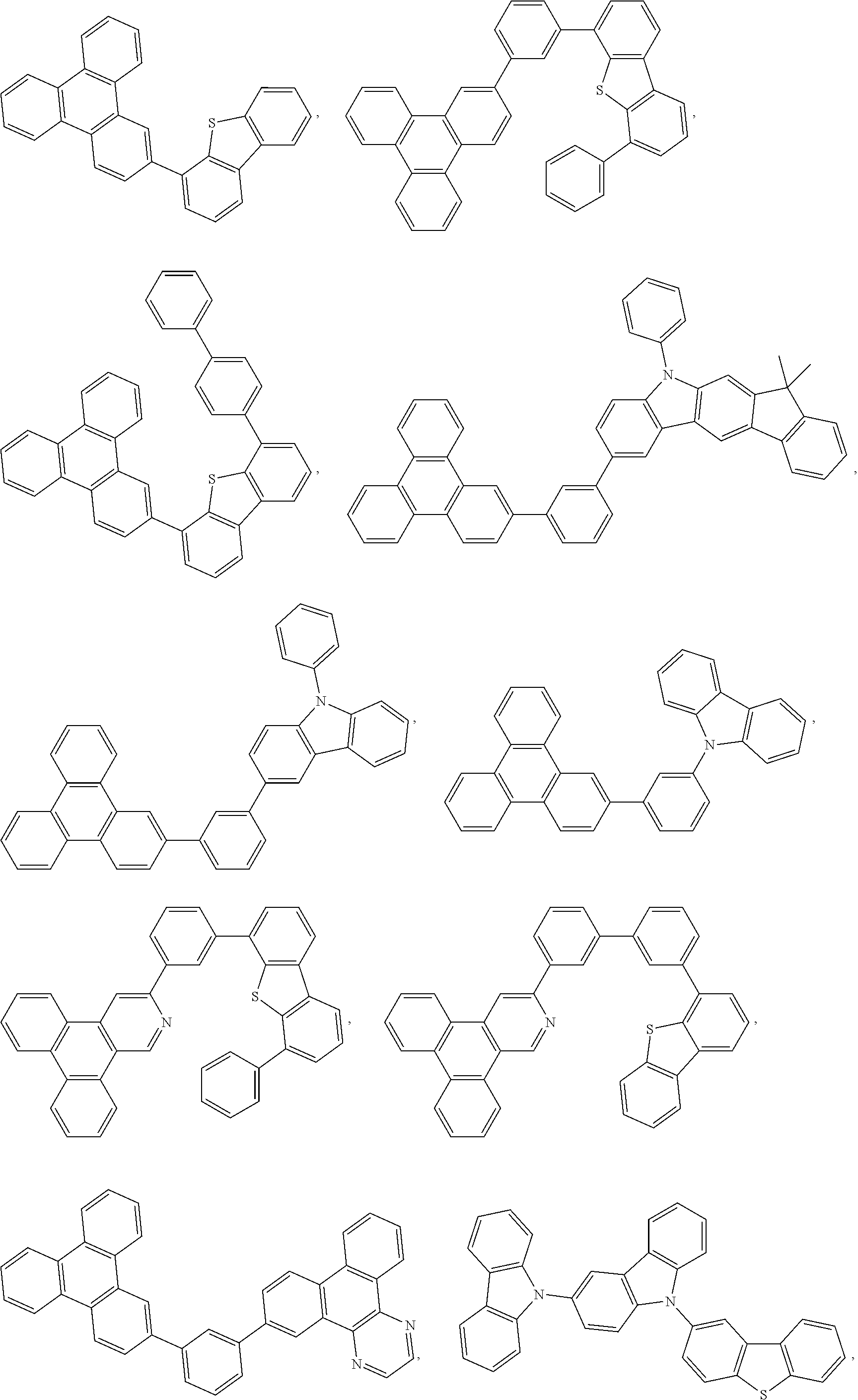

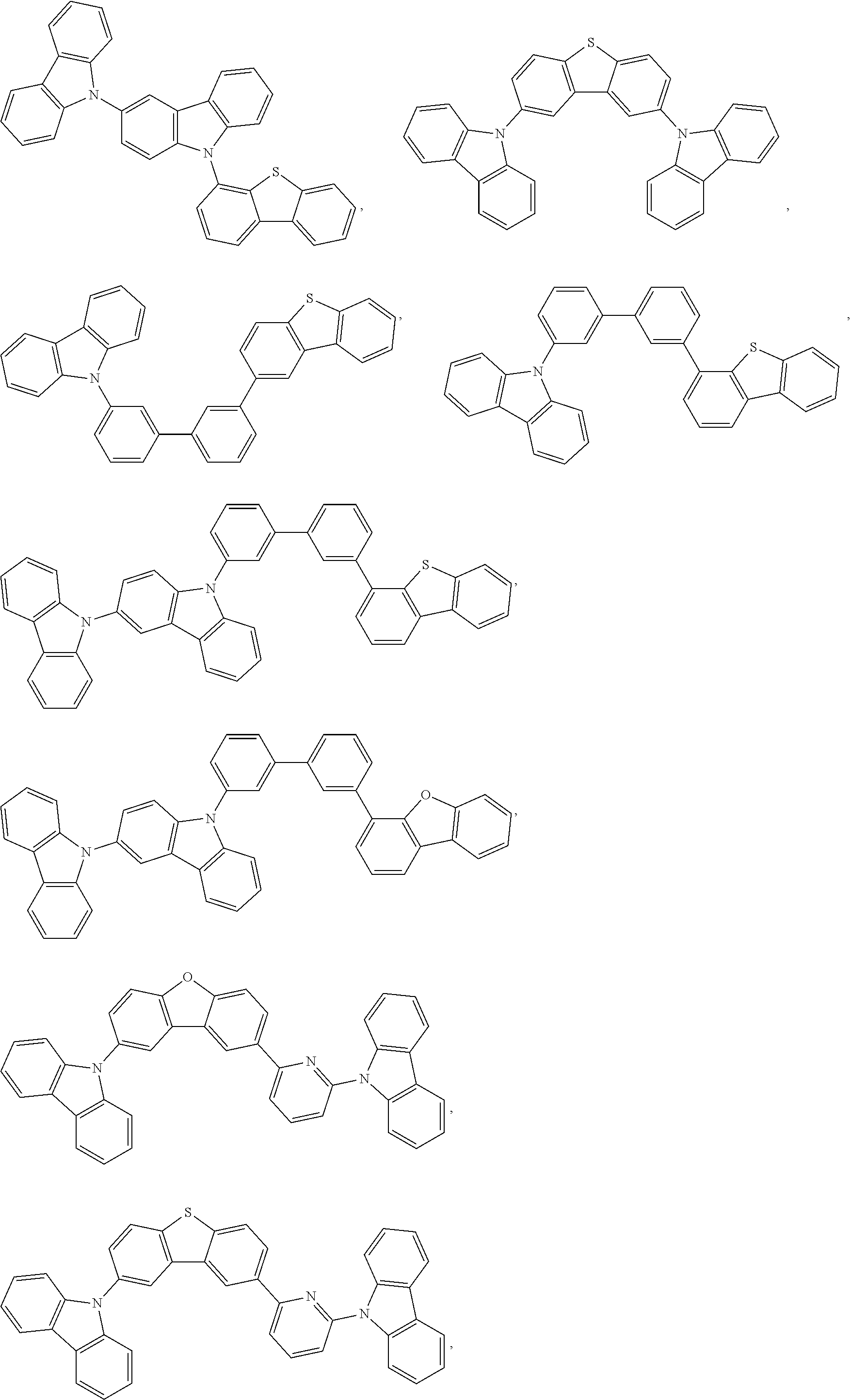

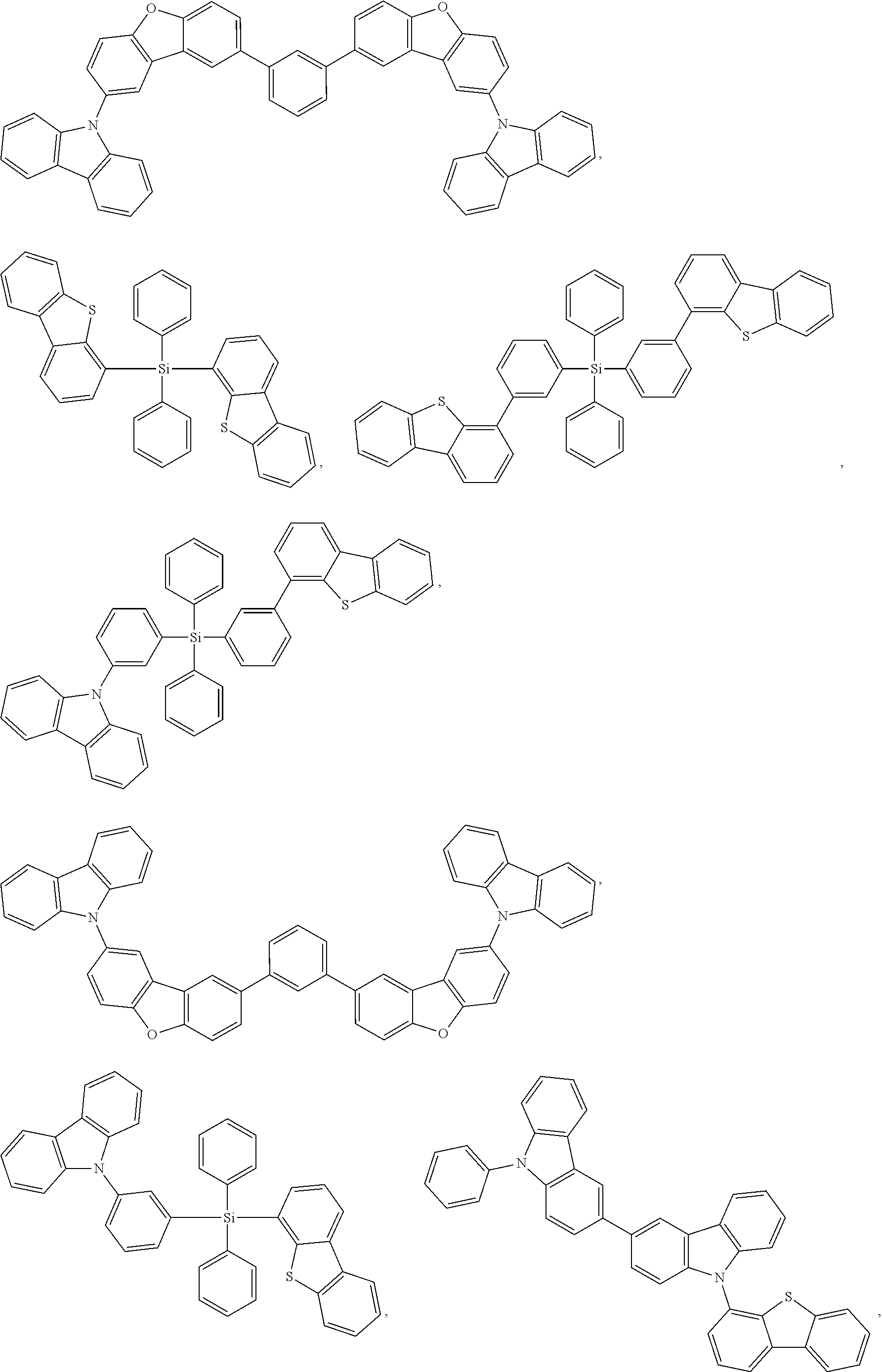

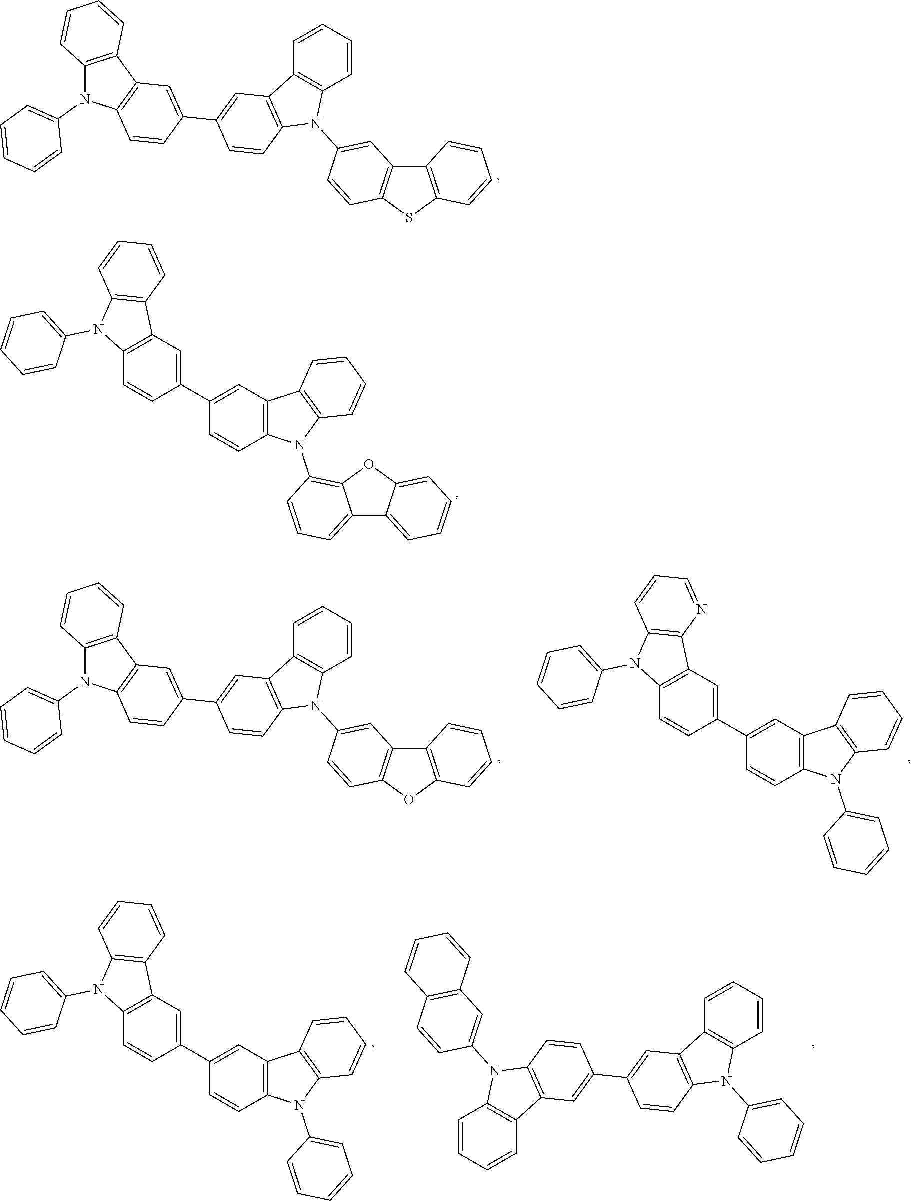 [SMILES: c1ccc(-n2c3ccccc3c3cc(-c4ccc5c(c4)c4ccccc4n5-c4ccc5sc6ccccc6c5c4)ccc32)cc1 ; c1ccc(-n2c3ccccc3c3cc(-c4ccc5c(c4)c4ccccc4n5-c4cccc5c4oc4ccccc45)ccc32)cc1 ; c1ccc(-n2c3ccccc3c3cc(-c4ccc5c(c4)c4ccccc4n5-c4ccc5oc6ccccc6c5c4)ccc32)cc1 ; c1ccc(-n2c3ccccc3c3cc(-c4ccc5c(c4)c4ncccc4n5-c4ccccc4)ccc32)cc1 ; c1ccc(-n2c3ccccc3c3cc(-c4ccc5c(c4)c4ccccc4n5-c4ccccc4)ccc32)cc1 ; c1ccc(-n2c3ccccc3c3cc(-c4ccc5c(c4)c4ccccc4n5-c4ccc5ccccc5c4)ccc32)cc1]

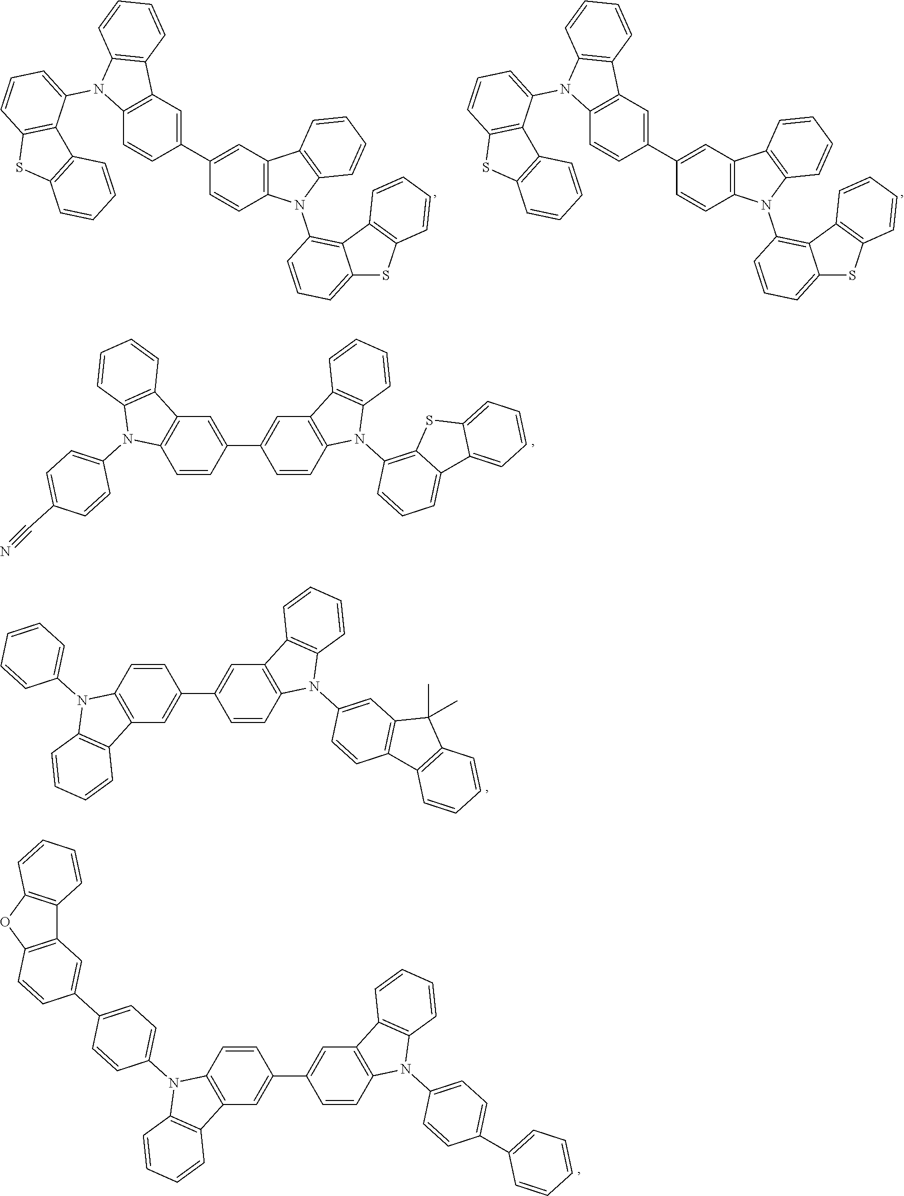 [SMILES: c1ccc2c(c1)sc1cccc(-n3c4ccccc4c4cc(-c5ccc6c(c5)c5ccccc5n6-c5cccc6sc7ccccc7c56)ccc43)c12 ; c1ccc2c(c1)sc1cccc(-n3c4ccccc4c4cc(-c5ccc6c(c5)c5ccccc5n6-c5cccc6sc7ccccc7c56)ccc43)c12 ; N#Cc1ccc(-n2c3ccccc3c3cc(-c4ccc5c(c4)c4ccccc4n5-c4cccc5c4sc4ccccc45)ccc32)cc1 ; CC1(C)c2ccccc2-c2ccc(-n3c4ccccc4c4cc(-c5ccc6c(c5)c5ccccc5n6-c5ccccc5)ccc43)cc21 ; c1ccc(-c2ccc(-n3c4ccccc4c4cc(-c5ccc6c(c5)c5ccccc5n6-c5ccc(-c6ccc7oc8ccccc8c7c6)cc5)ccc43)cc2)cc1]

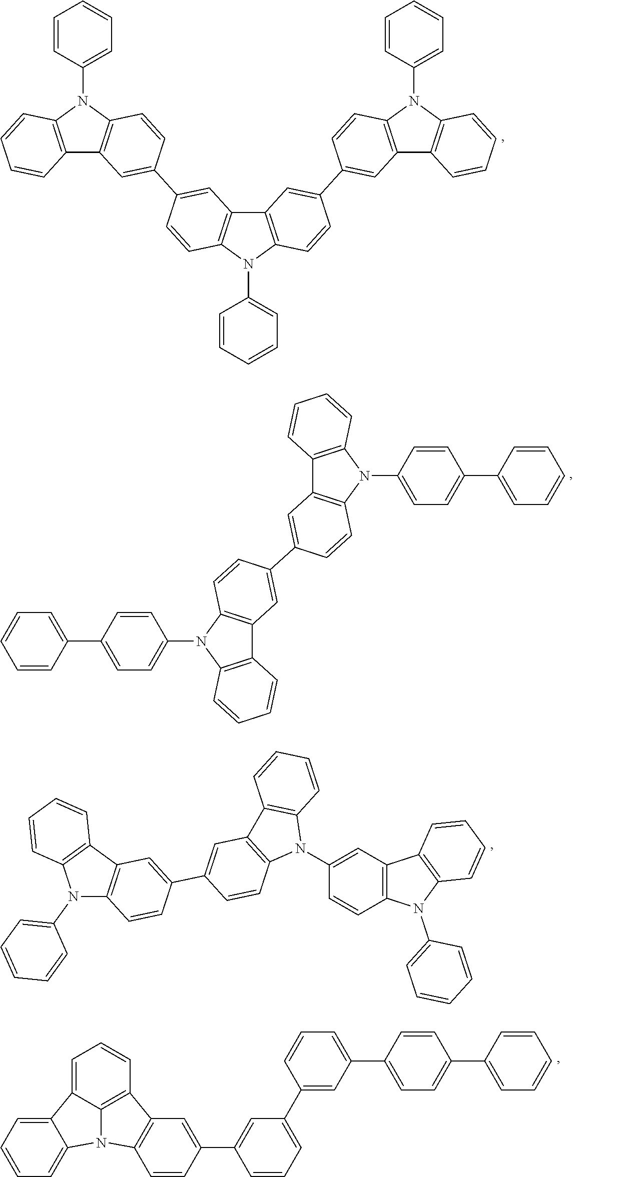

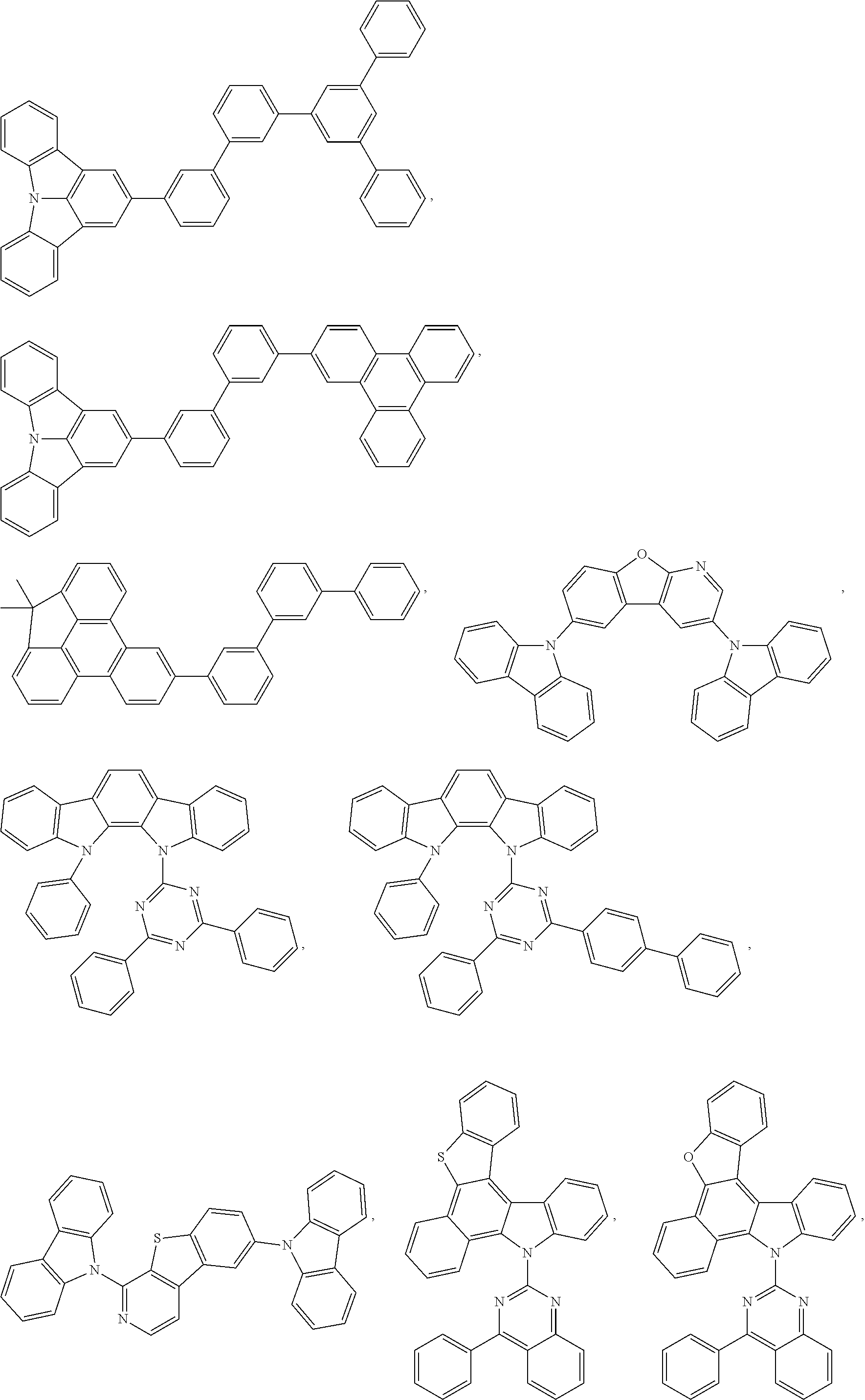

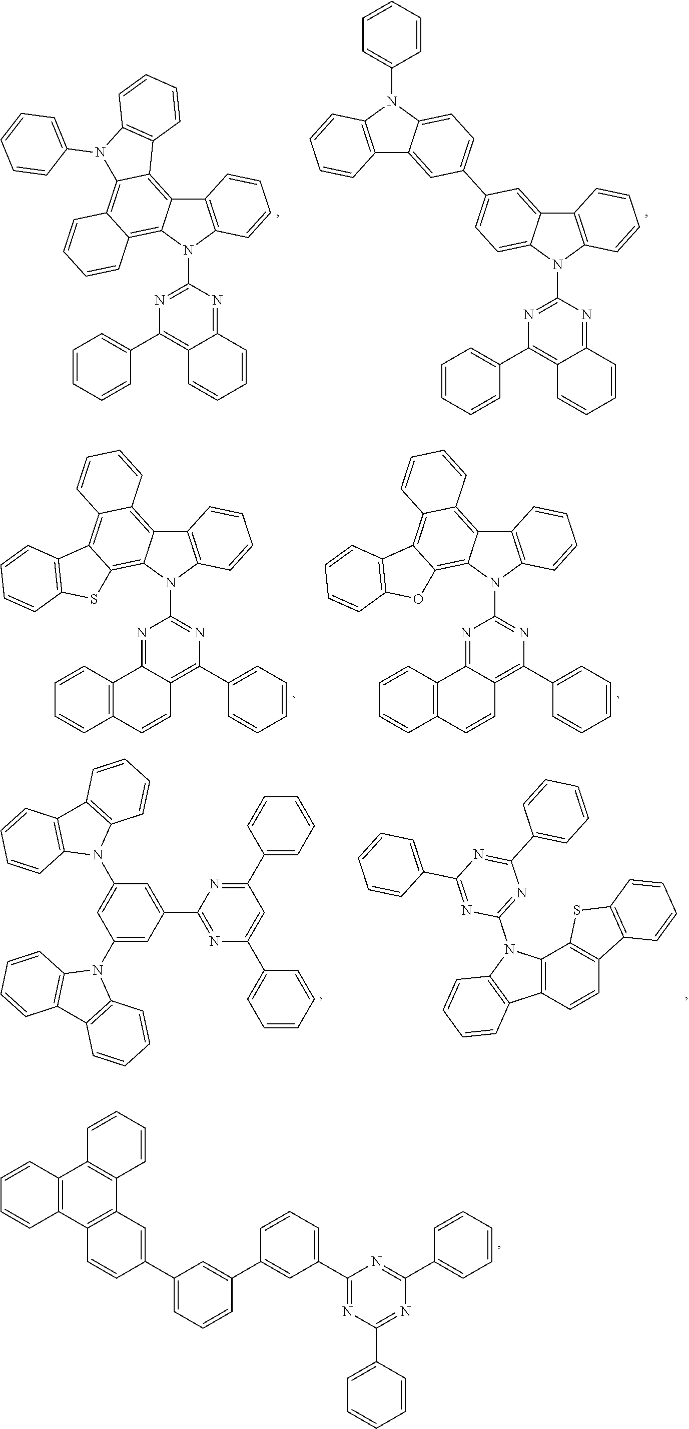

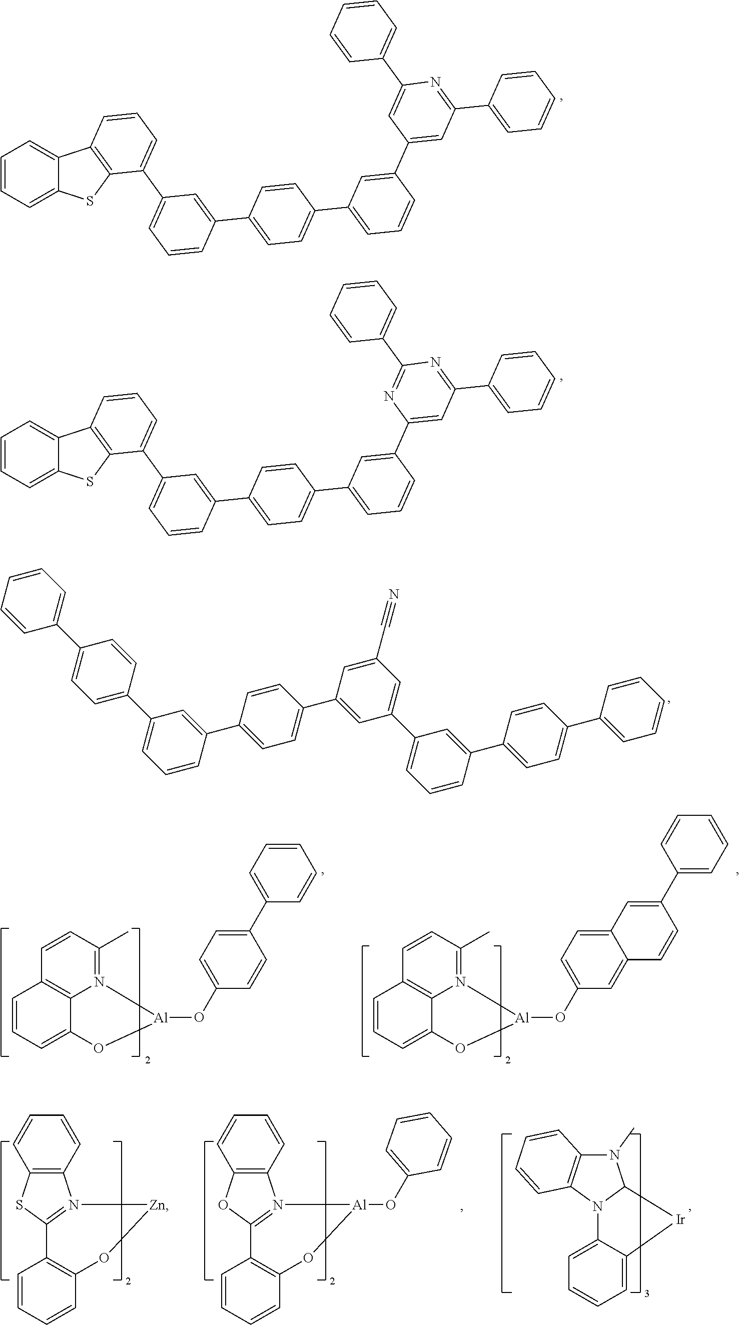

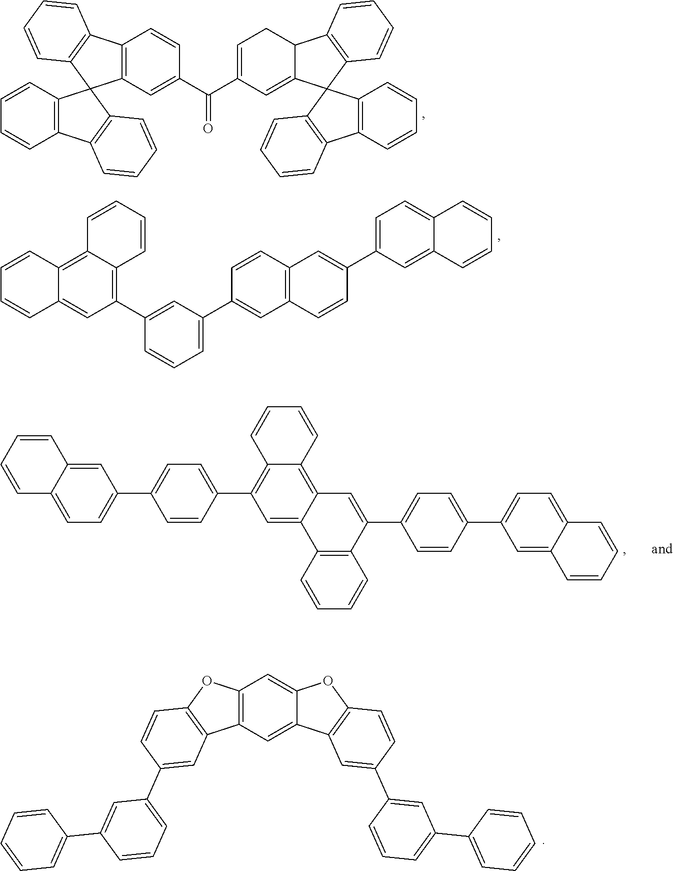

### e) Additional Emitters:

One or more additional emitter dopants may be used in conjunction with the compound of the present disclosure. Examples of the additional emitter dopants are not particularly limited, and any compounds may be used as long as the compounds are typically used as emitter materials. Examples of suitable emitter materials include, but are not limited to, compounds which can produce emissions via phosphorescence, fluorescence, thermally activated delayed fluorescence, i.e., TADF (also referred to as E-type delayed fluorescence), triplet-triplet annihilation, or combinations of these processes.

Non-limiting examples of the emitter materials that may be used in an OLED in combination with materials disclosed herein are exemplified below together with references that disclose those materials: CN103694277, CN1696137, EB01238981, EP01239526, EP01961743, EP1239526, EP1244155, EP1642951, EP1647554, EP1841834, EP1841834B, EP2062907, EP2730583, JP2012074444, JP2013110263, JP4478555, KR1020090133652, KR20120032054, KR20130043460, TW201332980, U.S. Ser. No. 06/699,599, U.S. Ser. No. 06/916,554, US20010019782, US20020034656, US20030068526, US20030072964, US20030138657, US20050123788, US20050244673, US2005123791, US2005260449, US20060008670, US20060065890, US20060127696, US20060134459, US20060134462, US20060202194, US20060251923, US20070034863, US20070087321, US20070103060, US20070111026, US20070190359, US20070231600, US2007034863, US2007104979, US2007104980, US2007138437, US2007224450, US2007278936, US20080020237, US20080233410, US20080261076, US20080297033, US200805851, US2008161567, US2008210930, US20090039776, US20090108737, US20090115322, US20090179555, US2009085476, US2009104472, US20100090591, US20100148663, US20100244004, US20100295032, US2010102716, US2010105902, US2010244004, US2010270916, US20110057559, US20110108822, US20110204333, US2011215710, US2011227049, US2011285275, US2012292601, US20130146848, US2013033172, US2013165653, US2013181190, US2013334521, US20140246656, US2014103305, U.S. Pat. Nos. 6,303,238, 6,413,656, 6,653,654, 6,670,645, 6,687,266, 6,835,469, 6,921,915, 7,279,704, 7,332,232, 7,378,162, 7,534,505, 7,675,228, 7,728,137, 7,740,957, 7,759,489, 7,951,947, 8,067,099, 8,592,586, 8,871,361, WO06081973, WO06121811, WO07018067, WO07108362, WO07115970, WO07115981, WO08035571, WO2002015645, WO2003040257, WO2005019373, WO2006056418, WO2008054584, WO2008078800, WO2008096609, WO2008101842, WO2009000673, WO2009050281, WO2009100991, WO2010028151, WO2010054731, WO2010086089, WO2010118029, WO2011044988, WO2011051404, WO2011107491, WO2012020327, WO2012163471, WO2013094620, WO2013107487, WO2013174471, WO2014007565, WO2014008982, WO2014023377, WO2014024131, WO2014031977, WO2014038456, WO2014112450.

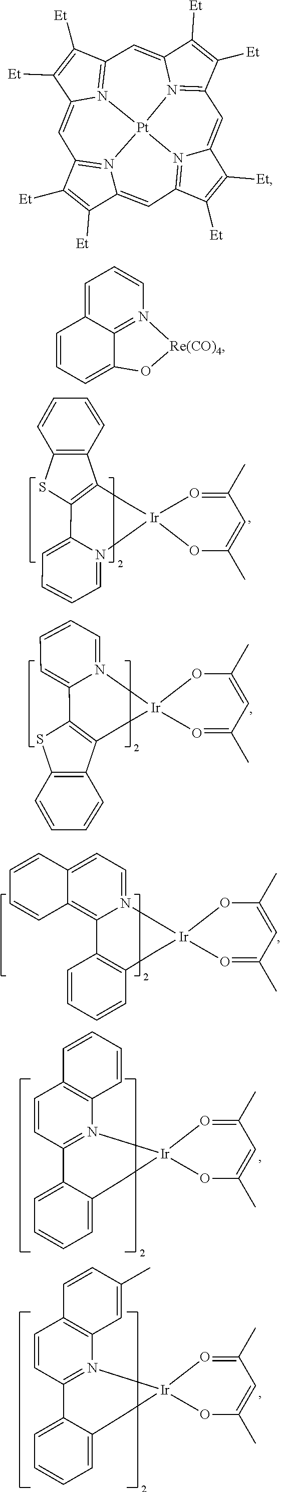

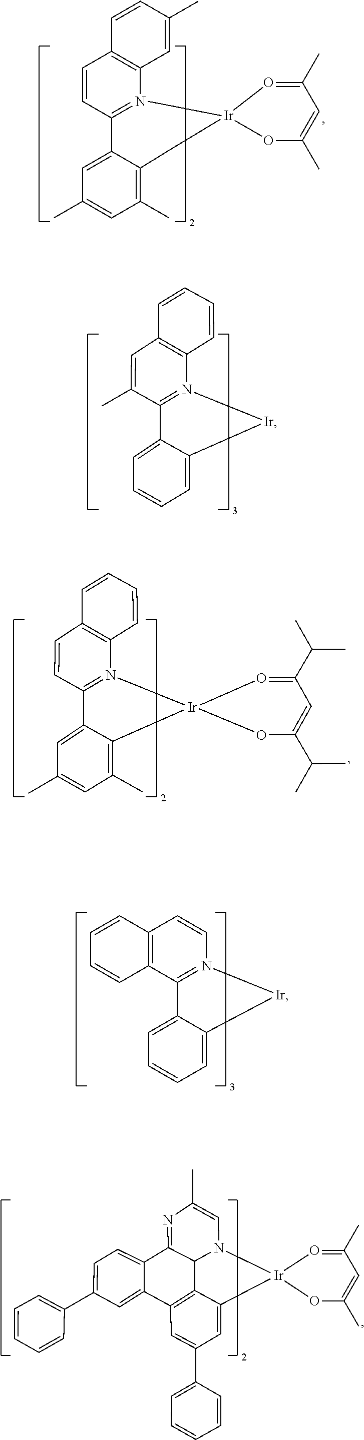

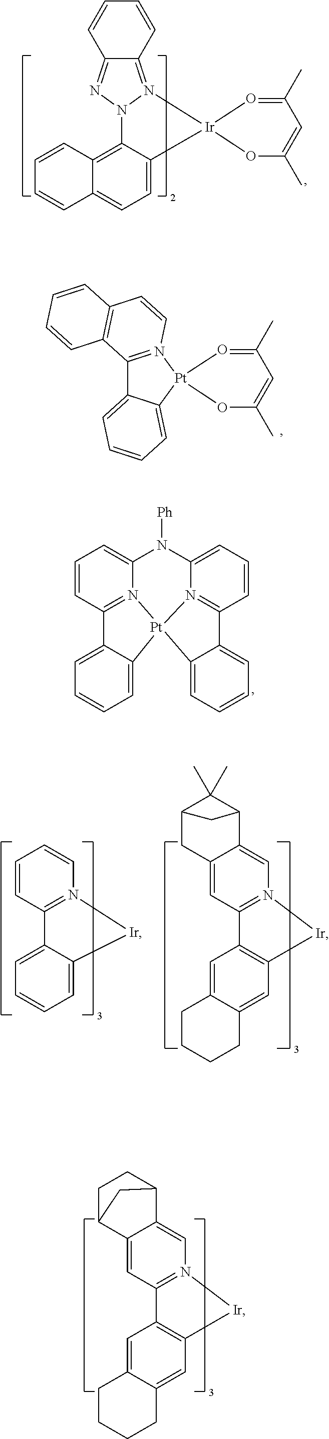

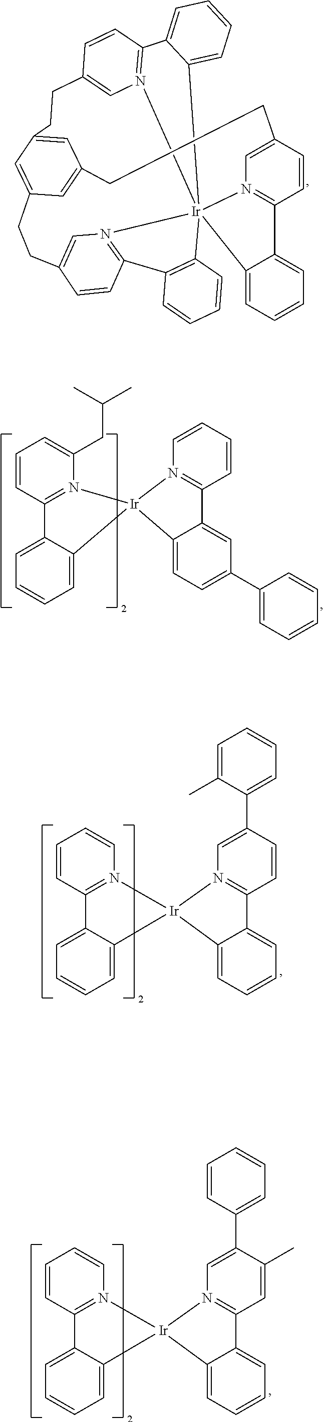

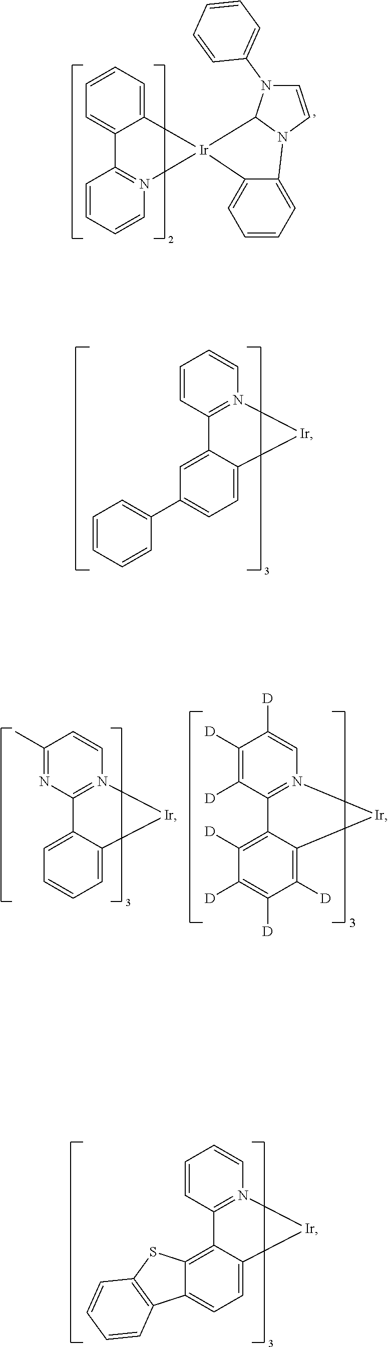

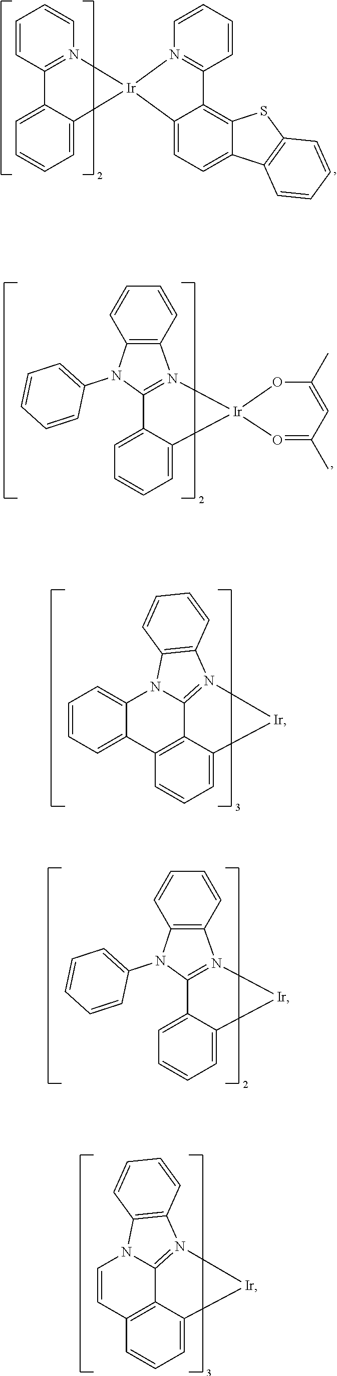

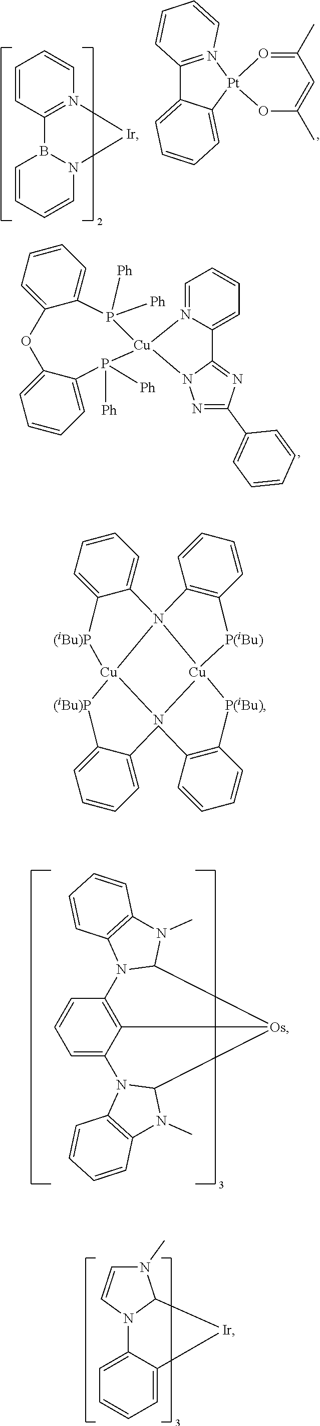

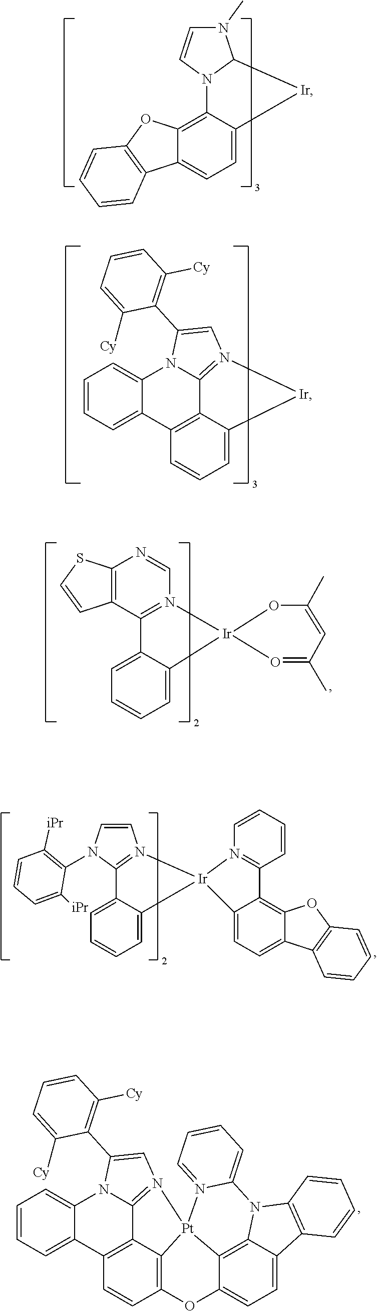

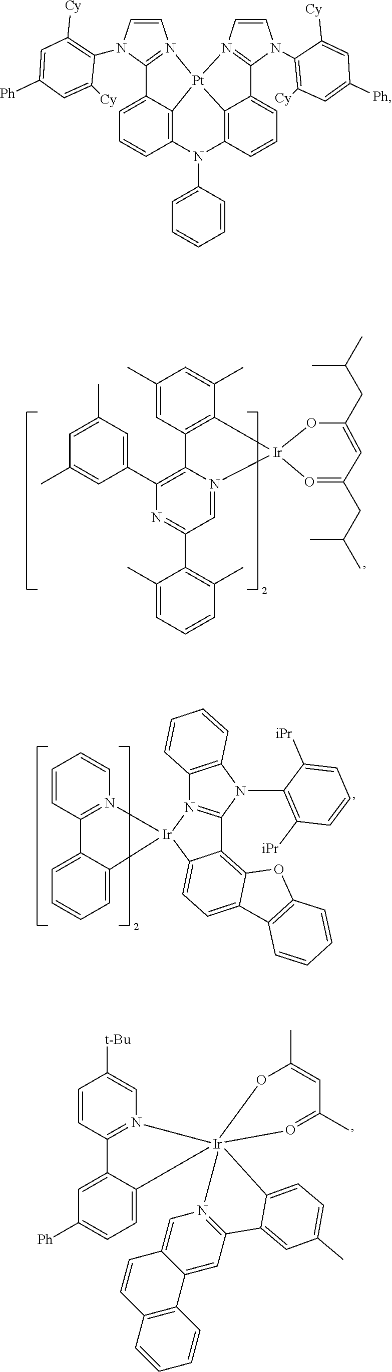

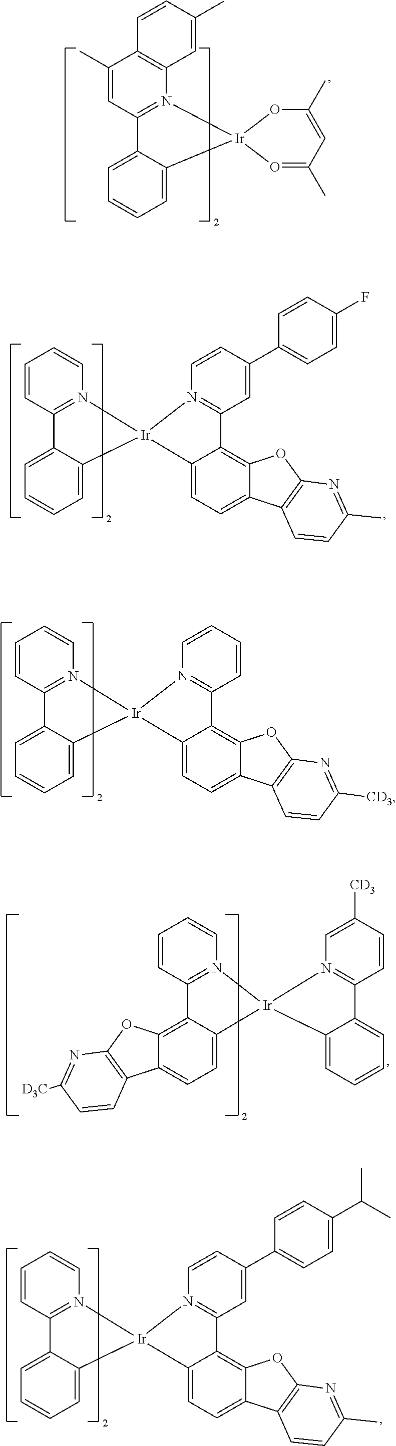

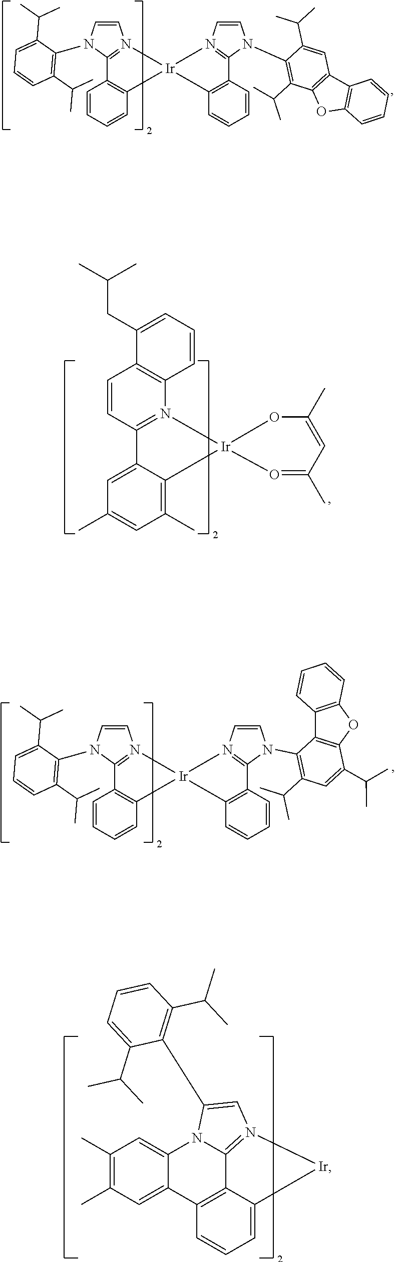

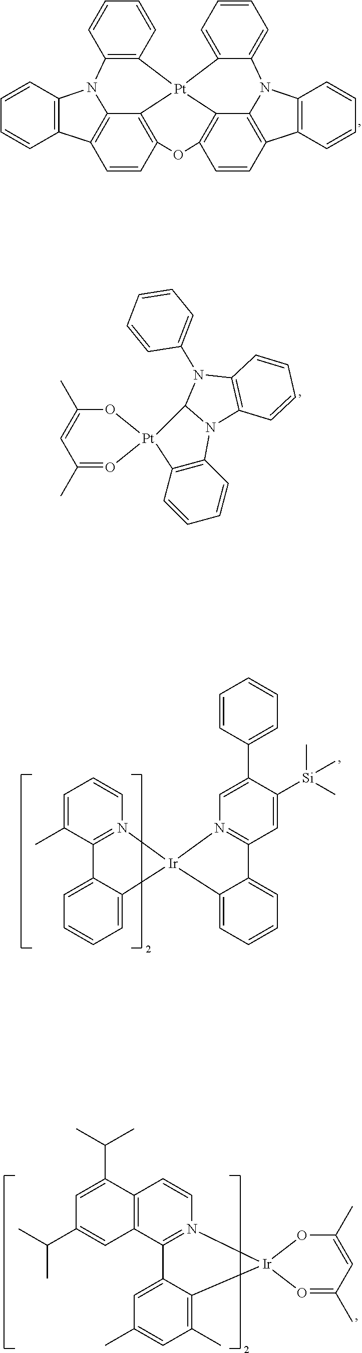

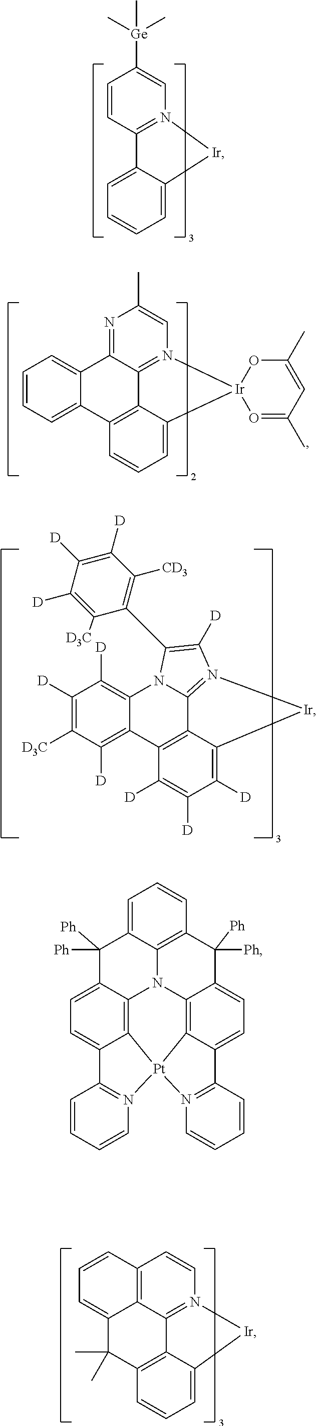

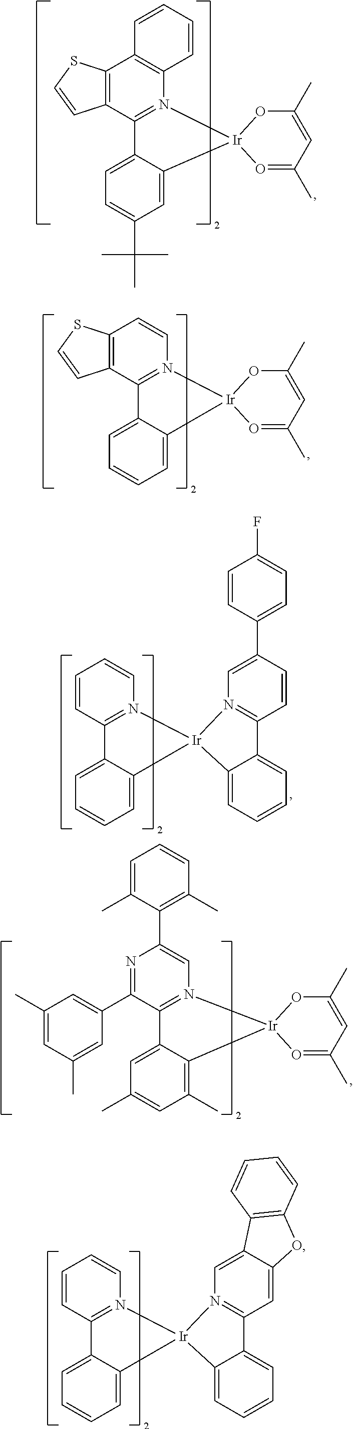

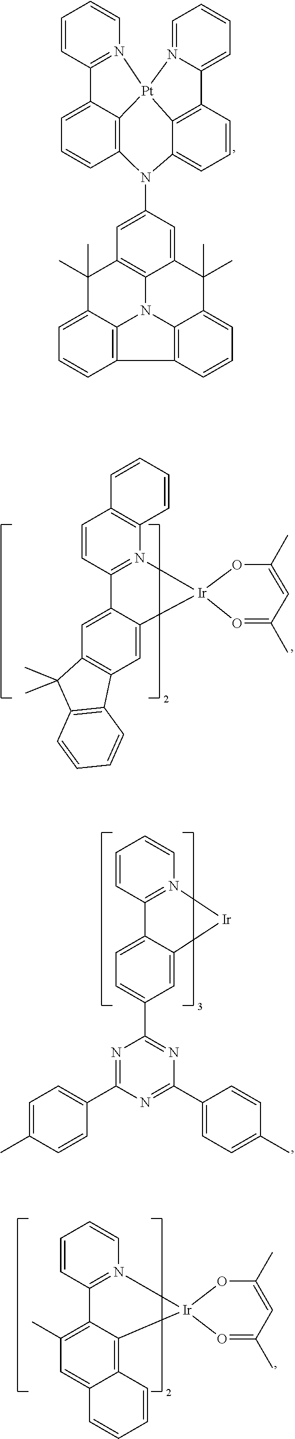

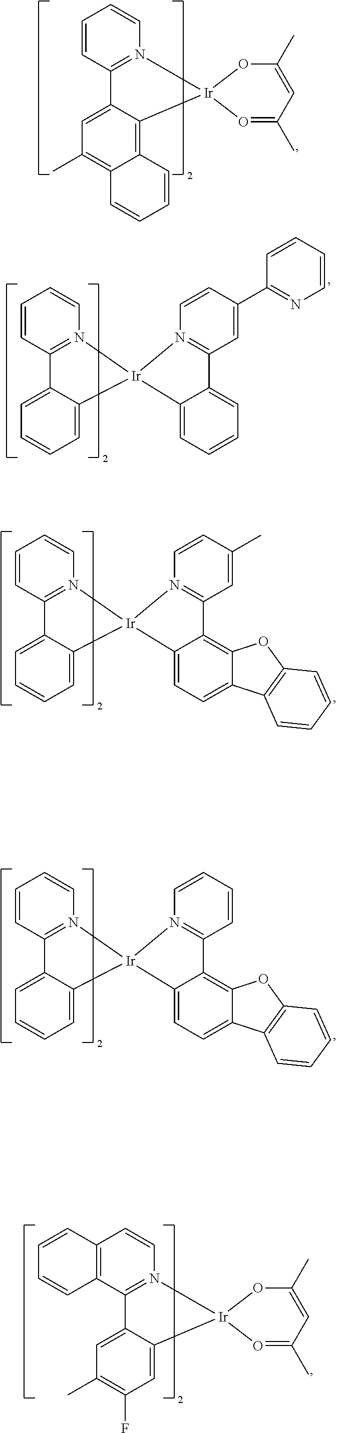

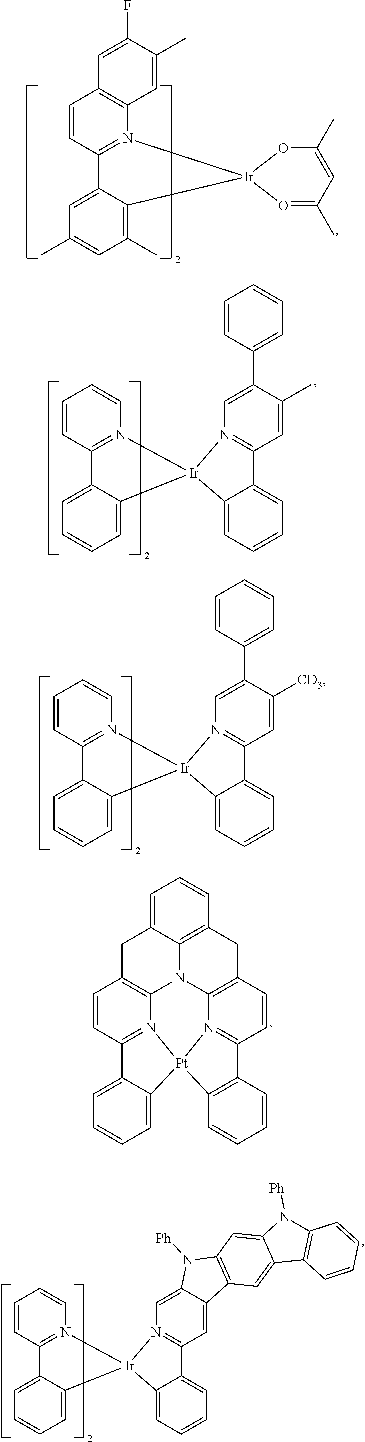

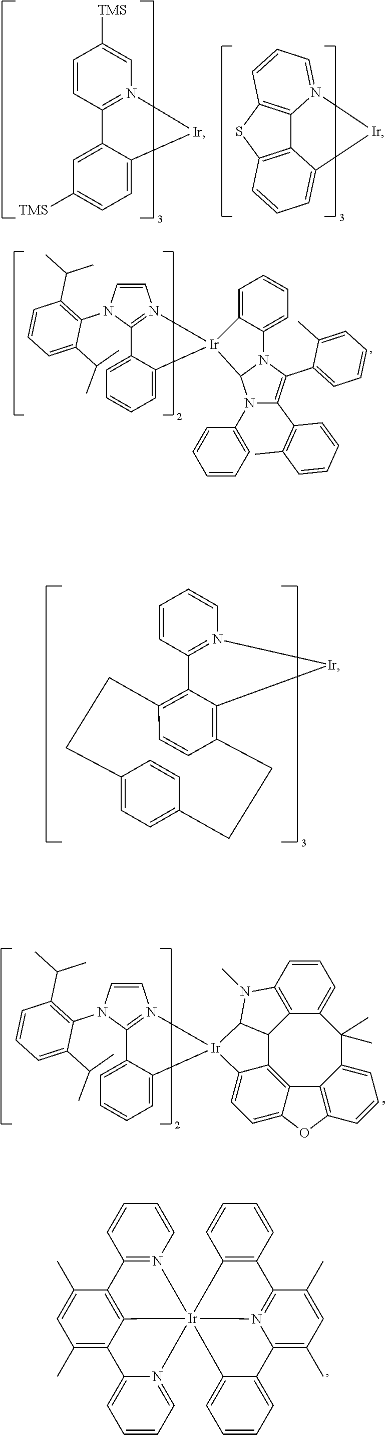

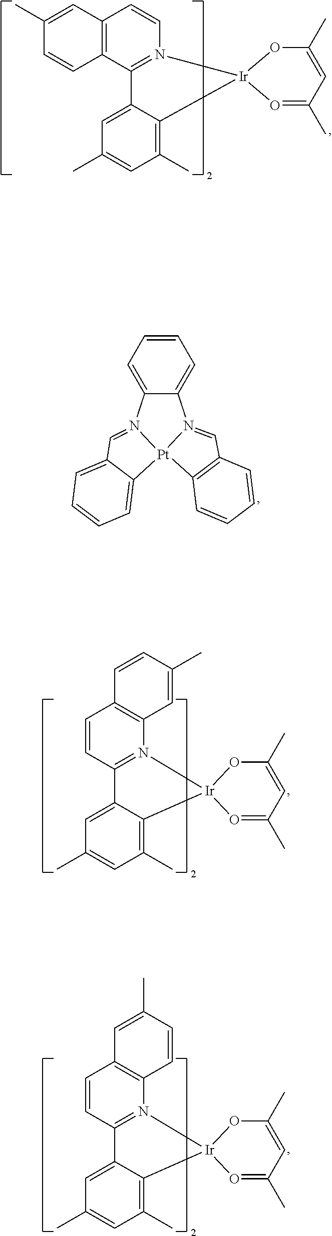

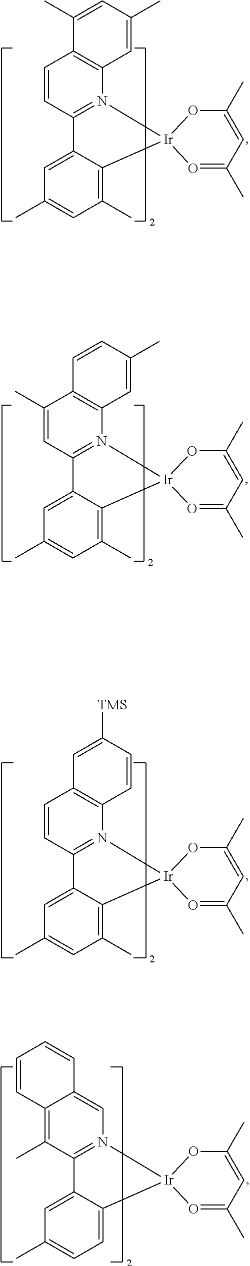

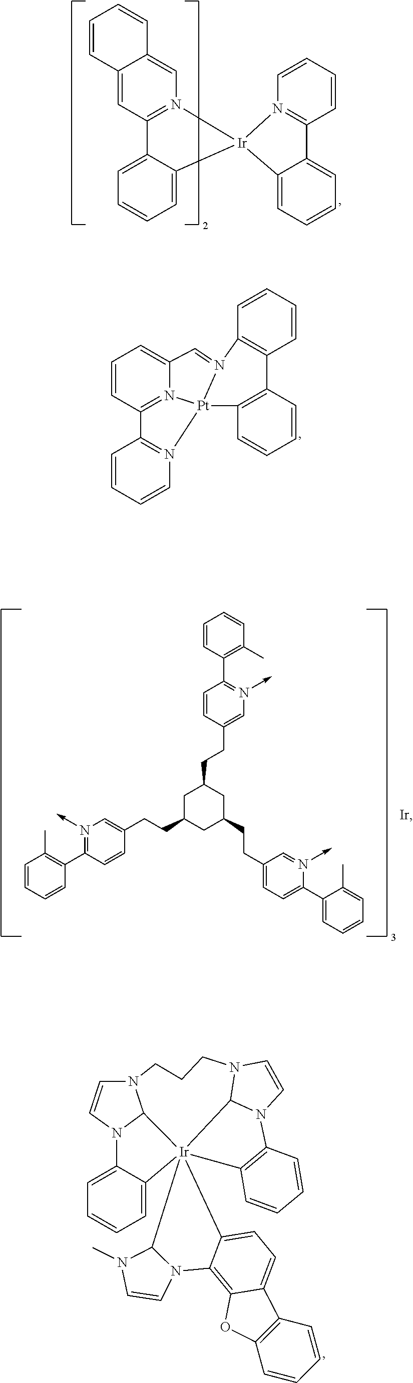

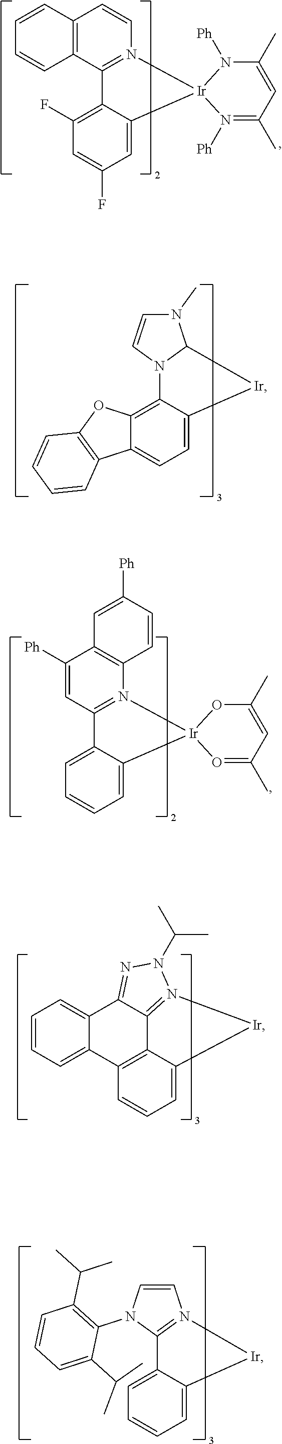

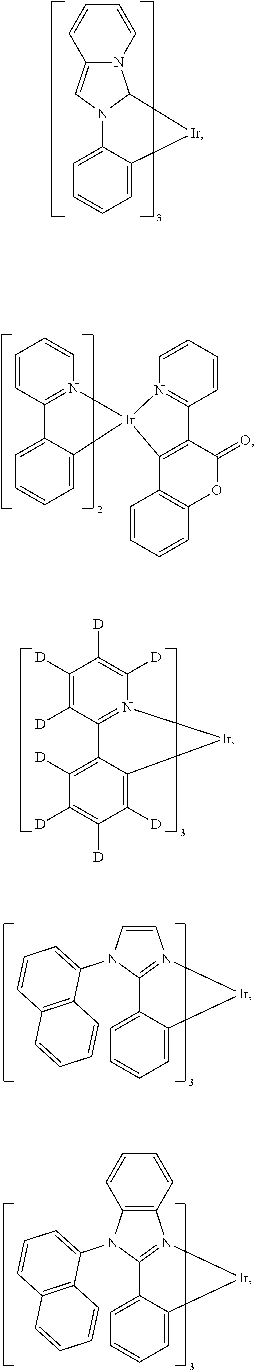

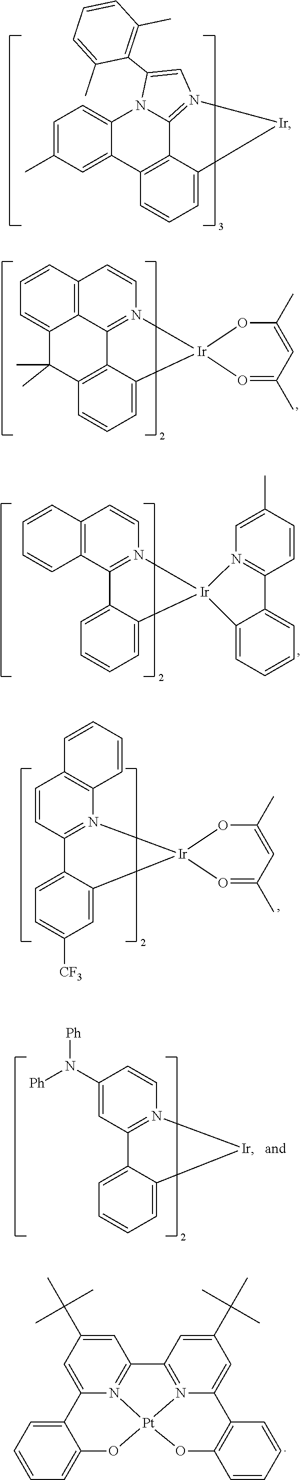

### f) HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and/or higher triplet energy than the emitter closest to the HBL interface. In some embodiments, the HBL material has a lower HOMO (further from the vacuum level) and/or higher triplet energy than one or more of the hosts closest to the HBL interface.

In one aspect, compound used in HBL contains the same molecule or the same functional groups used as host described above.

In another aspect, compound used in HBL contains at least one of the following groups in the molecule:

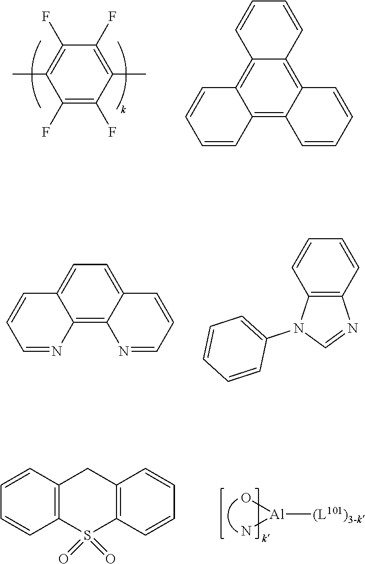

wherein k is an integer from 1 to 20; L¹⁰¹ is another ligand, k′ is an integer from 1 to 3.

### g) ETL:

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In one aspect, compound used in ETL contains at least one of the following groups in the molecule:

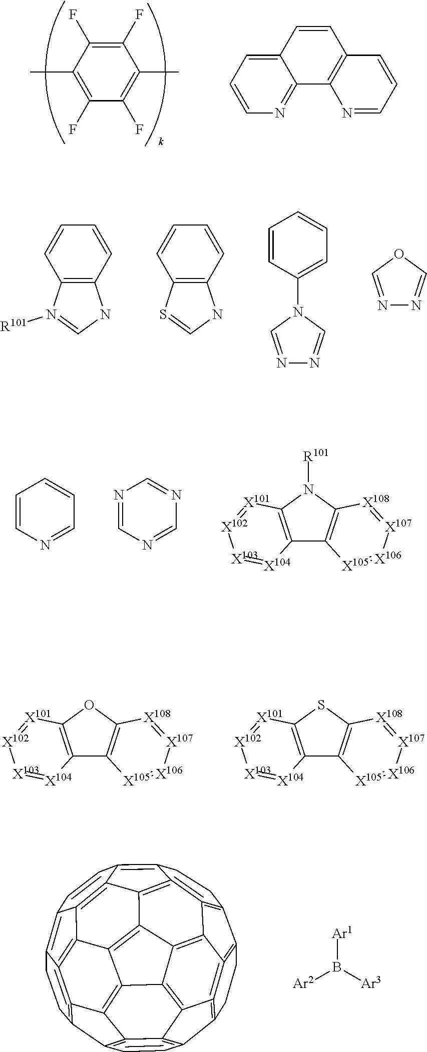

wherein R¹¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, when it is aryl or heteroaryl, it has the similar definition as Ar's mentioned above. Ar¹ to Ar³ has the similar definition as Ar's mentioned above. k is an integer from 1 to 20. X¹⁰¹ to X¹⁰⁸ is selected from C (including CH) or N.

In another aspect, the metal complexes used in ETL contains, but not limit to the following general formula:

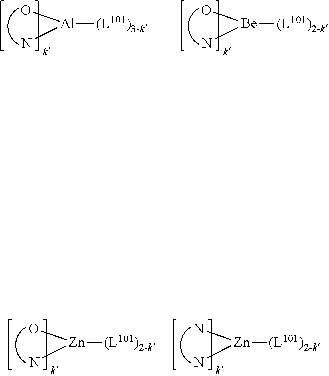

wherein (O—N) or (N—N) is a bidentate ligand, having metal coordinated to atoms O, N or N, N; L¹⁰¹ is another ligand; k′ is an integer value from 1 to the maximum number of ligands that may be attached to the metal.

Non-limiting examples of the ETL materials that may be used in an OLED in combination with materials disclosed herein are exemplified below together with references that disclose those materials: CN103508940, EP01602648, EP01734038, EP01956007, JP2004-022334, JP2005149918, JP2005-268199, KR0117693, KR20130108183, US20040036077, US20070104977, US2007018155, US20090101870, US20090115316, US20090140637, US20090179554, US2009218940, US2010108990, US2011156017, US2011210320, US2012193612, US2012214993, US2014014925, US2014014927, US20140284580, U.S. Pat. Nos. 6,656,612, 8,415,031, WO2003060956, WO2007111263, WO2009148269, WO2010067894, WO2010072300, WO2011074770, WO2011105373, WO2013079217, WO2013145667, WO2013180376, WO2014104499, WO2014104535,

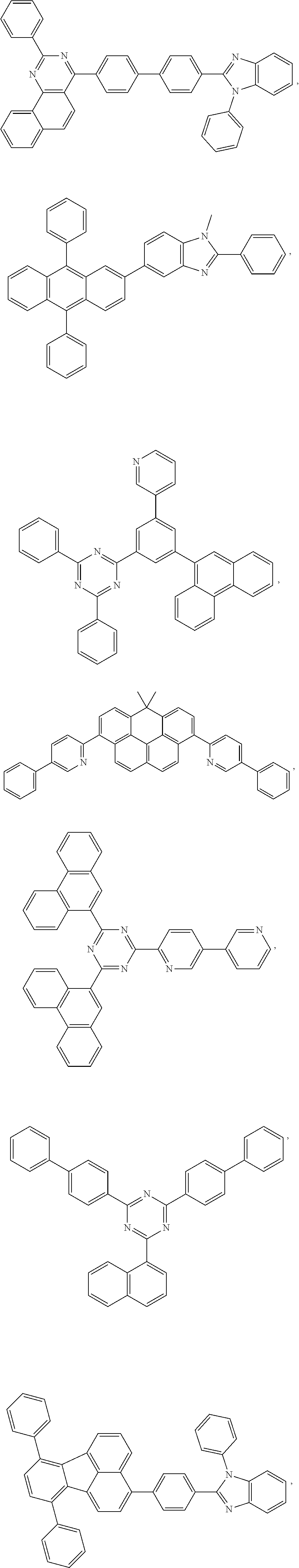

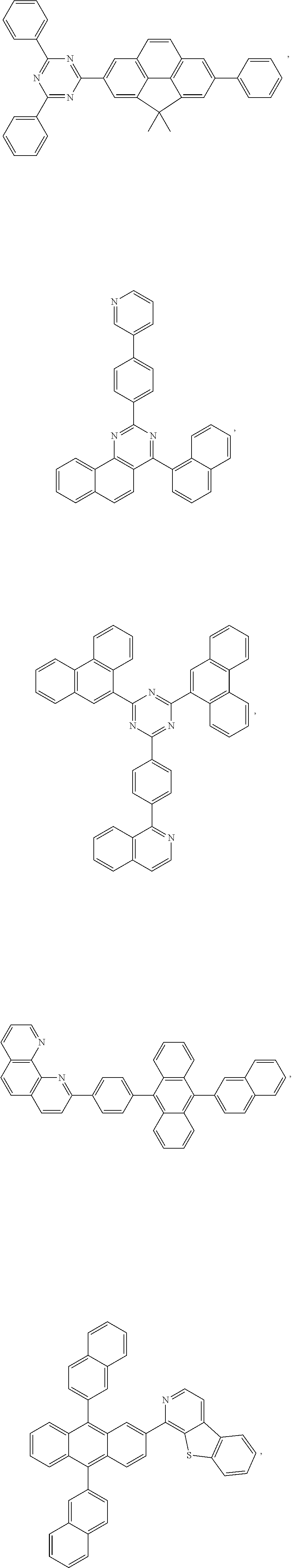 [SMILES: CC1(C)c2cc(-c3ccccc3)cc3ccc4cc(-c5nc(-c6ccccc6)nc(-c6ccccc6)n5)cc1c4c23 ; c1cncc(-c2ccc(-c3nc(-c4cccc5ccccc45)c4ccc5ccccc5c4n3)cc2)c1 ; c1ccc2c(-c3ccc(-c4nc(-c5cc6ccccc6c6ccccc56)nc(-c5cc6ccccc6c6ccccc56)n4)cc3)nccc2c1 ; c1ccc2cc(-c3c4ccccc4c(-c4ccc(-c5ccc6ccc7cccnc7c6n5)cc4)c4ccccc34)ccc2c1 ; c1ccc2cc(-c3c4ccccc4c(-c4ccc5ccccc5c4)c4cc(-c5nccc6c5sc5ccccc56)ccc34)ccc2c1]

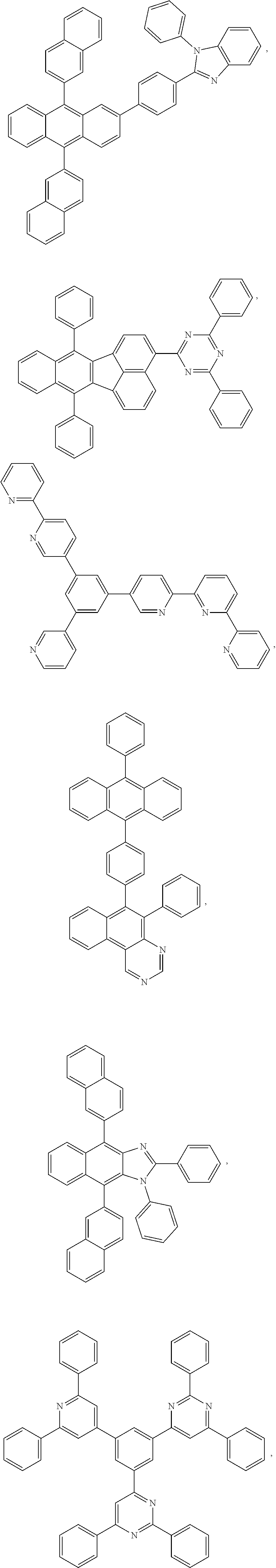

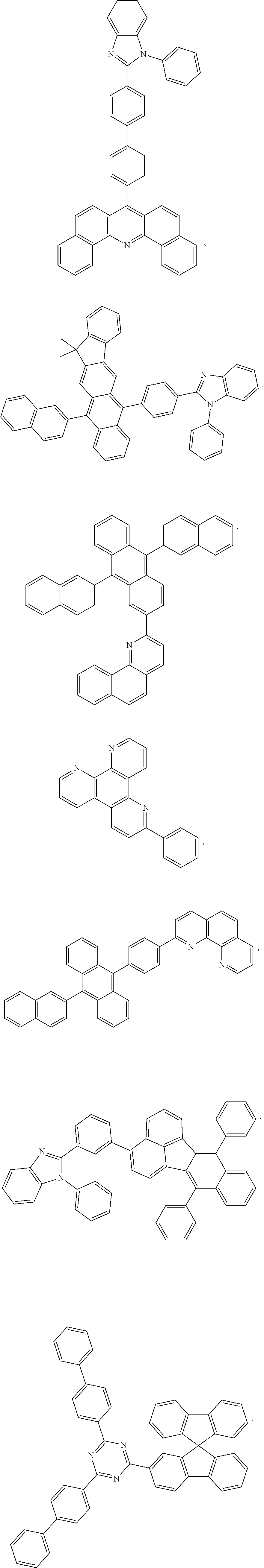

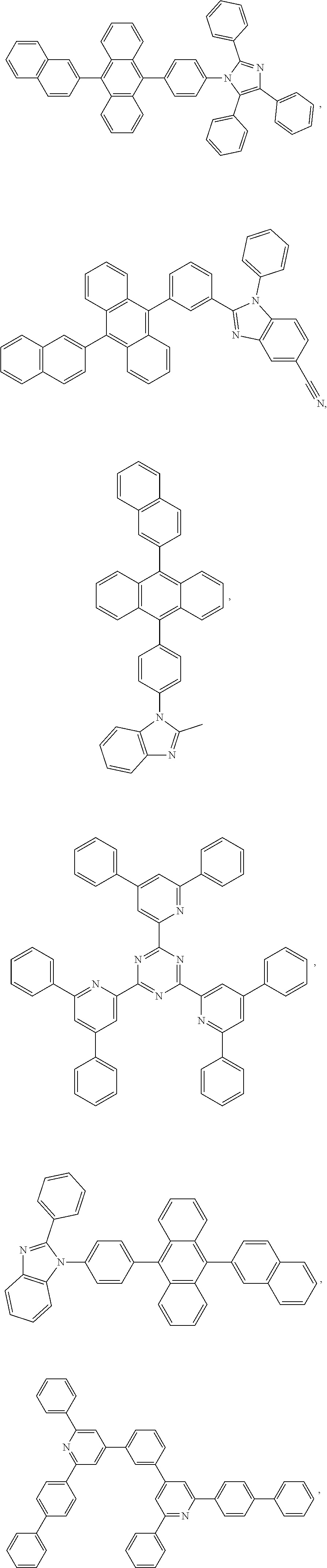

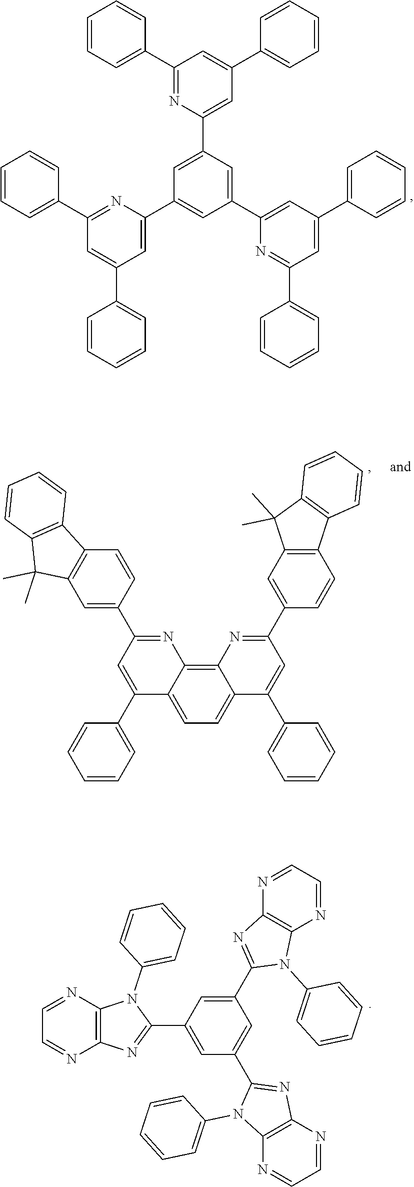 [SMILES: c1ccc(-c2cc(-c3ccccc3)nc(-c3cc(-c4cc(-c5ccccc5)cc(-c5ccccc5)n4)cc(-c4cc(-c5ccccc5)cc(-c5ccccc5)n4)c3)c2)cc1 ; CC1(C)c2ccccc2-c2ccc(-c3cc(-c4ccccc4)c4ccc5c(-c6ccccc6)cc(-c6ccc7c(c6)C(C)(C)c6ccccc6-7)nc5c4n3)cc21 ; c1ccc(-n2c(-c3cc(-c4nc5nccnc5n4-c4ccccc4)cc(-c4nc5nccnc5n4-c4ccccc4)c3)nc3nccnc32)cc1]

### h) Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

In any above-mentioned compounds used in each layer of the OLED device, the hydrogen atoms can be partially or fully deuterated. Thus, any specifically listed substituent, such as, without limitation, methyl, phenyl, pyridyl, etc. may be undeuterated, partially deuterated, and fully deuterated versions thereof. Similarly, classes of substituents such as, without limitation, alkyl, aryl, cycloalkyl, heteroaryl, etc. also may be undeuterated, partially deuterated, and fully deuterated versions thereof.

It is understood that the various embodiments described herein are by way of example only and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

### E. Experimental Section

### Synthesis of (L79253)-III-(A′3)(B1)(B3)

Synthesis of 2-(3-Bromophenoxy)-9-(4-(tert-butyl)pyridin-2-yl)-6-chloro-9H-carbazole

A suspension of 9-(4-(tert-butyl)pyridin-2-yl)-6-chloro-9H-carbazol-2-ol (50 g, 143 mmol, 1 equiv), potassium phosphate tribasic (60.5 g, 285 mmol, 2 equiv), copper(I) iodide (4.07 g, 21.4 mmol, 0.15 equiv), 1,3-dibromobenzene (88 ml, 713 mmol, 5 equiv) and 2-picolinic acid (5.26 g, 42.8 mmol, 0.3 equiv) in dimethyl sulfoxide (713 ml) was sparged with nitrogen for 50 minutes. The reaction temperature was raised to 120° C. and the reaction was stirred for 18 hours. The reaction mixture was cooled to room temperature and poured into water (3.6 L). The mixture was extracted with ethyl acetate (4×2 L). The combined organic layers were washed with saturated aqueous ammonium chloride (3 L), dried over anhydrous sodium sulfate (150 g) and concentrated under reduced pressure. The crude product was purified by column chromatography on silica eluting with a gradient of 5 to 40% ethyl acetate in hexanes as a gray solid (95% yield).

### Synthesis of N¹—([1,1′:3′,1″-Terphenyl]-2′-yl-2,2″,3,3″,4,4″,5,5″,6,6″-d₁₀)—N²—(3-((9-(4-(tert-butyl)pyridin-2-yl)-6-chloro-9H-carbazol-2-yl)oxy)phenyl)benzene-1,2-diamine

A mixture of 2-(3-Bromophenoxy)-9-(4-(tert-butyl)pyridin-2-yl)-6-chloro-9H-carbazole (29.4 g, 58.1 mmol, 1 equiv), N1-([1,1′:3′,1″-terphenyl]-2′-yl-2,2″,3,3″,4,4″,5,5″,6,6″-d10)benzene-1,2-diamine (20.1 g, 58.1 mmol, 1 equiv) and sodium tert-butoxide (8.94 g, 93 mmol, 1.6 equiv) in anhydrous toluene (232 ml) was sparged with nitrogen for 40 minutes. BINAP (2.90 g, 4.65 mmol, 0.08 equiv) and tris(dibenzylideneacetone)dipalladium(0) (2.13 g, 2.33 mmol, 0.04 equiv) were added. The reaction mixture was sparged with nitrogen for 15 minutes and then heated at 100° C. for 12 hours. The reaction mixture was cooled to room temperature and diluted with dichloromethane (300 mL). The resulting mixture was filtered through a pad of Celite, rinsing with dichloromethane (750 mL). The filtrate was concentrated under reduced pressure and the residue was purified by column chromatography on silica eluting with a gradient of 60 to 100% dichloromethane in hexanes to give product as a light brown solid (75% yield).

### Synthesis of 3-([1,1′:3′,1″-Terphenyl]-2′-yl-2,2″,3,3″,4,4″,5,5″,6,6″-d₁₀)-1-(3-((9-(4-(tert-butyl)pyridin-2-yl)-6-chloro-9H-carbazol-2-yl)oxy)phenyl)-1H-benzo[d]imidazol-3-ium chloride

35 wt. % solution of deuterium chloride solution in D₂O (8.81 ml, 106 mmol, 1.6 equiv) was added dropwise to a solution of N—([1,1′:3′,1″-Terphenyl]-2′-yl-2,2″,3,3″,4,4″,5,5″,6,6″-d₁₀)—N²-(3-((9-(4-(tert-butyl)pyridin-2-yl)-6-chloro-9H-carbazol-2-yl)oxy)phenyl)benzene-1,2-diamine (51 g, 66.1 mmol, 1 equiv) in triethyl orthoformate (330 ml). The reaction temperature was raised to 90° C. and the reaction was stirred for 1 hour. The reaction mixture was cooled to room temperature and concentrated under reduced pressure. Toluene (50 mL) was added and the resulting slurry was concentrated under reduced pressure. The residue was triturated with a 1:2 diethyl ether-hexane mixture (450 mL) to give product as an off-white solid (99% yield).

### Synthesis of 7-(3-(3-([1,1′:3′,1″-Terphenyl]-2′-yl-2,2″,3,3″,4,4″,5,5″,6,6″-d₁₀)-1H-3λ⁴-benzo[d]imidazol-1-yl)phenoxy)-9-(4-(tert-butyl)pyridin-2-yl)-3-chloro-9H-carbazole-platinum(II)

A mixture of of 3-([1,1′:3′,1″-Terphenyl]-2′-yl-2,2″,3,3″,4,4″,5,5″,6,6″-d₁₀)-1-(3-((9-(4-(tert-butyl)pyridin-2-yl)-6-chloro-9H-carbazol-2-yl)oxy)phenyl)-1H-benzo[d]imidazol-3-ium chloride (25.5 g, 32.6 mmol, 1 equiv), a platinum precursor (1.1 equiv) and a base (3.3 equiv) in an organic solvent (652 ml) was sparged with nitrogen for 40 minutes. The mixture was refluxed for 14.5 hours, cooled to room temperature, and filtered. The filter cake was washed with methanol (100 mL) and dried on the filter to give crude product (30 g). The crude product was purified by column chromatography on silica eluting with 80% dichloromethane in hexanes to yield product as a yellow solid (70% yield).

### Synthesis of (L79253)-III-(A′3)(B1)(B3)

A mixture of allylpalladium chloride dimer (28.2 mg, 0.08 mmol, 0.15 equiv) and cBRIDP (54.3 mg, 0.15 mmol, 0.3 equiv) was stirred in anhydrous THF (0.5 mL) under nitrogen for 5 minutes. 7-(3-(3-([1,1′:3′,1″-Terphenyl]-2′-yl-2,2″,3,3″,4,4″,5,5″,6,6″-d₁₀)-1H-3λ⁴-benzo[d]imidazol-1-yl)phenoxy)-9-(4-(tert-butyl)pyridin-2-yl)-3-chloro-9H-carbazole-platinum(II) (500 mg, 0.51 mmol, 1.0 equiv) was added followed by anhydrous xylene (2.5 mL) (Vial A). In another vial (Vial B), 1,8-dimethyl-9H-carbazole (601 mg, 3.08 mmol, 6 equiv) was dissolved in anhydrous THF (0.5 mL) and cooled to 0° C. A 3 M solution of methylmagnesium chloride in THF (1.03 mL, 3.08 mmol, 6 equiv) was added under nitrogen. The mixture was stirred at 0° C. for 5 minutes. The Vial A solution was added via syringe to Vial B under nitrogen. Vial A was rinsed with xylenes (2.5 mL) and added to Vial B. The reaction mixture (Vial B) was heated at 120° C. for 20 hours. After cooling to room temperature, the mixture was diluted with dichloromethane (5 mL) and filtered through a pad of celite. The celite pad was rinsed with additional dichloromethane (3×20 mL). The filtrate was purified by column chromatography eluting with a gradient of 10%-40% dichloromethane (containing 5% ethyl acetate) in hexanes to give product as a light yellow solid (41% yield).

### Synthesis of (L79253)-III-(A′4)(B34)(B3)

### Synthesis of N¹—([1,1′:3′,1″-Terphenyl]-2′-yl-2,2″,3,3″,4,4″,5,5″,6,6″-d₁₀)—N²-(3-((9′-(4-(tert-butyl)pyridin-2-yl)-9-phenyl-9H,9′H-[1,3′-bicarbazol]-7′-yl)oxy)phenyl)benzene-1,2-diamine

A mixture of 7′-(3-bromophenoxy)-9′-(4-(tert-butyl)pyridin-2-yl)-9-phenyl-9H,9′H-1,3′-bicarbazole (400 mg, 0.56 mmol, 1 equiv), N—([1,1′:3′,1″-terphenyl]-2′-yl-2,2″,3,3″,4,4″,5,5″,6,6″-d₁₀)benzene-1,2-diamine (233 mg, 0.67 mmol, 1.1 equiv) and sodium tert-butoxide (162 mg, 1.7 mmol, 3 equiv) in toluene (4 mL) was sparged with nitrogen for 15 minutes. A mixture of allylpalladium chloride dimer (24 mg, 0.06 mmol, 0.1 equiv) and cBRIDP (40 mg, 0.11 mmol, 0.2 equiv) in toluene (2 mL) was sparged with nitrogen for 15 minutes and transferred by syringe to the first mixture. After refluxing for 18 hours, the reaction mixture was cooled to room temperature and filtered through a pad of Celite, which was washed with dichloromethane (0.5 L). The filtrate was concentrated under reduced pressure to give crude product (99% yield).

### Synthesis of (3-([1,1′:3′,1″-Terphenyl]-2′-yl-2,2″,3,3″,4,4″,5,5″,6,6″-d₁₀)-1-(3-((9′-(4-(tert-butyl)pyridin-2-yl)-9-phenyl-9H,9′H-[1,3′-bicarbazol]-7′-yl)oxy)phenyl)-1H-benzo[d]imidazol-3-ium) chloride

A mixture of crude N¹—([1,1′:3′,1″-Terphenyl]-2′-yl-2,2″,3,3″,4,4″,5,5″,6,6″-d₁₀)-N²-(3-((9′-(4-(tert-butyl)pyridin-2-yl)-9-phenyl-9H,9′H-[1,3′-bicarbazol]-7′-yl)oxy)phenyl)benzene-1,2-diamine (549 mg, 1.1 mmol) and 35% deuterium chloride in deuterium oxide (0.8 mL, 9 mmol, 8 equiv) in triethyl orthoformate (15 mL) was refluxed for 18 hours. The reaction mixture was cooled to room temperature and concentrated under reduced pressure. The crude material was absorbed onto Celite and purified by column chromatography, eluting with a gradient of 80 to 100% dichloromethane in hexanes followed by 0 to 10% methanol in dichloromethane to give product (78% yield)

### Synthesis of (L79253)-III-(A′4)(B34)(B3)

An organic solvent (18 mL) was sparged with nitrogen for 30 minutes and was transferred to a round bottom flask containing (3-([1,1′:3′,1″-Terphenyl]-2′-yl-2,2″,3,3″,4,4″,5,5″,6,6″-d₁₀)-1-(3-((9′-(4-(tert-butyl)pyridin-2-yl)-9-phenyl-9H,9′H-[1,3′-bicarbazol]-7′-yl)oxy)phenyl)-1H-benzo[d]imidazol-3-ium) chloride (380 mg, 0.37 mmol, 1 equiv) and a base (3 equiv). The mixture was sparged with nitrogen for 15 minutes. A platinum precursor (1 equiv) was added and sparging was continued for 5 minutes. The reaction mixture was heated at 60° C. for one hour and at 190° C. for four days. The reaction mixture was cooled to room temperature and concentrated under reduced pressure. The crude material was absorbed onto Celite and purified by column chromatography, eluting with a gradient of 0 to 70% dichloromethane in hexanes to give product (30% yield).

### Synthesis of (L79253)-III-(A′6)(B34)(B3)

### Synthesis of 2-(3-Bromophenoxy)-9-(4-(tert-butyl)pyridin-2-yl)-6-chloro-9H-carbazole

A suspension of 9-(4-(tert-butyl)pyridin-2-yl)-6-chloro-9H-carbazol-2-ol (50 g, 143 mmol, 1 equiv), potassium phosphate tribasic (60.5 g, 285 mmol, 2 equiv), copper(I) iodide (4.07 g, 21.4 mmol, 0.15 equiv), 1,3-dibromobenzene (88 ml, 713 mmol, 5 equiv) and 2-picolinic acid (5.26 g, 42.8 mmol, 0.3 equiv) in dimethyl sulfoxide (713 ml) was sparged with nitrogen for 50 minutes. The reaction temperature was raised to 120° C. and the reaction was stirred for 18 hours. The reaction mixture was cooled to room temperature and poured into water (3.6 L). The mixture was extracted with ethyl acetate (4×2 L). The combined organic layers were washed with saturated aqueous ammonium chloride (3 L), dried over anhydrous sodium sulfate (150 g) and concentrated under reduced pressure. The residue was absorbed onto Celite and purified by column chromatography system eluting with a gradient of 5 to 40% ethyl acetate in hexanes to give product as a gray solid (95% yield).

### Synthesis of N¹—([1,1′:3′,1″-Terphenyl]-2′-yl-2,2″,3,3″,4,4″,5,5″,6,6″-d₁₀)—N-(3-((9-(4-(tert-butyl)pyridin-2-yl)-6-chloro-9H-carbazol-2-yl)oxy)phenyl)benzene-1,2-diamine

A mixture of 2-(3-Bromophenoxy)-9-(4-(tert-butyl)pyridin-2-yl)-6-chloro-9H-carbazole (29.4 g, 58.1 mmol, 1 equiv), N1-([1,1′:3′,1″-terphenyl]-2′-yl-2,2″,3,3″,4,4″,5,5″,6,6″-d₁₀)benzene-1,2-diamine (20.1 g, 58.1 mmol, 1 equiv) and sodium tert-butoxide (8.94 g, 93 mmol, 1.6 equiv) in anhydrous toluene (232 ml) was sparged with nitrogen for 40 minutes. BINAP (2.90 g, 4.65 mmol, 0.08 equiv) and tris(dibenzylideneacetone)dipalladium(0) (2.13 g, 2.33 mmol, 0.04 equiv) were added. The reaction mixture was sparged with nitrogen for 15 minutes and then heated at 100° C. for 12 hours. The reaction mixture was cooled to room temperature and diluted with dichloromethane (300 mL). The resulting mixture was filtered through a pad of Celite, rinsing with dichloromethane (750 mL). The filtrate was concentrated under reduced pressure and the residue was absorbed onto Celite (150 g). The crude product was purified by column chromatography, eluting with a gradient of 60 to 100% dichloromethane in hexanes to give product as a light brown solid (75% yield).

### Synthesis of 3-([1,1′:3′,1″-Terphenyl]-2′-yl-2,2″,3,3″,4,4″,5,5″,6,6″-d₁₀)-1-(3-((9-(4-(tert-butyl)pyridin-2-yl)-6-chloro-9H-carbazol-2-yl)oxy)phenyl)-1H-benzo[d]imidazol-3-ium chloride

A 35 wt. % solution of deuterium chloride solution in D₂O (8.81 ml, 106 mmol, 1.6 equiv) was added dropwise to a solution of N¹—([1,1′:3′,1″-Terphenyl]-2′-yl-2,2″,3,3″,4,4″,5,5″,6,6″-d₁₀)—N²-(3-((9-(4-(tert-butyl)pyridin-2-yl)-6-chloro-9H-carbazol-2-yl)oxy)phenyl)benzene-1,2-diamine (51 g, 66.1 mmol, 1 equiv) in triethyl orthoformate (330 ml). The reaction temperature was raised to 90° C. and the reaction was stirred for 1 hour. The reaction mixture was cooled to room temperature and concentrated under reduced pressure. The residue was triturated with a 1:2 diethyl ether-hexane mixture (450 mL) to give product as an off-white solid (99% yield).

### Synthesis of 7-(3-(3-([1,1′:3′,1″-Terphenyl]-2′-yl-2,2″,3,3″,4,4″,5,5″,6,6″-d₁₀)-1H-3λ⁴-benzo[d]imidazol-1-yl)phenoxy)-9-(4-(tert-butyl)pyridin-2-yl)-3-chloro-9H-carbazole-platinum(II)

A mixture of 3-([1,1′:3′,1″-Terphenyl]-2′-yl-2,2″,3,3″,4,4″,5,5″,6,6″-d₁₀)-1-(3-((9-(4-(tert-butyl)pyridin-2-yl)-6-chloro-9H-carbazol-2-yl)oxy)phenyl)-1H-benzo[d]imidazol-3-ium chloride (25.5 g, 32.6 mmol, 1 equiv), a platinum precurser (1.1 equiv) and a base (3.3 equiv) in a solvent (652 ml) was sparged with nitrogen for 40 minutes. The mixture was refluxed for 14.5 hours, cooled to room temperature, and filtered. The crude product was absorbed onto Celite and purified by column chromatography, eluting with 80% dichloromethane in hexanes to yield as a yellow solid (70% yield).

### Synthesis of (L79253)-III-(A′6)(B34)(B3)

A solution of 7-(3-(3-([1,1′:3′,1″-Terphenyl]-2′-yl-2,2″,3,3″,4,4″,5,5″,6,6″-d₁₀)-1H-3λ⁴-benzo[d]imidazol-1-yl)phenoxy)-9-(4-(tert-butyl)pyridin-2-yl)-3-chloro-9H-carbazole-platinum(II) (800 mg, 0.82 mmol, 1.0 equiv), potassium phosphate tribasic monohydrate (756 mg, 3.28 mmol, 4.0 equiv), (9-phenyl-9H-carbazol-3-yl)boronic acid (943 mg, 3.28 mmol, 4.0 equiv), and SPhos-Pd-G2 (59.2 mg, 0.08 mmol, 0.1 equiv) in a 10 to 1 mixture of dioxane and water (8.8 mL) was sparged with nitrogen for 15 minutes. The reaction mixture was heated at 100° C. for 18 h. The crude mixture was cooled to room temperature and filtered over a pad of celite. The crude material was absorbed onto celite and purified by column chromatography, eluting with 30% dichloromethane in hexanes to give product as a light yellow solid (41% yield).

### Synthesis of (L79253)-III-(A′1)(B41)(B3)

### Synthesis of 9-(4-(tert-Butyl)pyridin-2-yl)-7-methoxy-9H-3,9′-bicarbazole

A solution of tris(dibenzylideneacetone)dipalladium(0) (3.1 g, 3.4 mmol, 0.09 equiv) and tri-tert-butylphosphonium tetrafluoroborate (1.97 g, 6.79 mmol, 17.2 equiv) in toluene (400 mL) was sparged with nitrogen for 20 minutes followed by the addition of 9H-carbazole (7.0 g, 42 mmol, 1.1 equiv), 9-(4-(tert-Butyl)pyridin-2-yl)-6-chloro-2-methoxy-9H-carbazole (15.8 g, 39.4 mmol, 1.00 equiv), and additional toluene (450 mL). The mixture was sparged with nitrogen for an additional 10 minutes and then treated with sodium tert-butoxide (11.9 g, 124 mmol, 3.14 equiv) added in portions over one minute. The reaction mixture was heated at 111° C. for 17 hours, and then cooled to room temperature. The mixture was filtered through Celite and the filter pad was washed with toluene (1 L). The filtrate was washed with water (2×500 mL), saturated brine (500 mL), dried over sodium sulfate (30 g). The crude product was absorbed onto celite and purified by column chromatography, eluting with a gradient of 0 to 10% ethyl acetate in heptanes to give product as a light tan foam (69% yield).

### Synthesis of 9-(4-(tert-Butyl)pyridin-2-yl)-9H-[3,9′-bicarbazol]-7-ol

A mixture of 9-(4-(tert-Butyl)pyridin-2-yl)-7-methoxy-9H-3,9′-bicarbazole (14.4 g, 29.0 mmol, 1.00 equiv) in 48% HBr (440 mL, 656 g, 8.11 mol, 280 equiv) was heated at reflux for 16 hours. The mixture was cooled to room temperature, neutralized with solid sodium bicarbonate (450 g), partitioned between water (200 mL) and ethyl acetate (500 mL), and the layers were separated. The aqueous layer was extracted with ethyl acetate (400 mL). The combined organic layers were washed with saturated sodium chloride (300 mL), dried over sodium sulfate (50 g) and the residue was adsorbed onto Celite and purified by column chromatography, eluting with a gradient of 0 to 25% ethyl acetate in heptanes to give product as an off-white solid (76% yield).

### Synthesis of 7-(3-Bromophenoxy)-9-(4-(tert-butyl)pyridin-2-yl)-9H-3,9′-bicarbazole

A mixture of 9-(4-(tert-Butyl)pyridin-2-yl)-9H-[3,9′-bicarbazol]-7-ol (13.9 g, 28.9 mmol, 1.00 equiv), 1,3-dibromobenzene (20.9 g, 88.6 mmol, 3.07 equiv), and picolinic acid (0.43 g, 3.5 mmol, 0.12 equiv) in dimethyl sulfoxide (140 mL) was sparged with nitrogen for 15 minutes at room temperature. Tribasic potassium phoshate (12.9 g, 90.8 mmol, 2.10 equiv) was added and the mixture was sparged with nitrogen for five minutes. Copper(I) iodide (0.33 g, 1.7 mmol, 0.06 equiv) was added. The mixture was sparged with nitrogen for five minutes then heated at 120° C. for 21 hours. The reaction mixture was cooled to room temperature, partitioned between methyl tert-butyl ether (250 mL) and 28-30% aqueous ammonium hydroxide (240 mL) and water (220 mL). The layers were separated and the aqueous layer was extracted with methyl tert-butyl ether (2×250 mL). The combined organic layers were washed with water (2×250 mL), 28-30% aqueous ammonium hydroxide (200 mL), and saturated brine (250 mL). The organic layer was dried over sodium sulfate (10 g), concentrated under reduced pressure, and absorbed onto celite. The crude product was purified by column chromatography, eluting with a gradient of 0 to 10% ethyl acetate in heptanes to give product as a heterogeneous yellow and white solid (53% yield).

### Synthesis of N1-([1,1′:3′,1″-Terphenyl]-2′-yl-2,2″,3,3″,4,4″,5,5″,6,6″-d₁₀)-N2-(3-((9-(4-(tert-butyl)pyridin-2-yl)-9H-[3,9′-bicarbazol]-7-yl)oxy)phenyl)benzene-1,2-diamine

A mixture of allyl palladium chloride dimer (386 mg, 1.05 mmol, 0.060 equiv) and di-tert-butyl(1-methyl-2,2-diphenylcyclopropyl)phosphane (cBRIDP, 753 mg, 2.14 mmol, 1.22 equiv) in toluene (50 mL) was sparged with nitrogen for 25 minutes while heating to 80° C. to give a yellow solution. Separately, a mixture of N1-([1,1′:3′,1″-terphenyl]-2′-yl-2,2″,3,3″,4,4″,5,5″,6,6″-d₁₀)benzene-1,2-diamine (6.06 g, 17.5 mmol, 1.00 equiv), 7-(3-Bromophenoxy)-9-(4-(tert-butyl)pyridin-2-yl)-9H-3,9′-bicarbazole (11.7 g, 18.4 mmol, 1.05 equiv), and sodium tert-butoxide (5.28 g, 54.9 mmol, 3.14 equiv) in toluene (300 mL) was sparged with nitrogen for 15 minutes while heating to 85° C. The catalyst solution was transferred to the reagent mixture at 85° C. The combined mixture was sparged with nitrogen for five minutes at 85° C. then heated at 111° C. for eight hours. The mixture was cooled to room temperature and diluted with water (200 mL). The biphasic mixture was filtered through celite. The filter pad was washed with ethyl acetate (500 mL), and the layers of the filtrate were separated. The organic layer was washed with water (500 mL) and saturated brine (400 mL), dried over sodium sulfate (80 g) and concentrated under reduced pressure to a black foam (18.9 g). The residue was absorbed onto celite and purified by column chromatography, eluting with a gradient of 0 to 25% ethyl acetate in heptanes to give product as a brown solid (75% yield).

### Synthesis of 3-([1,1′:3′,1″-Terphenyl]-2′-yl-2,2″,3,3″,4,4″,5,5″,6,6″-d₁₀)-1-(3-((9-(4-(tert-butyl)pyridin-2-yl)-9H-[3,9′-bicarbazol]-7-yl)oxy)phenyl)-1H-benzo[d]imidazol-3-ium chloride

A solution of N1-([1,1′:3′,1″-Terphenyl]-2′-yl-2,2″,3,3″,4,4″,5,5″,6,6″-d₁₀)-N2-(3-((9-(4-(tert-butyl)pyridin-2-yl)-9H-[3,9′-bicarbazol]-7-yl)oxy)phenyl)benzene-1,2-diamine (12.5 g, 13.9 mmol, 1.00 equiv) in triethylorthoformate (75 mL) was treated with concentrated hydrochloric acid (2.0 mL, 24 mmol, 1.7 equiv) at room temperature. The mixture was stirred at room temperature for one hour, then at 80° C. for six hours. The reaction mixture was cooled to room temperature, concentrated under reduced pressure, then concentrated from ethanol (75 mL) to give a red/brown residue (18.7 g), which was absorbed onto silica gel. The residue was purified by column chromatography, eluting with a gradient of 0 to 10% methanol in dichloromethane to give product as a light tan foam (70% yield).

### Synthesis of (L79253)-III-(A′1)(B41)(B3)

A solution of 3-([1,1′:3′,1″-Terphenyl]-2′-yl-2,2″,3,3″,4,4″,5,5″,6,6″-d₁₀)-1-(3-((9-(4-(tert-butyl)pyridin-2-yl)-9H-[3,9′-bicarbazol]-7-yl)oxy)phenyl)-1H-benzo[d]imidazol-3-ium chloride (9.18 g, 9.68 mmol, 1.0 equiv) in an organic solvent (200 mL) was sparged with nitrogen for ten minutes in the absence of light at room temperature. The solution was treated with a base (3.33 equiv) and sparged with nitrogen for 15 minutes at room temperature. The reaction was treated with a platinum precursor (1.01 equiv), sparged with nitrogen for five minutes, then heated at 110° C. for 32 hours. The reaction was cooled to room temperature and concentrated under reduced pressure. The residue was absorbed onto celite and purified by column chromatography, eluting with 55% dichloromethane in hexanes. The product was triturated in methanol (230 mL) at 26° C. for 70 minutes, filtered and washed with methanol (100 mL) to give product as a yellow solid (41% yield).

### Synthesis of (L79221)-III-(A′6)(B34)(B3)

### Synthesis of (L79221)-III-(A′6)(B34)(B3)

A solution of 7′-(3-(1H-benzo[d]imidazol-1-yl)phenoxy)-9′-(4-(tert-butyl)pyridin-2-yl)-9-phenyl-9H,9′H-1,3′-bicarbazole (3.00 g, 3.35 mmol, 1.00 equiv) and silver(I) oxide (390 mg, 1.7 mmol, 0.50 equiv) in 1,2-dichloroethane (120 mL) was sparged with nitrogen for 20 minutes then stirred at room temperature for 3 days in the absence of light. The mixture was concentrated under reduced pressure. 1,2-Dichlorobenzene (120 mL) and dichloro(1,5-cyclooctadiene) platinum(II) (1.25 g, 3.35 mmol, 1.00 equiv) were added and the suspension was sparged with nitrogen for 20 minutes. The mixture was stirred at reflux for 26 hours in the absence of light. After cooling to room temperature, the solvent was removed under reduced pressure. The residue was absorbed onto Celite and purified by column chromatography, eluting with 50% dichloromethane in hexanes. Product fractions were triturated in methanol (80 mL) at room temperature for 3 hours, then filtered to give product as a yellow solid (57% yield).

### Synthesis of (L79221)-III-(A′1)(B41)(B3)

### Synthesis of (L79221)-III-(A′1)(B41)(B3)

7-(3-(1H-benzo[d]imidazol-1-yl)phenoxy)-9-(4-(tert-butyl)pyridin-2-yl)-9H-3,9′-bicarbazole (2.5 g, 3.05 mmol, 1.0 equiv) was stirred in 1,2-dichloroethane (120 mL) at room temperature until completely dissolved. Silver(I) oxide (0.352 g, 1.52 mmol, 0.5 equiv) was added and the mixture was stirred in the dark overnight. The mixture was concentrated under reduced pressure and the residue was dissolved in 1,2-dichlorobenzene (120 mL). The solution was sparged with nitrogen for 5 minutes and dichloro(1,5-cyclooctadiene)platinum(II) (1.14 g, 3.05 mmol, 1.0 equiv) was added. The mixture was heated at vigorous reflux overnight at which point L_{C}/MS analysis indicated that the reaction was complete. The mixture was cooled to room temperature and concentrated under reduced pressure. The crude material was dry loaded on Celite and purified by column chromatography, eluting with 60% dichloromethane in hexanes to give a yellow solid. The purified compound was triturated with methanol (100 mL) and dried under vacuum at 50° C. for 18 hours to give product as a yellow solid (37% yield).

### Synthesis of 3-Bromo-2-methoxy-9H-carbazole

A solution of 2-methoxy-9H-carbazole (20.1 g, 102 mmol, 1.00 equiv) and N-bromosuccinimide (18.1 g, 102 mmol, 1.00 equiv) in dichloromethane (1 L) was stirred at room temperature for 18 h. The reaction mixture was washed with saturated aqueous ammonium chloride solution (2×800 mL) and saturated brine (800 mL), dried over sodium sulfate and concentrated under reduced pressure. The crude product was absorbed onto Celite and purified by column chromatography, eluting with a gradient from 0 to 50% ethyl acetate in heptanes to give product as a white solid (88% yield).

### Synthesis of 3-Bromo-9-(4-tert-butyl)pyridin-2-yl)-2-methoxy-9H-carbazole

A mixture of 3-Bromo-2-methoxy-9H-carbazole (25.1 g, 91.0 mmol, 1.00 equiv) and 2-bromo-4-(tert-butyl)pyridine (20.4 g, 95.3 mmol, 1.05 equiv) in toluene (500 mL) was sparged with nitrogen for five minutes. 1-Methyl-N-imidazole (7.25 mL, 7.46 g, 91.0 mmol, 1.00 equiv), lithium tert-butoxide (15.3 g, 191 mmol, 2.1 equiv), and copper(I) iodide (6.97 g, 37.0 mmol, 0.40 equiv) were added and the mixture was sparged with nitrogen for five minutes, then heated at reflux for 18 hours. The reaction mixture was cooled to room temperature, partitioned between ethyl acetate (300 mL) and 28-30% aqueous ammonium hydroxide (200 mL), and the layers were separated. The organic layer was washed with 28-30% aqueous ammonium hydroxide (3×200 mL). The aqueous layer was extracted with ethyl acetate (700 mL). The combined organic layers were washed with saturated brine (500 mL), dried over sodium sulfate, and concentrated under reduced pressure. The residue was absorbed onto celite and purified by column chromatography, eluting with a gradient from 0 to 10% ethyl acetate in heptanes to give a 2:1 mixture of 3-Bromo-9-(4-tert-butyl)pyridin-2-yl)-2-methoxy-9H-carbazole and 3-Iodo-9-(4-tert-butyl)pyridin-2-yl)-2-methoxy-9H-carbazole as a yellow and white heterogeneous solid (75% yield).

### Synthesis of N-(9-(4-(tert-Butyl)pyridin-2-yl)-2-methoxy-9H-carbazol-3-yl)acetamide

A mixture of 3-Bromo-9-(4-tert-butyl)pyridin-2-yl)-2-methoxy-9H-carbazole and 3-Iodo-9-(4-tert-butyl)pyridin-2-yl)-2-methoxy-9H-carbazole (31.5 g, 72.8 mmol, 1.00 equiv) in toluene (750 mL) was sparged with nitrogen for 30 minutes while acetamide (22.8 g, 386 mmol, 5.02 equiv), potassium carbonate (22.6 g, 164 mmol, 2.25 equiv), 1,2-diaminocyclohexane (9.25 mL, 8.80 g, 77.0 mmol, 1.06 equiv), and copper(I) iodide (3.60 g, 18.9 mmol, 0.26 equiv) were added. The mixture was sparged with nitrogen for five minutes and heated to 111° C. for four days. The reaction mixture was cooled to room temperature, treated with water (500 mL), then filtered through celite (160 g) rinsing with ethyl acetate (1.5 L) and water (500 mL). The layers of the biphasic filtrate were separated and the aqueous layer was extracted with ethyl acetate (500 mL). The combined organic layers were washed with 10% aqueous ammonium hydroxide (2×300 mL), water (500 mL), and saturated brine (500 mL), dried over sodium sulfate and concentrated under reduced pressure. The crude product was absorbed onto Celite and purified by column chromatography, eluting with a gradient from 20 to 100% ethyl acetate in heptanes to give product as an off-white solid (83% yield).

### Synthesis of 9-(4-(tert-Butyl)pyridin-2-yl)-2-methoxy-9H-carbazol-3-amine

A solution of N-(9-(4-(tert-Butyl)pyridin-2-yl)-2-methoxy-9H-carbazol-3-yl)acetamide (25.6 g, 66.1 mmol, 1.00 equiv) in 2-propanol (600 mL) was treated with a solution of potassium hydroxide (157 g, 2.80 mol, 42 equiv) in water (75 mL) at 80° C. for 22 hours. The mixture was cooled to room temperature and the layers were separated. The organic layer was concentrated to a minimum volume under reduced pressure. The aqueous layer was extracted with ethyl acetate (500 mL). The combined organics were washed with saturated brine (400 mL), dried over sodium sulfate, and concentrated under reduced pressure to give a black foam (23.5 g). The residue was absorbed onto Celite and purified by column chromatography, eluting with a gradient from 10 to 25% ethyl acetate in heptanes to give product as a brown solid (83% yield).

### Synthesis of 9-(4-(tert-Butyl)pyridin-2-yl)-2-methoxy-9H-carbazol-3-amine

A mixture of 9-(4-(tert-Butyl)pyridin-2-yl)-2-methoxy-9H-carbazol-3-amine (20.0 g, 57.9 mmol, 1.00 equiv) and 2,2′-dibromo-1,1′-biphenyl (19.9 g, 63.8, 1.10 equiv) in xylenes (1.1 L) was sparged with nitrogen for 20 minutes at room temperature. The mixture was treated with sodium tert-butoxide (11.8 g, 123 mmol, 2.10 equiv) and sparged with nitrogen for another 20 minutes while heating to 90° C. Separately, a mixture of tris(dibenzylideneacetone)dipalladium(0) (3.18 g, 3.47 mmol, 0.06 equiv) and dicyclohexyl(2′,6′-dimethoxy-[1,1′-biphenyl]-2-yl)phosphane (SPhos, 2.87 g, 6.99 mmol, 0.12 equiv) in xylenes (100 mL) was sparged with nitrogen for 30 minutes while heating to 90° C. The catalyst mixture (at 90° C.) was poured directly into the reagent mixture (at 90° C.), which was sparged with nitrogen for another 10 minutes, then heated at 111° C. for 18 hours. The mixture was cooled to room temperature and diluted with water (1 L) with vigorous stirring. The biphasic mixture was filtered through celite (100 g) washing with ethyl acetate (1 L). The layers of the filtrate were separated. The organic layer was washed with saturated brine (1 L), dried over sodium sulfate, and concentrated under reduced pressure to give a brown oil. The residue was absorbed onto Celite and purified by column chromatography, eluting with a gradient of 0 to 25% ethyl acetate in heptanes to give product as a red oil (92% yield).

### Synthesis of 9-(4-(tert-Butyl)pyridin-2-yl)-9H-[3,9′-bicarbazol]-2-ol

A solution of 9-(4-(tert-Butyl)pyridin-2-yl)-2-methoxy-9H-carbazol-3-amine (27 g, 55 mmol, 1.00 equiv) and sodium ethanethiolate (13.8 g, 163 mmol, 3.0 equiv) in N-methyl-2-pyrrolidinone (400 mL) was heated at 130° C. for 18 hours. The reaction mixture was cooled to room temperature and diluted with saturated aqueous ammonium chloride (400 mL) and ethyl acetate (250 mL). The layers were separated and the aqueous layer was extracted with ethyl acetate (250 mL). The combined organic layers were washed with saturated aqueous sodium bicarbonate (2×250 mL) and saturated brine (500 mL), dried over sodium sulfate and concentrated under reduced pressure. The crude product was absorbed onto Celite and purified by column chromatography, eluting with a gradient of 0 to 20% ethyl acetate in heptanes to give product as a light brown solid (92% yield).

### Synthesis of 2-(3-Bromophenoxy)-9-(4-(tert-butyl)pyridin-2-yl)-9H-3,9′-bicarbazole

A mixture of 9-(4-(tert-Butyl)pyridin-2-yl)-9H-[3,9′-bicarbazol]-2-ol (24.9 g, 51.7 mmol, 1.00 equiv) and 1,3-dibromobenzene (24.0 g, 102 mmol, 1.97 equiv) in dimethyl sulfoxide (300 mL) was sparged with nitrogen for 30 minutes while picolinic acid (0.75 g, 6.1 mmol, 0.12 equiv), tribasic potassium phosphate (22.7 g, 107 mmol, 2.07 equiv), and copper(I) iodide (0.58 g, 3.1 mmol, 0.06 equiv) were added. The mixture was heated at 120° C. for 47 hours. The reaction mixture was cooled to room temperature and diluted with methyl tert-butyl ether (250 mL) and 10% aqueous ammonium hydroxide (250 mL). The layers were separated and the organic layer was washed with 10% aqueous ammonium hydroxide (2×250 mL). The combined aqueous layers were extracted with methyl tert-butyl ether (250 mL). The combined organic layers were washed with saturated brine (500 mL), dried over sodium sulfate, and concentrated under reduced pressure to give a black oil. The residue was absorbed onto Celite and purified by column chromatography system, eluting with a gradient from 5 to 50% dichloromethane in heptanes to give product as a dull yellow solid (49% yield).

### Synthesis of N1-([1,1′:3′,1″-Terphenyl]-2′-yl-2,2″,3,3″,4,4″,5,5″,6,6″-d₁₀)-N2-(3-((9-(4-(tert-Butyl)pyridin-2-yl)-9H-[3,9′-bicarbazol]-2-yl)oxy)phenyl)benzene-1,2-diamine (DSC-2020-698-1)

A mixture of N1-([1,1′:3′,1″-terphenyl]-2′-yl-2,2″,3,3″,4,4″,5,5″,6,6″-d₁₀)benzene-1,2-diamine (0.286 g, 0.825 mmol, 1.05 equiv), 2-(3-Bromophenoxy)-9-(4-(tert-butyl)pyridin-2-yl)-9H-3,9′-bicarbazole (0.5 g, 0.785 mmol, 1.0 equiv) and sodium tert-butoxide (0.266 g, 2.356 mmol, 3 equiv) in toluene (8 mL) was sparged with nitrogen for 15 minutes. A mixture of tris(dibenzylideneacetone)dipalladium(0) (29 mg, 0.031 mmol, 0.04 equiv) and BINAP (39 mg, 0.063 mmol, 0.08 equiv) in toluene (1 mL) was sparged with nitrogen for 15 minutes and transferred by syringe to the first mixture. After refluxing for 18 hours, the reaction mixture was cooled to room temperature and concentrated under reduced pressure. The crude material was absorbed onto Celite and purified by column, eluting with a gradient of 10 to 30% ethyl acetate in hexanes to give product as a white solid (71% yield).

### Synthesis of 2-(3-(1-([1,1′:3′,1″-Terphenyl]-2′-yl-2,2″,3,3″,4,4″,5,5″,6,6″-d₁₀)-1H-3λ⁴-Benzo[d]imidazol-3-yl)phenoxy)-9-(4-(tert-butyl)pyridin-2-yl)-9H-3,9′-bicarbazole

A mixture of N1-([1,1′:3′,1″-Terphenyl]-2′-yl-2,2″,3,3″,4,4″,5,5″,6,6″-d₁₀)-N2-(3-((9-(4-(tert-Butyl)pyridin-2-yl)-9H-[3,9′-bicarbazol]-2-yl)oxy)phenyl)benzene-1,2-diamine (5.0 g, 5.54 mmol, 1 equiv) and 35% deuterium chloride in deuterium oxide (0.9 mL, 22.17 mmol, 4 equiv) in triethylorthoformate (37 mL) was refluxed for 18 hours. The reaction mixture was cooled to room temperature and concentrated under reduced pressure. The crude material was absorbed onto Celite and purified by column chromatography, eluting with a gradient of 0 to 10% methanol in dichloromethane to give product (65% yield).

### Synthesis of (L79253)-VI-(A′1)B41)(B3)

A suspension of 2-(3-(1-([1,1′:3′,1″-Terphenyl]-2′-yl-2,2″,3,3″,4,4″,5,5″,6,6″-d₁₀)-1H-3λ⁴-Benzo[d]imidazol-3-yl)phenoxy)-9-(4-(tert-butyl)pyridin-2-yl)-9H-3,9′-bicarbazole (0.1 g, 0.11 mmol, 1.0 equiv) and a platinum precursor (59 mg, 0.142 mmol, 1.3 equiv) in an organic solvent (3 mL) in a pressure tube was sparged with nitrogen for 15 minutes. Abase (47 mg, 0.438 mmol, 4.0 equiv) was added to the reaction mixture in one portion. The reaction mixture was heated at 130° C. for 16 hours. The reaction mixture was cooled to room temperature and concentrated under reduced pressure. The residue was dissolved in dichloromethane (20 mL), absorbed onto Celite and purified by column chromatography, eluting with 50% dichloromethane in hexanes. Product was concentrated under reduced pressure and dried in a vacuum oven at 50° C. for 18 hours as a pale yellow solid (40% yield).

Formula I and Formula II of the present disclosure are believed to result in narrow blue emission, and can be used in OLED devices for narrow and deep blue color. Table 1 below shows some of the photoluminescent properties of some representative compounds of the present disclosure. It can be seen that these compounds have a peak wavelength of less than 460 nm and a full width half maximum (FWHM) of less than 21 nm. Emission spectrum were acquired using a Hamamatsu Quantaurus-QY Plus UV-NIR absolute PL quantum yield spectrometer with an excitation wavelength of 340 nm on films of the Compound in polymethyl methacrylate (PMMA). Films were made by creating solutions of less than 1% emitter with PMMA in toluene which were prepared, filtered, and dropcast onto Quartz substrates.

TABLE 1

| | | Peak | |
|---|---|---|---|
| | | Wavelength | FWHM |
| Compound | Structure | (nm) | (nm) |
| (L79253)-III- (A′3)(B1)(B3) | 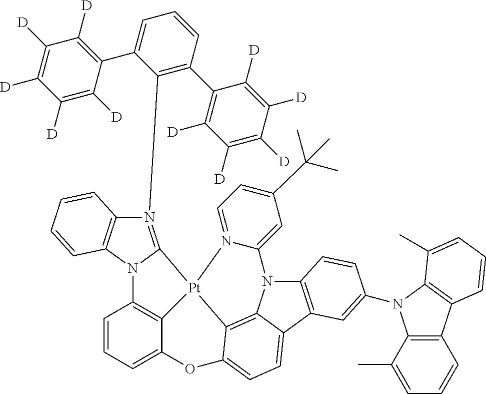 | 456 | 15 |
| (L79253)-III- (A′4)(B34)(B3) | 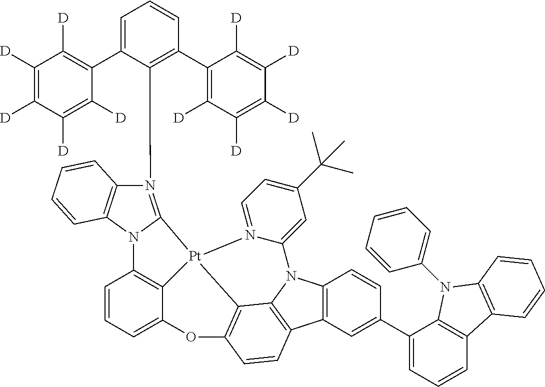 | 456 | 16 |
| (L79253)-III- (A′6)(B34)(B3) | 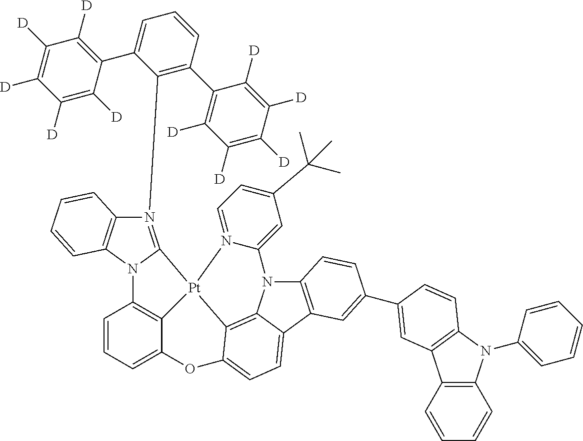 | 457 | 17 |
| (L79253)-III- (A′1)(B41)(B3) | 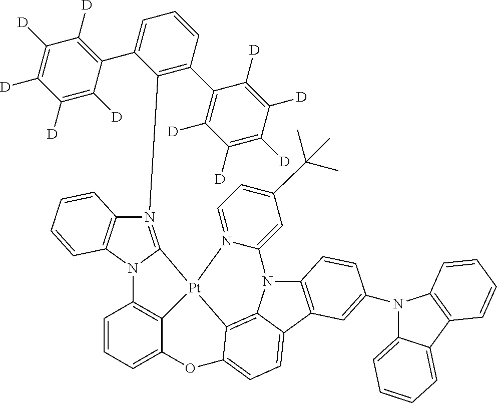 | 456 | 14 |
| (L79221)-III- (A′6)(B34)(B3) | 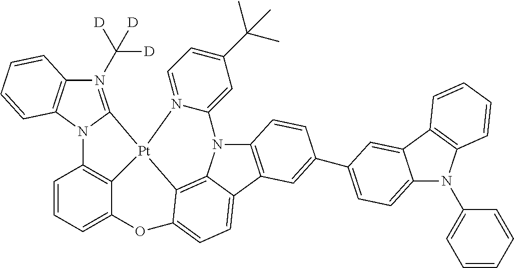 | 453 | 20 |
| (L79221)-III- (A′1)(B41)(B3) | 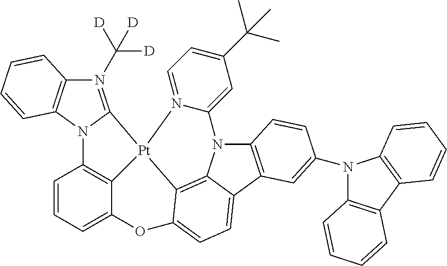 | 452 | 15 |
| (L79253)-VI- (A′1)(B41)(B3) | 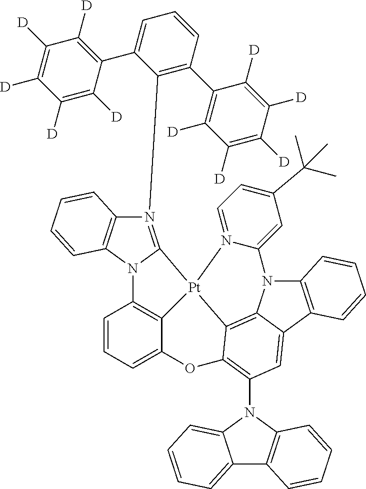 | 452 | 16 |

OLEDs were made with several representative compounds and were found to be narrow with FWHMs under 30 nm. Further, the OLED devices reached deep blue color with 1931 CIE y less than 0.160. In general, the FWHM for a conversional phosphorescent emitter complex is above 60 nm. It has been a long-sought goal to achieve the small FWHM. The smaller FWHM, the better color purity for the display application. As a background information, the ideal line shape is a single wavelength (single line). As can be seen here, the current inventive compounds can cut more than half of the FWHM number from the conversional phosphorescent emitters. In the past of the OLED research, narrowing emission lineshape has been achieved nanometer by nanometer, the large decrease of the FWHM obtained from these inventive compounds is a remarkably unexpected result.

The OLEDs were grown on a glass substrate pre-coated with an indium-tin-oxide (ITO) layer having a sheet resistance of 1542/sq. Prior to any organic layer deposition or coating, the substrate was degreased with solvents and then treated with an oxygen plasma for 1.5 minutes with 50 W at 100 mTorr and with UV ozone for 5 minutes.

The devices in Tables 2 were fabricated in high vacuum (<10-6 Torr) by thermal evaporation. The anode electrode was 750 Å of indium tin oxide (ITO). The device example had organic layers consisting of, sequentially, from the ITO surface, 100 Å of Compound 1 (HIL), 250 Å of Compound 2 (HTL), 50 Å of Compound 3 (EBL), 300 Å of Compound 4 doped with 20% of Compound 4 and 5% of Compound 3 and 10% of Emitter 1 (EML), 50 Å of Compound 5 (BL), 300 Å of Compound 6 doped with 35% of Compound 7 (ETL), 10 Å of Compound 6 (EIL) followed by 1,000 Å of A1 (Cathode). All devices were encapsulated with a glass lid sealed with an epoxy resin in a nitrogen glove box (<1 ppm of H₂O and O₂,) immediately after fabrication with a moisture getter incorporated inside the package. Doping percentages are in volume percent.

| | | | at 10 mA/cm² | | | | At 20 mA/cm² |
|---|---|---|---|---|---|---|---|
| | 1931 CIE | | λ max | FWHM | Voltage | EQE | LT_{90%} |
| | x | y | [nm] | [nm] | [norm] | [norm] | [norm] |
| (L79221)-III-(A′1)(B41)(B3) | 0.141 | 0.155 | 459 | 26 | 1.00 | 1.00 | 1.00 |
| (L79253)-III-(A′3)(B1)(B3) | 0.131 | 0.143 | 461 | 19 | 0.98 | 1.04 | 1.13 |
| (L79253)-III-(A′1)(B41)(B3) | 0.132 | 0.143 | 462 | 20 | 0.95 | 1.13 | 3.07 |

Compounds utilized in making OLED devices are the following:

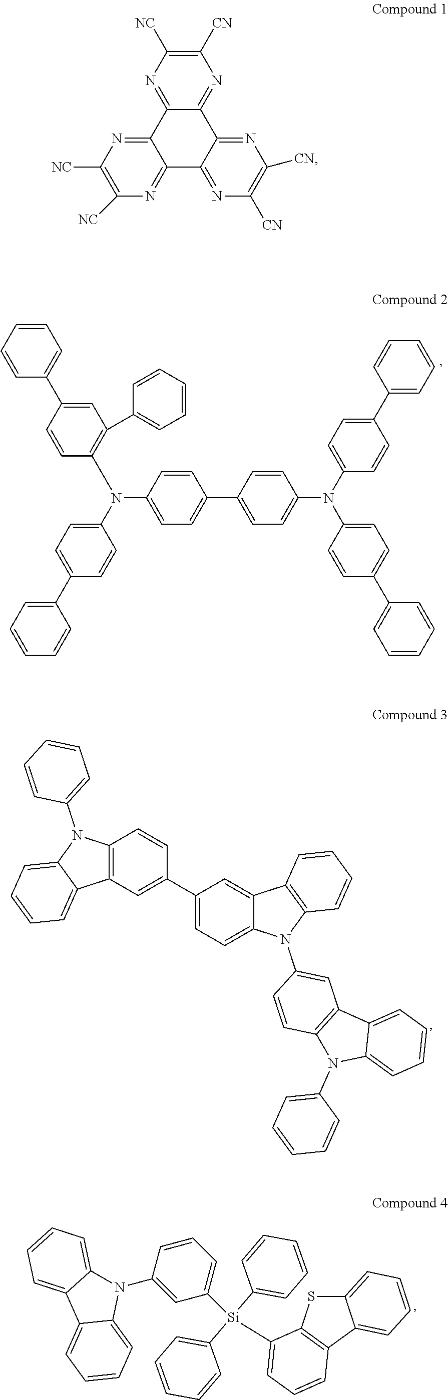 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5-c5ccccc5)cc4)cc3)cc2)cc1 ; c1ccc(-n2c3ccccc3c3cc(-c4ccc5c(c4)c4ccccc4n5-c4ccc5c(c4)c4ccccc4n5-c4ccccc4)ccc32)cc1 ; c1ccc([Si](c2ccccc2)(c2cccc(-n3c4ccccc4c4ccccc43)c2)c2cccc3c2sc2ccccc23)cc1]

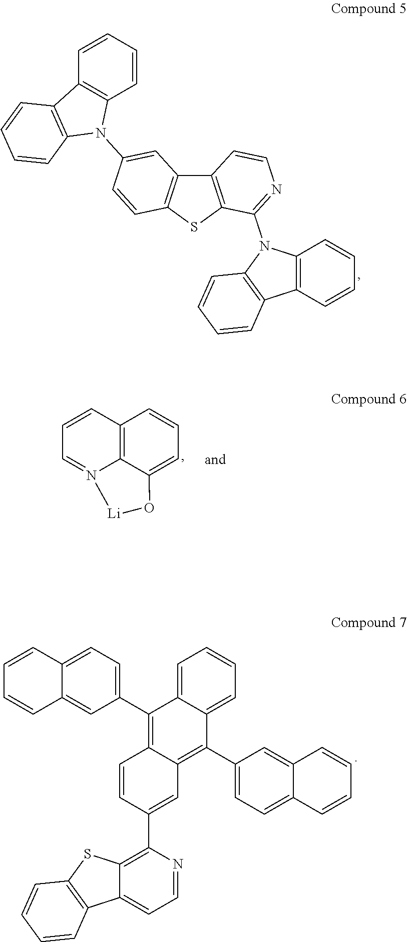

What is claimed is:

1. A compound having a structure of Formula VI 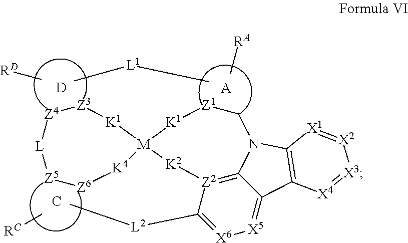
wherein:
rings A, C, and D are each independently a 5-membered or 6-membered carbocyclic or heterocyclic ring;
ring D is not pyrazole;
each of X¹—X⁶ is independently N or CR;
Z¹, Z², Z³, Z⁴, Z⁵, and Z⁶ are each independently C or N;
one of Z¹ and Z² is C and the other is N;
each of K¹, K², K³ or K⁴ is independently a direct bond, S, or O, with at least two of them being direct bonds;
L, L¹, and L² are each independently selected from the group consisting of a direct bond, being absent, O, S, CR″R″′, SiR″R″′, BR″, and NR″, wherein at least one of L¹ and L² is present;
R^{A}, R^{C}, and R^{D} each independently represent zero, mono, or up to the maximum allowed number of substitutions to its associated ring;
at least one of R or R^{A} has a structure of 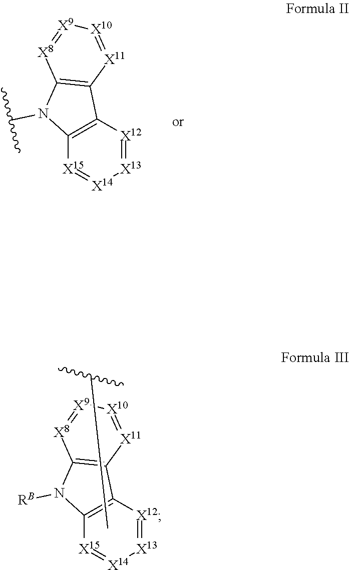
wherein: each of X⁸—X¹⁵ is independently N or CR′, the particular one of X⁸—X¹⁵ that is bonded to one of X¹—X⁶ or ring A of Formula VI is C;
the maximum number of N atoms that can connect to each other within a ring is two;
each of the remaining R and R^{A} is independently a hydrogen, Formula II, Formula III, or a substituent selected from the group consisting of deuterium, halogen, alkyl, cycloalkyl, heteroalkyl, heterocycloalkyl, arylalkyl, alkoxy, aryloxy, amino, silyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
each of R′ and R^{B} is independently a hydrogen, or a substituent selected from the group consisting of deuterium, halogen, alkyl, cycloalkyl, heteroalkyl, heterocycloalkyl, arylalkyl, alkoxy, aryloxy, amino, silyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
each of R″, R″′, R^{C}, and R^{D} is independently a hydrogen or a substituent selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, sulfanyl, and combinations thereof;
M is Pd or Pt; and
any two adjacent R, R′, R″, R″′, R^{A}, R^{B}, R^{C}, or R^{D} can be joined or fused together to form a ring where chemically feasible.

2. The compound of claim 1, wherein each of the remaining R and R^{A} is independently a hydrogen or a substituent selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, sulfanyl, and combinations thereof.

3. The compound of claim 1, wherein X¹—X⁶ are each CR, and X⁸—X¹⁵ are each independently C or CR′.

4. The compound of claim 1, wherein one of X¹—X⁶ and X⁸—X¹⁵ is N, and the remainder of X¹—X⁶ and X⁸—X¹⁵ are each CR for X¹—X⁶ and independently C or CR′ for X⁸—X¹⁵.

5. The compound of claim 1, wherein two of X¹—X⁶ and X⁸—X¹⁵ is N, and the remainder of X¹—X⁶ and X⁸—X¹⁵ are each CR for X¹—X⁶ and independently C or CR′ for X⁸—X¹⁵.

6. The compound of claim 1, wherein one of X¹—X⁶ is N, one of X⁸—X¹⁵ is N, and the remainder of X¹—X⁶ and X¹—X¹⁵ are each CR for X¹—X⁶ and independently C or CR′ for X⁸—X¹⁵.

7. The compound of claim 1, wherein Z¹ is N, and Z² is C.

8. The compound of claim 1, wherein Z¹ is C, and Z² is N.

9. The compound of claim 1, wherein ring A is a 5-membered or 6-membered aromatic ring.

10. The compound of claim 1, wherein the compound comprises Formula II, which bonds to X³; or
wherein the compound comprises Formula III in which X¹⁰ of Formula III bonds to X³.

11. The compound of claim 1, wherein ring D is imidazole and Z³ is a carbene carbon.

12. The compound of claim 1, wherein the compound is selected from the group consisting of: 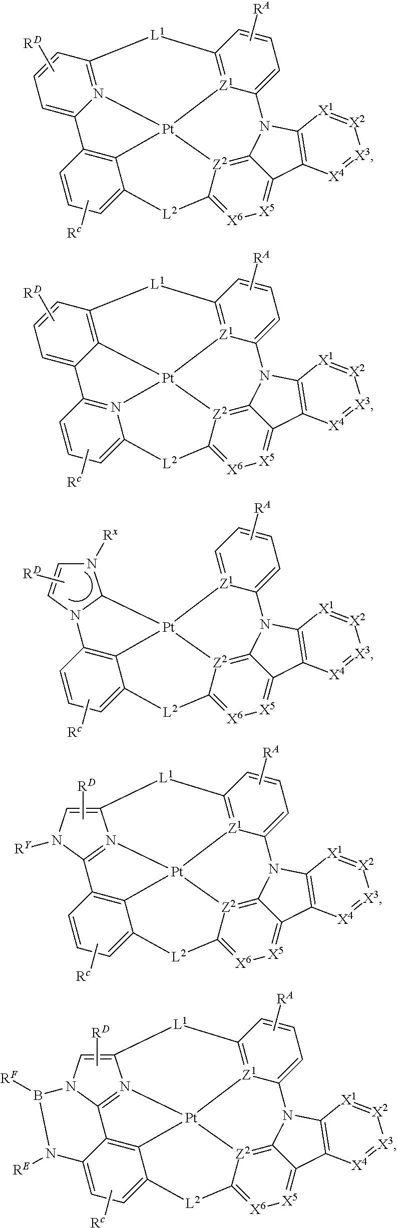 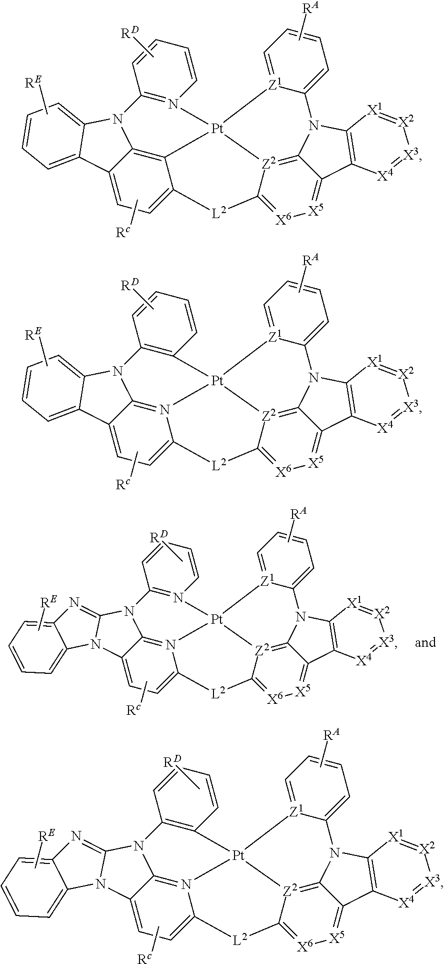
wherein:
each of X¹—X⁶ is independently N or CR;
at least one R or R^{A} has a structure of 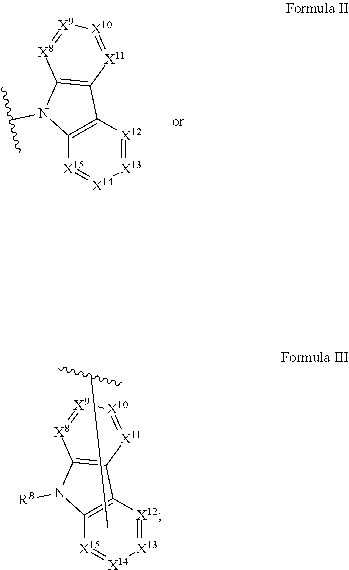
wherein: each of X⁸—X¹⁵ is independently N or CR′, the particular one of X⁸—X¹⁵ that is bonded to one of X¹—X⁷ or ring A of Formula I is C;
R^{x} and R^{y} are each independently selected from the group consisting of alkyl, cycloalkyl, heteroalkyl, heterocycloalkyl, aryl, heteroaryl, and combinations thereof; and
R^{E} for each occurrence is independently a hydrogen or a substituent selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, sulfanyl, and combinations thereof.

13. The compound of claim 1, wherein the compound is selected from the group consisting of:

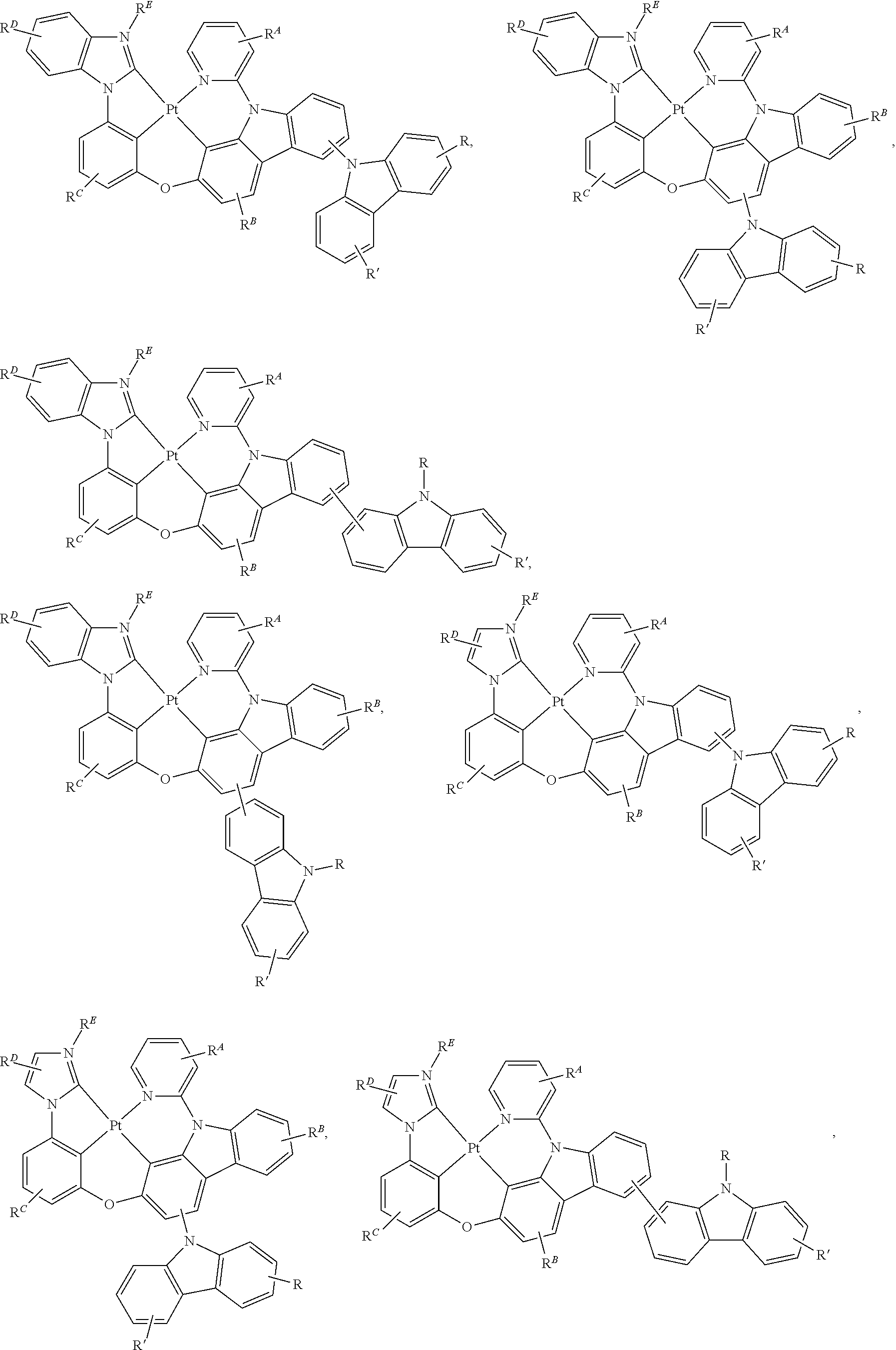

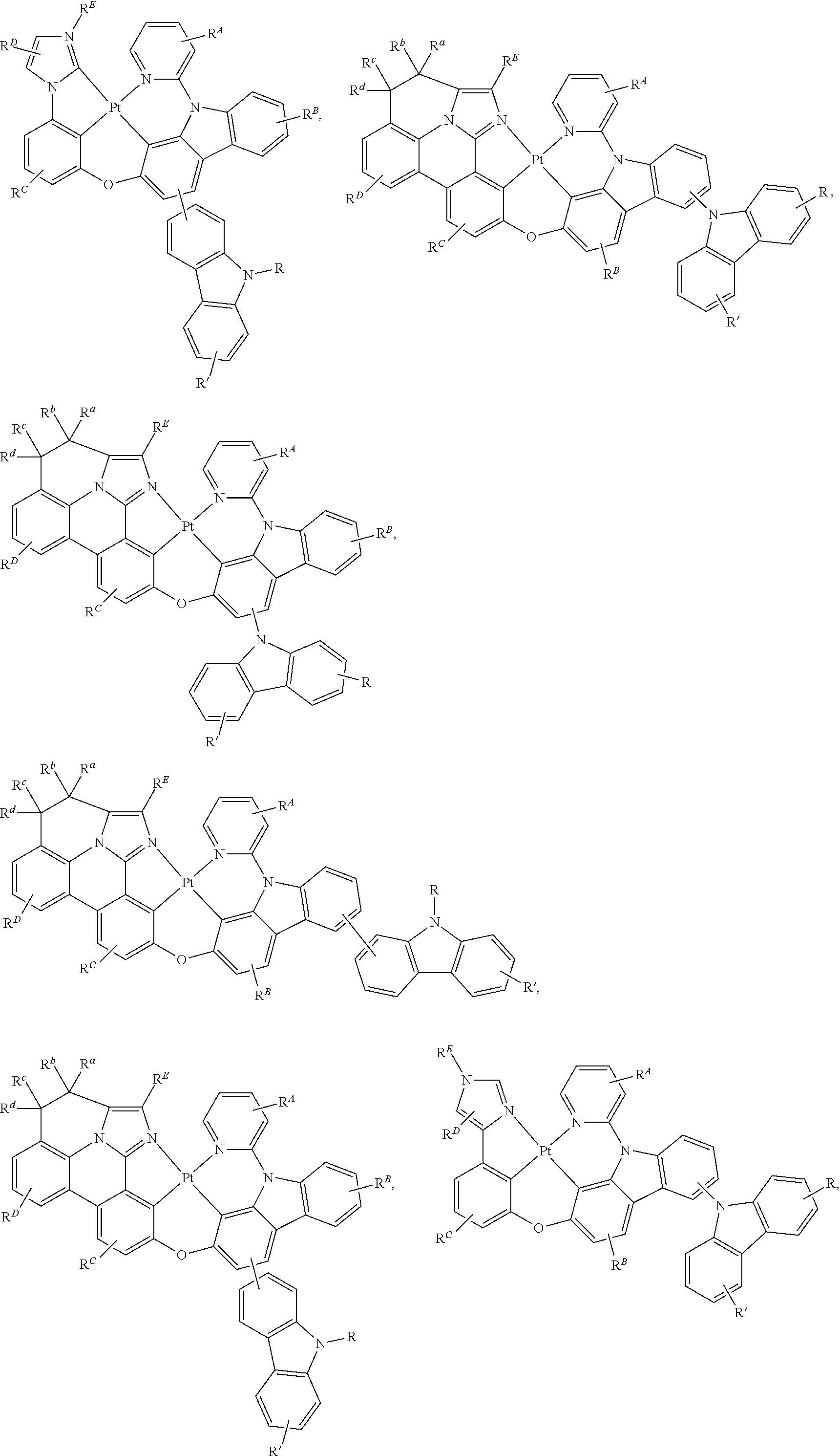

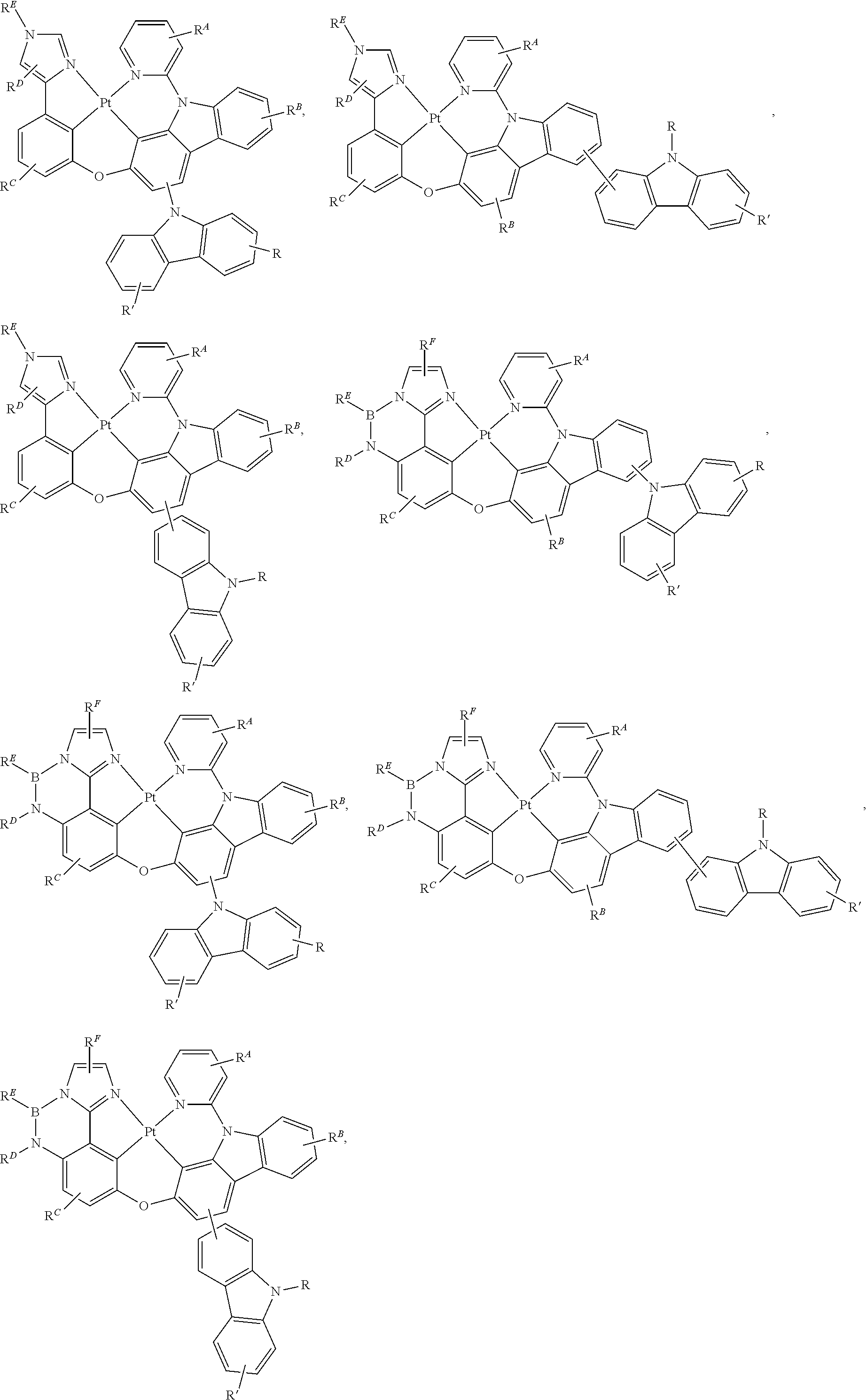

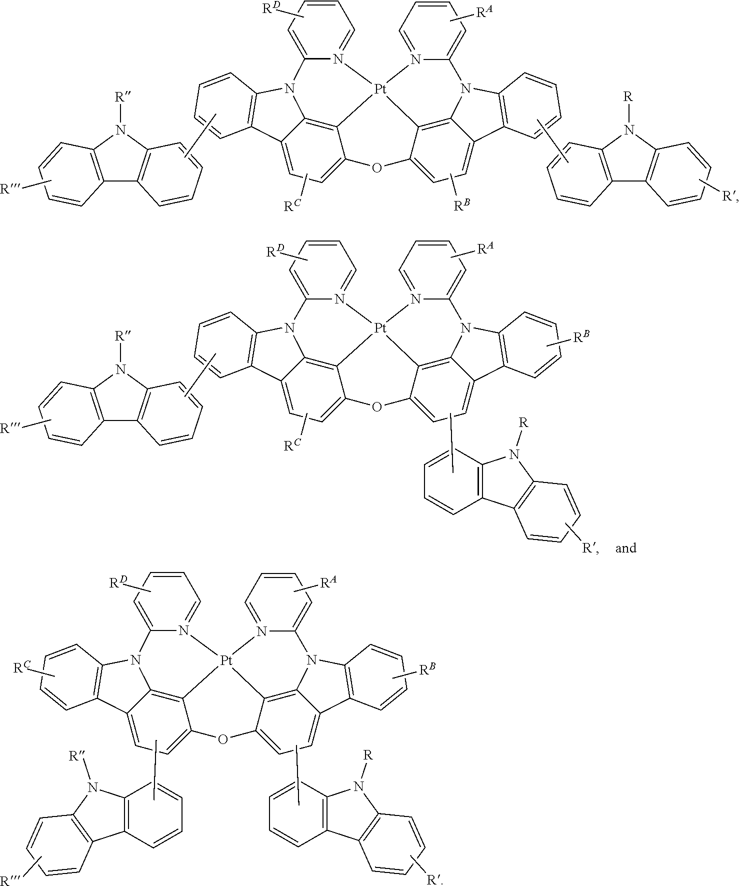

14. The compound of claim 1, wherein the compound is selected from the group consisting of Compound (l)-I-(A′i)(Bj)(Bk) to Compound (l)-XIV-(A′i)(Bj)(Bk) each Compound having the formula of Pt(L_{A})(L_{B}) with the following structure: 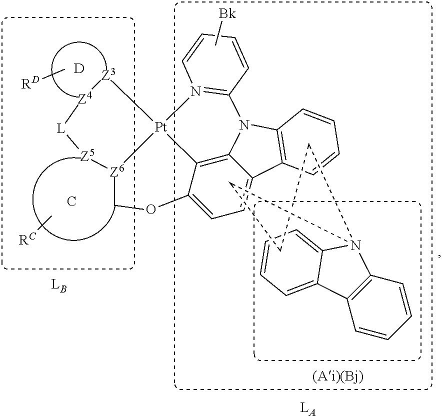
wherein L_{A} has the structure shown above and is selected from the group consisting of I-(A′i)(Bj)(Bk) to XIV-(A′i)(Bj)(Bk), wherein i is an integer from 1 to 7 and k is an integer from 1 to 47, and when i=1 to 3, j is an integer from 1 to 41, and when i=4 to 7, j is an integer from 1 to 47;
wherein L_{B} has the structure shown above and is selected from the group consisting of L1;
wherein l is an integer from 1 to 99333 and 99396 to 230107;
wherein rings C and D are as defined above for Formula VI; or
the compound can be selected from the group consisting of Compound [I-(A′i)(Bj)(Bk)][I-(A′m)(Bn)(Bo)] to Compound [XIV-(A′i)(Bj)(Bk)][XIV-(A′m)(Bn)(Bo)], each Compound having the formula of Pt(L_{A})(L_{C}) with the following structure: 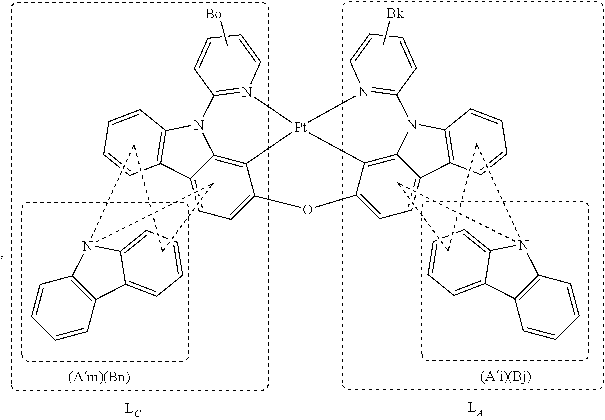
wherein L_{A} is as defined above;
wherein L_{C} has the structure shown above and is selected from the group consisting of I-(A′m)(Bn)(Bo) to XIV-(A′m)(Bn)(Bo);
wherein Ll for each occurrence independently has the structure defined in the table below:
wherein each squiggly line in each structure is independently for linking to the relevant part of L_{A}:

| Ll | Structure of Ll | Ar¹, Ar², Ar³, R¹, R² |
|---|---|---|
| for each Ll, wherein | thus defined ligands Ll to L9900 | wherein Ar¹ = Ap, and |
| l = 330(p − 1) + q, | each has a structure of | R¹ = Rq, and |
| wherein p is an integer from 1 to 30, and q is an integer from 1 to 330, | 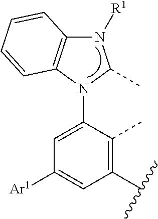 | |
| for each Ll, wherein | thus defined ligands L9901 to | wherein Ar¹ = Ap and |
| l = 330(p − 1) + q + 9900, | L19800 each has a structure of | R¹ = Rq, and |
| wherein p is an integer from 1 to 30, and q is an integer from 1 to 330, | 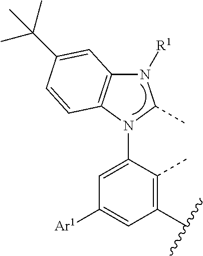 | |
| for each Ll, wherein | thus defined ligands Ll9801 to | wherein Ar¹ = Ap and |
| l = 330(p − 1) + q + 19800, | L29700 each has a structure of | R¹ = Rq, and |
| wherein p is an integer from 1 to 30, and q is an integer from 1 to 330, | 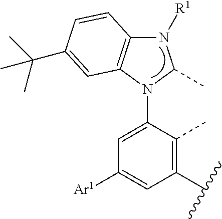 | |
| for each Ll, wherein | thus defined ligands L29701 to | wherein Ar¹ = Ap and |
| l = 330(p − 1) + q + 29700, | L39600 each has a structure of | R¹ = Rq, and |
| wherein p is an integer from 1 to 30, and q is an integer from 1 to 330, | 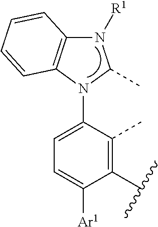 | |
| for each Ll, wherein | thus defined ligands L39601 to | wherein Ar¹ = Ap and |
| l = 330(p − 1) + q + 39600, | L49500 each has a structure of | R¹ = Rq, and |
| wherein p is an integer from 1 to 30, and q is an integer from 1 to 330, | 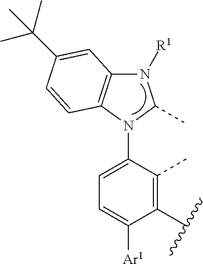 | |
| for each Ll, wherein | thus defined ligands L49501 to | wherein Ar¹ = Ap and |
| l = 330(p − 1) + q + 49500, | L59400 each has a structure of | R¹ = Rq, and |
| wherein p is an integer from 1 to 30, and q is an integer from 1 to 330, | 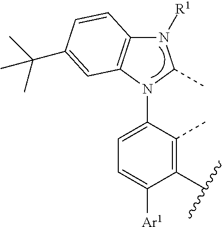 | |
| for each Ll, wherein | thus defined ligands L59401 to | wherein Ar¹ = Ap and |
| l = 330(p − 1) + q + 59400, | L69300 each has a structure of | R¹ = Rq, and |
| wherein p is an integer from 1 to 30, and q is an integer from 1 to 330, | 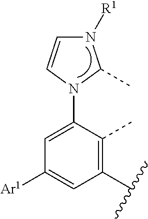 | |
| for each Ll, wherein | thus defined ligands L69301 to | wherein Ar¹ = Ap and |
| l = 330(p − 1) + q + 69300, | L79200 each has a structure of | R¹ = Rq, and |
| wherein p is an integer from 1 to 30, and q is an integer from 1 to 330, | 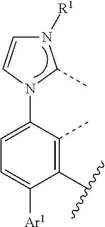 | |
| for each Ll, wherein | thus defined ligands L79201 to | wherein R¹ = Rq, and |
| l = q + 79200, wherein q is an | L79530 each has a structure of | |
| integer from 1 to 330, | 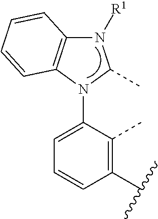 | |
| for each Ll, wherein | thus defined ligands L79531 to | wherein R¹ = Rq, and |
| 1 = q + 79530, wherein q is an | L79860 each has a structure of | |
| integer from 1 to 330, | 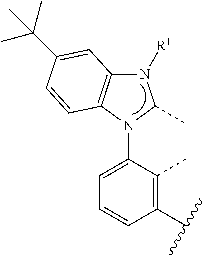 | |
| for each Ll, wherein | thus defined ligands L79861 to | wherein R¹ = Rq, and |
| l = q + 79860, wherein q is an | L80190 each has a structure of | |
| integer from 1 to 330, | 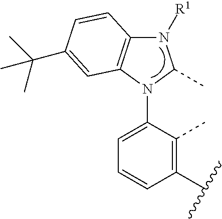 | |
| for each Ll, wherein | thus defined ligands L80191 to | wherein R¹ = Rq, and |
| l = q + 80190, wherein q is an | L80520 each has a structure of | |
| integer from 1 to 330, | 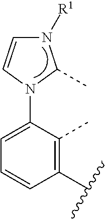 | |
| for each Ll, wherein | thus defined ligands L80521 to | wherein Ar¹ = Ap and |
| l = 330(p − 1) + q + 80520, | L81510 each has a structure of | R¹ = Rq, and |
| wherein p is an integer from 1 to 30, and q is an integer from 1 to 330, | 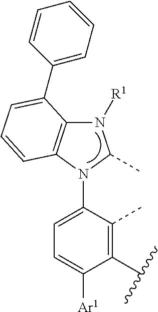 | |
| for each Ll, wherein | thus defined ligands L81511 to | wherein R¹ = Rq, and |
| l = q + 81510, wherein q is an | L82500 each has a structure of | |
| integer from 1 to 330, | 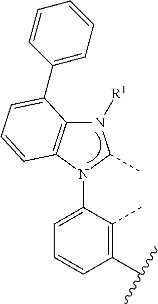 | |
| for each Ll, wherein | thus defined ligands L82501 to | wherein R¹ = Rq, and |
| l = q + 82500, wherein q is an | L82830 each has a structure of | |
| integer from 1 to 330, | 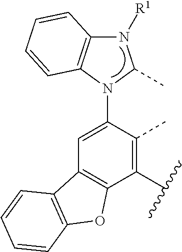 | |
| for each Ll, wherein | thus defined ligands L82831 to | wherein R¹ = Rq, and |
| l = q + 82830, wherein q is an | L83160 each has a structure of | |
| integer from 1 to 330, | 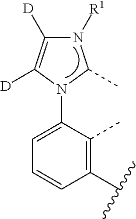 | |
| for each Ll, wherein | thus defined ligands L83161 to | wherein Ar¹ = Ap and |
| l = 330(p − 1) + q + 83160, | L84150 each has a structure of | R¹ = Rq, and |
| wherein p is an integer from 1 to 30, and q is an integer from 1 to 330, | 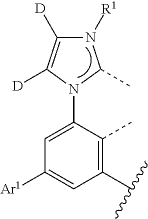 | |
| for each Ll, wherein | thus defined ligands L84151 to | wherein Ar¹ = Ap and |
| l = 330(p − 1) + q + 84150, | L85140 each has a structure of | R¹ = Rq, and |
| wherein p is an integer from 1 to 30, and q is an integer from 1 to 330, | 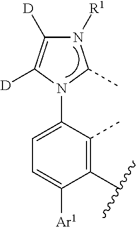 | |
| for each Ll, wherein | thus defined ligands L85141 to | wherein R¹ = Rq, and |
| l = q + 85140, wherein q is an | L85470 each has a structure of | |
| integer from 1 to 330, | 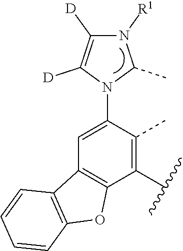 | |
| for each Ll, wherein | thus defined ligands L85471 to | wherein R¹ = Rq, and |
| l = q + 85470, wherein q is an | L85800 each has a structure of | |
| integer from 1 to 330, | 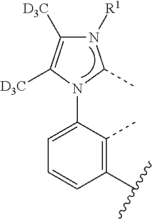 | |
| for each Ll, wherein | thus defined ligands L85801 to | wherein Ar¹ = Ap and |
| l = 330(p − 1) + q + 85800, | L86790 each has a structure of | R¹ = Rq, and |
| wherein p is an integer from 1 to 30, and q is an integer from 1 to 330, | 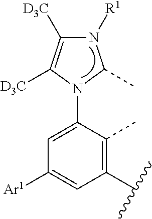 | |
| for each Ll, wherein | thus defined ligands L86791 to | wherein Ar¹ = Ap and |
| l = 330(p − 1) + q + 8679, | L87780 each has a structure of | R¹ = Rq, and |
| wherein p is an integer from 1 to 30, and q is an integer from 1 to 330, | 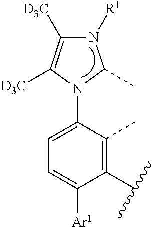 | |
| for each Ll, wherein | thus defined ligands L87781 to | wherein R¹ = Rq, and |
| l = q + 87780, wherein q is an | L88110 each has a structure of | |
| integer from 1 to 330, | 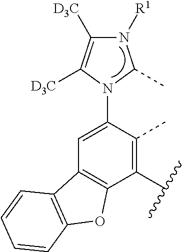 | |
| for each Ll, wherein | thus defined ligands L88111 to | wherein Ar² = Ar, and |
| l = r + 88110, wherein r is an | L88140 each has a structure of | |
| integer from 1 to 30, | 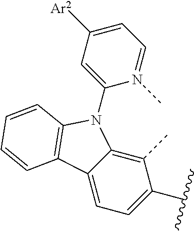 | |
| | wherein ligand L88141 | |
| | has the structure | |
| | 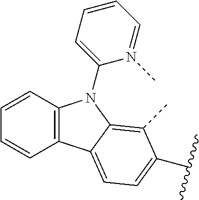 | |
| for each Ll, wherein | thus defined ligands L88142 to | wherein Ar² = Ar and |
| l = 30(r − 1) + s + 88141, | L89041 each has a structure of | Ar³ = As, and |
| wherein r is an integer from 1 to 30, and s is an integer from 1 to 30, | 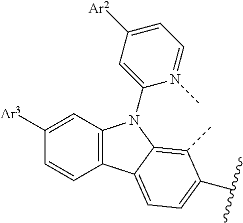 | |
| for each Ll, wherein | thus defined ligands L89042 to | wherein Ar² = Ar, and |
| l = r + 89041, wherein r is an | L89071 each has a structure of | |
| integer from 1 to 30, | 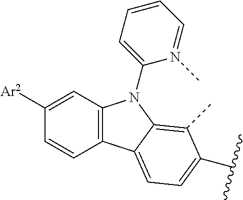 | |
| for each Ll, wherein | thus defined ligands L89072 to | wherein Ar² = Ar and |
| l = 30(r − 1) + s + 89071, | L89971 each has a structure of | Ar³ = As, and |
| wherein r is an integer from 1 to 30, and s is an integer from 1 to 30, | 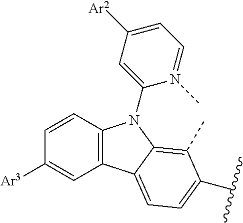 | |
| for each Ll, wherein | thus defined ligands L89972 to | wherein Ar² = Ar, and |
| l = r + 89971, wherein r is an | L90001 each has a structure of | |
| integer from 1 to 30, | 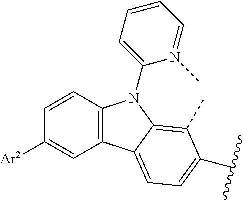 | |
| for each Ll, wherein | thus defined ligands L90002 to | wherein Ar² = Ar, and |
| l = r + 90001, wherein r is an | L90031 each has a structure of | |
| integer from 1 to 30, | 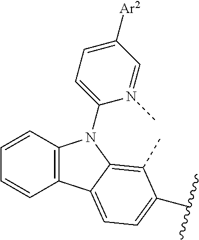 | |
| for each Ll, wherein | thus defined ligands L90032 to | wherein Ar² = Ar and |
| l = 30(r − 1) + s + 90031, | L90931 each has a structure of | Ar³ = As, and |
| wherein r is an integer from 1 to 30, and s is an integer from 1 to 30, | 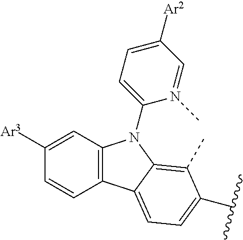 | |
| for each Ll, wherein | thus defined ligands L90932 to | wherein Ar² = Ar and |
| l = 30(r + 1) + s + 90931, | L91831 each has a structure of | Ar³ = As, and |
| wherein r is an integer from 1 to 30, and s is an integer from 1 to 30, | 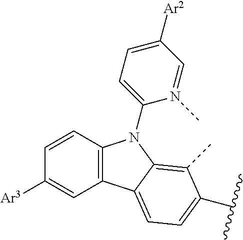 | |
| for each Ll, wherein | thus defined ligands L91832 to | wherein Ar² = Ar and |
| l = 30(r − 1) + s + 91831, | L92731 each has a structure of | Ar³ = As, and |
| wherein r is an integer from 1 to 30, and s is an integer from 1 to 30, | 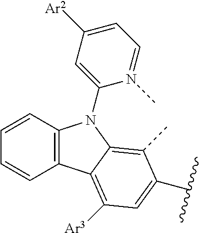 | |
| for each Ll, wherein | thus defined ligands L92732 to | wherein Ar² = Ar, and |
| l = r + 92731, wherein r is an | L92761 each has a structure of | |
| integer from 1 to 30, | 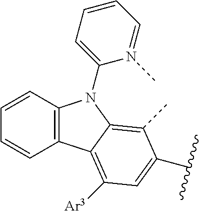 | |
| for each Ll, wherein | thus defined ligands L92762 to | wherein Ar² = Ar and |
| l = 30(r − 1) + s + 92761, | L93661 each has a structure of | Ar³ = As, and |
| wherein r is an integer from 1 to 30, and s is an integer from 1 to 30, | 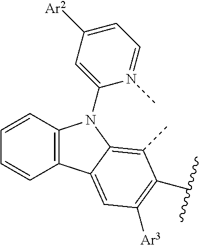 | |
| for each Ll, wherein | thus defined ligands L93662 to | wherein Ar² = Ar, and |
| l = r + 93661, wherein r is an | L93691 each has a structure of | |
| integer from 1 to 30, | 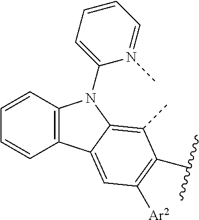 | |
| for each Ll, wherein | thus defined ligands L93692 to | wherein Ar² = Ar and |
| l = 30(r − 1) + s + 93691, | L94591 each has a structure of | Ar³ = As, and |
| wherein r is an integer from 1 to 30, and s is an integer from 1 to 30, | 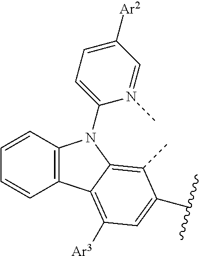 | |
| for each Ll, wherein | thus defined ligands L94592 to | wherein Ar² = Ar and |
| l = 30(r − 1) + s + 94591, | L95491 each has a structure of | Ar³ = As, and |
| wherein r is an integer from 1 to 30, and s is an integer from 1 to 30, | 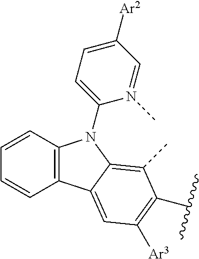 | |
| | ligand L95492 has the structure of | |
| | 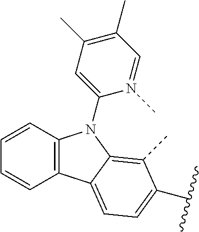 | |
| for each Ll, wherein | thus defined ligands L95493 to | wherein Ar² = Ar, and |
| l = r + 95492, wherein r is an | L95522 each has a structure of | |
| integer from 1 to 30, | 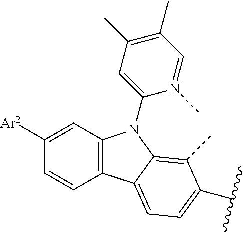 | |
| for each Ll, wherein | thus defined ligands L95523 to | wherein Ar² = Ar, and |
| l = r + 95522, wherein r is an | L95552 each has a structure of | |
| integer from 1 to 30, | 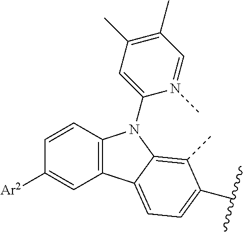 | |
| for each Ll, wherein | thus defined ligands L95553 to | wherein Ar² = Ar, and |
| l = r + 95552, wherein r is an | L95582 each has a structure of | |
| integer from 1 to 30, | 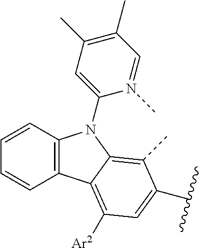 | |
| for each Ll, wherein | thus defined ligands L95583 to | wherein Ar² = Ar, and |
| l = r + 95582, wherein r is an | L95612 each has a structure of | |
| integer from 1 to 30, | 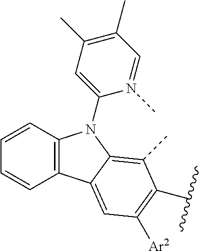 | |
| | ligand L95613 has the structure of | |
| | 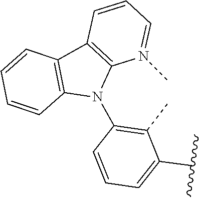 | |
| for each Ll, wherein | thus defined ligands L95614 to | wherein Ar¹ = Ar, and |
| l = r + 95613, wherein r is an | L95643 each has a structure of | |
| integer from 1 to 30, | 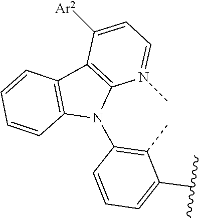 | |
| for each Ll, wherein | thus defined ligands L95644 to | wherein Ar² = Ar and |
| l = 30(r − 1) + s + 95643, | L96543 each has a structure of | Ar³ = As, and |
| wherein r is an integer from 1 to 30, and s is an integer from 1 to 30, | 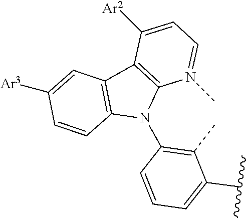 | |
| for each Ll, wherein | thus defined ligands L96544 to | wherein Ar² = Ar, and |
| l = r +30 96543, wherein r is an | L96573 each has a structure of | |
| integer from 1 to 30, | 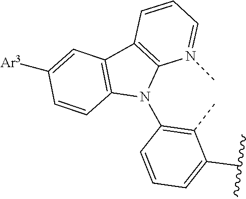 | |
| for each Ll, wherein | thus defined ligands L96574 to | wherein Ar² = Ar and |
| l = 30(r − 1) + s + 96573, | L97473 each has a structure of | Ar³ = As, and |
| wherein r is an integer from 1 to 30, and s is an integer from 1 to 30, | 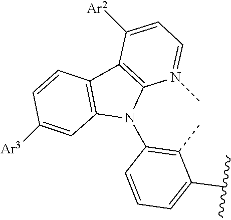 | |
| for each Ll, wherein | thus defined ligands L97474 to | wherein Ar² = Ar, and |
| l = r + 97473, wherein r is an | L97503 each has a structure of | |
| integer from 1 to 30, | 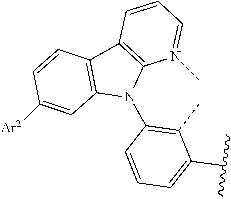 | |
| for each Ll, wherein | thus defined ligands L97504 to | wherein Ar² = Ar, and |
| l = r + 97503, wherein r is an | L97533 each has a structure of | |
| integer from 1 to 30, | 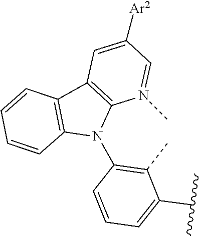 | |
| for each Ll, wherein | thus defined ligands L97534 to | wherein Ar² = Ar and |
| l = 30(r − 1) + s + 97533, | L98433 each has a structure of | Ar³ = As, and |
| wherein r is an integer from 1 to 30, and s is an integer from 1 to 30, | 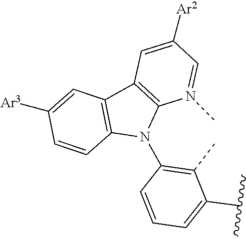 | |
| for each Ll, wherein | thus defined ligands L98434 to | wherein Ar² = Ar and |
| l = 30(r − 1) + s + 98433, | L99333 each has a structure of | Ar³ = As, and |
| wherein r is an integer from 1 to 30, and s is an integer from 1 to 30, | 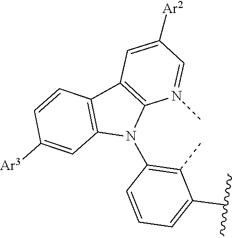 | |
| for each Ll, wherein | thus defined ligands L99396 to | wherein Ar² = Ar and |
| l = 100(r − 1) + q + 99395, | L102395 each has a structure of | R² = Rq, and |
| wherein r is an integer from 1 to 30, and q is an integer from 1 to 100, | 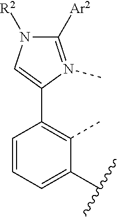 | |
| for each Ll, wherein | thus defined ligands L102396 to | wherein R² = Rq, and |
| l = q + 102395, wherein q is an | L102495 each has a structure of | |
| integer from 1 to 100, | 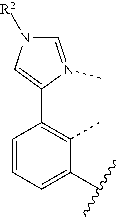 | |
| for each Ll, wherein | thus defined ligands L102496 to | wherein Ar² = Ar and |
| l = 100(r − 1) + q + 102495, | L105495 each has a structure of | R² = Rq, and |
| wherein r is an integer from 1 to 30, and q is an integer from 1 to 100, | 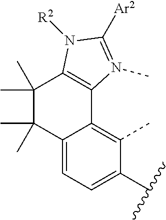 | |
| for each Ll, wherein | thus defined ligands L105496 to | wherein R² = Rq, and |
| l = q + 105495, wherein q is an | L105595 each has a structure of | |
| integer from 1 to 100, | 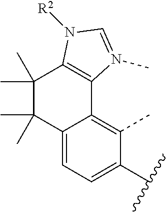 | |
| for each Ll, wherein | thus defined ligands L105596 to | wherein Ar² = Ar and |
| l = 100(r − 1) + q + 105595, | L108595 each has a structure of | R² = Rq, and |
| wherein r is an integer from 1 to 30, and q is an integer from 1 to 100, | 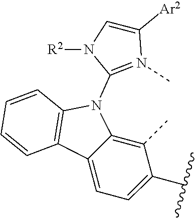 | |
| for each Ll, wherein | thus defined ligands L108596 to | wherein R² = Rq, and |
| l = q + 108595, wherein q is an | L108695 each has a structure of | |
| integer from 1 to 100, | 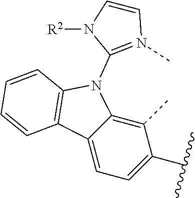 | |
| for each Ll, wherein | thus defined ligands L108696 to | wherein Ar² = Ar and |
| l = 100(r − 1) + q + 111695, | L111695 each has a structure of | R² = Rq, and |
| wherein r is an integer from 1 to 30, and q is an integer from 1 to 100, | 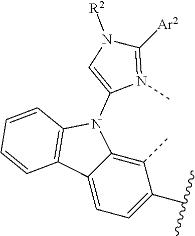 | |
| for each Ll, wherein | thus defined ligands L111696 to | wherein R² = Rq, and |
| l = q + 111795, wherein q is an | L111795 each has a structure of | |
| integer from 1 to 100, | 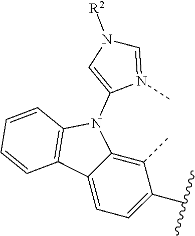 | |
| for each Ll, wherein | thus defined ligands L111796 to | wherein Ar² = Ar and |
| l = 100(r − 1) + q + 111795, | L114795 each has a structure of | R² = Rq, and |
| wherein r is an integer from 1 to 30, and q is an integer from 1 to 100, | 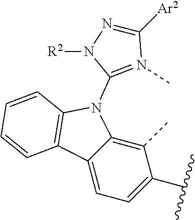 | |
| for each Ll, wherein | thus defined ligands L114796 to | wherein R² = Rq, and |
| l = q + 114795, wherein q is an | L114895 each has a structure of | |
| integer from 1 to 100, | 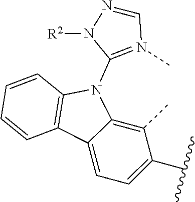 | |
| for each Ll, wherein | thus defined ligands L114896 to | wherein Ar² = Ar and |
| l = 100(r − 1) + q + 114895, | L117895 each has a structure of | R² = Rq, and |
| wherein r is an integer from 1 to 30, and q is an integer from 1 to 100, | 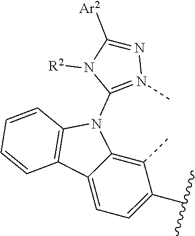 | |
| for each Ll, wherein | thus defined ligands L117896 to | wherein R² = Rq, and |
| l = q + 117895, wherein q is an | L117995 each has a structure of | |
| integer from 1 to 100, | 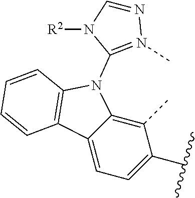 | |
| for each Ll, wherein | thus defined ligands L117996 to | wherein Ar² = Ar and |
| l = 100(r − 1) + q + 117995, | L120995 each has a structure of | R² = Rq, and |
| wherein r is an integer from 1 to 30, and q is an integer from 1 to 100, | 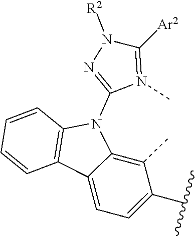 | |
| for each Ll, wherein | thus defined ligands L120996 to | wherein R² = Rq, and |
| l = q + 120995, wherein q is an | L121095 each has a structure of | |
| integer from 1 to 100, | 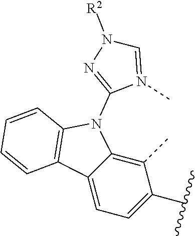 | |
| for each Ll, wherein | thus defined ligands L121096 to | wherein Ar² = Ar, and |
| l = r + 121095, wherein r is an | L121125 each has a structure of | |
| integer from 1 to 30, | 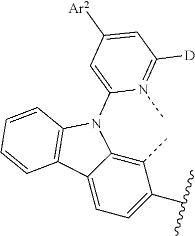 | |
| | ligand L121126 has the structure of | |
| | 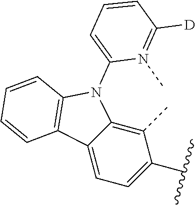 | |
| for each Ll, wherein | thus defined ligands L121127 to | wherein Ar² = Ar and |
| l = 30(r − 1) + s + 121126, | L122026 each has a structure of | Ar³ = As, and |
| wherein r is an integer from 1 to 30, and s is an integer from 1 to 30, | 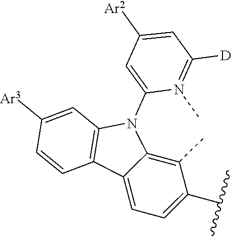 | |
| for each Ll, wherein | thus defined ligands L122027 to | wherein Ar² = Ar, and |
| l = r + 122026, wherein r is an | L122056 each has a structure of | |
| integer from 1 to 30, | 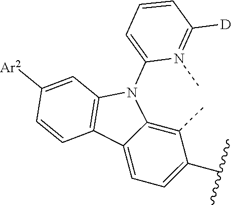 | |
| for each Ll, wherein | thus defined ligands L122057 to | wherein Ar² = Ar and |
| l = 30(r − 1) + s + 122056, | L122956 each has a structure of | Ar³ = As, and |
| wherein r is an integer from 1 to 30, and s is an integer from 1 to 30, | 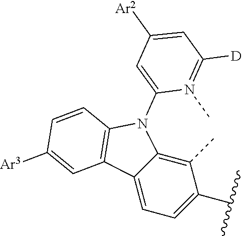 | |
| for each Ll, wherein | thus defined ligands L122957 to | wherein Ar² = Ar, and |
| l = r + 122956, wherein r is an | L122986 each has a structure of | |
| integer from 1 to 30, | 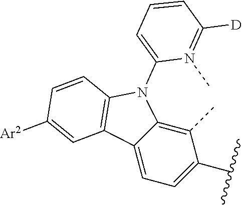 | |
| for each Ll, wherein | thus defined ligands L122987 to | wherein Ar² = Ar, and |
| l = r + 122986, wherein r is an | L123016 each has a structure of | |
| integer from 1 to 30, | 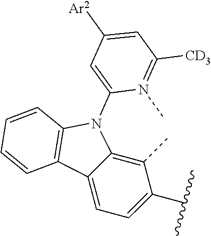 | |
| | Ligand L123017 has a structure of | |
| | 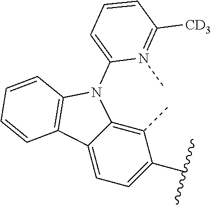 | |
| for each Ll, wherein | thus defined ligands L123018 to | wherein Ar² = Ar and |
| l = 30(r − 1) + s + 123017, | L123917 each has a structure of | Ar³ = As, and |
| wherein r is an integer from 1 to 30, and s is an integer from 1 to 30, | 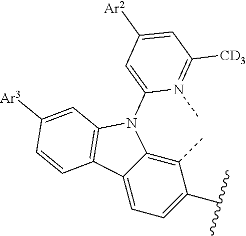 | |
| for each Ll, wherein | thus defined ligands L123918 to | wherein Ar² = Ar, and |
| l = r + 223917, wherein r is an | L123947 each has a structure of | |
| integer from 1 to 30, | 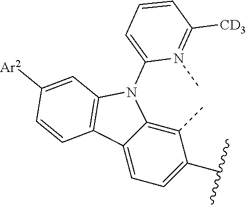 | |
| for each Ll, wherein | thus defined ligands L223948 to | wherein Ar² = Ar and |
| l = 30(r − 1) + s + 223947, | L224847 each has a structure of | Ar³ = As, and |
| wherein r is an integer from 1 to 30, and s is an integer from 1 to 30, | 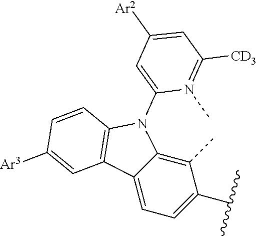 | |
| for each Ll, wherein | thus defined ligands L224848 to | wherein Ar² = Ar, and |
| l = r + 224847, wherein r is an | L224877 each has a structure of | |
| integer from 1 to 30, | 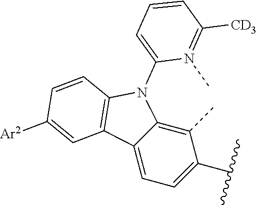 | |
| for each Ll, wherein | thus defined ligands L224878 to | wherein Ar² = Ar and |
| l = 30(r − 1) + s + 224877, | L225777 each has a structure of | Ar³ = As, and |
| wherein r is an integer from 1 to 30, and s is an integer from 1 to 30, | 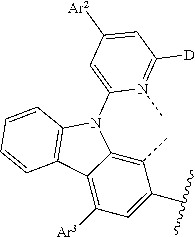 | |
| for each Ll, wherein | thus defined ligands L225778 to | wherein Ar² = Ar, and |
| l = r + 225777, wherein r is an | L225807 each has a structure of | |
| integer from 1 to 30, | 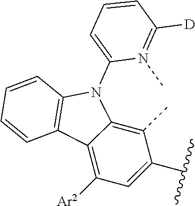 | |
| for each Ll, wherein | thus defined ligands L225808 to | wherein Ar² = Ar and |
| l = 30(r − 1) + s + 225807, | L226707 each has a structure of | Ar³ = As, and |
| wherein r is an integer from 1 to 30, and s is an integer from 1 to 30, | 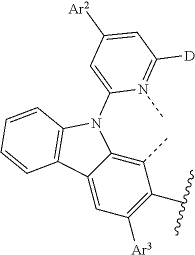 | |
| for each Ll, wherein | thus defined ligands L226708 to | wherein Ar² = Ar, and |
| l = r + 226707, wherein r is an | L226737 each has a structure of | |
| integer from 1 to 30, | 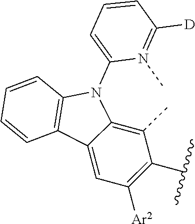 | |
| for each Ll, wherein | thus defined ligands L226738 to | wherein Ar² = Ar and |
| l = 30(r − 1) + s + 226737, | L227637 each has a structure of | Ar³ = As, and |
| wherein r is an integer from 1 to 30, and s is an integer from 1 to 30, | 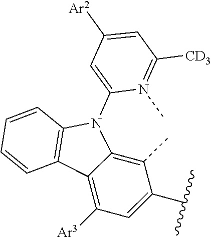 | |
| for each Ll, wherein | thus defined ligands L227638 to | wherein Ar² = Ar, and |
| l = r + 227637, | L227667 each has a structure of | |
| wherein r is an integer from 1 to 30, | 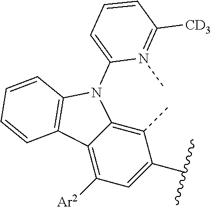 | |
| for each Ll, wherein | thus defined ligands L227668 to | wherein Ar² = Ar and |
| l = 30(r − 1) + s + 227667, | L228567 each has a structure of | Ar³ = As, and |
| wherein r is an integer from 1 to 30, and s is an integer from 1 to 30, | 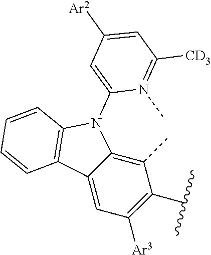 | |
| for each Ll, wherein | thus defined ligands L228568 to | wherein Ar² = Ar, and |
| l = r + 228567, wherein r is an | L228597 each has a structure of | |
| integer from 1 to 30, | 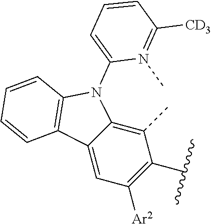 | |
| for each Ll, wherein | thus defined ligands L228598 to | wherein Ar² = Ar, and |
| l = r + 228597, wherein r is an | L228627 each has a structure of | |
| integer from 1 to 30, | 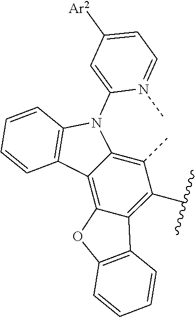 | |
| for each Ll, wherein | thus defined ligands L228628 to | wherein Ar² = Ar, and |
| l = r + 228627, wherein r is an | L228657 each has a structure of | |
| integer from 1 to 30, | 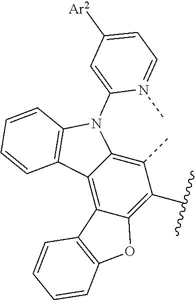 | |
| for each Ll, wherein | thus defined ligands L228658 to | wherein Ar² = Ar, and |
| l = r + 228657, wherein r is an | L228687 each has a structure of | |
| integer from 1 to 30, | 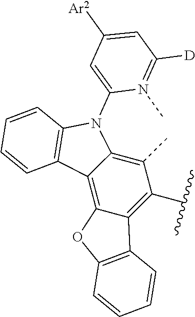 | |
| for each Ll, wherein | thus defined ligands L228688 to | wherein Ar² = Ar, and |
| l = r + 228787, wherein r is | L228717 each has a structure of | |
| integer from 1 to 30, | 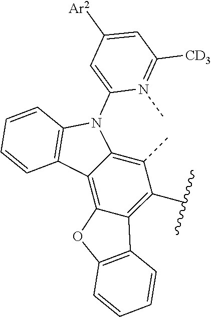 | |
| for each Ll, wherein | thus defined ligands L228718 to | wherein Ar² = Ar, and |
| l = r + 228717, wherein r is an | L228747 each has a structure of | |
| integer from 1 to 30, | 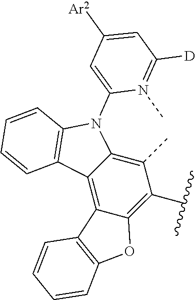 | |
| for each Ll, wherein | thus defined ligands L228748 to | wherein Ar² = Ar, and |
| l = r + 228747, wherein r is an | L228777 each has a structure of | |
| integer from 1 to 30, | 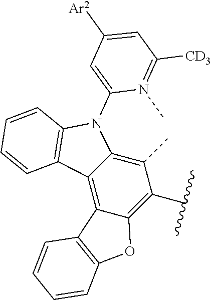 | |
| | ligand L228778 has a structure of | |
| | 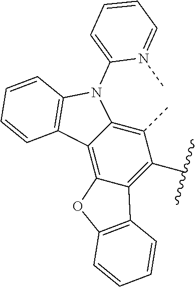 | |
| | ligand L228779 has a structure of | |
| | 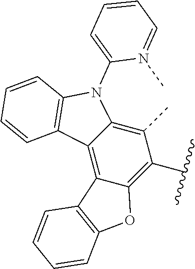 | |
| | ligand L228780 has a structure of | |
| | 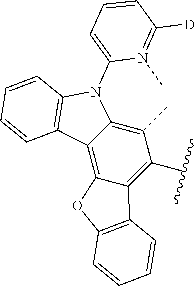 | |
| | ligand L228781 has a structure of | |
| | 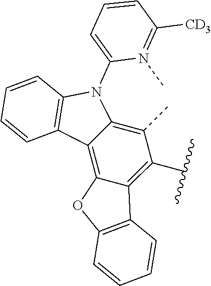 | |
| | ligand L228782 has a structure of | |
| | 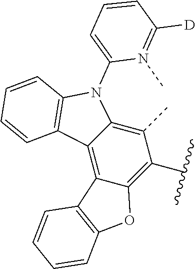 | |
| | ligand L228783 has a structure of | |
| | 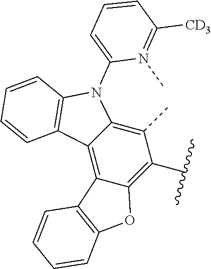 | |
| for each Ll, wherein | thus defined ligands L228784 to | wherein R¹ = Rq, and |
| l = q + 228783, wherein q is an | L229114 each has a structure of | |
| integer from 1 to 330, | 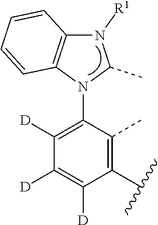 | |
| for each Ll, wherein | thus defined ligands L229115 to | wherein R¹ = Rq, and |
| l = q + 229114, wherein q is an | L229445 each has a structure of | |
| integer from 1 to 330, | 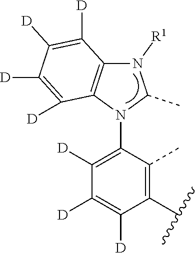 | |
| for each Ll, wherein | thus defined ligands L229446 to | wherein R¹ = Rq, and |
| l = q + 229445, wherein q is an | L229776 each has a structure of | |
| integer from 1 to 330, | 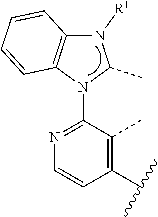 | |
| for each Ll, wherein | thus defined ligands L229777 to | wherein R¹ = Rq, and |
| l = q + 229776, wherein q is an | L230107 each has a structure of | |
| integer from 1 to 330, | 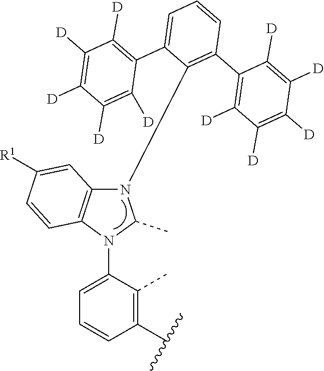 | |

wherein A1 to A30 have the following structures: 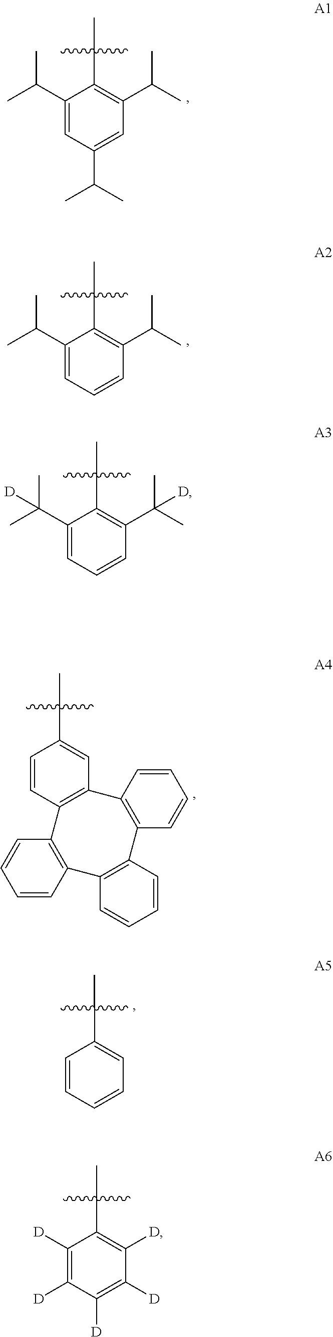 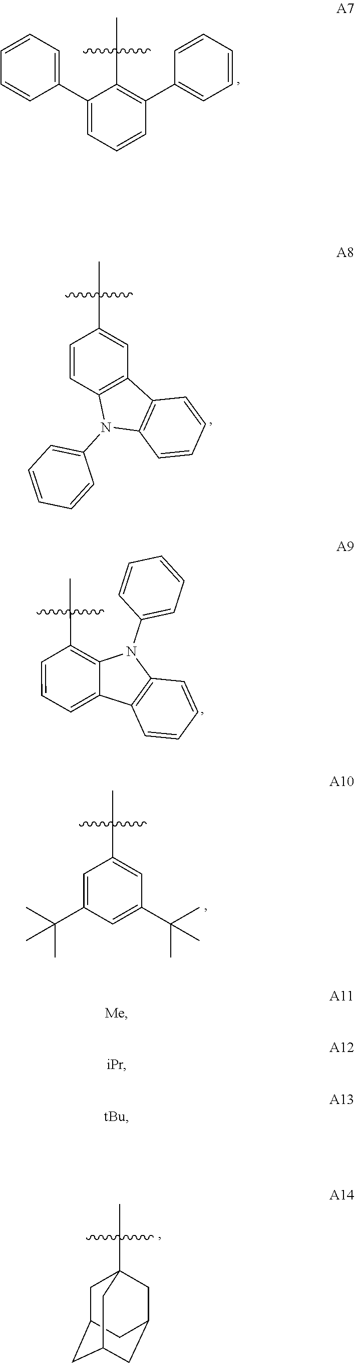 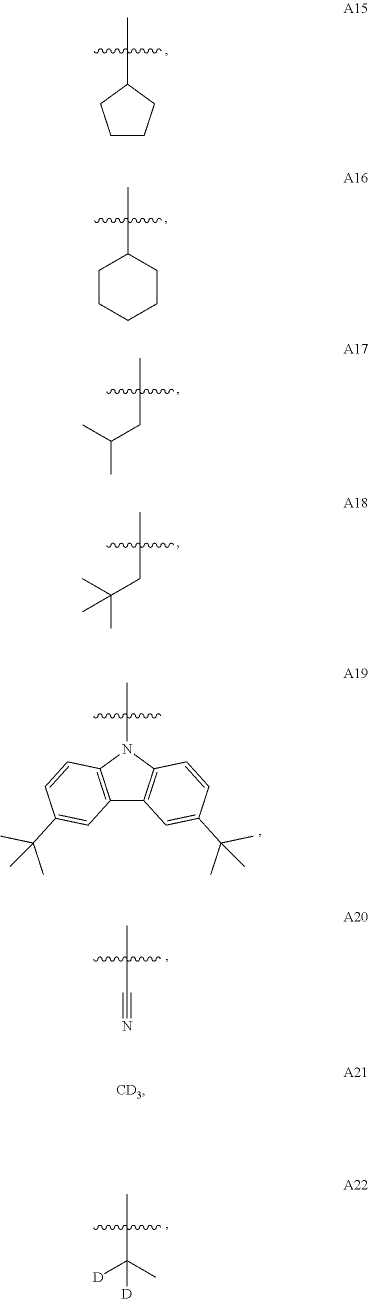 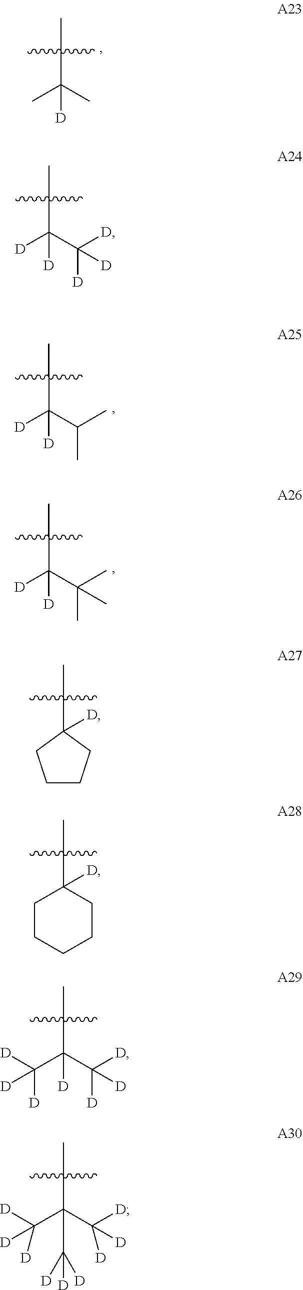 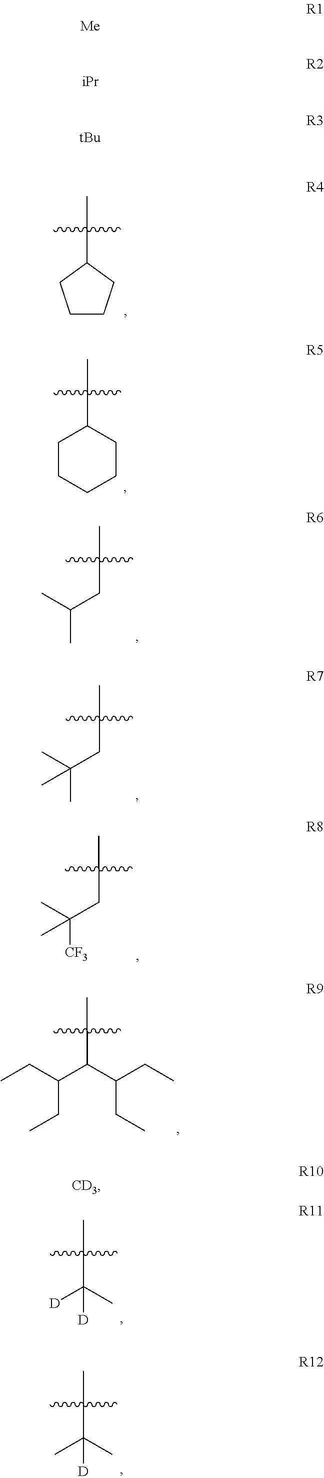 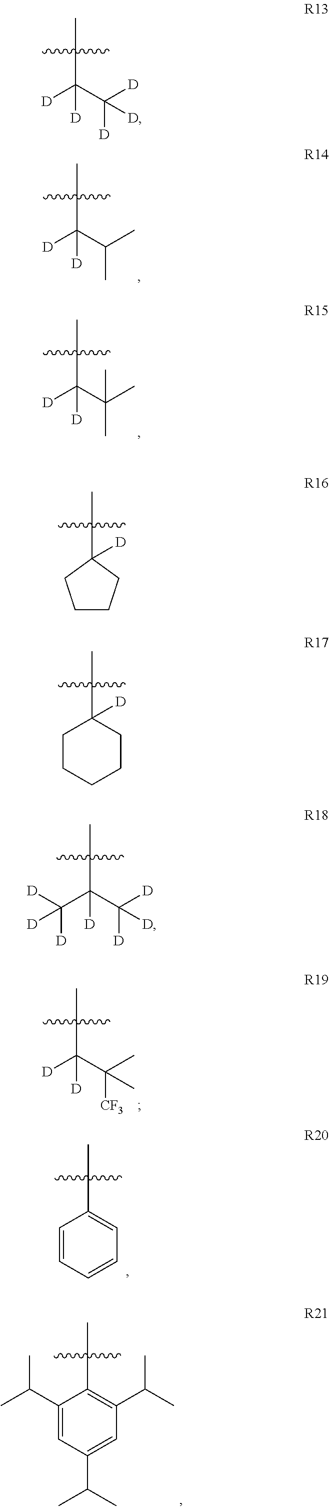 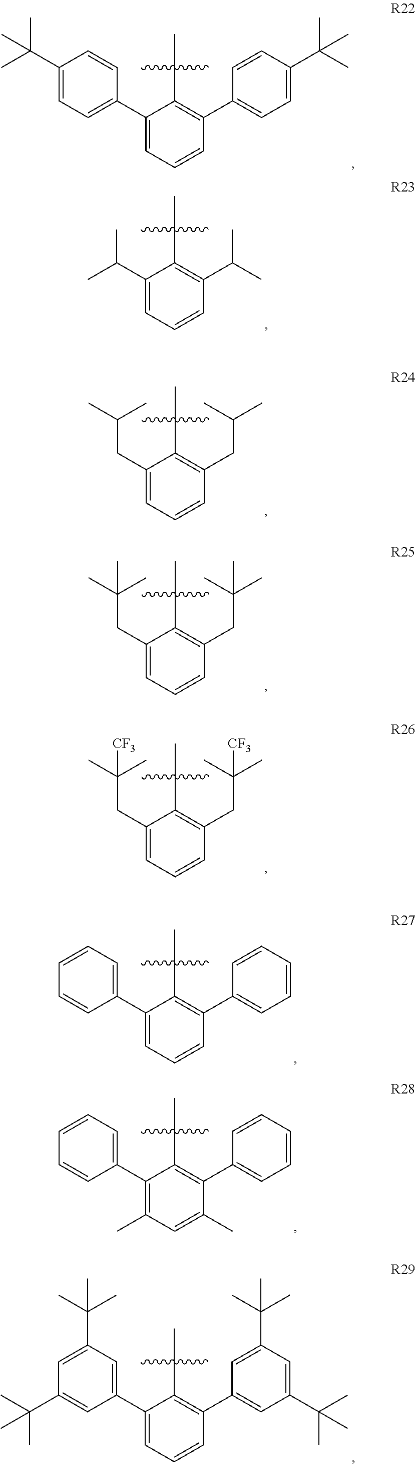 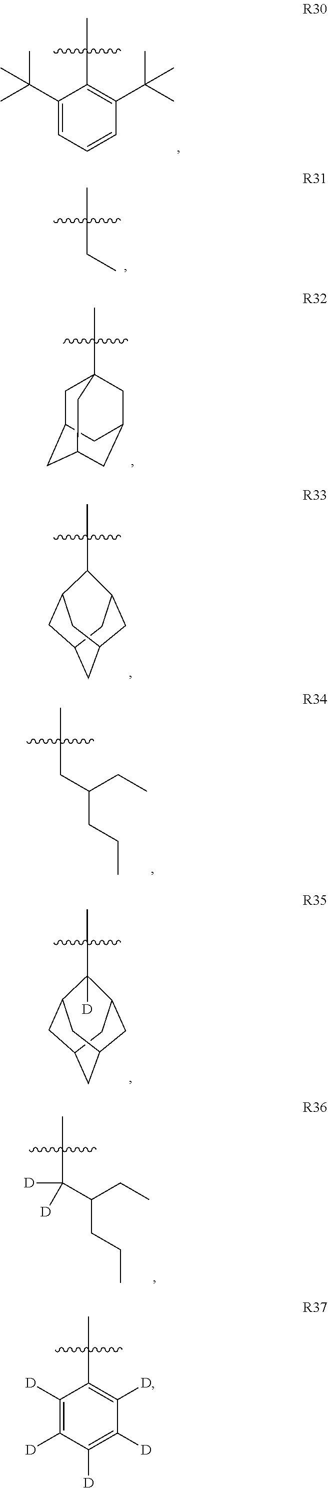 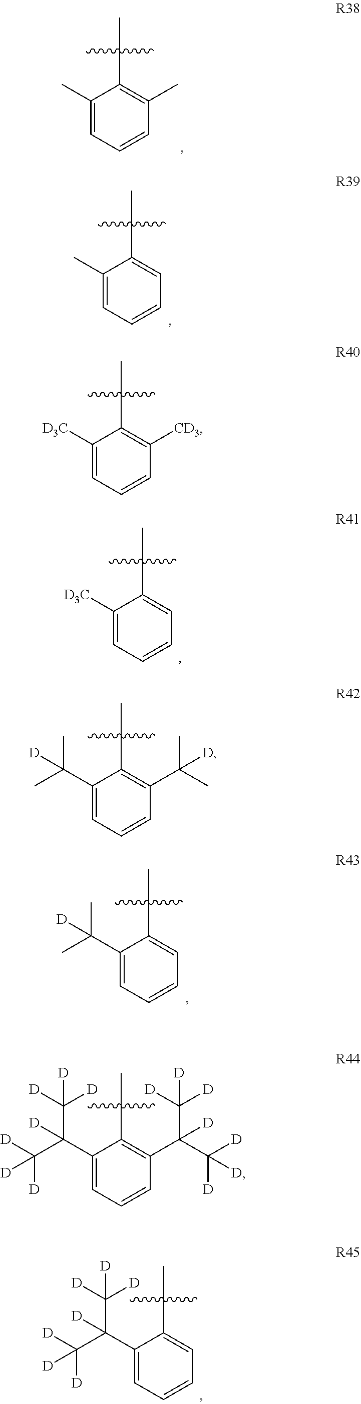 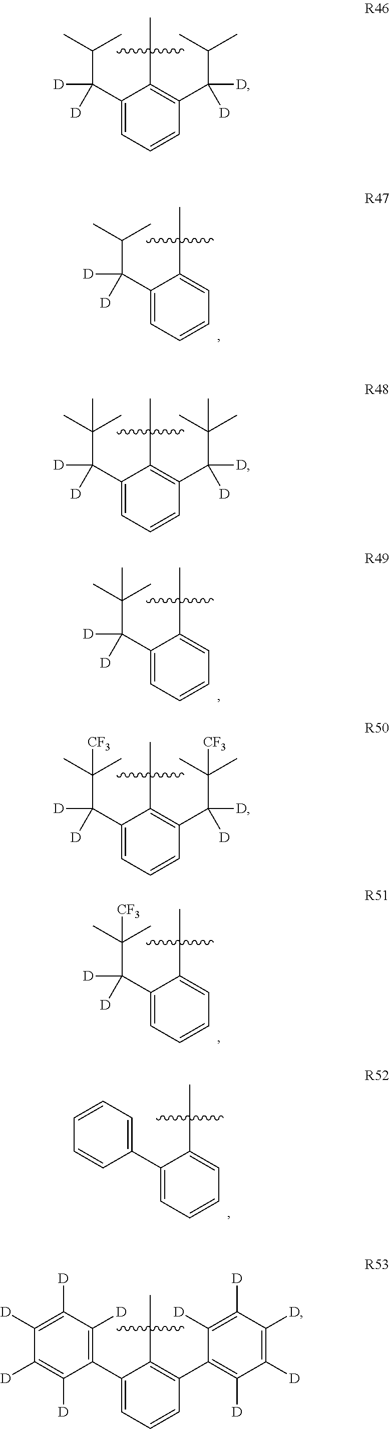 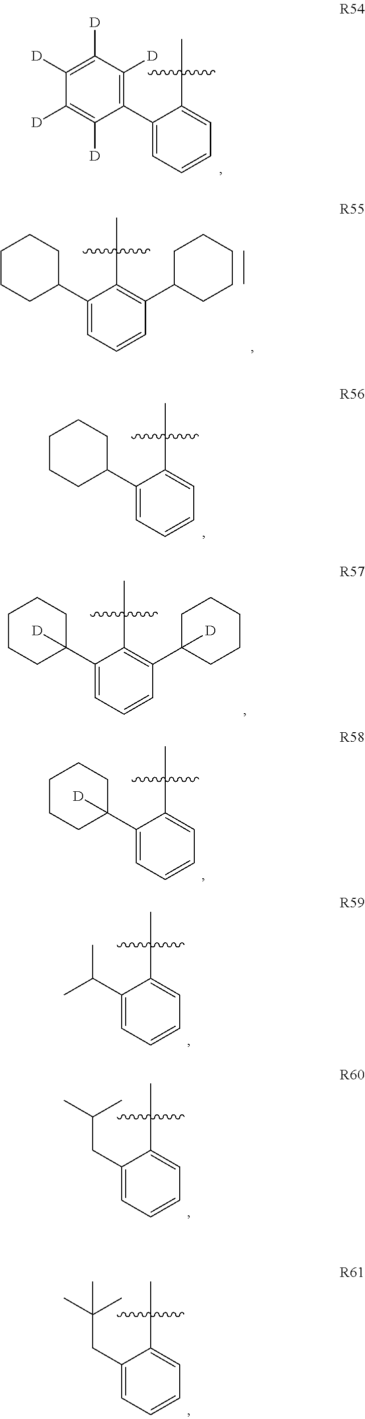 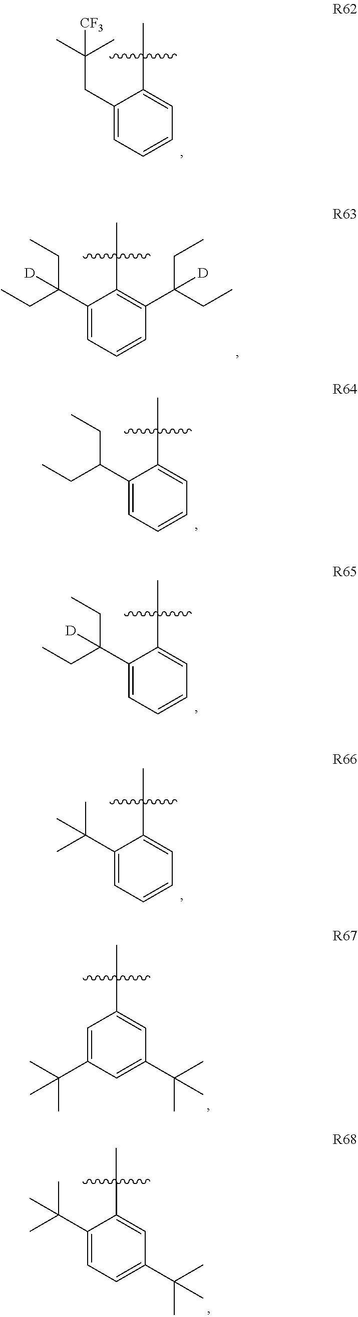 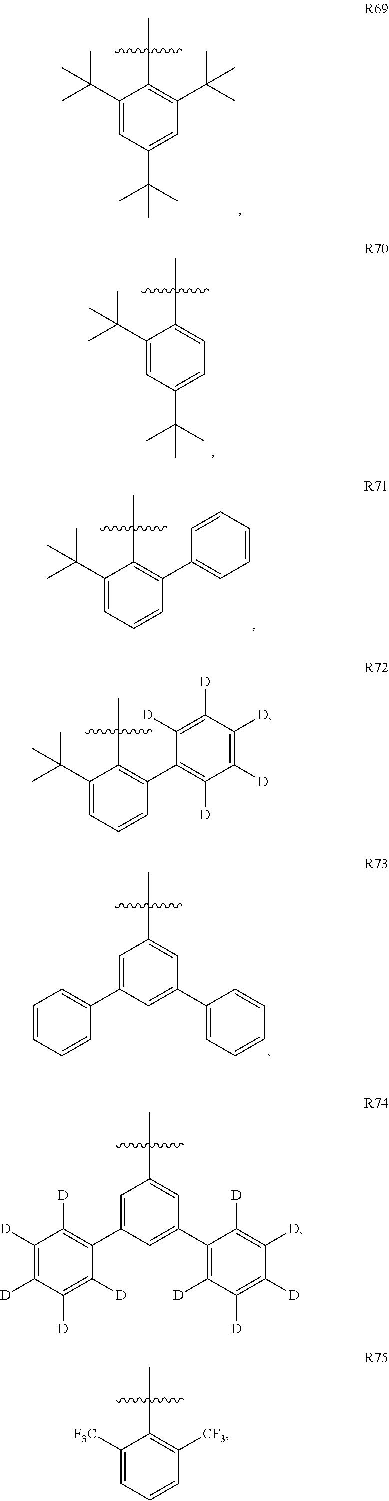 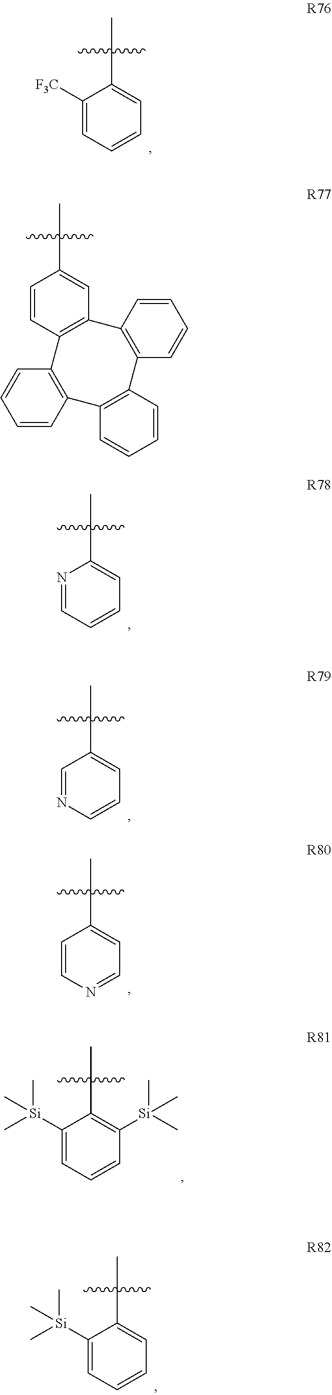 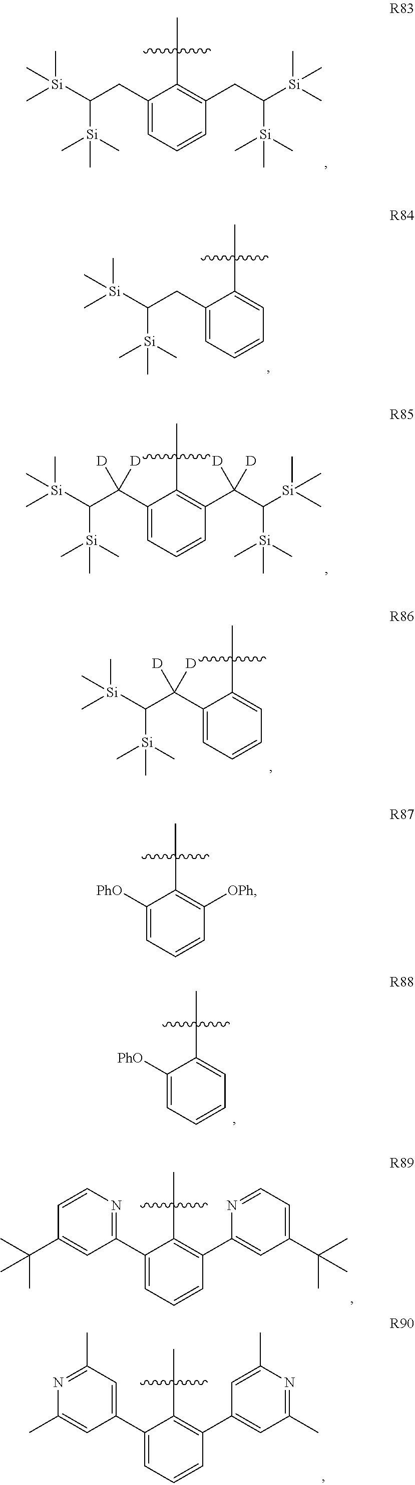 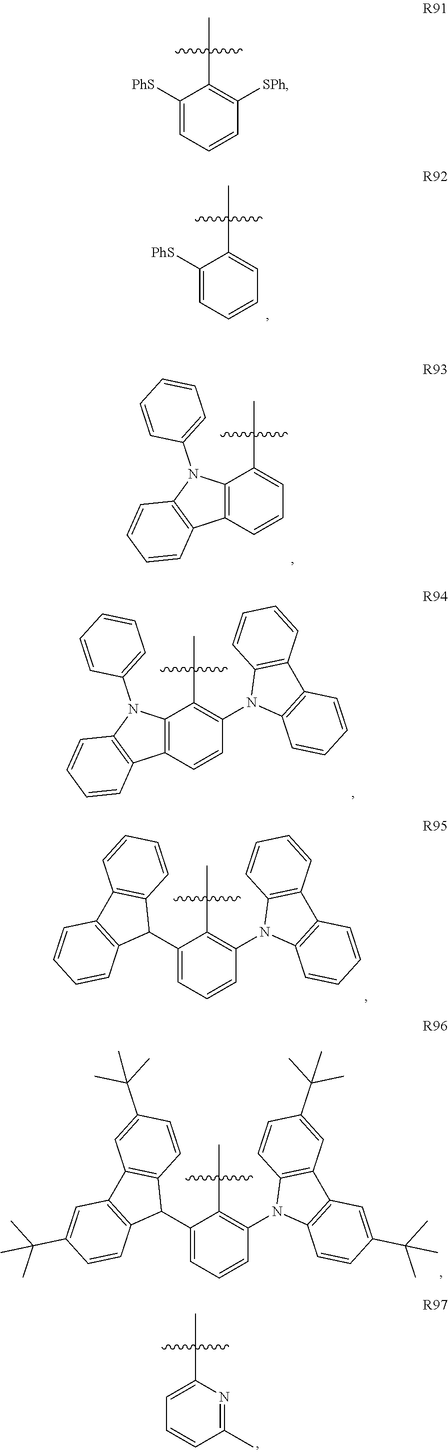 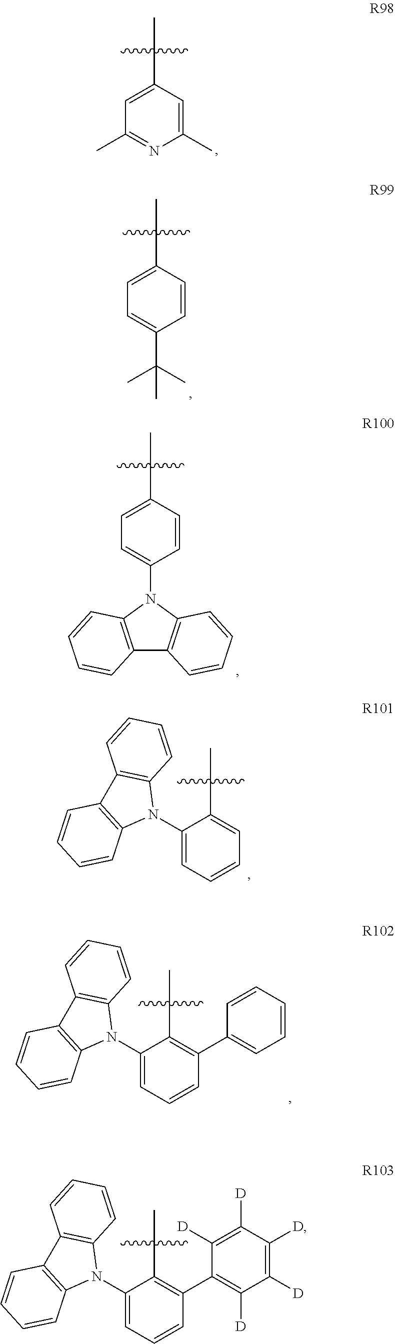 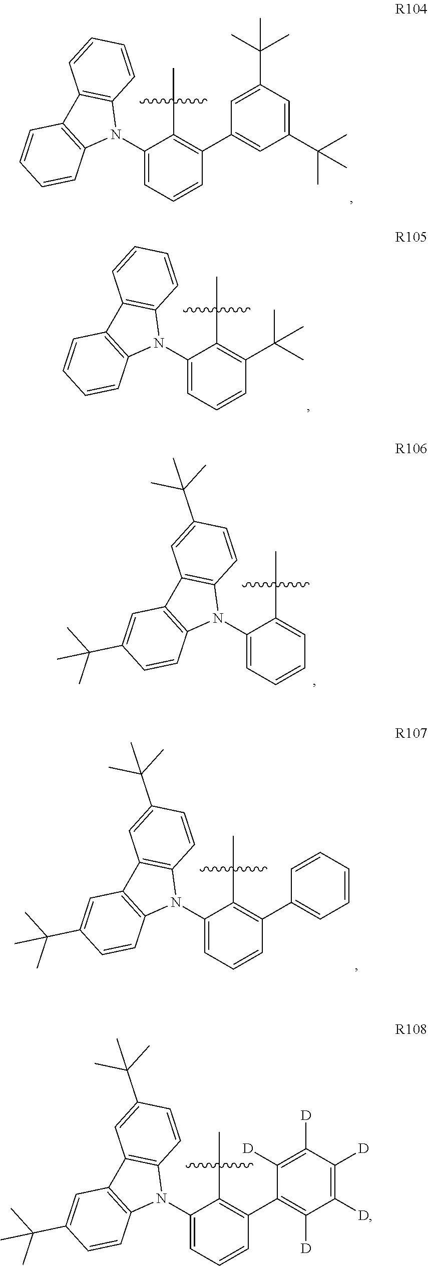 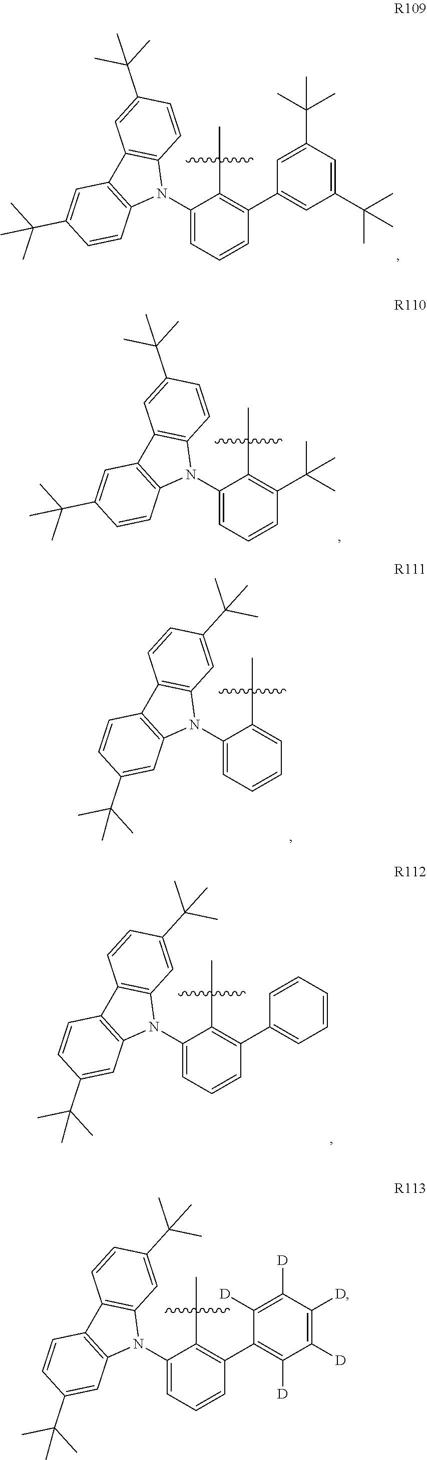 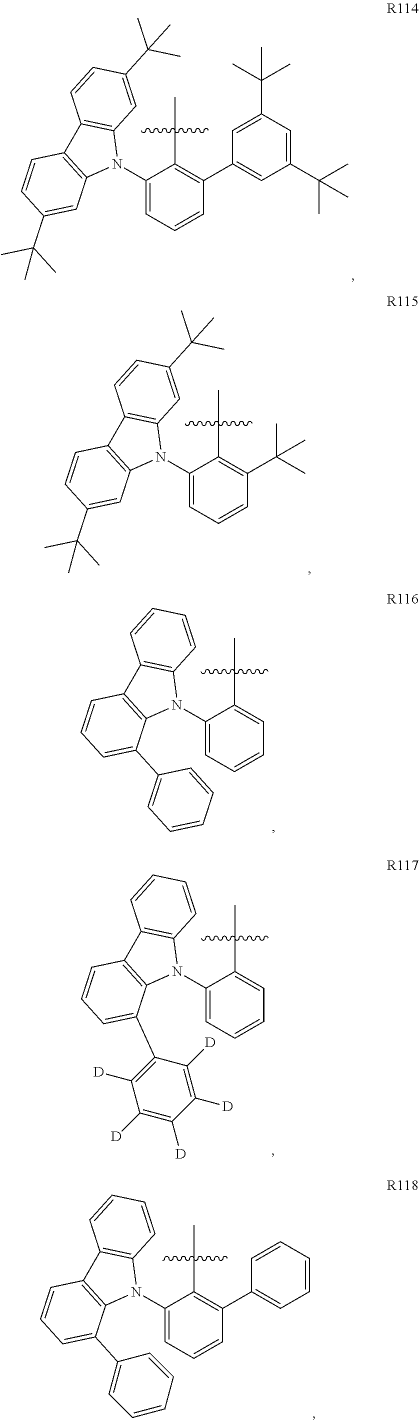 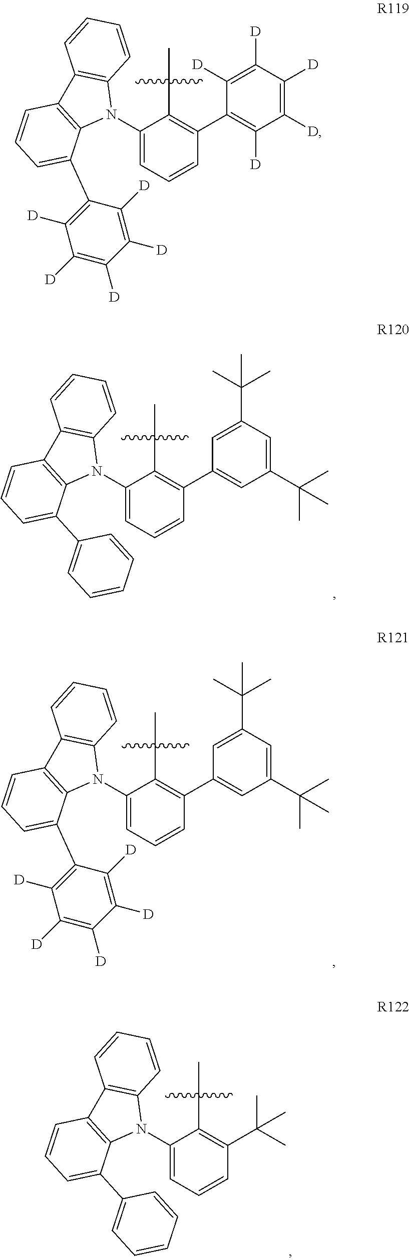 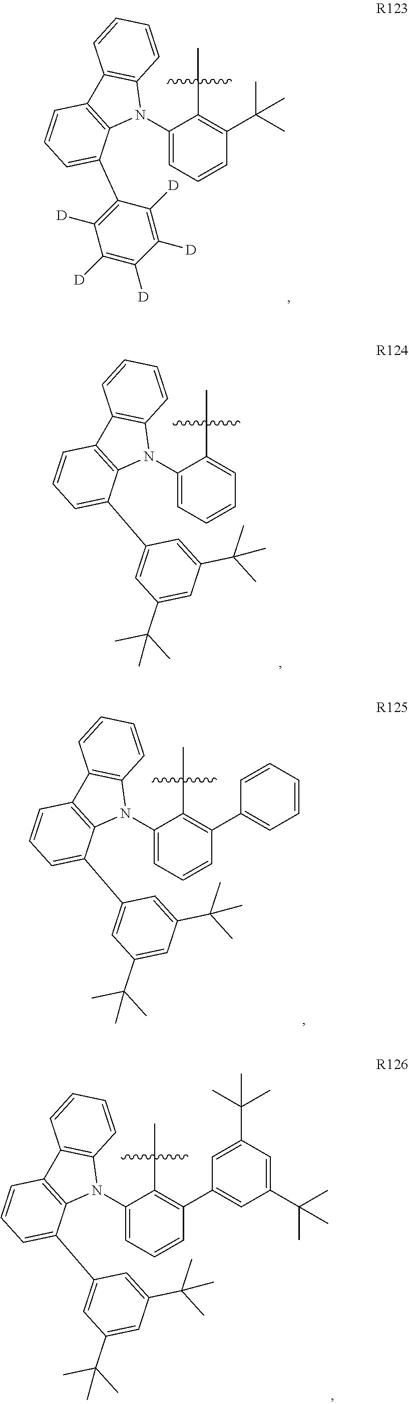 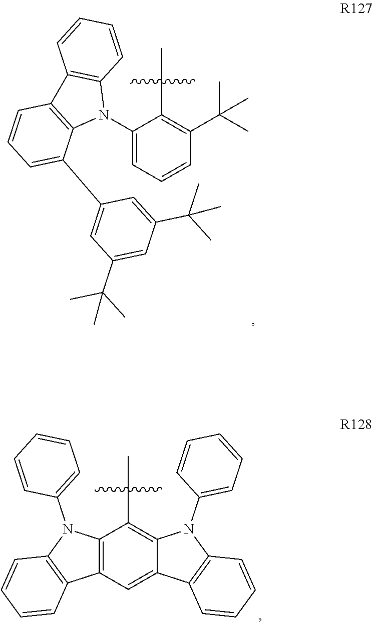 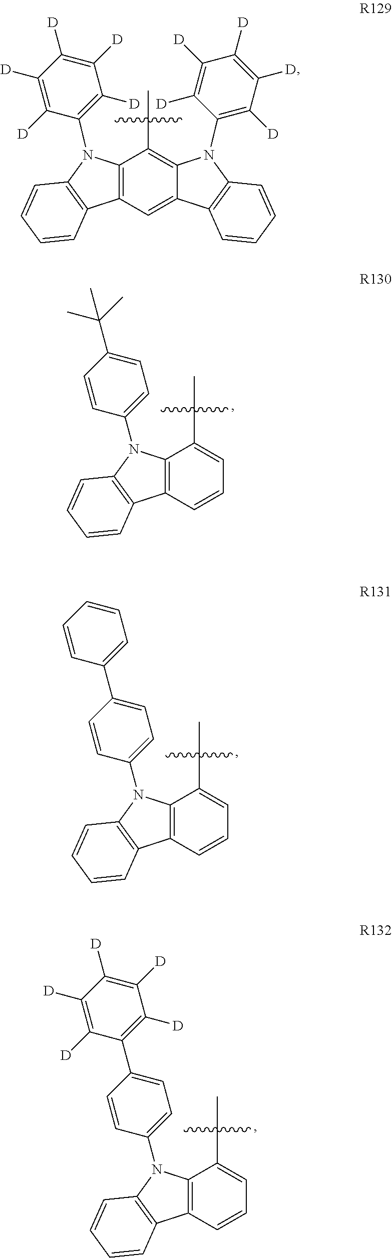 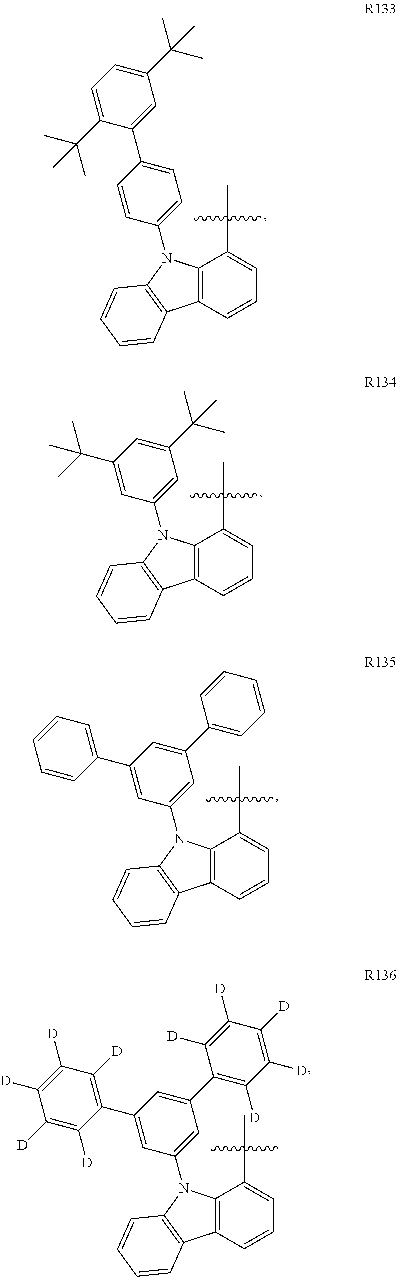 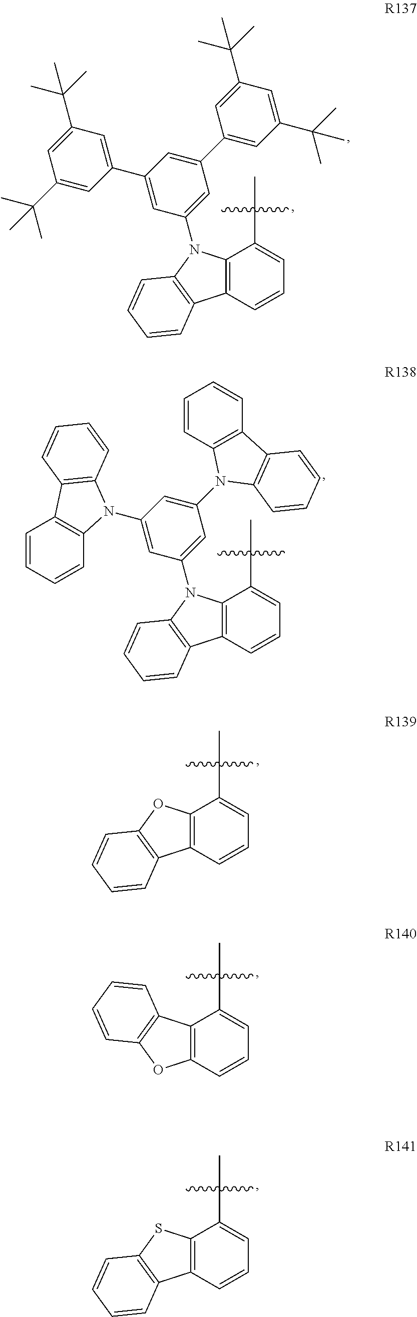 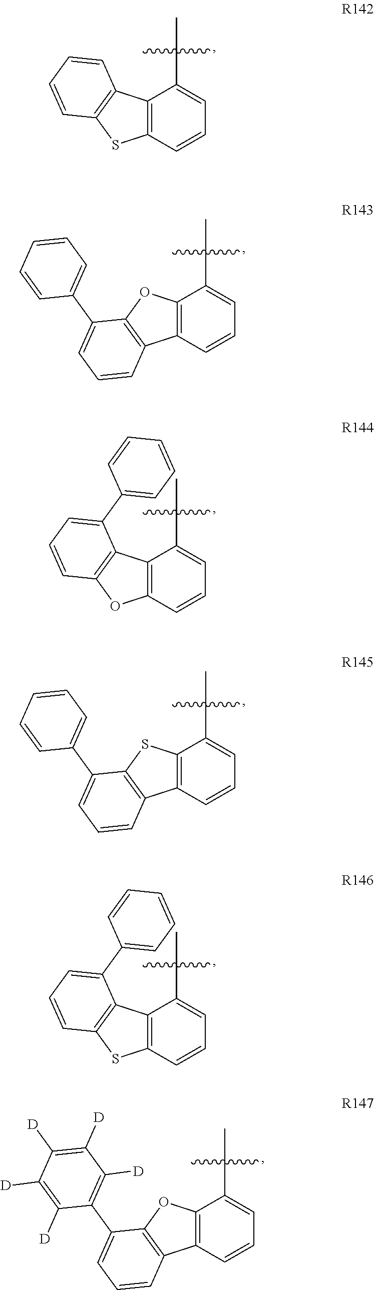 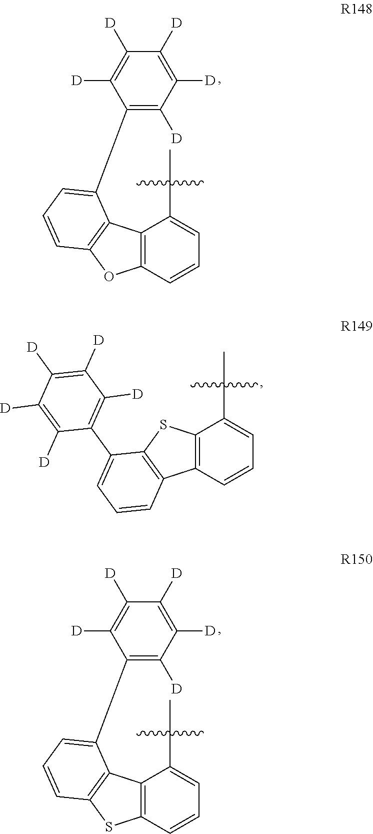 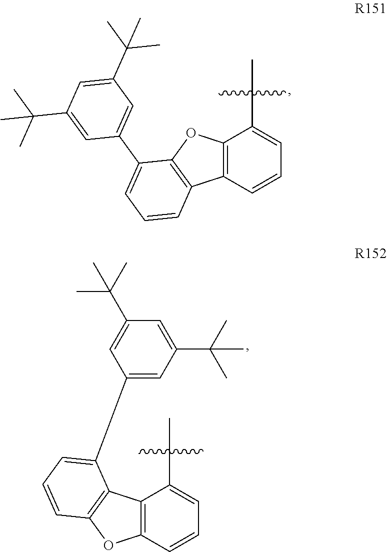 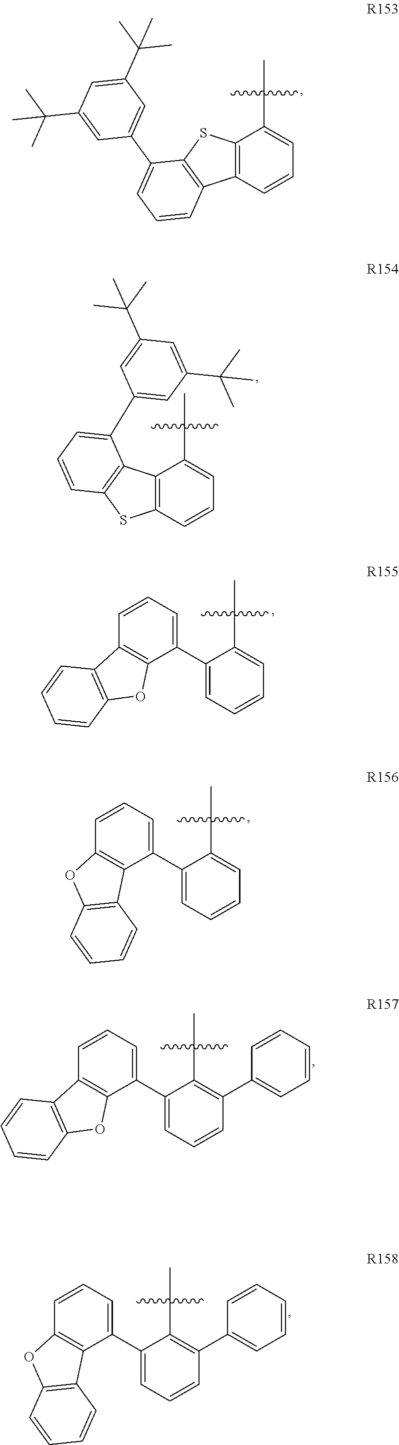 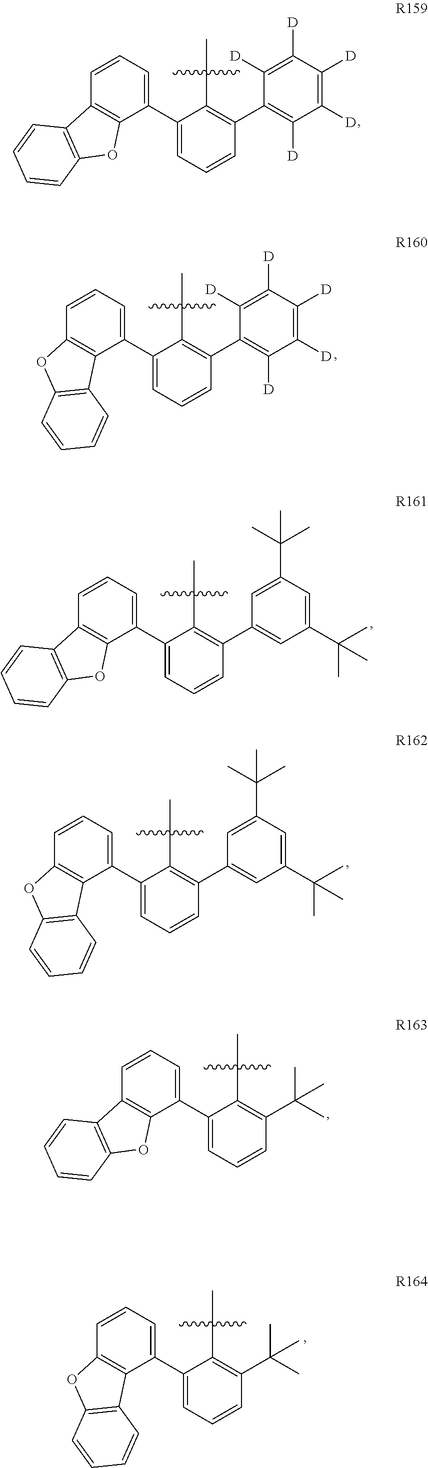 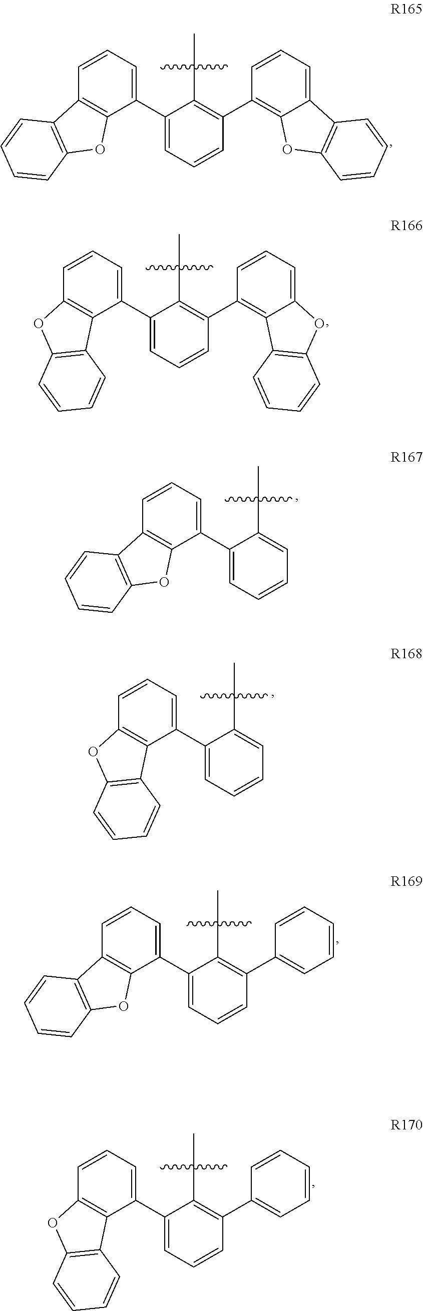 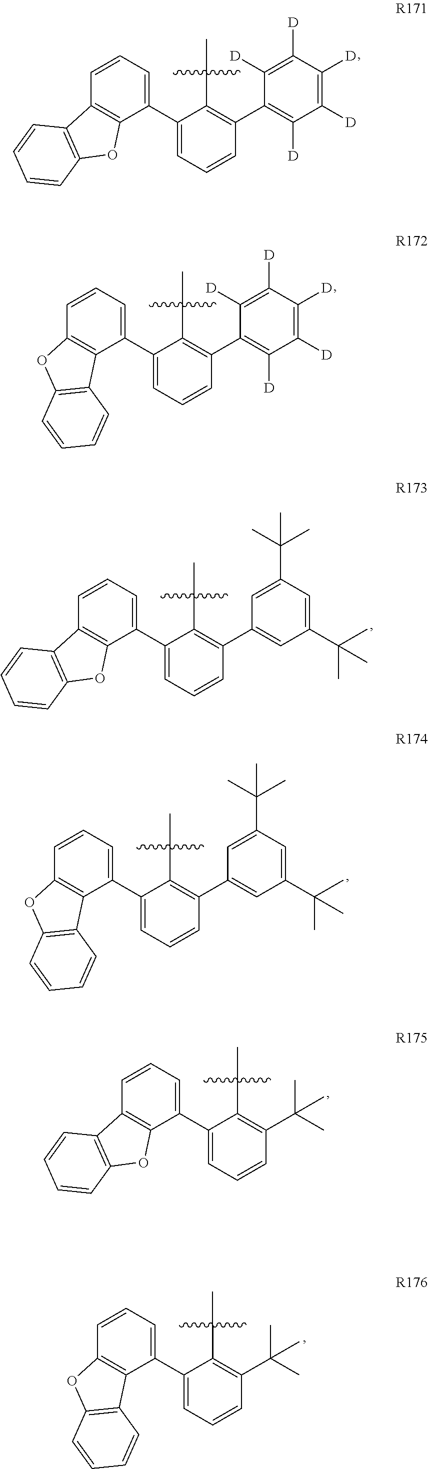 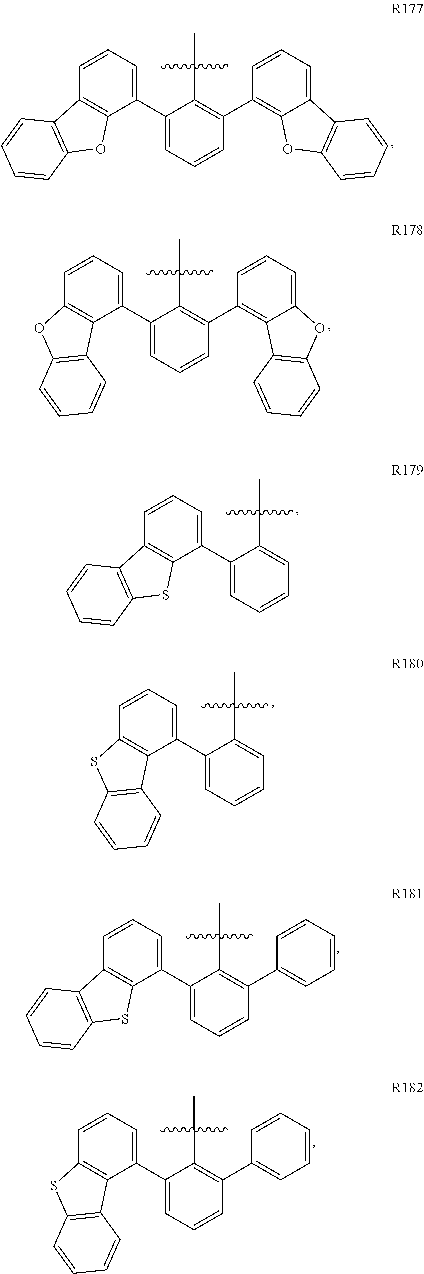 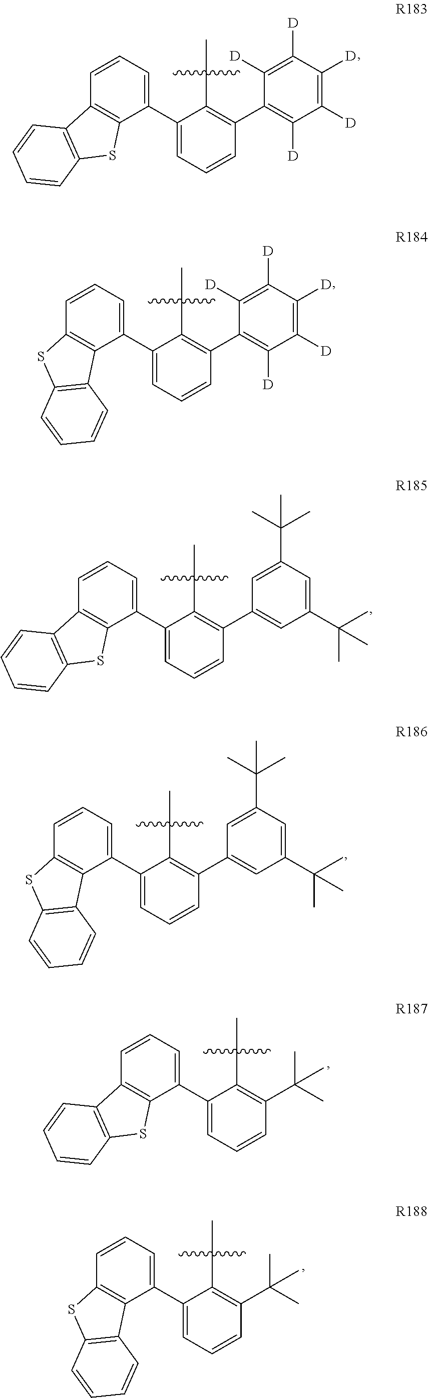 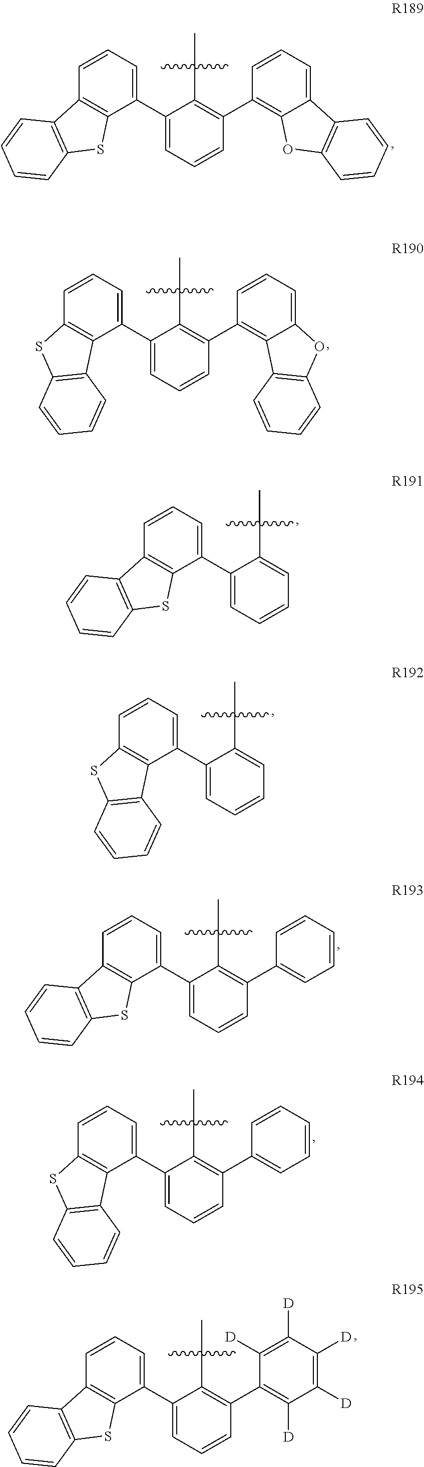 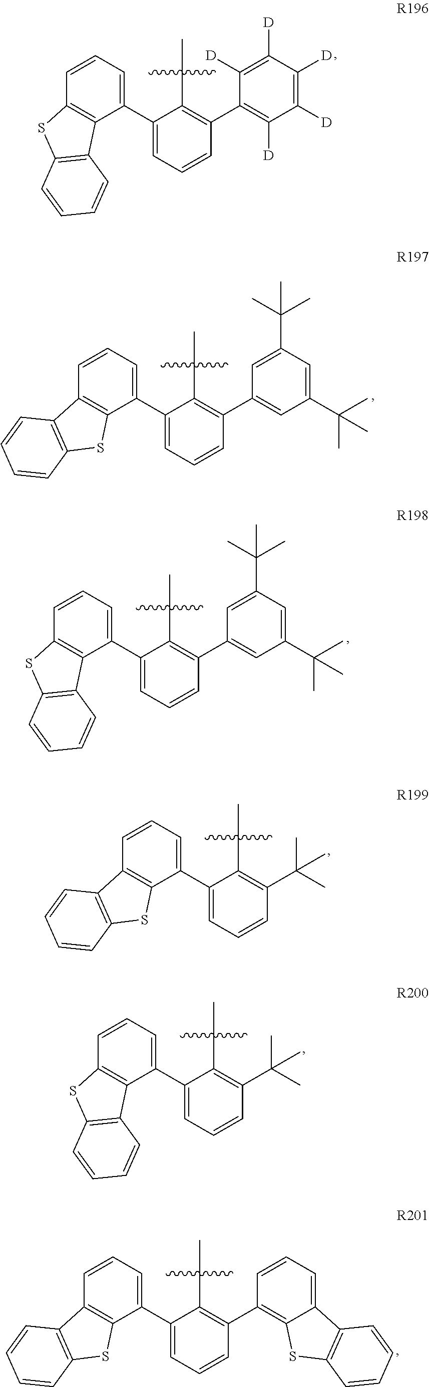 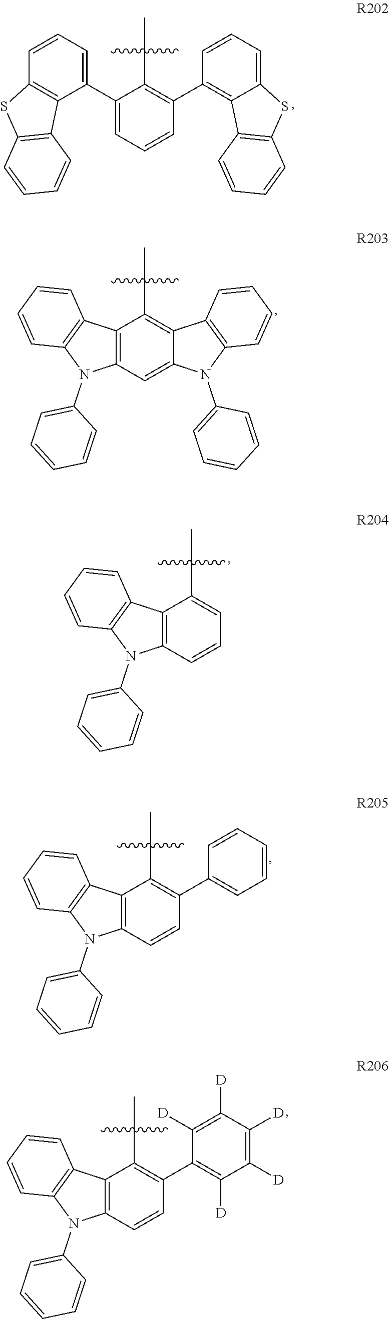 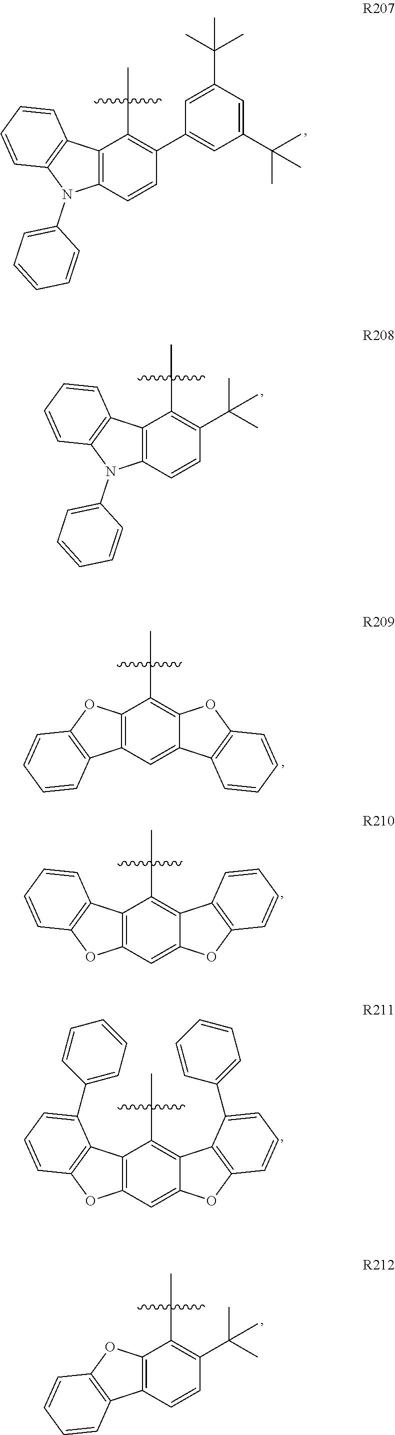 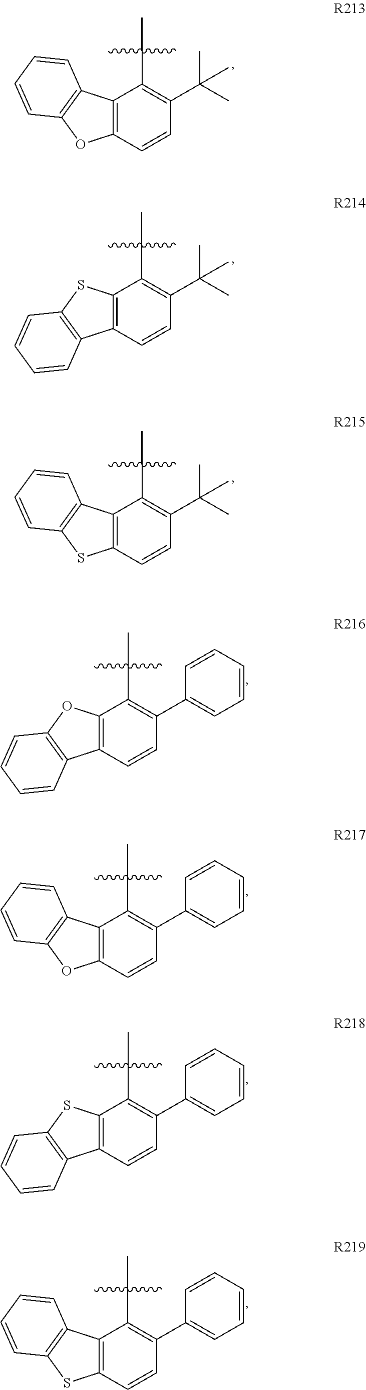 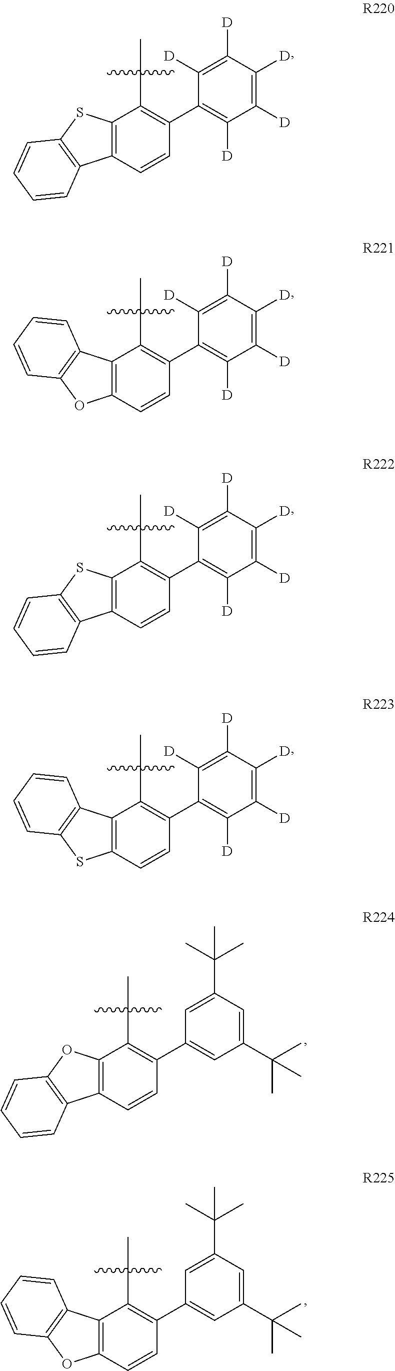 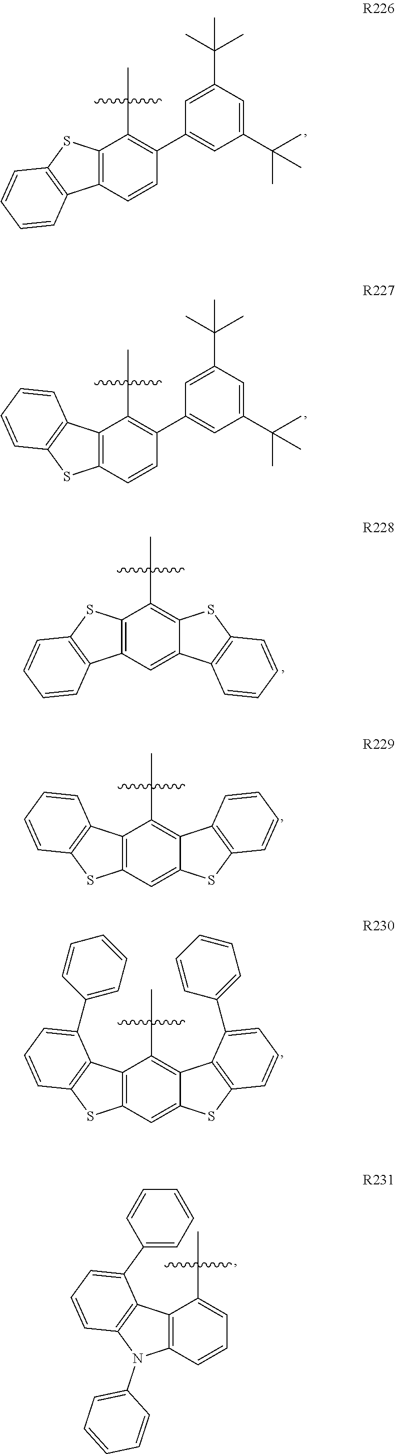 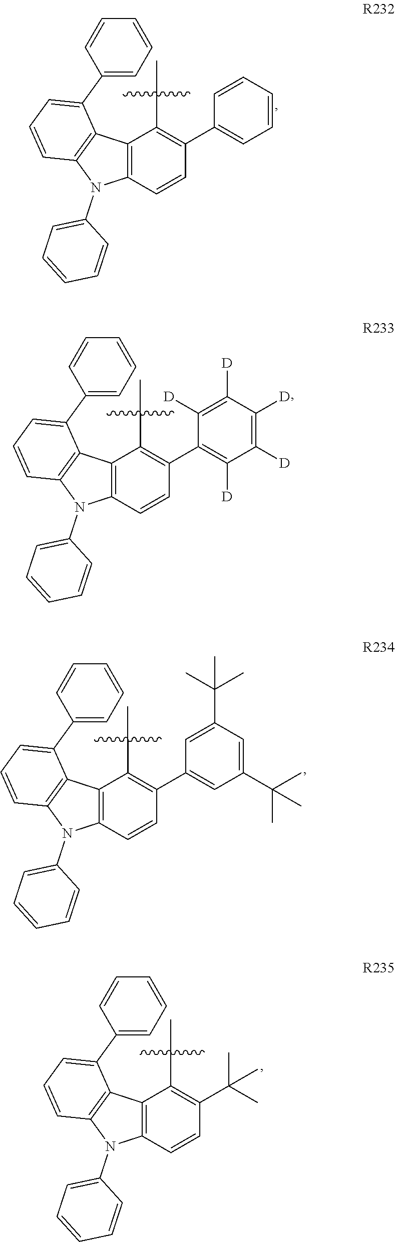 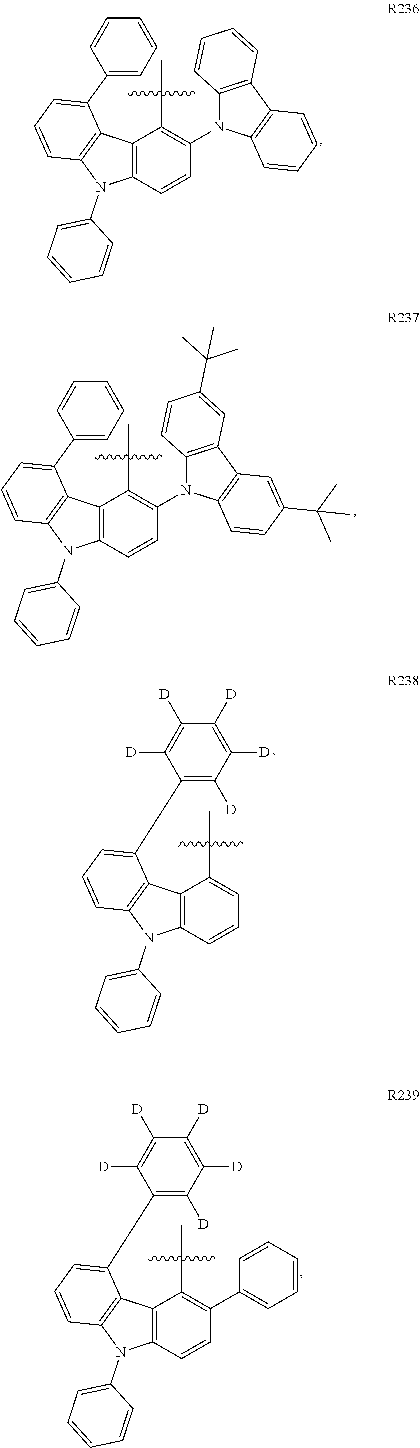 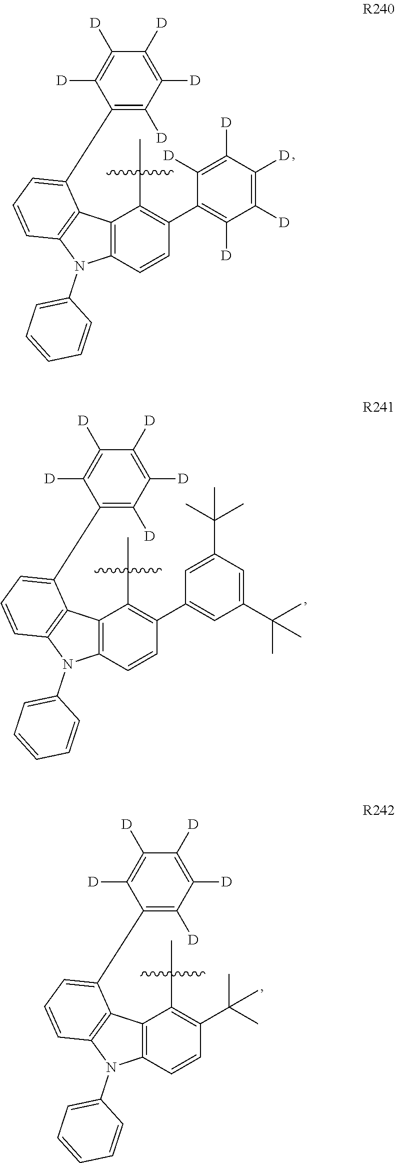 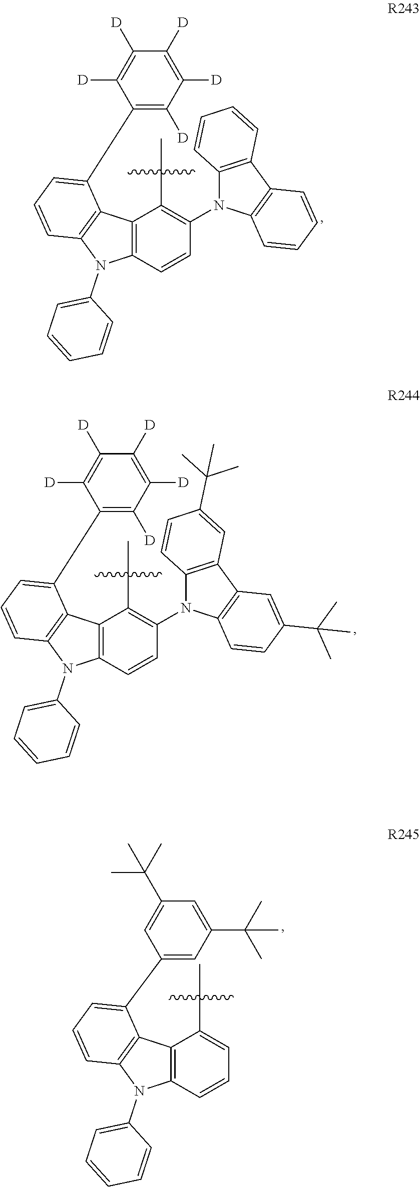 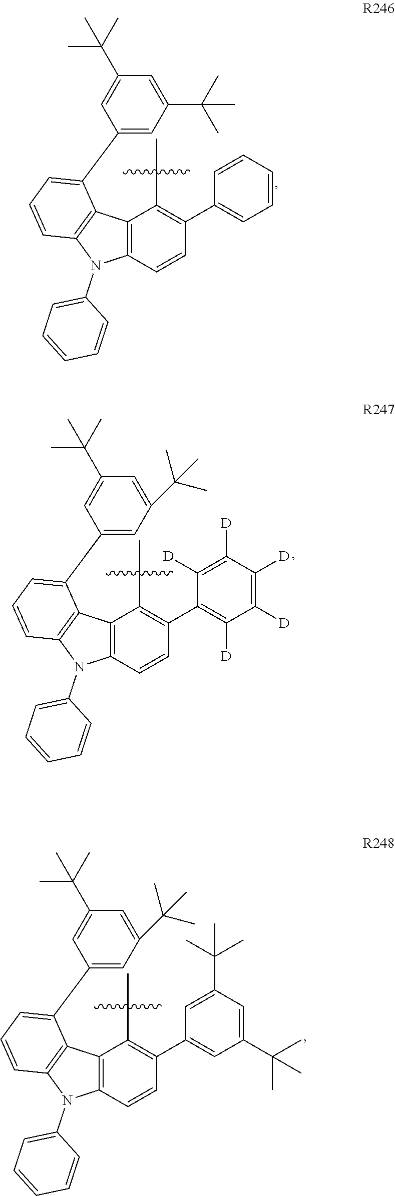 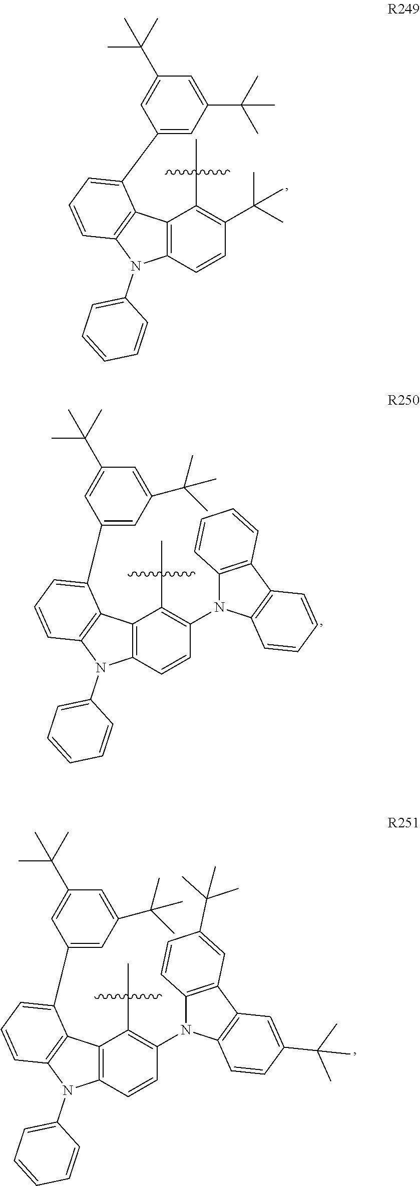 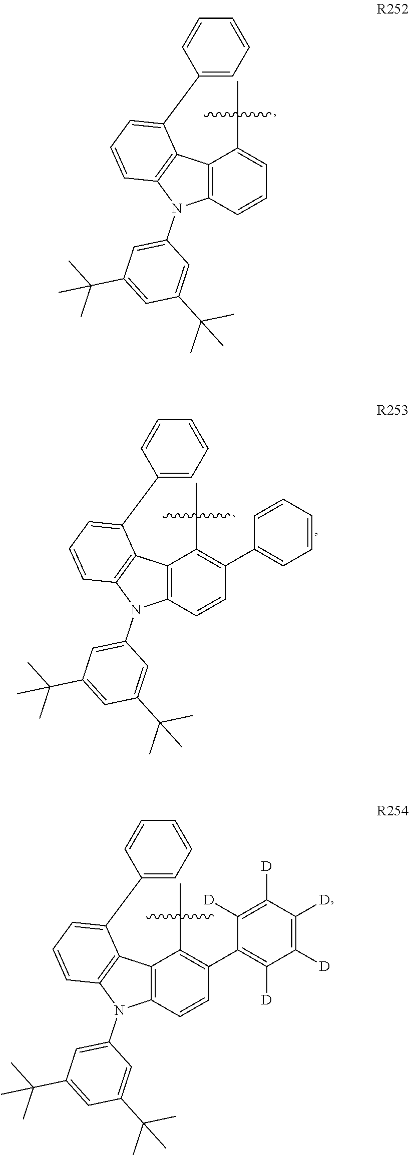 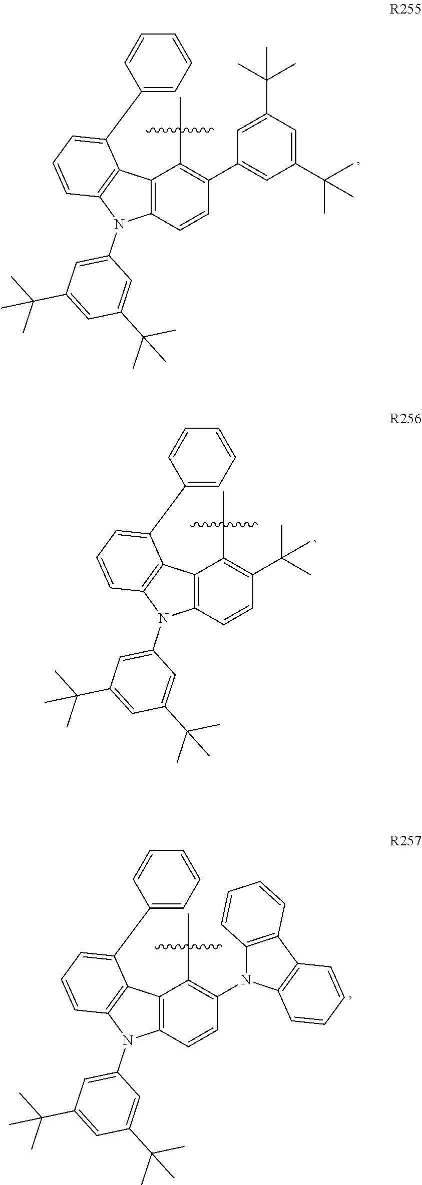 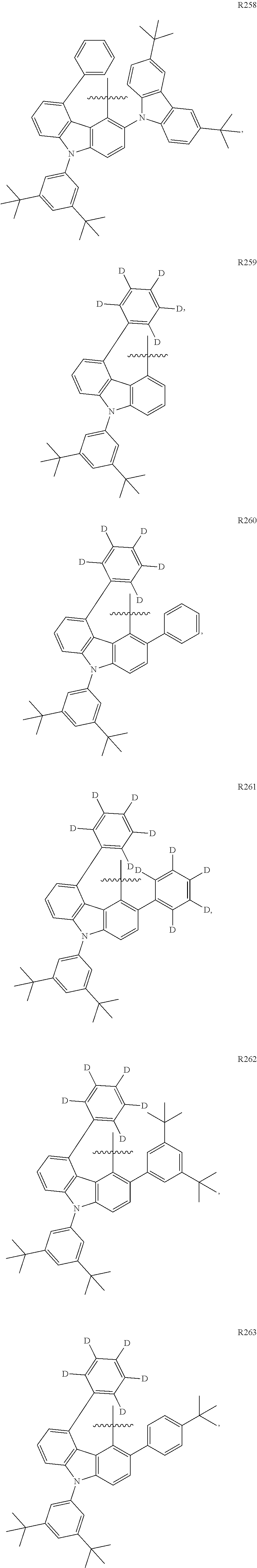 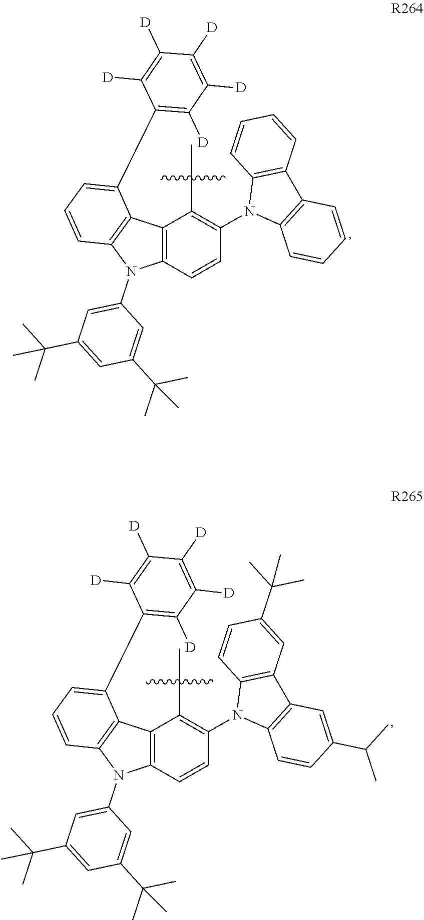 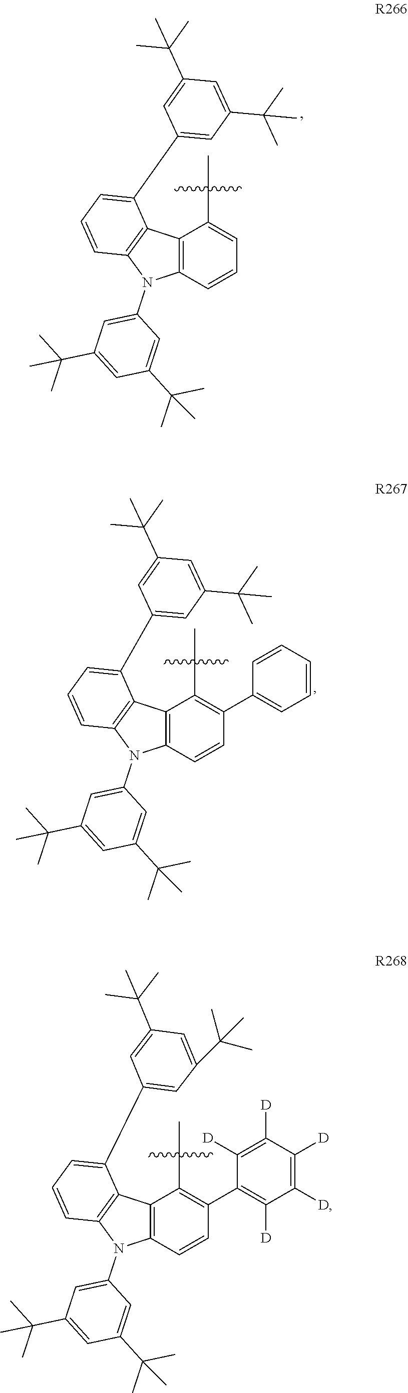 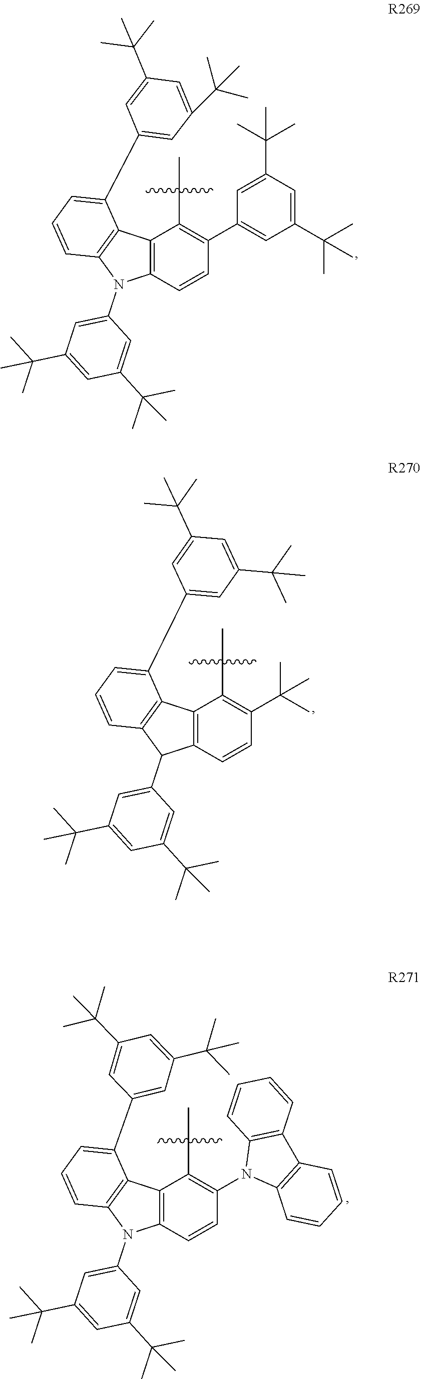 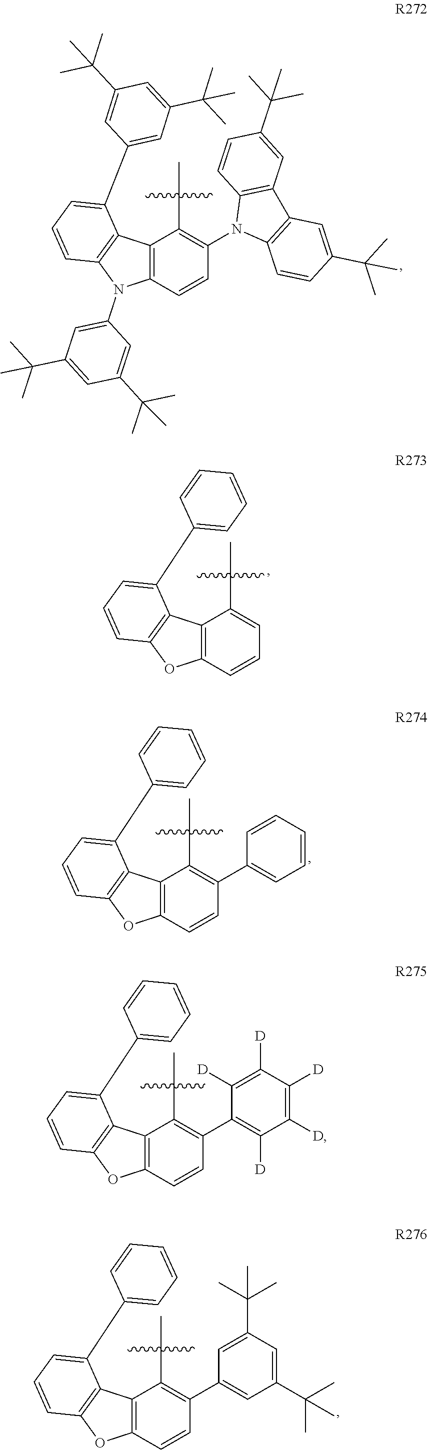 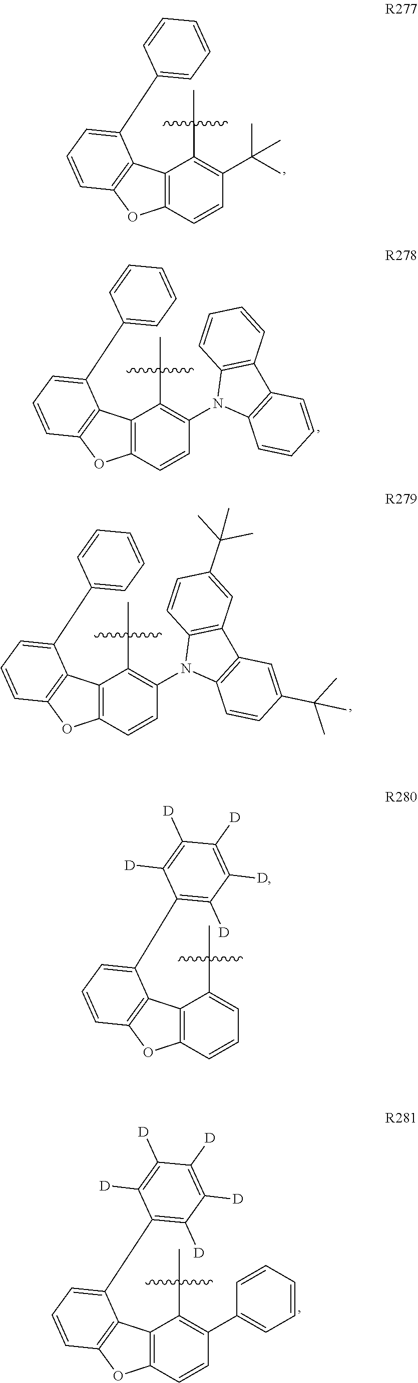 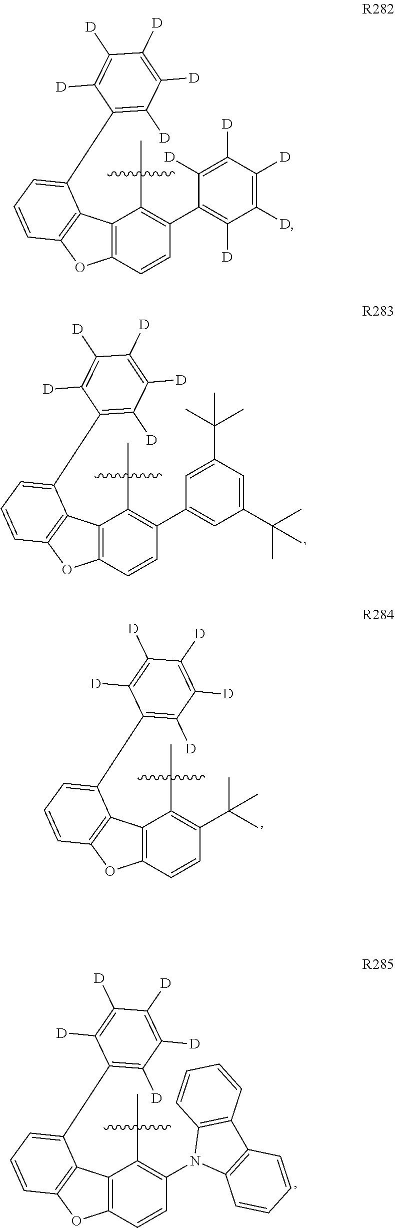 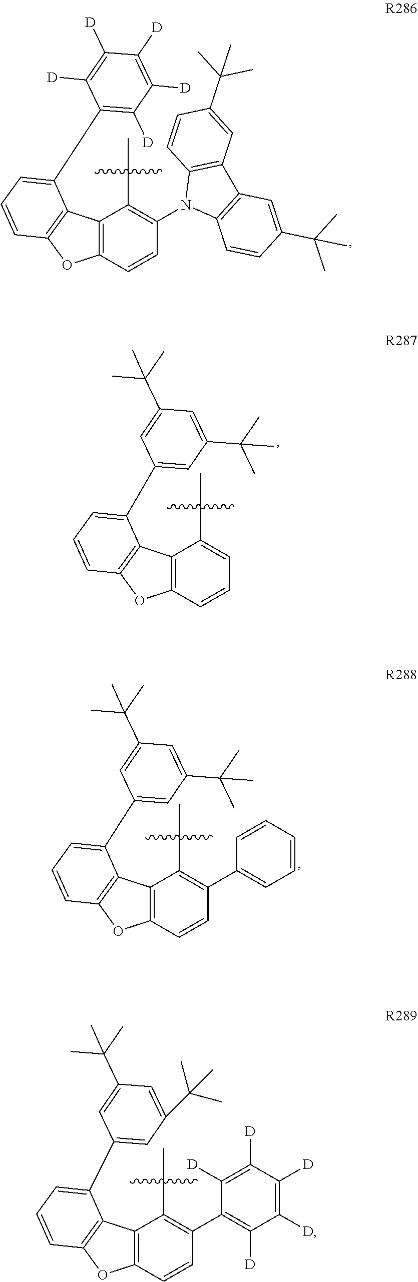 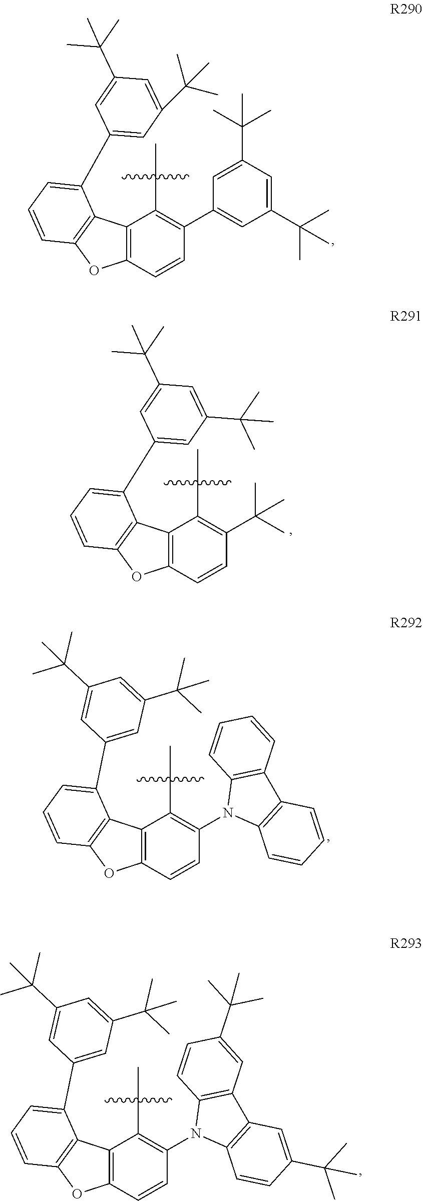 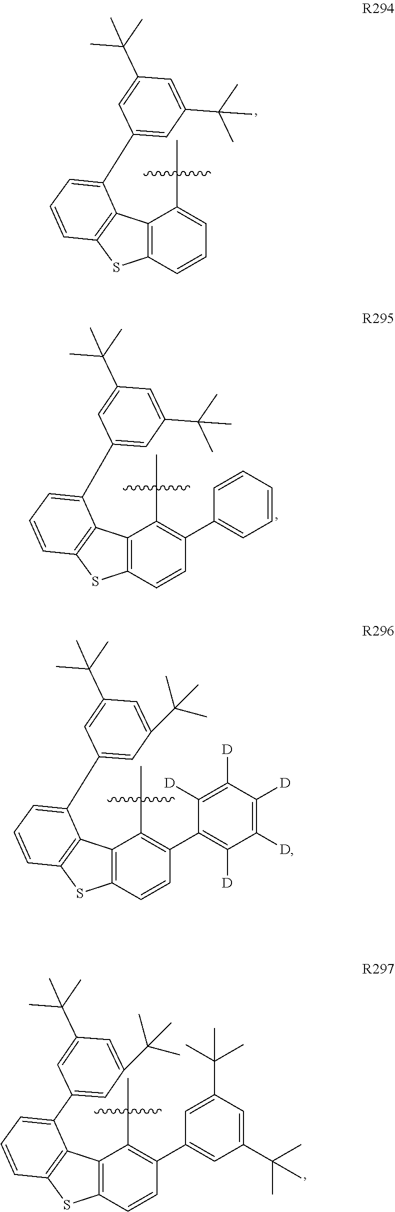 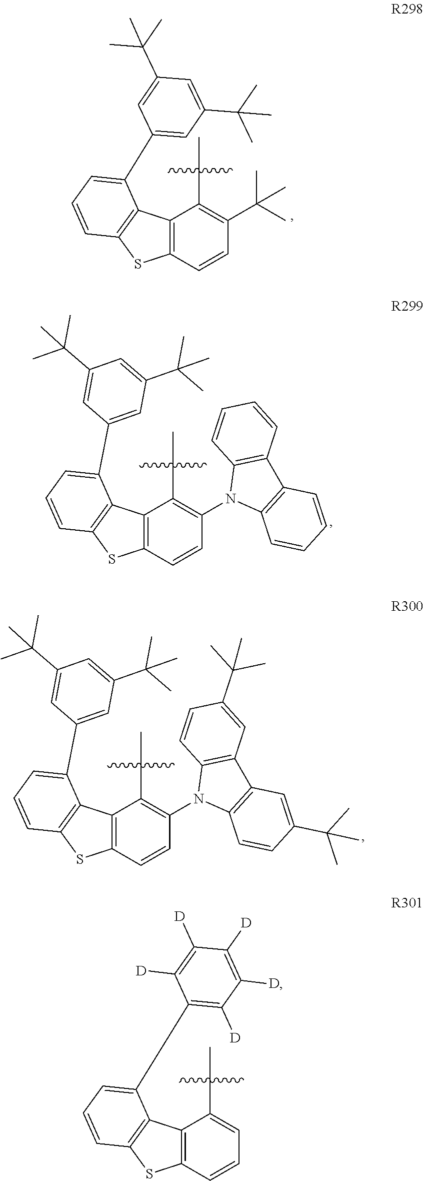 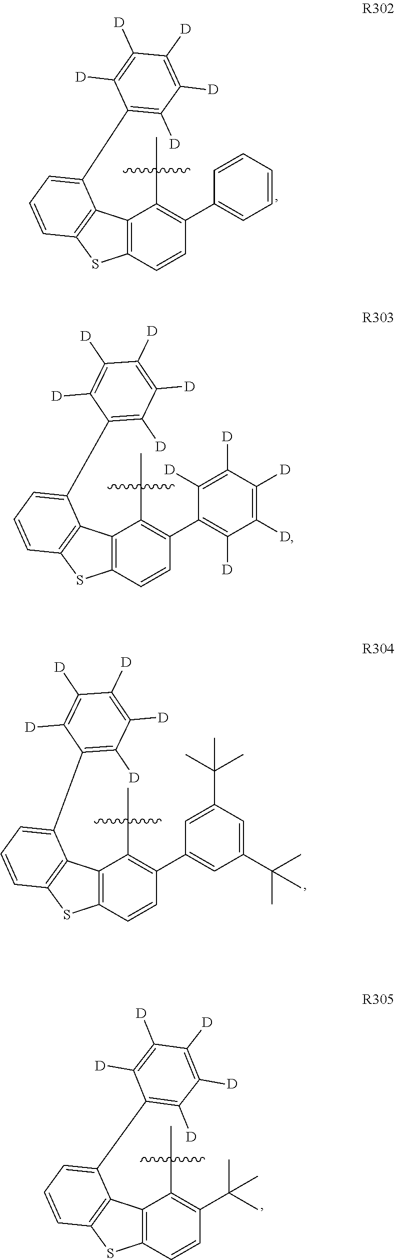 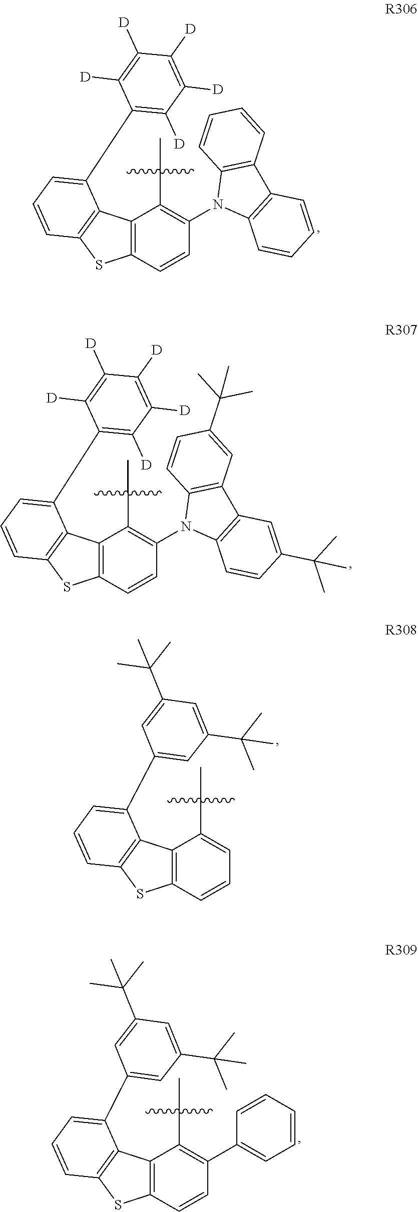 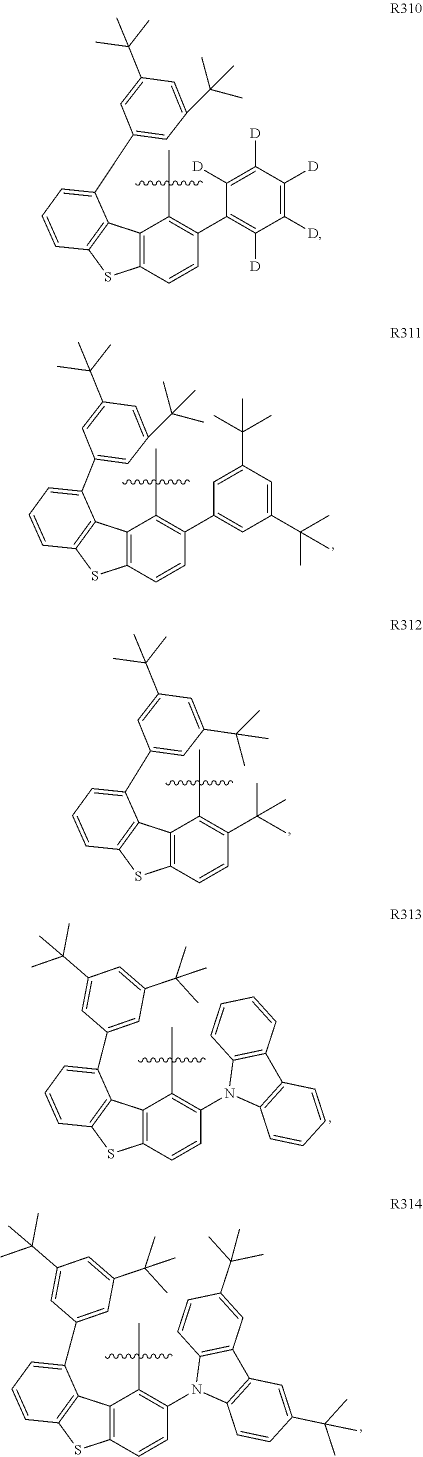 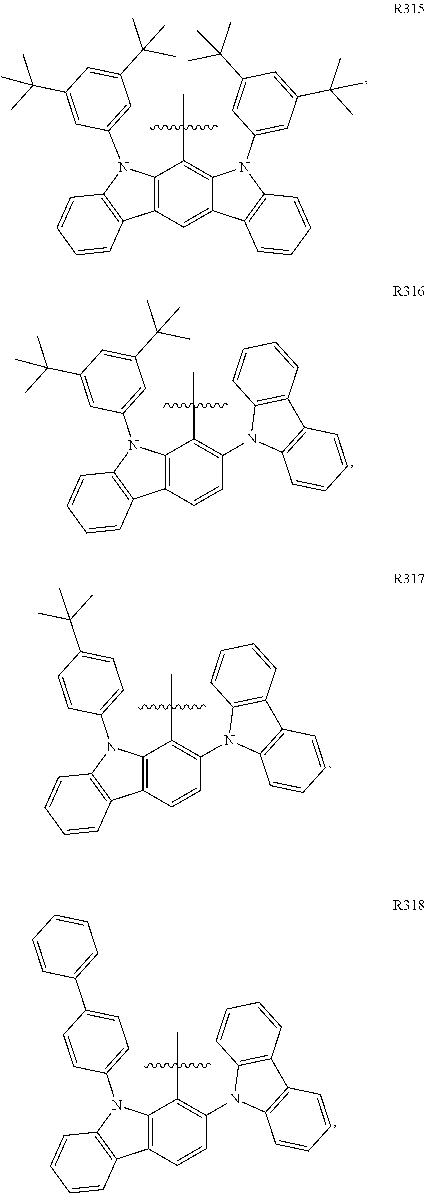 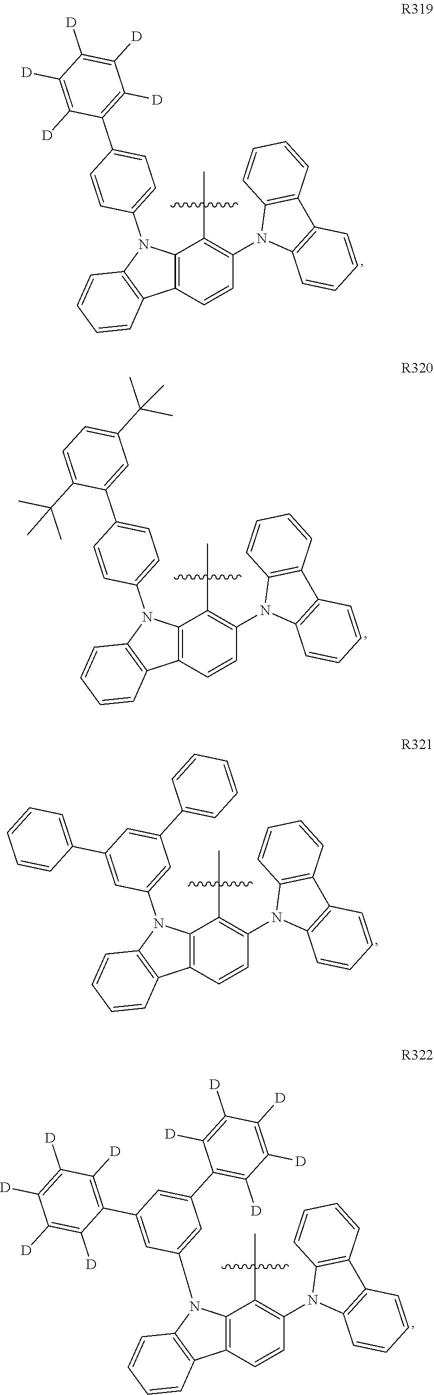 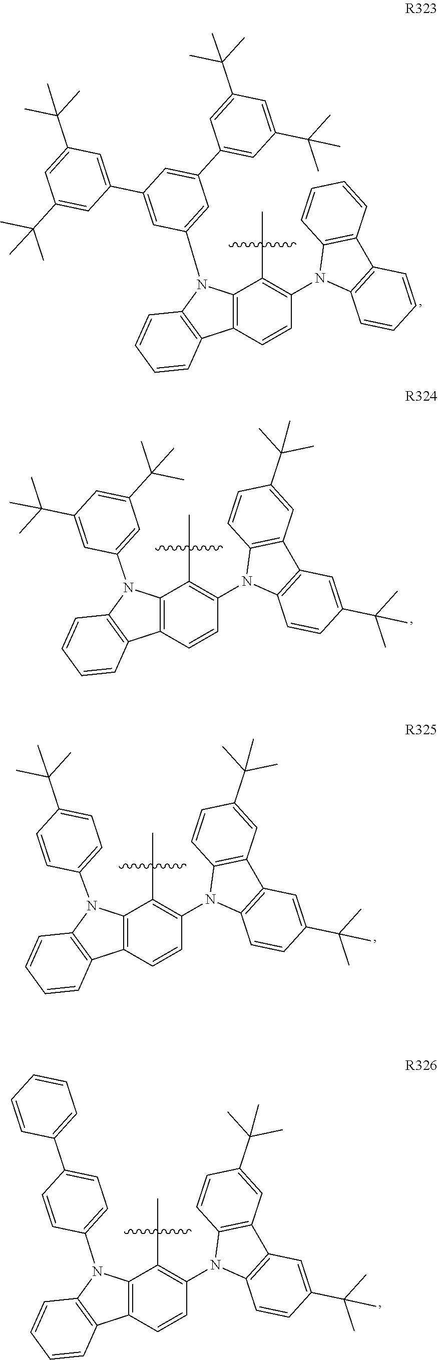 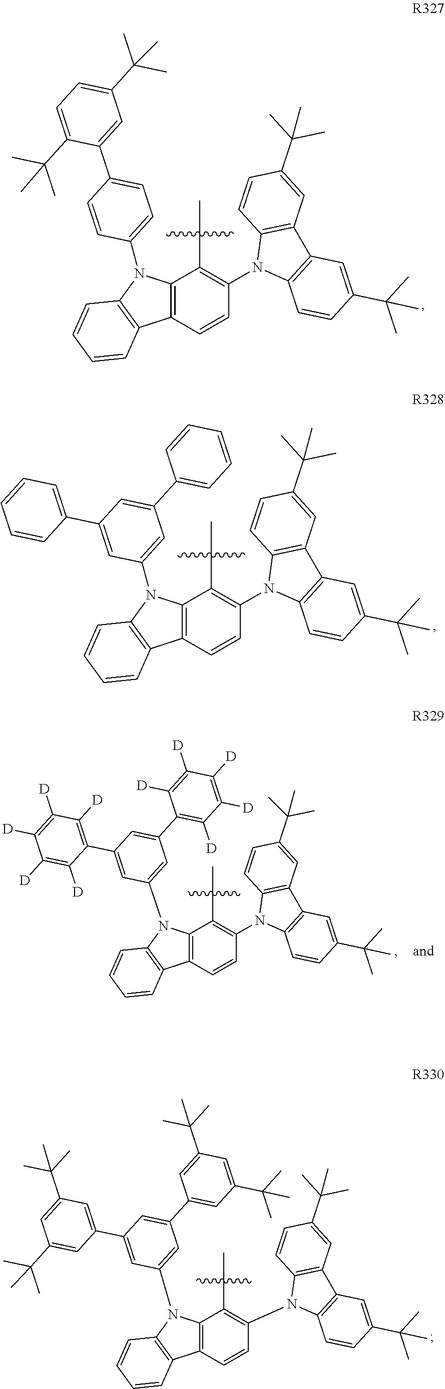
wherein L_{A} and L_{C} independently have the structures structures defined in the table below:

| | Structure | i, j, k, m, n, o |
|---|---|---|
| where L_{A} is I-(A′i)(Bj)(Bk) and L_{C} is I-(A′m)(Bn)(Bo) having the structure | 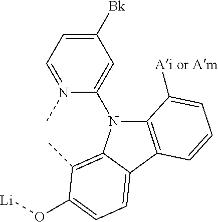 | wherein i is an integer from 1 to 7 and k is an integer from 1 to 47, and when i = 1 to 3, j is an integer from 1 to 41, and when i = 4 to 7, j is an integer from 1 to 47; wherein m is an integer from 1 to 7 and o is an integer from 1 to 47, and when m = 1 to 3, n is an integer from 1 to 41, and when m = 4 to 7, n is an integer from 1 to 47; wherein L_{A} and L_{C} are independently selected from the group consisting of I- (A′1)(B1)(B1) to I-(A′3)(B41)(B47), and I-(A′4)(B1)(B1) to I-(A′7)(B47)(B47), |
| where L_{A} is II- (A′i)(Bj)(Bk) and L_{C} is II (A′m)(Bn)(Bo) having the structure | 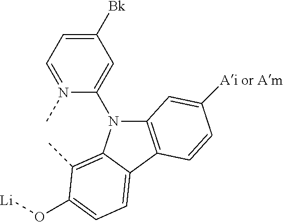 | wherein i is an integer from 1 to 7 and k is an integer from 1 to 47; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of II-(A′1)(B1)(B1) to II- (A′3)(B41)(B47), and II-(A′4)(B1)(B1) to II-(A′7)(B47)(B47), |
| where L_{A} is III- (A′i)(Bj)(Bk) and L_{C} is III- (A′m)(Bn)(Bo), having the structure | 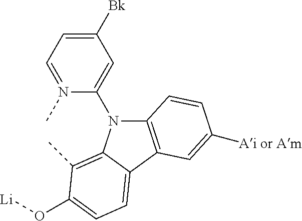 | wherein i is an integer from 1 to 7 and k is an integer from 1 to 47; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of III-(A′1)(B1)(B1) to III- (A′3)(B41)(B47), and III-(A′4)(B1)(B1) to III-(A′7)(B47)(B47), |
| where L_{A} is IV- (A′i)(Bj)(Bk) and L_{C} is IV- (A′m)(Bn)(Bo), having the structure | 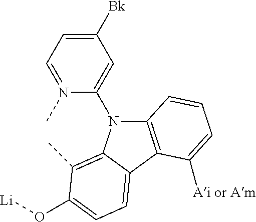 | wherein i is an integer from 1 to 7 and k is an integer from 1 to 47; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of IV-(A′1)(B1)(B1) to IV- (A′3)(B41)(B47), and IV-(A′4)(B1)(B1) to IV-(A′7)(B47)(B47), |
| where L_{A} is V- (A′i)(Bj)(Bk) and L_{C} is V- (A′m)(Bn)(Bo), having the structure | 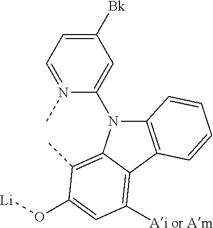 | wherein i is an integer from 1 to 7 and k is an integer from 1 to 47; when i or m = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of V-(A′1)(B1)(B1) to V- (A′3)(B41)(B47), and V-(A′4)(B1)(B1) to V-(A′7)(B47)(B47), |
| where L_{A} is VI- (A′i)(Bj)(Bk) and L_{C} is VI- (A′m)(Bn)(Bo), having the structure | 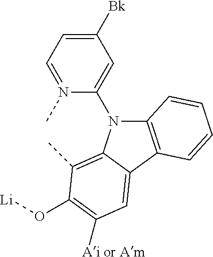 | wherein i is an integer from 1 to 7 and k is an integer from 1 to 47; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of VI-(A′1)(B1)(B1) to VI- (A′3)(B41)(B47), and VI-(A′4)(B1)(B1) to VI-(A′7)(B47)(B47), |
| where L_{A} is VII-(A′i)(Bj) and L_{C} is VII-(A′m)(Bn), having the structure | 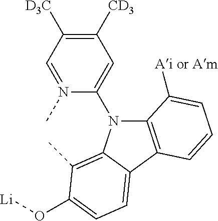 | wherein i is an integer from 1 to 7; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of VII-(A′1)(B1)(B1) to VII- (A′3)(B41)(B47), and VII-(A′4)(B1)(B1) to VII-(A′7)(B47)(B47), |
| where L_{A} is VIII-(A′i)(Bj) and L_{C} is VIII-(A′m)(Bn), having the structure | 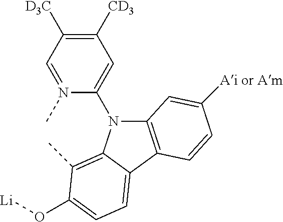 | wherein i is an integer from 1 to 7; when i = 1 to 3, j is an integer from 1 to 41 and when i or m = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of VII-(A′1)(B1)(B1) to VII- (A′3)(B41)(B47), and VII-(A′4)(B1)(B1) to VII-(A′7)(B47)(B47), |
| where L_{A} is IX-(A′i)(Bj) and L_{C} is IX-(A′m)(Bn), having the structure | 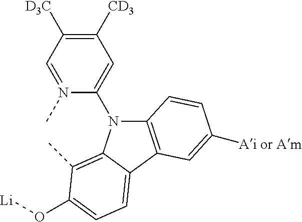 | wherein i is an integer from 1 to 7; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of IX-(A′1)(B1)(B1) to IX- (A′3)(B41)(B47), and IX-(A′4)(B1)(B1) to IX-(A′7)(B47)(B47), |
| where L_{A} is X-(A′i)(Bj) and L_{C} is X-(A′m)(Bn), having the structure | 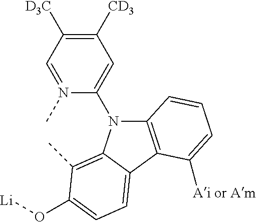 | wherein i is an integer from 1 to 7; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of X-(A′1)(B1)(B1) to X- (A′3)(B41)(B47), and X-(A′4)(B1)(B1) to X-(A′7)(B47)(B47), |
| where L_{A} is XI-(A′i)(Bj) and L_{C} is XI-(A′m)(Bn), having the structure | 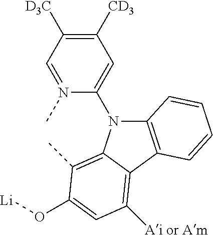 | wherein i is an integer from 1 to 7; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of XI-(A′1)(B1)(B1) to XI- (A′3)(B41)(B47), and XI-(A′4)(B1)(B1) to XI-(A′7)(B47)(B47), |
| where L_{A} is XII-(A′i)(Bj) and L_{C} is XII-(A′m)(Bn), having the structure | 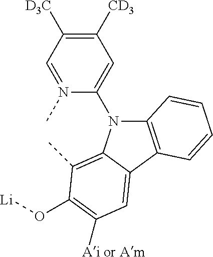 | wherein i is an integer from 1 to 7; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of XII-(A′1)(B1)(B1) to XII- (A′3)(B41)(B47), and XII-(A′4)(B1)(B1) to XI-(A′7)(B47)(B47), |
| where L_{A} is XIII- (A′i)(Bj)(Bk) and L_{C} is XIII-(A′m)(Bn)(Bo), having the structure | 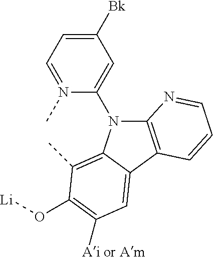 | wherein i is an integer from 1 to 7 and k is an integer from 1 to 47; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of XIII-(A′1)(B1)(B1) to XIII- (A′3)(B41)(B47), and XIII-(A′4)(B1)(B1) to XI-(A′7)(B47)(B47), |
| where L_{A} is XIV- (A′)(Bj)(Bk) and L_{C} is XIV-(A′m)(Bn)(Bo), having the structure | 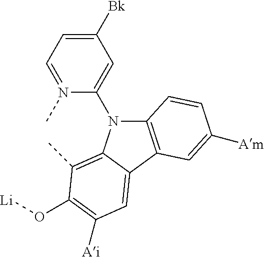 | wherein i is an integer from 1 to 7 and k is an integer from 1 to 47; when i = 1 to 3, j is an integer from 1 to 41 and when i = 4 to 7, j is an integer from 1 to 47, and when m = 1 to 3, n is an integer from to 4, and when m = 4 to 7, n is an integer from 1 to 47; wherein L_{A} and L_{C} are independently selected from the group consisting of XII-(A′1)(B1)(B1) to XII- (A′3)(B41)(B47), and XII-(A′4)(B1)(B1) to XI-(A′7)(B47)(B47), |

wherein A′1 to A′7 have the following structures: 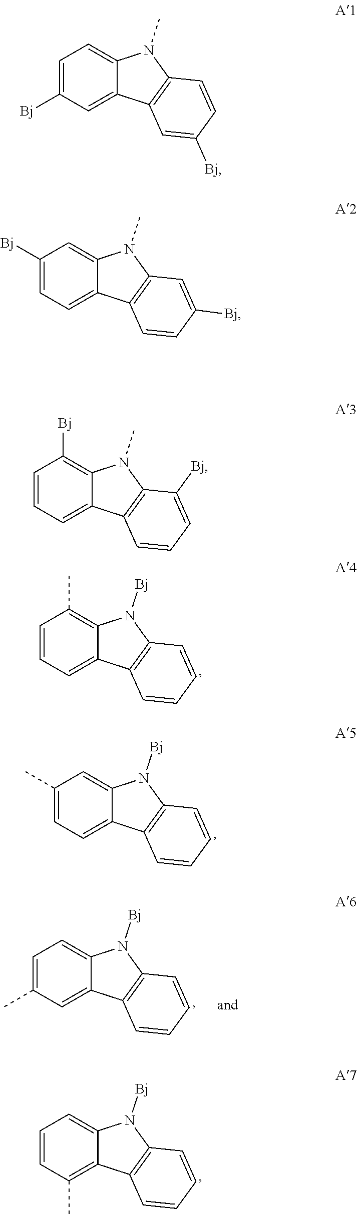
wherein B1 to B47 have the following structures:

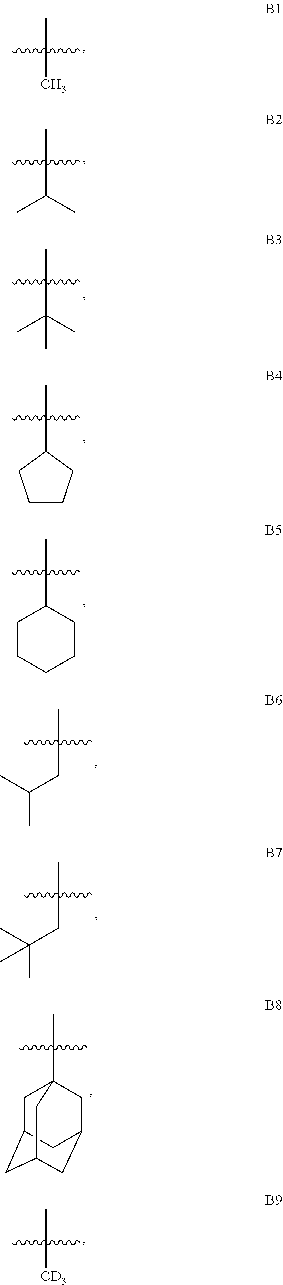

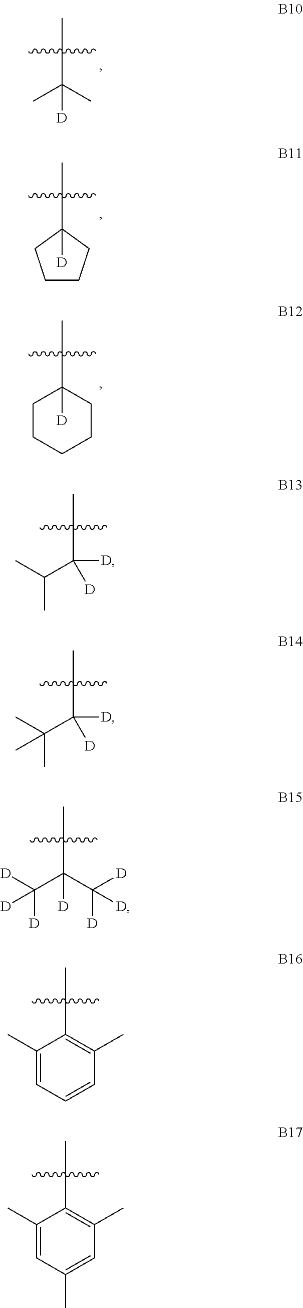

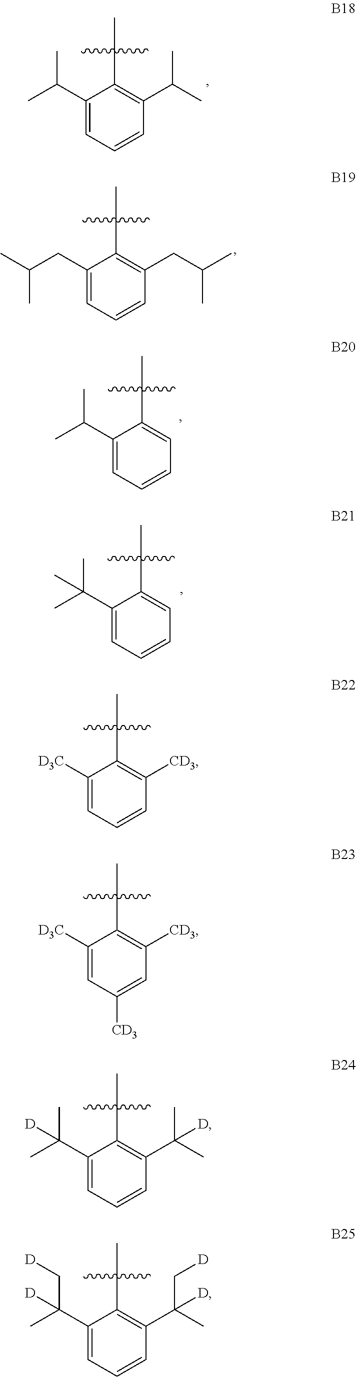

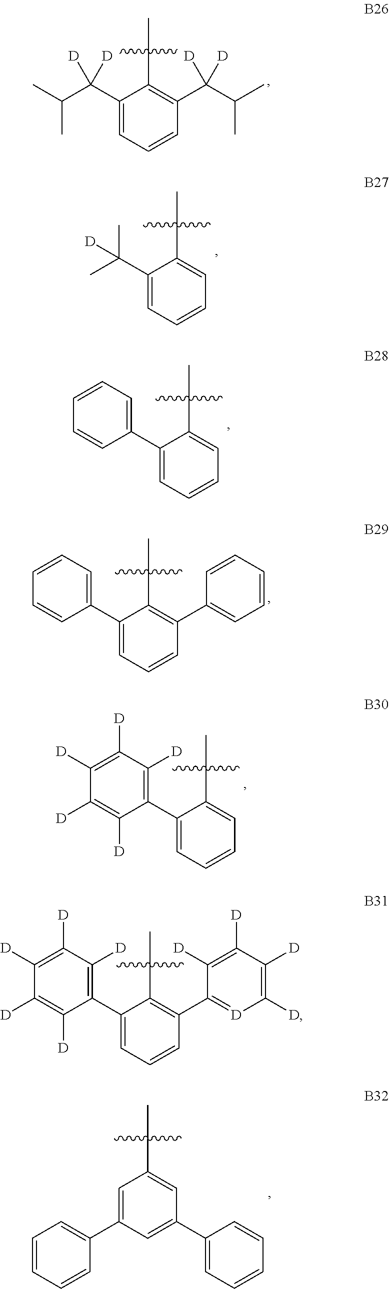

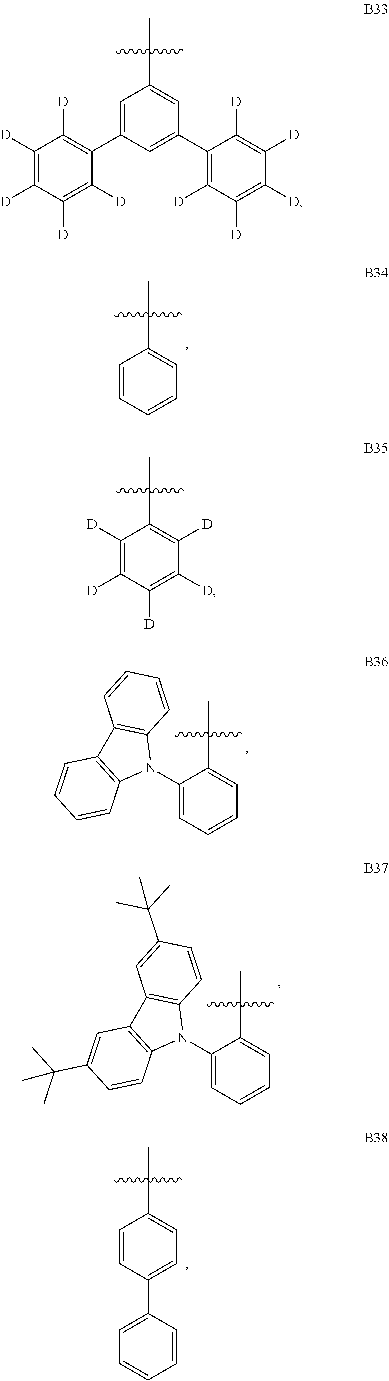

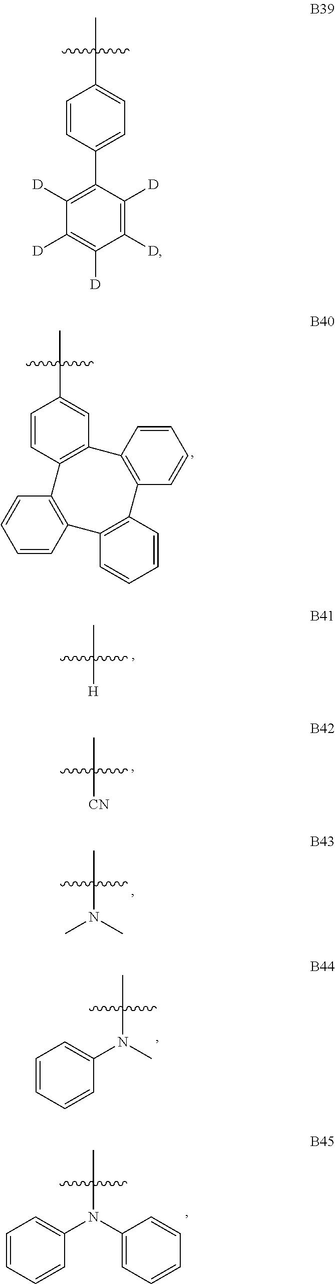

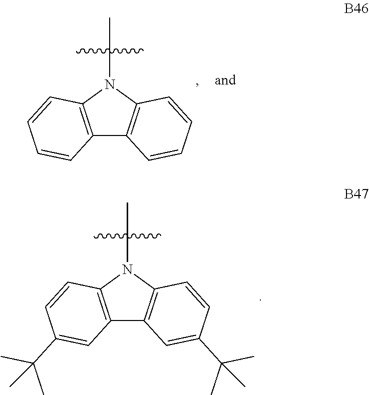 [SMILES: *n1c2ccccc2c2ccccc21 ; *n1c2ccc(C(C)(C)C)cc2c2cc(C(C)(C)C)ccc21]

15. The compound of claim 1, wherein the compound is selected from the group consisting of

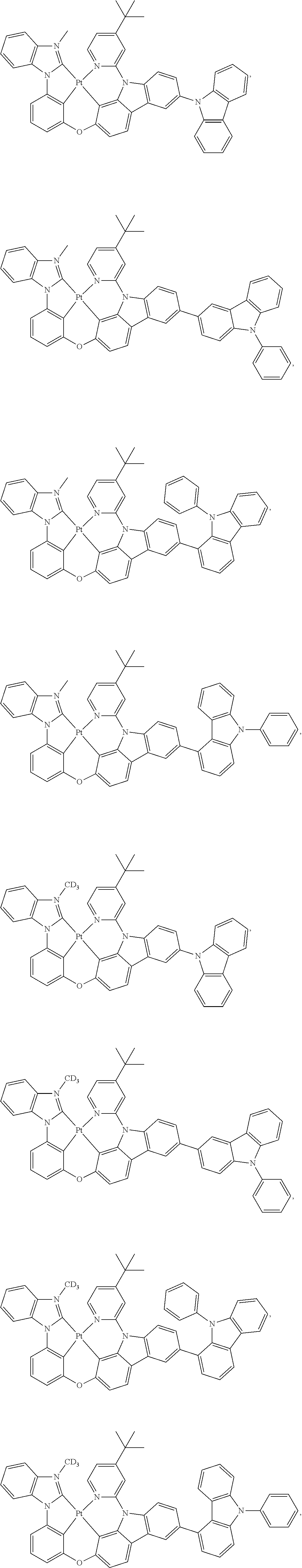

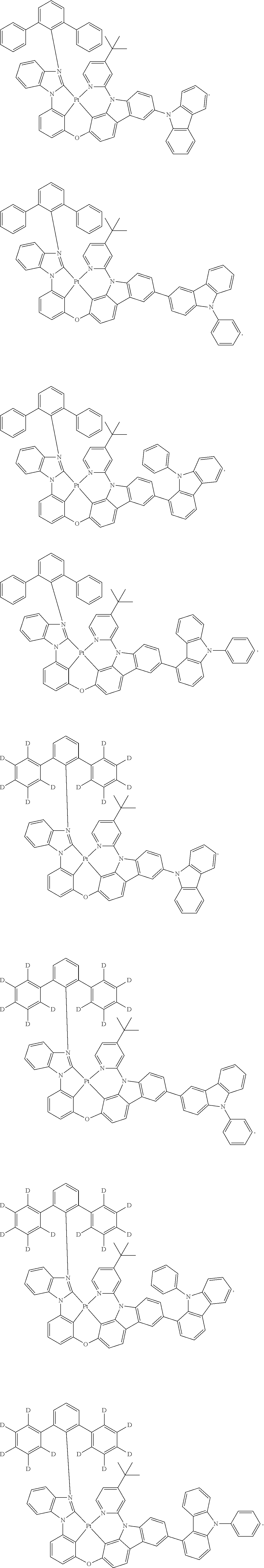

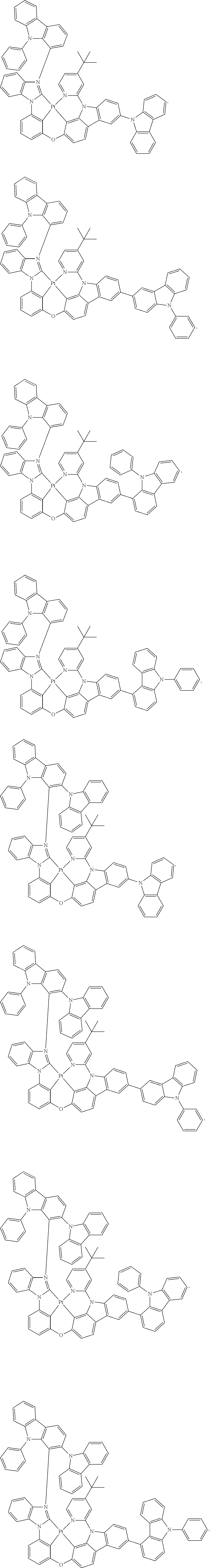

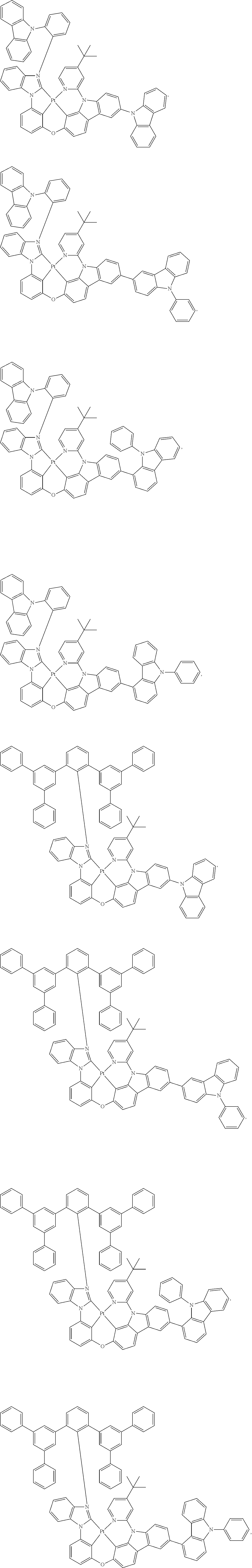

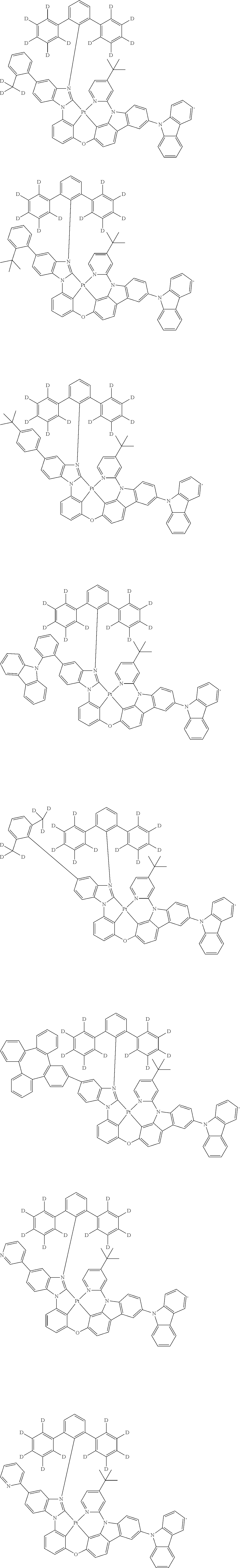

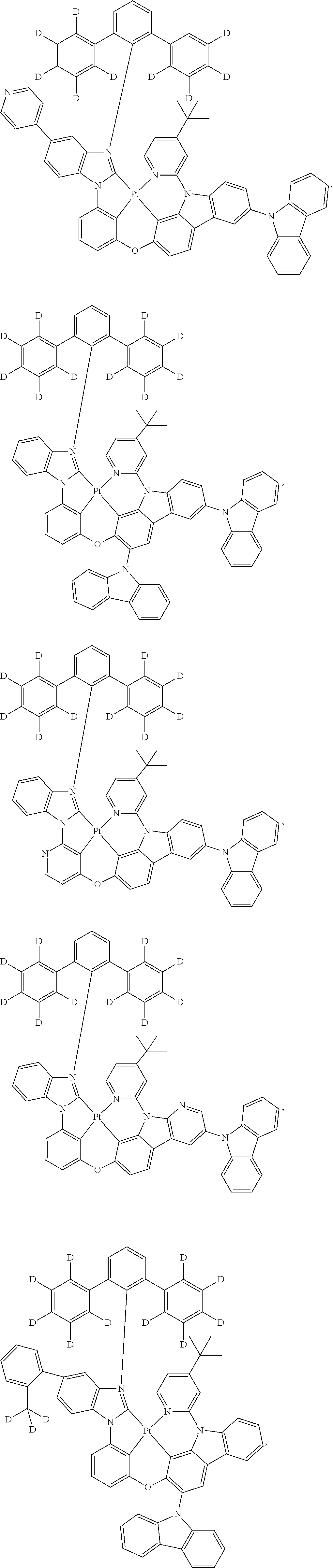

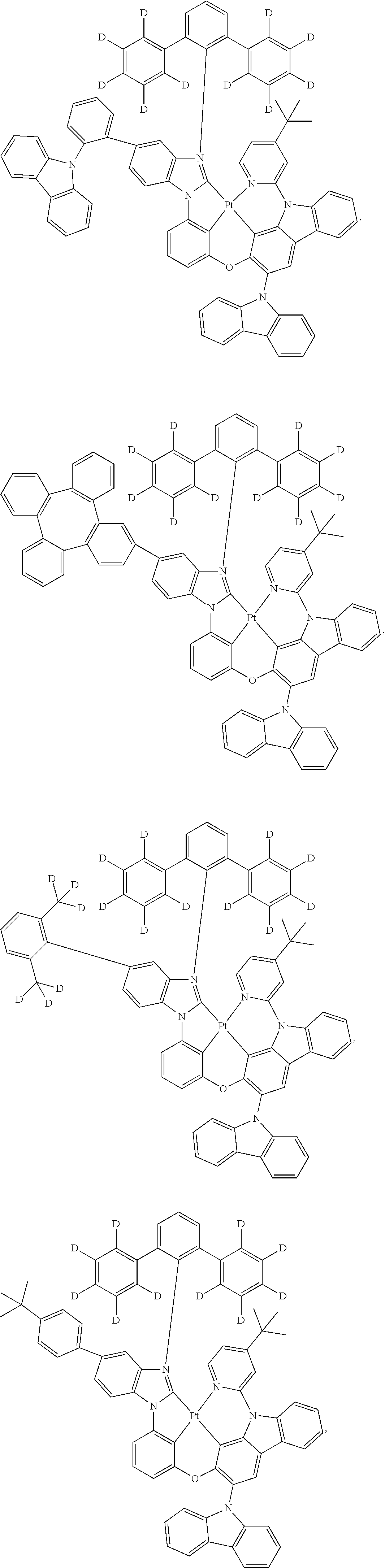

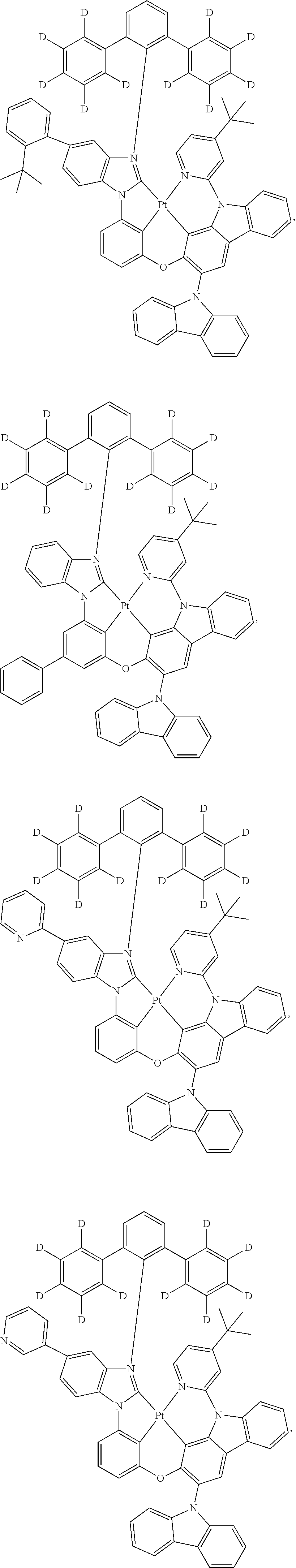

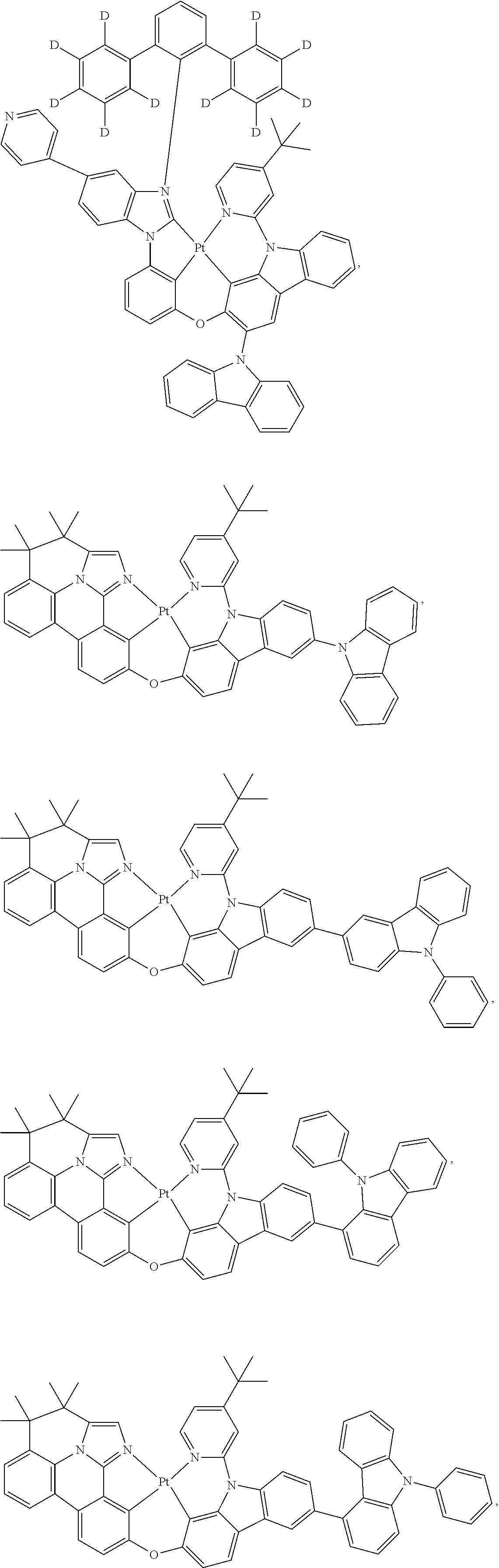

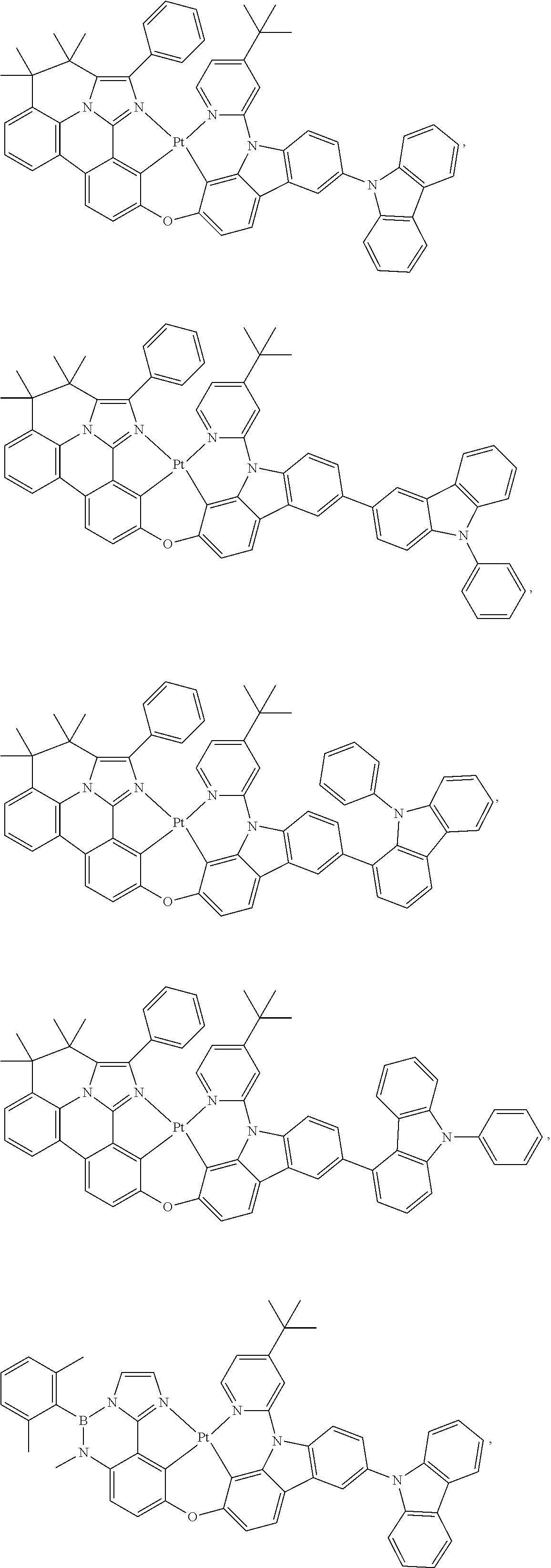

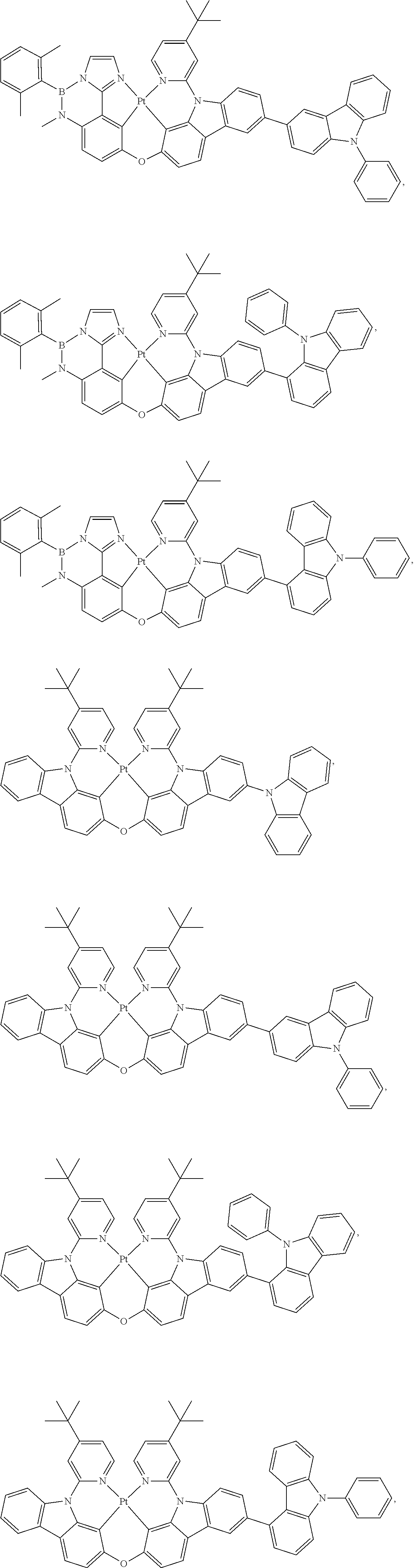

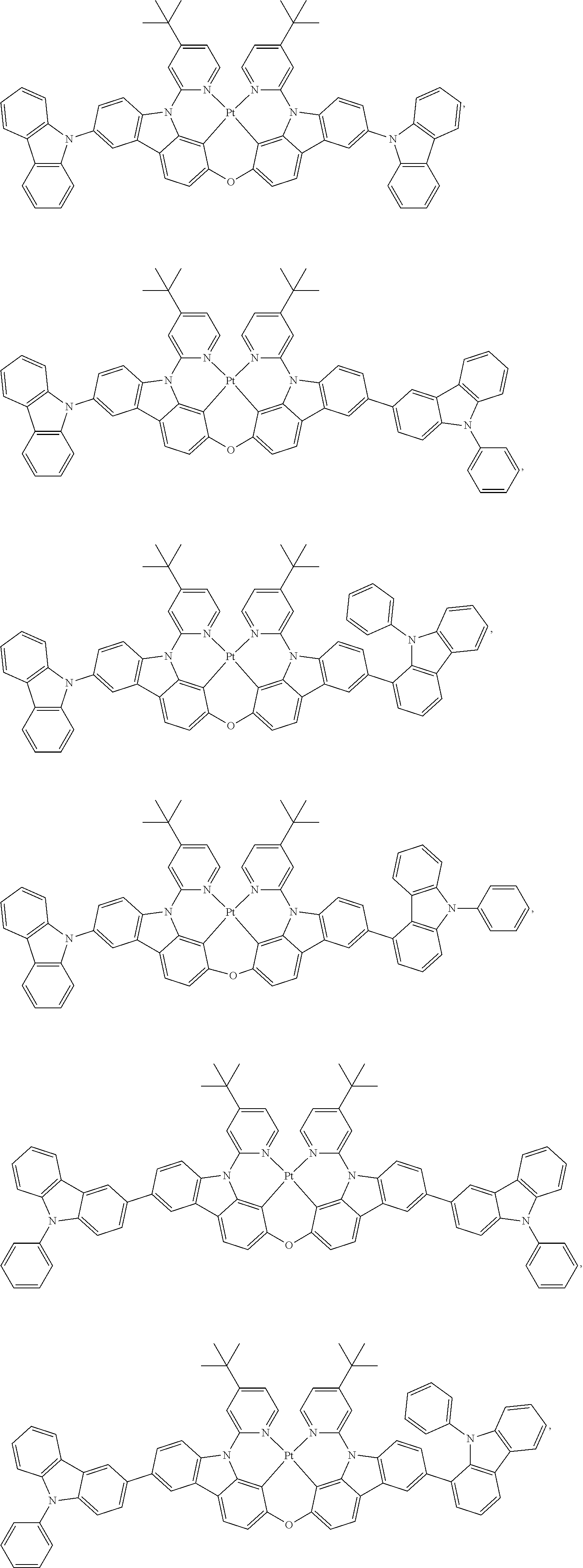

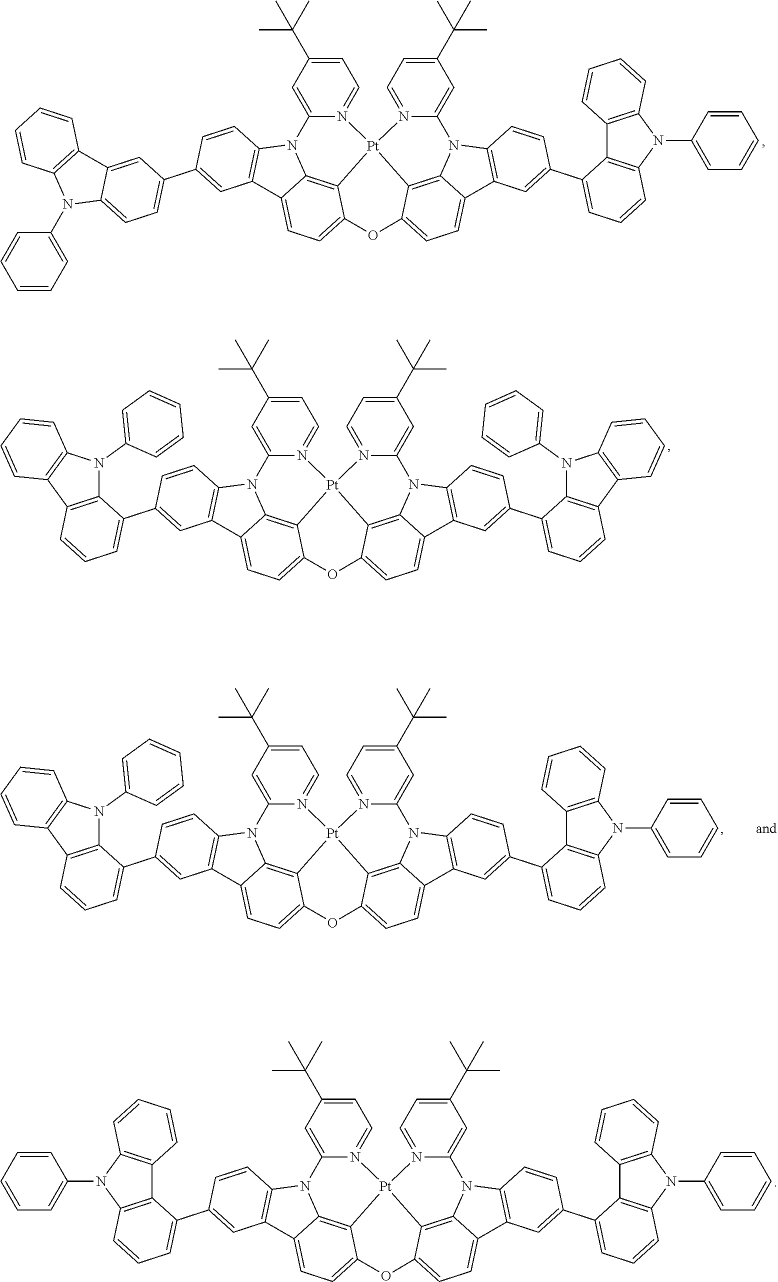

16. An organic light emitting device (OLED) comprising:
an anode;
a cathode; and
an organic layer disposed between the anode and the cathode,
wherein the organic layer comprises a compound having a structure of Formula VI 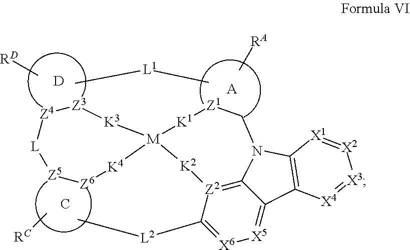
wherein:
rings A, C, and D are each independently a 5-membered or 6-membered carbocyclic or heterocyclic ring;
ring D is not pyrazole;
each of X¹—X⁶ is independently N or CR;
Z¹, Z², Z³, Z⁴, Z⁵, and Z⁶ are each independently C or N;
one of Z¹ and Z² is C and the other is N;
each of K¹, K², K³ or K⁴ is independently a direct bond, S, or O, with at least two of them being direct bonds;
L, L¹, and L² are each independently selected from the group consisting of a direct bond, being absent, O, S, CR″R″′, SiR″R″′, BR″, and NR″, wherein at least one of L¹ and L² is present;
R^{A}, R^{C}, and R^{D} each independently represent zero, mono, or up to the maximum allowed number of substitutions to its associated ring;
at least one of R or R^{A} has a structure of 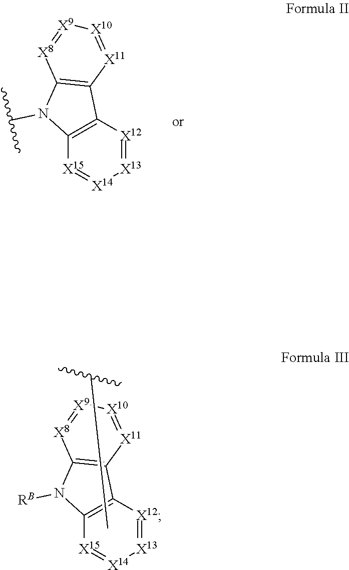
wherein: each of X⁸—X¹⁵ is independently N or CR′, the particular one of X⁸—X¹⁵ that is bonded to one of X¹—X⁶ or ring A of Formula VI is C;
the maximum number of N atoms that can connect to each other within a ring is two;
each of the remaining R and R^{A} is independently a hydrogen, Formula II, Formula III, or a substituent selected from the group consisting of deuterium, halogen, alkyl, cycloalkyl, heteroalkyl, heterocycloalkyl, arylalkyl, alkoxy, aryloxy, amino, silyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
each of R′ and R^{B} is independently a hydrogen, or a substituent selected from the group consisting of deuterium, halogen, alkyl, cycloalkyl, heteroalkyl, heterocycloalkyl, arylalkyl, alkoxy, aryloxy, amino, silyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
each of R″, R″′, R^{C}, and R^{D} is independently a hydrogen or a substituent selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, sulfanyl, and combinations thereof;
M is Pd or Pt; and
any two adjacent R, R′, R″, R″′, R^{A}, R^{B}, R^{C}, or R^{D} can be joined or fused together to form a ring where chemically feasible.

17. The OLED of claim 16, wherein the organic layer further comprises a host, wherein the host comprises at least one chemical moiety selected from the group consisting of triphenylene, carbazole, indolocarbazole, dibenzothiophene, dibenzofuran, dibenzoselenophene, 5,9-dioxa-13b-boranaphtho[3,2,1-de]anthracene, aza-triphenylene, aza-carbazole, aza-indolocarbazole, aza-dibenzothiophene, aza-dibenzofuran, aza-dibenzoselenophene, and aza-(5,9-dioxa-13b-boranaphtho[3,2,1-de]anthracene).

18. The OLED of claim 16, wherein the organic layer further comprises a host, wherein the host is selected from the group consisting of: 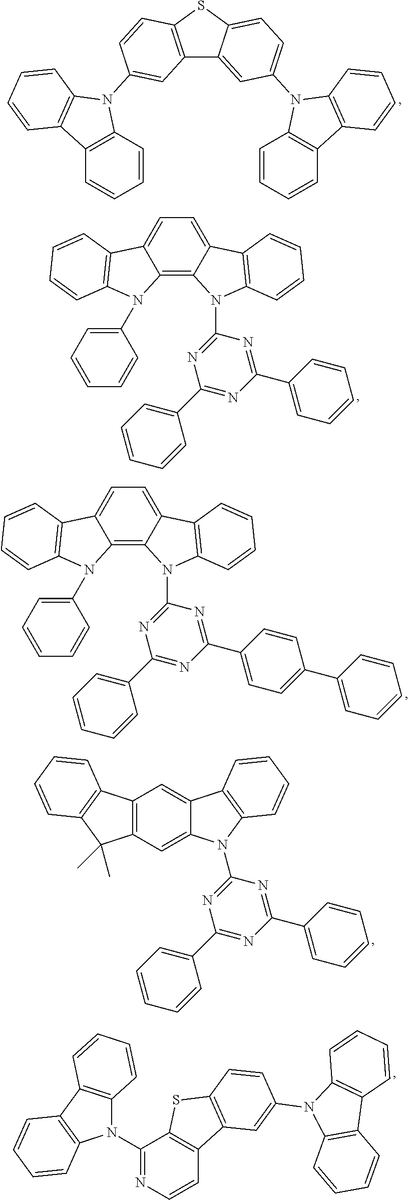 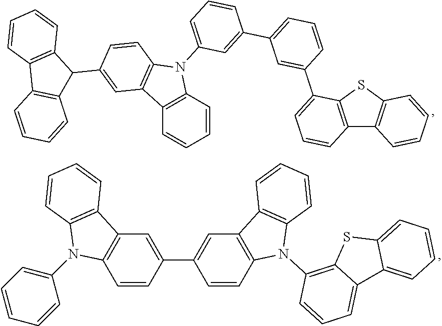 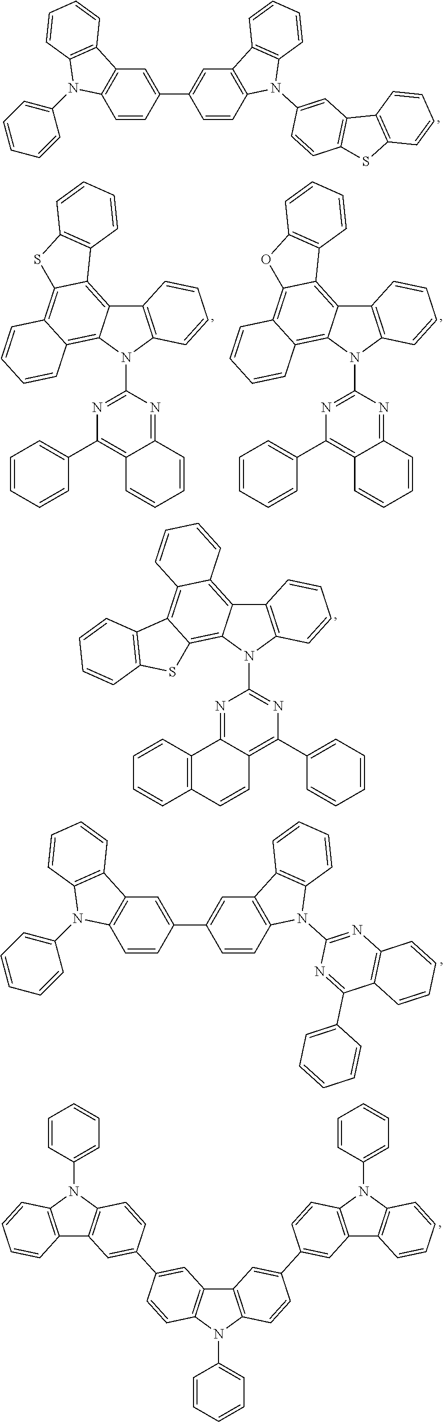 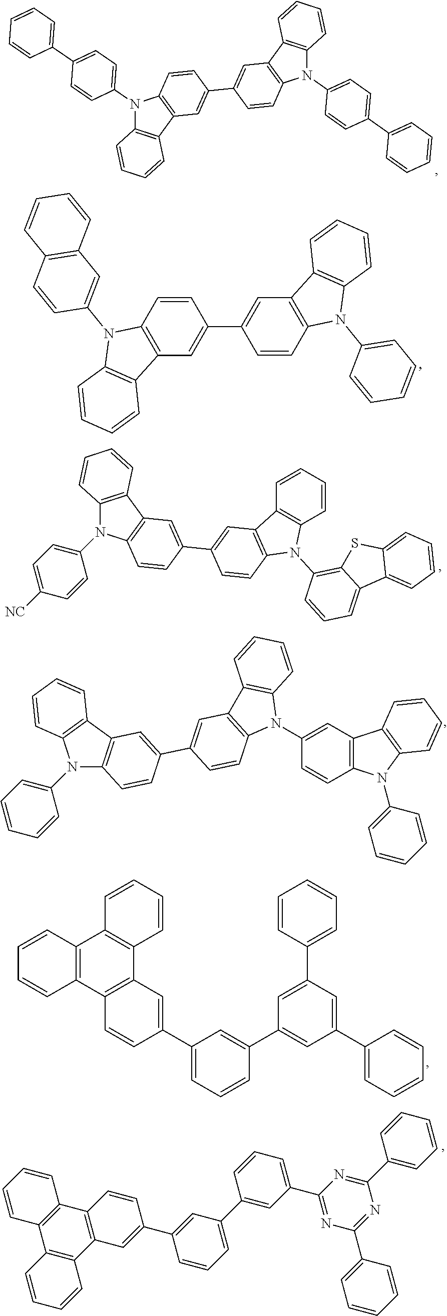 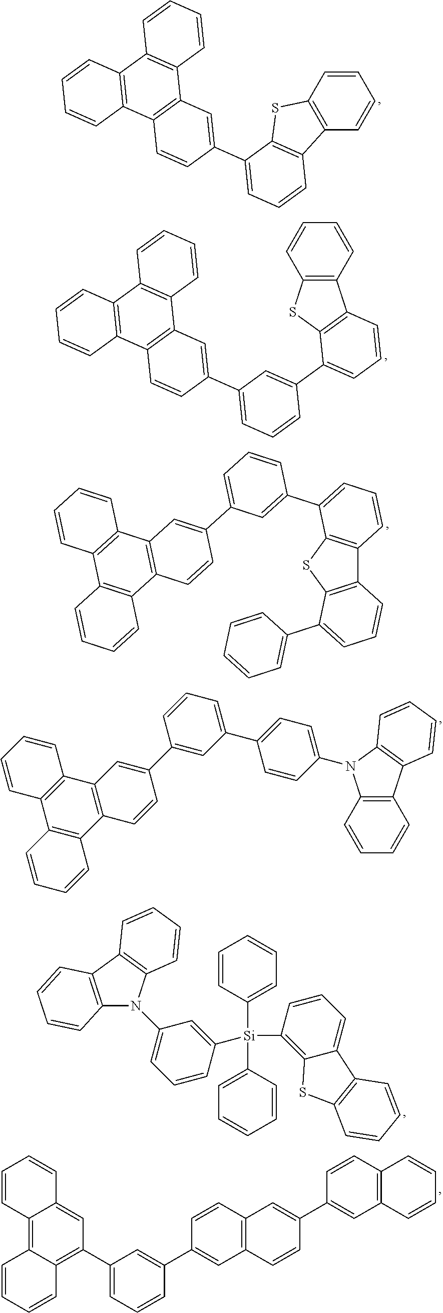 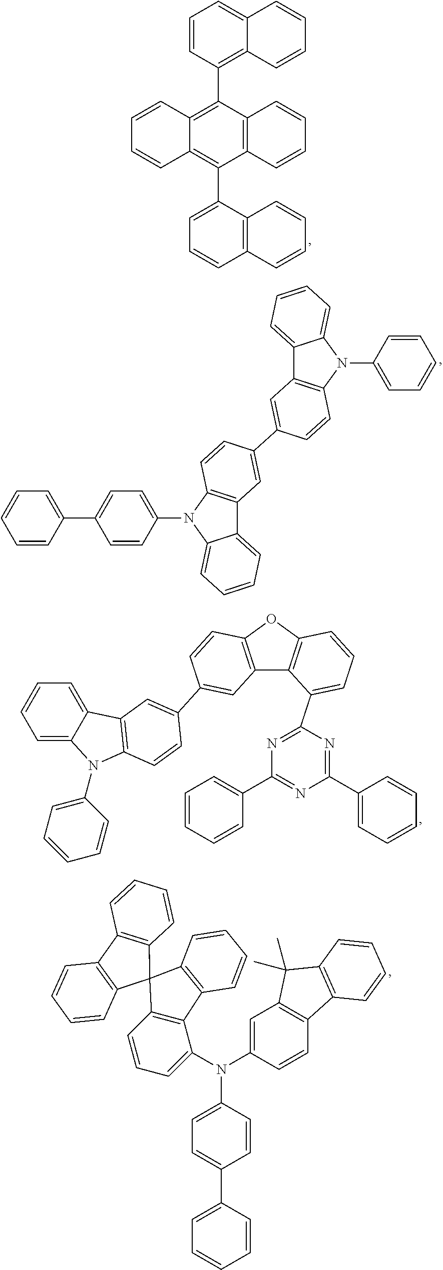 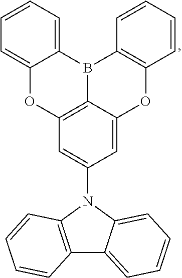 [SMILES: c1ccc2c(c1)Oc1cc(-n3c4ccccc4c4ccccc43)cc3c1B2c1ccccc1O3]
and combinations thereof.

19. A consumer product comprising an organic light-emitting device (OLED) comprising:
an anode;
a cathode; and
an organic layer disposed between the anode and the cathode,
wherein the organic layer comprises a compound having a structure of Formula VI 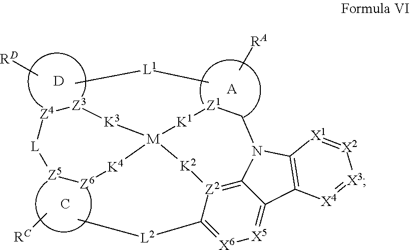
wherein:
rings A, C, and D are each independently a 5-membered or 6-membered carbocyclic or heterocyclic ring;
ring D is not pyrazole;
each of X¹—X⁶ is independently N or CR;
Z¹, Z², Z³, Z⁴, Z⁵, and Z⁶ are each independently C or N;
one of Z¹ and Z² is C and the other is N;
each of K¹, K², K³ or K⁴ is independently a direct bond, S, or O, with at least two of them being direct bonds;
L, L¹, and L² are each independently selected from the group consisting of a direct bond, being absent, O, S, CR″R″′, SiR″R″′, BR″, and NR″, wherein at least one of L¹ and L² is present;
R^{A}, R^{C}, and R^{D} each independently represent zero, mono, or up to the maximum allowed number of substitutions to its associated ring;
at least one of R or R^{A} has a structure of 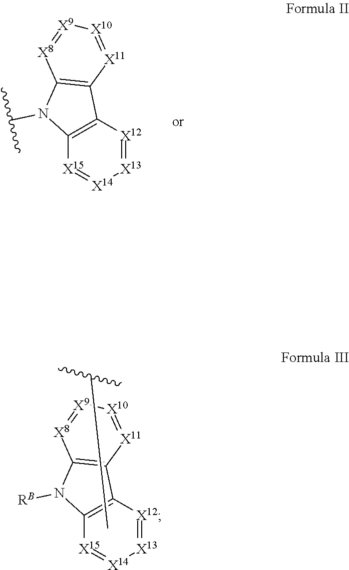
wherein: each of X⁸—X¹⁵ is independently N or CR′, the particular one of X⁸—X¹⁵ that is bonded to one of X¹—X⁶ or ring A of Formula VI is C;
the maximum number of N atoms that can connect to each other within a ring is two;
each of the remaining R and R^{A} is independently a hydrogen, Formula II, Formula III, or a substituent selected from the group consisting of deuterium, halogen, alkyl, cycloalkyl, heteroalkyl, heterocycloalkyl, arylalkyl, alkoxy, aryloxy, amino, silyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
each of R′ and R^{B} is independently a hydrogen, or a substituent selected from the group consisting of deuterium, halogen, alkyl, cycloalkyl, heteroalkyl, heterocycloalkyl, arylalkyl, alkoxy, aryloxy, amino, silyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
each of R″, R″′, R^{C}, and R^{D} is independently a hydrogen or a substituent selected from the group consisting of deuterium, fluorine, alkyl, cycloalkyl, heteroalkyl, alkoxy, aryloxy, amino, silyl, boryl, alkenyl, cycloalkenyl, heteroalkenyl, aryl, heteroaryl, nitrile, isonitrile, sulfanyl, and combinations thereof;
M is Pd or Pt; and
any two adjacent R, R′, R″, R″′, R^{A}, R^{B}, R^{C}, or R^{D} can be joined or fused together to form a ring where chemically feasible.

20. A formulation comprising a compound according to claim 1.
